(19) United States
(12) Patent Application Publication
(10) Pub. No.: US 2025/0250483 A1
(43) Pub. Date: Aug. 7, 2025

(54) ORGANOMETALLIC COMPLEX AND LIGHT-EMITTING DEVICE

(71) Applicant: SEMICONDUCTOR ENERGY LABORATORY CO., LTD., Atsugi-shi (JP)

(72) Inventors: Keito TOSU, Atsugi (JP); Yui YOSHIYASU, Atsugi (JP); Hiromitsu KIDO, Atsugi (JP); Nobuharu OHSAWA, Zama (JP); Hideko YOSHIZUMI, Atsugi (JP)

(21) Appl. No.: 19/033,732

(22) Filed: Jan. 22, 2025

(30) Foreign Application Priority Data
Feb. 2, 2024 (JP) 2024-015113

(51) Int. Cl. C09K 11/06; C07F 15/00; H10K 50/12; H10K 85/30

(52) U.S. Cl. CPC C09K 11/06; C07F 15/0033; H10K 85/342; C07B 2200/05; C09K 2211/1007; C09K 2211/1029; C09K 2211/1033; C09K 2211/185; H10K 50/12

(57) ABSTRACT

A novel organometallic complex is provided. The organometallic complex is represented by General Formula (G1). In the organometallic complex represented by General Formula (G1), each of R¹, R¹³, and R¹⁴ independently represents an alkyl group that has 1 to 6 carbon atoms and includes deuterium, each of R² to R¹² independently represents hydrogen (including deuterium) or an alkyl group that has 1 to 6 carbon atoms and includes deuterium, each of R¹⁵ to R²¹ independently represents hydrogen (including deuterium), and n represents 1 or 2.

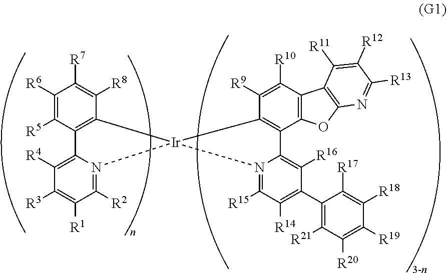

### BACKGROUND OF THE INVENTION

### 1. Field of the Invention

One embodiment of the present invention relates to an organometallic complex, an organic compound, a light-emitting device, a light-receiving device, a light-emitting and light-receiving device, a light-emitting apparatus, a light-emitting and light-receiving apparatus, a display apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display apparatus, a liquid crystal display apparatus, a light-emitting apparatus, a lighting device, a power storage device, a memory device, an image capturing device, a driving method thereof, and a manufacturing method thereof.

### 2. Description of the Related Art

Organic electroluminescence (EL) devices (organic EL elements) typified by light-emitting devices, light-receiving devices, and light-emitting and light-receiving devices, which utilize EL with an organic compound, are being put to practical use.

In the basic structure of the light-emitting devices, for example, an organic compound layer containing a light-emitting material (also referred to as an EL layer) is located between a pair of electrodes. Carriers are injected by application of voltage to the device, and recombination energy of the carriers is used, whereby light emission can be obtained from the light-emitting material.

In the basic structure of the light-receiving devices, an organic compound layer containing a photoelectric conversion material (an active layer) is located between a pair of electrodes. This device absorbs light energy to generate carriers, whereby electrons from the photoelectric conversion material can be obtained.

For example, a functional panel in which a pixel provided in a display region includes a light-emitting element (light-emitting device) and a photoelectric conversion element (light-receiving device) is known (Patent Document 1).

Displays or lighting devices that include organic EL devices can be suitably used for a variety of electronic appliances as described above, and research and development of organic EL devices have progressed for higher efficiency or a longer lifetime.

Although the characteristics of organic EL devices have been improved considerably, advanced requirements for various characteristics including efficiency and durability are not yet satisfied. In particular, to solve a problem such as burn-in, which is an issue peculiar to organic EL devices, it is preferable to inhibit a reduction in efficiency due to deterioration as much as possible.

Deterioration largely depends on a light-emitting material and its surrounding materials; therefore, organic compound materials having good characteristics, such as an organometallic complex, have been actively developed.

### REFERENCES

[Patent Document 1] PCT International Publication No. WO2020/152556

### Non-Patent Document

[Non-Patent Document 1]P. Liehm et al., Applied Physics Letters, 101, 253304 (2012)

### SUMMARY OF THE INVENTION

An object of one embodiment of the present invention is to provide an organometallic complex having high planarity. Another object of one embodiment of the present invention is to provide an organometallic complex that is easily oriented parallel to a substrate. Another object of one embodiment of the present invention is to provide an organometallic complex that is easy to synthesize. Another object of one embodiment of the present invention is to provide a novel organometallic complex. Another object of one embodiment of the present invention is to provide a light-emitting device having high emission efficiency. Another object of one embodiment of the present invention is to provide a novel light-emitting device. Another object of one embodiment of the present invention is to provide a light-emitting apparatus, an electronic appliance, or a lighting device having low power consumption.

Note that the description of these objects does not preclude the presence of other objects. One embodiment of the present invention does not need to achieve all these objects. Other objects will be apparent from and can be derived from the description of the specification, the drawings, claims, and the like.

One embodiment of the present invention is an organometallic complex represented by General Formula (G1).

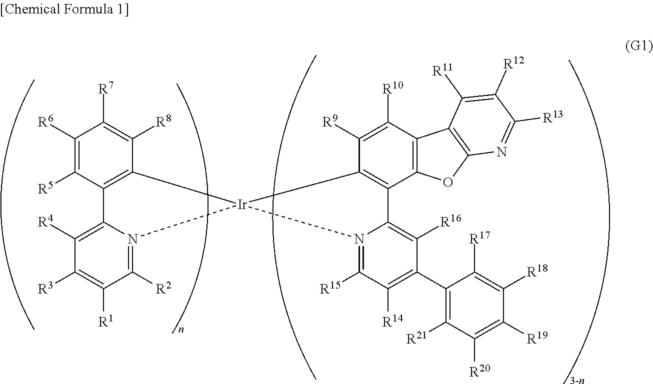

In the organometallic complex represented by General Formula (G1), each of R¹, R¹³, and R¹⁴ independently represents an alkyl group that has 1 to 6 carbon atoms and includes deuterium, each of R² to R¹² independently represents hydrogen (including deuterium) or an alkyl group that has 1 to 6 carbon atoms and includes deuterium, each of R¹⁵ to R²¹ independently represents hydrogen (including deuterium), and n represents 1 or 2.

Another embodiment of the present invention is an organometallic complex represented by General Formula (G2).

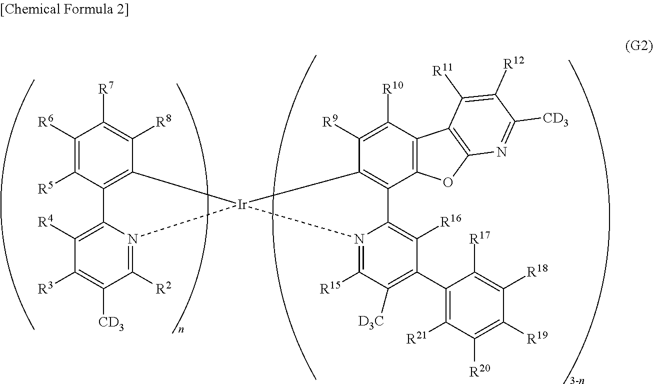

In the organometallic complex represented by General Formula (G2), each of R² to R¹² independently represents hydrogen (including deuterium) or an alkyl group that has 1 to 6 carbon atoms and includes deuterium, each of R¹⁵ to R²¹ independently represents hydrogen (including deuterium), and n represents 1 or 2.

In the organometallic complex having any of the above structures, n is preferably 2.

In the organometallic complex having any of the above structures, when a vector B is defined as a transition dipole moment involved in light emission, the vector B is preferably greater than or equal to 0.5 debye.

A vector A is defined as a vector connecting two most distant atoms in the lowest triplet excited state of the organometallic complex having any of the above structures. A plane A is defined as a plane that includes the vector A and corresponds to the largest area of a quadrilateral surrounding an atomic group that is included in the organometallic complex and projected perpendicularly onto the plane. A plane B is defined as a plane that is perpendicular to the plane A and includes the vector A. A vector B is defined as a transition dipole moment involved in light emission of the organometallic complex. The angle formed between the vector A and a vector B′ obtained by projecting the vector B onto the plane B is less than or equal to 25°. Note that the direction of the vector A is determined such that an angle between the vectors A and B is less than or equal to 90°.

One embodiment of the present invention is an organometallic complex represented by Structural Formula (100) or Structural Formula (101).

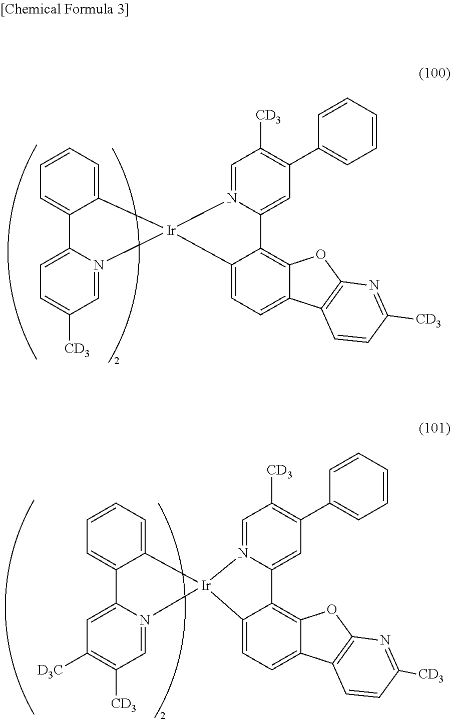

Another embodiment of the present invention is a light-emitting device including the organometallic complex with any of the above structures.

Another embodiment of the present invention is a light-emitting device including an organometallic complex as a light-emitting material in a light-emitting layer. The organometallic complex includes a first ligand and a second ligand. The first ligand includes a benzene ring and a pyridine ring. A carbon at a 2-position of the pyridine ring is bonded to the benzene ring. The second ligand includes a benzofuro[2,3-b]pyridine ring. A molecular orientation parameter a of light emitted from the light-emitting device is less than or equal to 0.28.

Another embodiment of the present invention is a light-emitting device including the organometallic complex having any of the above structures as a light-emitting material in a light-emitting layer in which a molecular orientation parameter a of light emitted from the light-emitting device is less than or equal to 0.28.

One embodiment of the present invention can provide an organometallic complex having high planarity. Another embodiment of the present invention can provide an organometallic complex that is easily oriented parallel to a substrate. Another embodiment of the present invention can provide an organometallic complex that is easy to synthesize. Another embodiment of the present invention can provide a novel organometallic complex. Another embodiment of the present invention can provide a light-emitting device having high emission efficiency. Another embodiment of the present invention can provide a novel light-emitting device. Another embodiment of the present invention can provide a light-emitting apparatus, an electronic appliance, or a lighting device having low power consumption.

Note that the description of these effects does not preclude the existence of other effects. One embodiment of the present invention does not necessarily have all these effects. Other effects will be apparent from and can be derived from the description of the specification, the drawings, claims, and the like.

### BRIEF DESCRIPTION OF THE DRAWINGS

FIGS. 1A and 1B illustrate a structure of a light-emitting device in an embodiment.

FIGS. 2A to 2D schematically illustrate states of molecular orientation.

FIG. 3 shows a relationship between the observation direction of a detector in measuring the spatial distribution of the emission intensity and vector components of a transition dipole moment over a substrate.

FIGS. 4A to 4F each illustrate a structure of a light-emitting device in an embodiment.

FIGS. 5A and 5B are a top view and a cross-sectional view, respectively, of a light-emitting apparatus.

FIGS. 6A to 6D each illustrate a light-emitting device.

FIGS. 7A to 7E are cross-sectional views illustrating an example of a method for manufacturing a light-emitting apparatus.

FIGS. 8A and 8B are cross-sectional views illustrating an example of a method for manufacturing a light-emitting apparatus.

FIGS. 9A to 9D are cross-sectional views illustrating an example of a method for manufacturing a light-emitting apparatus.

FIGS. 10A to 10C are cross-sectional views illustrating an example of a method for manufacturing a light-emitting apparatus.

FIGS. 11A to 11C are cross-sectional views illustrating an example of a method for manufacturing a light-emitting apparatus.

FIGS. 12A to 12C are cross-sectional views illustrating an example of a method for manufacturing a light-emitting apparatus.

FIGS. 13A to 13G are top views each illustrating a structure example of a pixel.

FIGS. 14A to 14I are top views each illustrating a structure example of a pixel.

FIGS. 15A and 15B are perspective views illustrating a structure example of a display module.

FIGS. 16A and 16B are cross-sectional views each illustrating a structure example of a light-emitting apparatus.

FIG. 17 is a perspective view illustrating a structure example of a light-emitting apparatus.

FIG. 18A is a cross-sectional view illustrating a structure example of a light-emitting apparatus. FIGS. 18B and 18C are cross-sectional views each illustrating a structure example of a transistor.

FIG. 19 is a cross-sectional view illustrating a structure example of a light-emitting apparatus.

FIGS. 20A to 20C are a cross-sectional view and top views illustrating a structure example of a light-emitting apparatus.

FIGS. 21A to 21D are cross-sectional views illustrating structure examples of a light-emitting apparatus.

FIGS. 22A to 22C are a cross-sectional view and top views illustrating a structure example of a light-emitting apparatus.

FIGS. 23A to 23D illustrate examples of electronic appliances.

FIGS. 24A to 24F illustrate examples of electronic appliances.

FIGS. 25A to 25G illustrate examples of electronic appliances.

FIG. 26 shows a ¹H-NMR spectrum of Ir(5mppy-d₃)₂(mbfpy5m4ppy-d₆) (Structural Formula (100)).

FIG. 27 shows an absorption spectrum and an emission spectrum of Ir(5mppy-d₃)₂(mbfpy5m4ppy-d₆) (Structural Formula (100)) in a dichloromethane solution.

FIG. 28 shows a ¹H-NMR spectrum of Ir(dmppy-d₆)₂(mbfpy5m4ppy-d₆) (Structural Formula (101)).

FIG. 29 shows an absorption spectrum and an emission spectrum of Ir(dmppy-d₆)₂(mbfpy5m4ppy-d₆) (Structural Formula (101)) in a dichloromethane solution.

FIG. 30A is a schematic view of a device structure of a light-emitting device, and FIG. 30B is a schematic view illustrating a device structure of a light-emitting device for orientation measurement.

FIG. 31 shows the luminance-current density characteristics of a light-emitting device 1 and a comparative light-emitting device 2.

FIG. 32 shows the luminance-voltage characteristics of the light-emitting device 1 and the comparative light-emitting device 2.

FIG. 33 shows the current efficiency-current density characteristics of the light-emitting device 1 and the comparative light-emitting device 2.

FIG. 34 shows the current-voltage characteristics of the light-emitting device 1 and the comparative light-emitting device 2.

FIG. 35 shows the external quantum efficiency-current density characteristics of the light-emitting device 1 and the comparative light-emitting device 2.

FIG. 36 shows electroluminescence spectra of the light-emitting device 1 and the comparative light-emitting device 2.

FIG. 37 shows luminance changes over driving time when the light-emitting device 1 and the comparative light-emitting device 2 are driven at a constant current.

FIG. 38 shows the luminance-current density characteristics of a light-emitting device 3 and a comparative light-emitting device 4.

FIG. 39 shows the luminance-voltage characteristics of the light-emitting device 3 and the comparative light-emitting device 4.

FIG. 40 shows the current efficiency-current density characteristics of the light-emitting device 3 and the comparative light-emitting device 4.

FIG. 41 shows the current-voltage characteristics of the light-emitting device 3 and the comparative light-emitting device 4.

FIG. 42 shows the external quantum efficiency-current density characteristics of the light-emitting device 3 and the comparative light-emitting device 4.

FIG. 43 shows electroluminescence spectra of the light-emitting device 3 and the comparative light-emitting device 4.

FIG. 44 shows luminance changes over driving time when the light-emitting device 3 and the comparative light-emitting device 4 were driven at a constant current.

FIG. 45 shows the luminance-current density characteristics of a light-emitting device 5a and a light-emitting device 5b.

FIG. 46 shows the luminance-voltage characteristics of the light-emitting device 5a and the light-emitting device 5b.

FIG. 47 shows the current efficiency-current density characteristics of the light-emitting device 5a and the light-emitting device 5b.

FIG. 48 shows the current-voltage characteristics of the light-emitting device 5a and the light-emitting device 5b.

FIG. 49 shows the external quantum efficiency-current density characteristics of the light-emitting device 5a and the light-emitting device 5b.

FIG. 50 shows electroluminescence spectra of the light-emitting device 5a and the light-emitting device 5b.

FIG. 51 shows the luminance-current density characteristics of a light-emitting device 6a and a light-emitting device 6b.

FIG. 52 shows the luminance-voltage characteristics of the light-emitting device 6a and the light-emitting device 6b.

FIG. 53 shows the current efficiency-current density characteristics of the light-emitting device 6a and the light-emitting device 6b.

FIG. 54 shows the current-voltage characteristics of the light-emitting device 6a and the light-emitting device 6b.

FIG. 55 shows the external quantum efficiency-current density characteristics of the light-emitting device 6a and the light-emitting device 6b.

FIG. 56 shows electroluminescence spectra of the light-emitting device 6a and the light-emitting device 6b.

FIG. 57 shows the luminance-current density characteristics of a comparative light-emitting device 7a and a comparative light-emitting device 7b.

FIG. 58 shows the luminance-voltage characteristics of the comparative light-emitting device 7a and the comparative light-emitting device 7b.

FIG. 59 shows the current efficiency-current density characteristics of the comparative light-emitting device 7a and the comparative light-emitting device 7b.

FIG. 60 shows the current-voltage characteristics of the comparative light-emitting device 7a and the comparative light-emitting device 7b.

FIG. 61 shows the external quantum efficiency-current density characteristics of the comparative light-emitting device 7a and the comparative light-emitting device 7b.

FIG. 62 shows electroluminescence spectra of the comparative light-emitting device 7a and the comparative light-emitting device 7b.

FIG. 63 illustrates a method for measuring a molecular orientation parameter a.

FIG. 64 is a graph showing the integrated intensity depending on an angle (θ) of the light-emitting device 5a and the angle (θ) of a detector to a substrate.

FIG. 65 is a graph showing the integrated intensity depending on an angle (θ) of the light-emitting device 6a and the angle (θ) of a detector to a substrate.

FIG. 66 is a graph showing the integrated intensity depending on an angle (θ) of the comparative light-emitting device 7a and the angle (θ) of a detector to a substrate.

FIG. 67 illustrates vectors and a formed angle in Ir(5mppy-d₃)₂(mbfpy5m4ppy-d₆) (Structural Formula (100)).

### DETAILED DESCRIPTION OF THE INVENTION

### Embodiment 1

In this embodiment, an organometallic complex of one embodiment of the present invention and a light-emitting device that includes the organometallic complex are described.

### [Structure Examples of Light-Emitting Device]

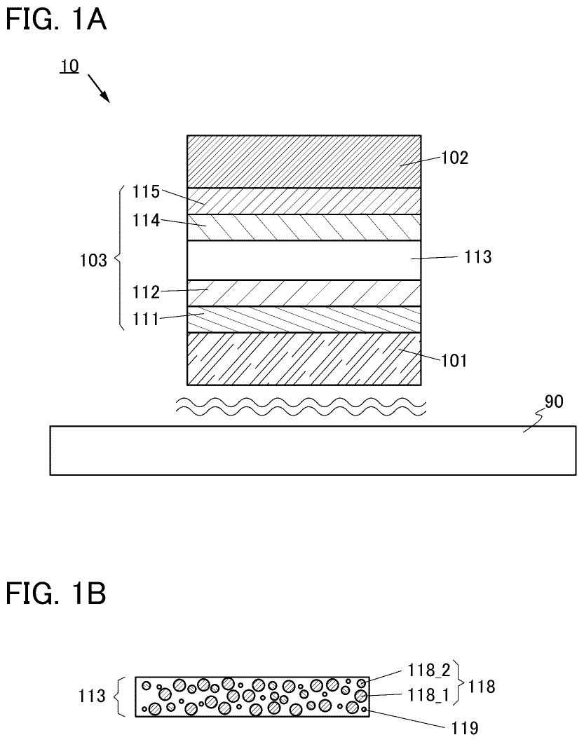

First, structure examples of a light-emitting device of one embodiment of the present invention is described with reference to FIGS. 1A and 1B.

FIG. 1A is a schematic cross-sectional view of a light-emitting device 10 of one embodiment of the present invention. The light-emitting device 10 is provided over a substrate 90 and includes a pair of electrodes (a first electrode 101 and a second electrode 102) and an organic compound layer 103 between the pair of electrodes. The organic compound layer 103 includes at least a light-emitting layer 113.

The organic compound layer 103 illustrated in FIG. 1A includes functional layers such as a hole-injection layer 111, a hole-transport layer 112, an electron-transport layer 114, and an electron-injection layer 115, in addition to the light-emitting layer 113. The structure of the organic compound layer 103 is not limited to the structure illustrated in FIG. 1A, and a structure including, in addition to the light-emitting layer 113, at least one layer selected from the hole-injection layer 111, the hole-transport layer 112, the electron-transport layer 114, and the electron-injection layer 115 may be employed. Alternatively, the organic compound layer 103 may include, in addition to the light-emitting layer 113, a functional layer which has a function of lowering a hole- or electron-injection barrier, improving a hole- or electron-transport property, inhibiting a hole- or electron-transport property, or reducing quenching by an electrode, for example. Note that the functional layer may be either a single layer or stacked layers.

Although description in this embodiment is made assuming that the first electrode 101 and the second electrode 102 of the pair of electrodes serve as an anode and a cathode, respectively, the structure of the light-emitting device 10 is not limited thereto. That is, the first electrode 101 may be a cathode, the second electrode 102 may be an anode, and the stacking order of the layers between the electrodes may be reversed. In other words, the hole-injection layer 111, the hole-transport layer 112, the light-emitting layer 113, the electron-transport layer 114, and the electron-injection layer 115 may be stacked in this order from the anode side. FIG. 1B is a schematic cross-sectional view illustrating an example of the light-emitting layer 113 in FIG. 1A. The light-emitting layer 113 shown in FIG. 1B contains a host material 118 (an organic compound 118_1 and an organic compound 118_2) and a light-emitting material 119.

The light-emitting material 119 may be a light-emitting organometallic complex, and the light-emitting organometallic complex is preferably a substance capable of emitting phosphorescent light (hereinafter also referred to as a phosphorescent compound). In the description below, an organometallic complex is used as the light-emitting material 119.

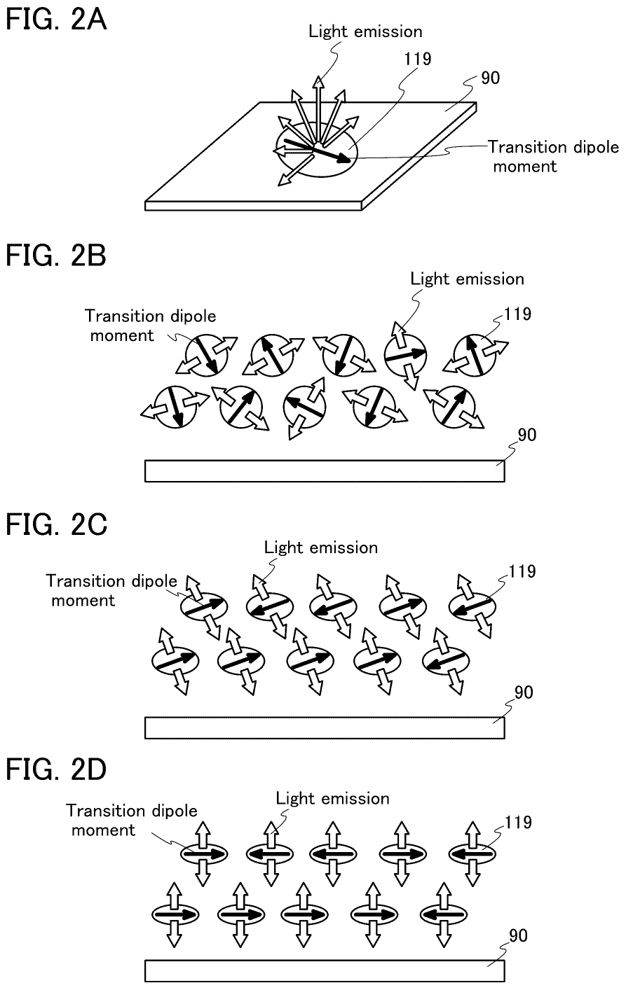

One of the factors that significantly affect the external quantum efficiency of light-emitting devices is light extraction efficiency (χ). The light extraction efficiency (χ) is generally 20% to 30% in an organic EL device over a glass substrate, although it depends on the structure, stacked layers, or the like of a light-emitting apparatus. However, the above value is based on the assumption that light emission from the light-emitting layer is isotropic; therefore, this value changes when light emission from the light-emitting layer is anisotropic. Light emission of the light-emitting material 119 is perpendicular to the transition dipole moment involved in the light emission (see FIG. 2A). Hence, when the light-emitting layer includes a light-emitting material so that the transition dipole moment involved in the light emission is easily oriented parallel to the substrate, the light emission from the light-emitting layer can be anisotropic, leading to the higher light extraction efficiency (χ) of the light-emitting device.

In view of the above, the inventors have developed the light-emitting material 119 having high planarity so that the transition dipole moment involved in light emission is easily oriented parallel to the substrate. In the case where the light-emitting material has low planarity 119, the orientations of the transition dipole moments involved in the light emission of the light-emitting material 119 are not easily aligned in the light-emitting layer, as illustrated in FIG. 2B, making the light emission from the light-emitting layer likely to be isotropic. By contrast, in the case where the light-emitting material 119 has high planarity, the orientations of the transition dipole moments involved in the light emission are easily aligned in the light-emitting layer, as illustrated in FIG. 2C, whereby the light emission from the light-emitting layer can be anisotropic. In this case, the transition dipole moments involved in light emission of the light-emitting material 119 are oriented parallel to the substrate, as illustrated in FIG. 2D, and the light emission perpendicular to the substrate can be increased, leading to the higher light extraction efficiency (χ) of the light-emitting device 10.

### [Molecular Design]

In the present invention, an organometallic complex including iridium (Ir) as a central metal is used as the light-emitting material 119. The organometallic complex of one embodiment of the present invention includes iridium as the central metal, a first ligand, and a second ligand. The first ligand and the second ligand are each a cyclometalated ligand. The first ligand includes a benzene ring and a pyridine ring each coordinated to iridium. The second ligand includes a benzofuro[2,3-b]pyridine ring and a pyridine ring that are coordinated to iridium. In the organometallic complex of one embodiment of the present invention, the proportion of one of the first and second ligands is twice as high as that of the other.

In the benzene ring included in the first ligand of the organometallic complex of one embodiment of the present invention, carbon at the 1-position is coordinated to the central metal, and carbon at the 2-position is bonded to carbon at the 2-position of the pyridine ring. In the pyridine ring, preferably, nitrogen at the 1-position is coordinated to the central metal and an alkyl group including deuterium is bonded to carbon at the 5-position.

In the benzofuro[2,3-b]pyridine ring included in the second ligand of the organometallic complex of one embodiment of the present invention, it is preferable that carbon at the 2-position include an alkyl group including deuterium, carbon at the 7-position be coordinated to the central metal, and carbon at the 8-position be bonded to carbon at the 2-position of the pyridine ring. In the pyridine ring, it is preferable that nitrogen at the 1-position be coordinated to the central metal, a phenyl group be bonded to carbon at the 4-position, and an alkyl group including deuterium be bonded to carbon at the 5-position.

The organometallic complex of one embodiment of the present invention can have higher planarity by having the structure in which the phenyl group is bonded to carbon at the 4-position in the pyridine ring of the second ligand and the second ligand is extended, as described above. Thus, when such an organometallic complex is used as the light-emitting material 119, the orientations of the transition dipole moments involved in light emission of the light-emitting material 119 are easily aligned, whereby the light emission from the light-emitting layer can be anisotropic.

In the case where the proportion of the first ligand to the second ligand is 2:1 in the organometallic complex of one embodiment of the present invention, the organometallic complex has much higher planarity. Thus, in the light-emitting layer 113, using such an organometallic complex as the light-emitting material 119 enables the vector connecting the two most distant atoms of the light-emitting material 119 to be easily oriented parallel to the substrate. Since the transition dipole moment involved in light emission of the organometallic complex is likely to be parallel to the vector, using such an organometallic complex as the light-emitting material 119 allows the transition dipole moment of the light-emitting material 119 to be easily aligned parallel to the substrate, leading to the higher light extraction efficiency (χ) of the light-emitting device.

By contrast, in the case where the proportion of the second ligand to the first ligand in the organometallic complex of one embodiment of the present invention is 2:1, more second ligands are involved in light emission and each second ligand has a smaller load, so that the stability is increased. The use of such an organometallic complex as the light-emitting material 119 increases the reliability of the light-emitting device 10.

As described above, in the organometallic complex of one embodiment of the present invention, an alkyl group including deuterium is bonded to carbon at the 5-position of the pyridine ring included in the first ligand, carbon at the 2-position of the benzofuro[2,3-b]pyridine ring included in the second ligand, and carbon at the 5-position of the pyridine ring included in the second ligand. Since the alkyl group including deuterium is an electron-donating group, it is capable of increasing the electron density of the pyridine ring when introduced thereto. The increase in electron density increases the highest occupied molecular orbital (HOMO) level and the lowest unoccupied molecular orbital (LUMO) level of the organometallic complex. Using such an organometallic complex having a high HOMO level as the light-emitting material 119 of the light-emitting layer can reduce a hole-injection barrier in the light-emitting layer 113 and promotes hole injection to the light-emitting layer 113, thereby decreasing the driving voltage of the light-emitting device 10. Accordingly, a driving load on the light-emitting device 10 is reduced and the reliability of the light-emitting device can be improved.

In addition, introduction of an alkyl group including deuterium into an organometallic complex enables adjustment of the light emission characteristics of the organometallic complex. In the organometallic complex of one embodiment of the present invention, the bond of the alkyl group including deuterium to carbon at the 5-position of the pyridine ring included in the second ligand can inhibit the π-conjugated system from being extended between the pyridine ring and the phenyl group. This can shorten the wavelength of the emission color of the organometallic complex.

In the organometallic complex of one embodiment of the present invention, an alkyl group including deuterium is preferably bonded to carbon in each pyridine ring. The bond dissociation energy of a bond between carbon and deuterium is higher than that of a bond between carbon and protium, and thus is stable and not easily cut. Accordingly, introducing an alkyl group including deuterium into a ligand can make the ligand more stable than introducing an alkyl group not including deuterium. Note that in this specification and the like, “hydrogen” includes protium and deuterium. Deuterium is a stable hydrogen isotope having a mass number of 2. Protium is a stable hydrogen isotope having a mass number of 1.

If the alkyl group bonded to carbon in the pyridine ring has too many carbon atoms, the sublimation properties of the organometallic complex of one embodiment of the present invention might be degraded. Thus, the alkyl group including deuterium introduced into the pyridine ring preferably has 1 to 6 carbon atoms as described above, to prevent degradation of the sublimation properties of the organometallic complex.

In the organometallic complex of one embodiment of the present invention, the inclusion of the alkyl group including deuterium in each pyridine ring can inhibit intermolecular interaction. For example, when the organometallic complex with the above structure is used as the light-emitting material 119 in the light-emitting layer 113 illustrated in FIG. 1B, interaction between the light-emitting material 119 and the host material 118 (one or both of the organic compound 118_1 and the organic compound 118_2) can be prevented, increasing the emission efficiency of the light-emitting device 10.

### <Organometallic Complex Example>

The organometallic complex of one embodiment of the present invention is described below using general formulae.

One embodiment of the present invention is an organometallic complex represented by General Formula (Ga).

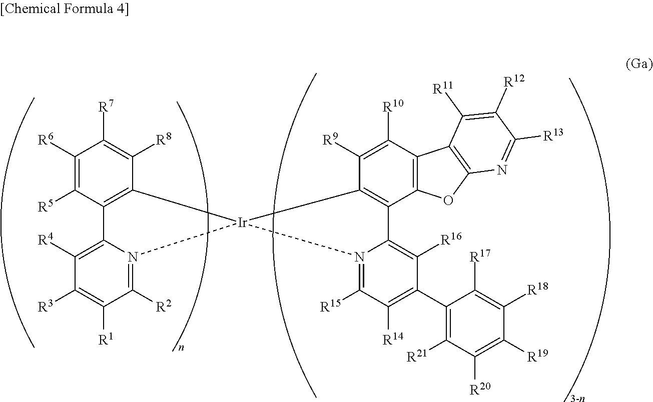

In the organometallic complex represented by General Formula (Ga), each of R¹ to R²¹ independently represents hydrogen (including deuterium) or an alkyl group that has 1 to 6 carbon atoms and includes deuterium including, and n represents 1 or 2.

In General Formula (Ga), a ligand shown on the left is the above-described first ligand, and a ligand shown on the right is the above-described second ligand. Furthermore, a pyridine ring having R¹ to R⁴ is the pyridine ring included in the first ligand, a pyridine ring having R⁵ to R⁸ is the benzene ring included in the first ligand, a benzofuro[2,3-b]pyridine ring having R⁹ to R¹³ is the benzofuro[2,3-b]pyridine ring included in the second ligand, and a pyridine ring having R¹⁴ to R¹⁶ is the pyridine ring included in the second ligand. A phenyl group having R¹⁷ to R²¹ is the phenyl group bonded to carbon at the 4-position of the pyridine ring included in the second ligand. As described above, the planarity of the metal complex can be increased due to the structure in which a phenyl group is bonded to carbon at the 4-position of the pyridine ring included in the second ligand and the second ligand is extended, as in the organometallic complex of General Formula (Ga). Thus, when such an organometallic complex is used as the light-emitting material 119, the orientations of the transition dipole moments involved in light emission of the light-emitting material 119 are easily aligned, whereby the light emission from the light-emitting layer can be anisotropic.

One embodiment of the present invention is an organometallic complex represented by General Formula (Gb).

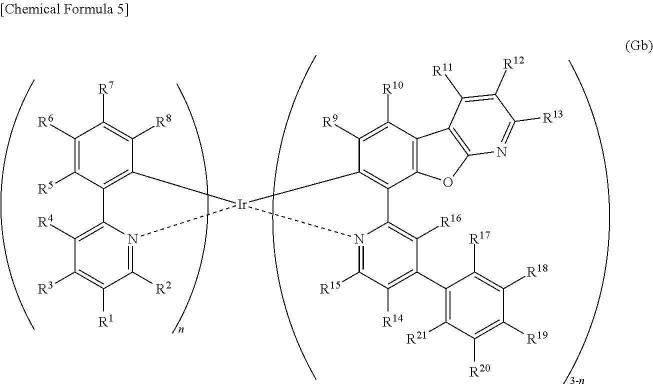

In the organometallic complex represented by General Formula (Gb), each of R¹, R¹³, and R¹⁴ independently represents an alkyl group that has 1 to 6 carbon atoms and includes deuterium, each of R² to R¹² and R¹⁵ to R²¹ independently represents hydrogen (including deuterium) or an alkyl group that has 1 to 6 carbon atoms and includes deuterium, and n represents 1 or 2.

General Formula (Gb) is a formula in which each of R¹, R¹³, and R¹⁴ in General Formula (Ga) only represents an alkyl group that has 1 to 6 carbon atoms and includes deuterium. In General Formula (Gb), R¹ is the alkyl group including deuterium bonded to carbon at the 5-position of the pyridine ring included in the first ligand, R¹³ is the alkyl group including deuterium bonded to carbon at the 2-position of the benzofuro[2,3-b]pyridine ring included in the second ligand, and R¹⁴ is the alkyl group including deuterium bonded to carbon at the 5-position of the pyridine ring included in the second ligand. As described above, such introduction of an alkyl group including deuterium to an organometallic complex can increase the HOMO level and the LUMO level of the organometallic complex. Using such an organometallic complex having a high HOMO level as the light-emitting material 119 of the light-emitting layer can reduce a hole-injection barrier in the light-emitting layer 113 and promotes hole injection to the light-emitting layer 113, thereby decreasing the driving voltage of the light-emitting device 10. Thus, a driving load on the light-emitting device 10 is reduced and the reliability of the light-emitting device can be improved. As described above, the introduction of an alkyl group including deuterium into an organometallic complex enables adjustment of the light emission characteristics of the organometallic complex. Furthermore, as described above, the introduction of the alkyl group including deuterium to the organometallic complex can inhibit intermolecular interaction, and the use of the organometallic complex can improve the emission efficiency of the light-emitting device.

One embodiment of the present invention is an organometallic complex represented by General Formula (G1).

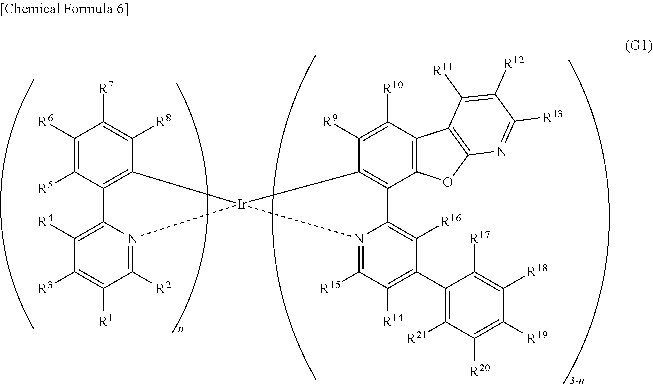

In the organometallic complex represented by General Formula (G1), each of R¹, R¹³, and R¹⁴ independently represents an alkyl group that has 1 to 6 carbon atoms and includes deuterium, each of R² to R¹² independently represents hydrogen (including deuterium) or an alkyl group that has 1 to 6 carbon atoms and includes deuterium, each of R¹⁵ to R²¹ independently represents hydrogen (including deuterium), and n represents 1 or 2.

General Formula (G1) is a formula in which R¹⁵ and R¹⁶ of the pyridine ring and R¹⁷ to R²¹ of the phenyl group bonded to carbon at the 4-position of the pyridine ring each only represent hydrogen (including deuterium) in the second ligand in General Formula (Gb). When R¹⁵ to R²¹ each only represent hydrogen (including deuterium), the stability of the organometallic complex in an excited state can be further increased. The use of such an organometallic complex as the light-emitting material 119 increases the reliability of the light-emitting device 10.

Another embodiment of the present invention is an organometallic complex represented by General Formula (G2).

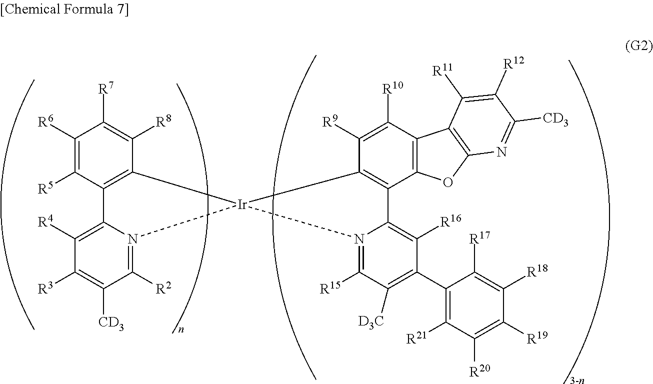

In the organometallic complex represented by General Formula (G2), each of R² to R¹² independently represents hydrogen (including deuterium) or an alkyl group that has 1 to 6 carbon atoms and includes deuterium, each of R¹⁵ to R²¹ independently represents hydrogen (including deuterium), and n represents 1 or 2.

General Formula (G2) is a formula in which each of R¹, R¹³, and R¹⁴ in General Formula (G1) only represents a methyl-d₃ group (—CD₃). A group in which all hydrogen atoms are substituted by deuterium atoms, such as a methyl-d₃ group, is preferably introduced into the organometallic complex to further increase the stability. The methyl-d₃ group is preferred also because it enables less expensive synthesis of the organometallic complex than an alkyl group including deuterium having 2 or more carbon atoms.

In the case where n is 2 (the proportion of the first ligand to the second ligand is 2:1), the organometallic complex represented by each of General Formulae (G1) and (G2) above has much higher planarity as described above. Accordingly, using such an organometallic complex as the light-emitting material 119 allows the vector connecting the two most distant atoms of the light-emitting material 119 in the light-emitting layer 113 to be easily oriented parallel to the substrate. Since the transition dipole moment involved in light emission of the organometallic complex is likely to be parallel to the vector, using such an organometallic complex as the light-emitting material 119 allows the transition dipole moment of the light-emitting material 119 to be easily aligned parallel to the substrate, leading to the higher light extraction efficiency (χ) of the light-emitting device 10.

Next, specific examples of substituents that can be used for the organometallic complexes represented by the above general formulae will be described. Note that in the specific examples of the substituents described below, some or all of hydrogen atoms may be deuterium unless otherwise specified. The substituents that can be used in the above general formulae are not limited to the specific examples described below.

<<Alkyl Group that has 1 to 6 Carbon Atoms and Includes Deuterium>>

An alkyl group that has 1 to 6 carbon atoms and includes deuterium refers to a monovalent group which is formed by removal of one hydrogen atom from an alkane having 1 to 6 carbon atoms and in which one or more of the remaining hydrogen atoms are deuterium atoms. Specific examples of the alkyl group including deuterium having 1 to 6 carbon atoms include a methyl-d₃ group (—CD₃), an ethyl-d₅ group, a propyl-d₇ group, an isopropyl-1-d group, an isopropyl-d₇ group, a butyl-d₉ group, an isobutyl-1,1-d₂ group, an isobutyl-d₉ group, a sec-butyl-d₉ group, a tert-butyl-d₉ group, a pentyl-dii group, an isopentyl-dii group, a hexyl-d₁₃ group, a neopentyl-1,1-d₂ group, and an isohexyl-d₆ group. A group in which all hydrogen atoms are substituted by deuterium atoms, such as a methyl-d₃ group, is preferably used to further increase the stability of the organometallic complex. The methyl-d₃ group is preferred also because it enables less expensive synthesis of the organometallic complex than an alkyl group including deuterium having 2 or more carbon atoms.

### SPECIFIC EXAMPLES

Next, specific examples of the organometallic complex of one embodiment of the present invention having any of the above general formulae are shown below. Note that the organometallic complex of one embodiment of the present invention is not limited to those shown below.

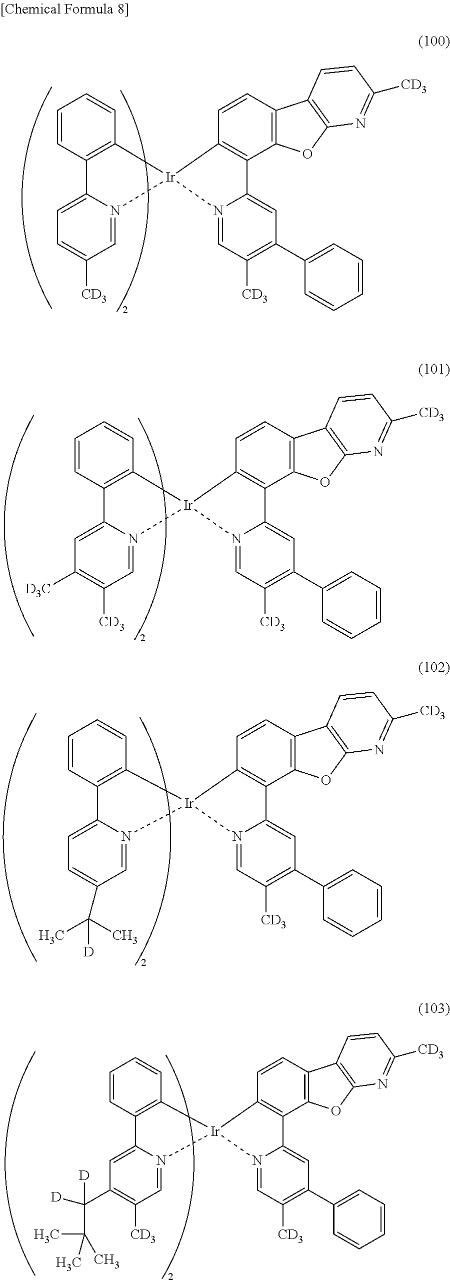

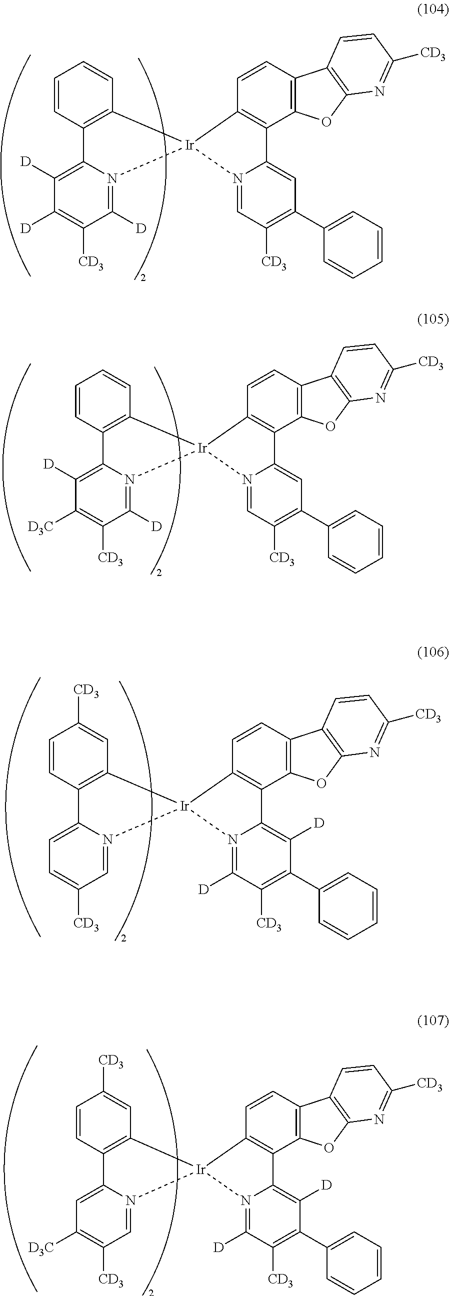

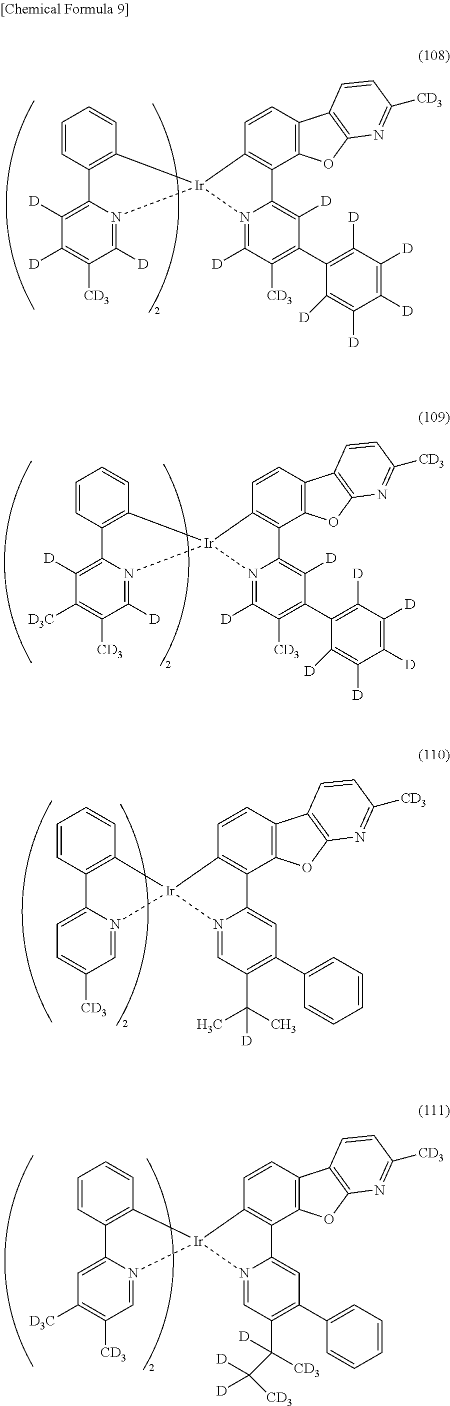

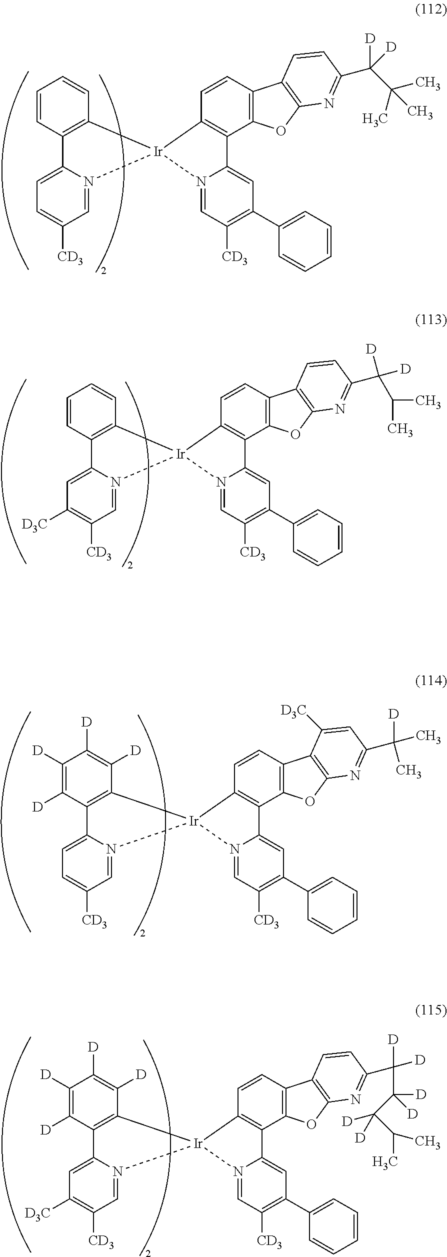

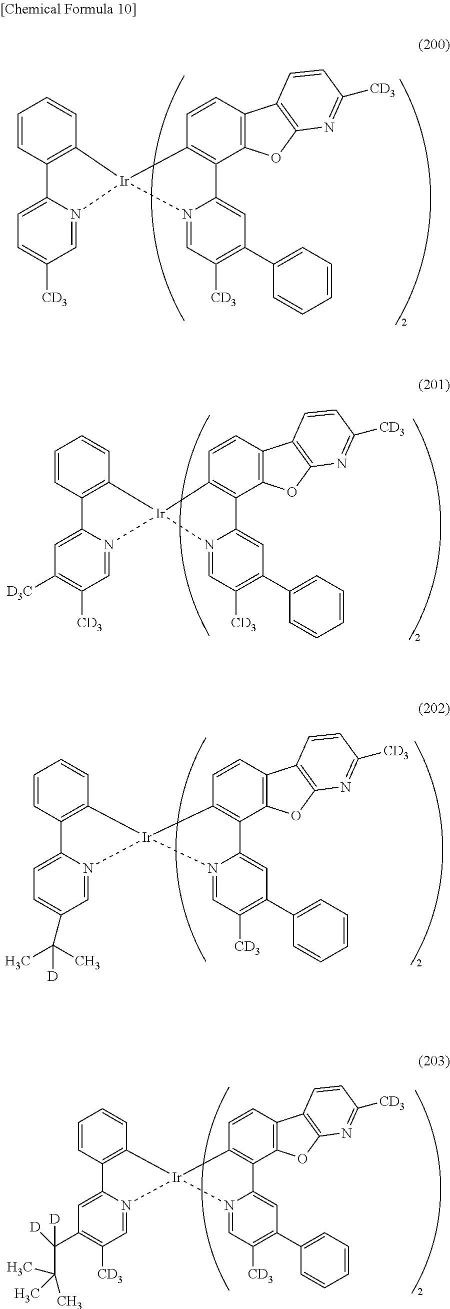

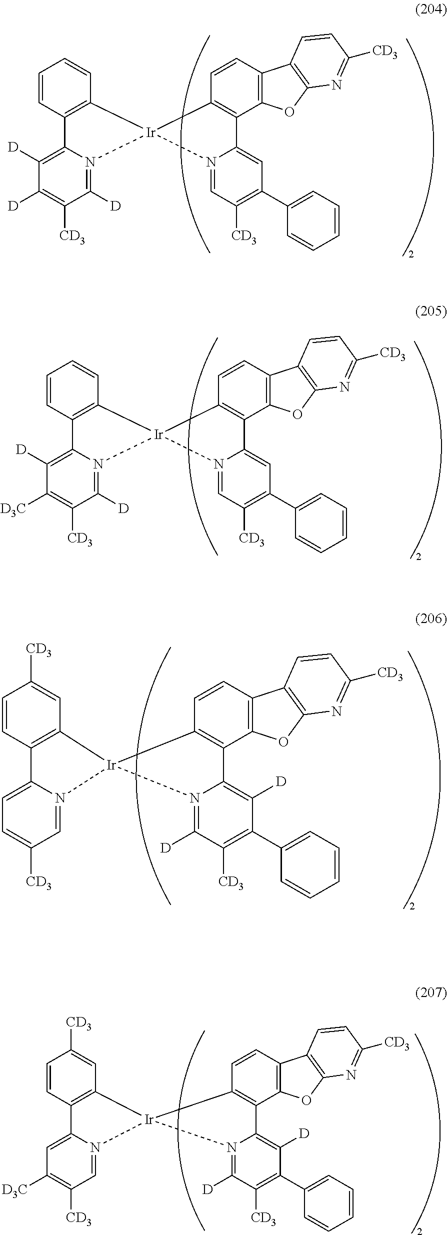

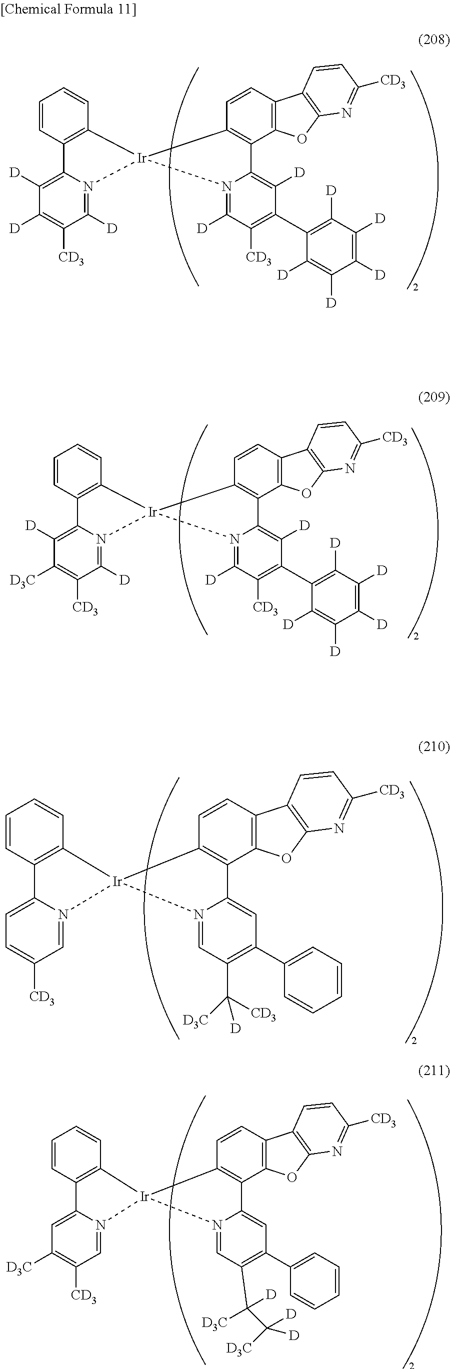

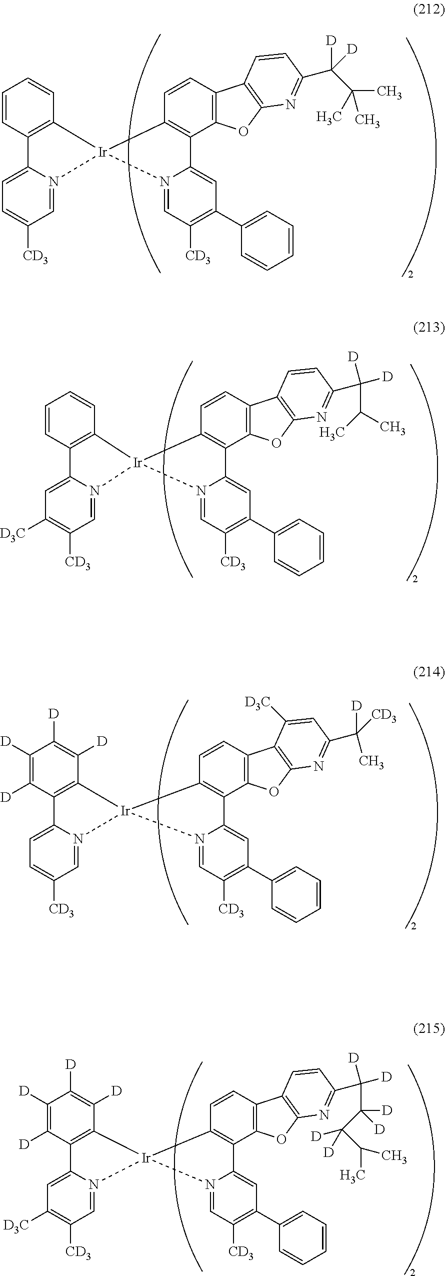

### <Synthesis Method of Organometallic Complex>

Next, a method for synthesizing the organometallic complex represented by General Formula (G1) is described. A variety of reactions can be applied to the synthesis method of the organometallic complex. For example, the organometallic complex represented by General Formula (G1) can be synthesized through simple synthesis schemes shown below.

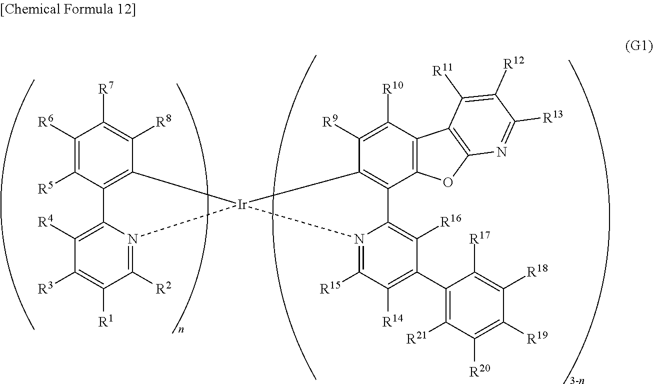

In the organometallic complex represented by General Formula (G1), each of R¹, R¹³, and R¹⁴ independently represents an alkyl group that has 1 to 6 carbon atoms and includes deuterium, each of R² to R¹² independently represents hydrogen (including deuterium) or an alkyl group that has 1 to 6 carbon atoms and includes deuterium, each of R¹⁵ to R²¹ independently represents hydrogen (including deuterium), and n represents 1 or 2.

<<Synthesis Method of Compound (a1)>>

First, an example of a synthesis method of a compound (a1) functioning as a ligand in the organometallic complex represented by General Formula (G1) is described. Note that the groups in the compound (a1) are the same as those in General Formula (G1) described above; thus, the description thereof is omitted here.

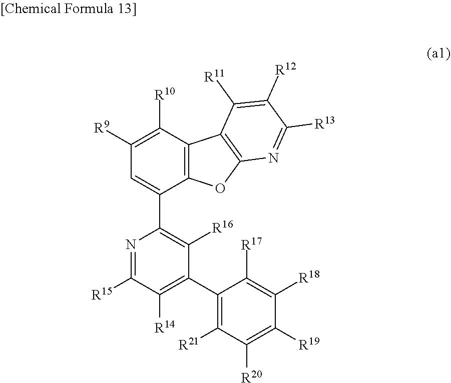

Any of a variety of reactions can be applied to the synthesis of the compound (a1). For example, a boron compound (a1-1) and a halogen compound (a1-2) are coupled to give a halogen compound (a1-3), as shown in Synthesis Scheme (A-1) below; then, the halogen compound (a1-3) is coupled with a boron compound (a1-4) to give the target compound (a1), as shown in Scheme (A-2) below. For these reactions, a synthesis method in which a metal catalyst is used under the presence of a base, e.g., the Suzuki-Miyaura reaction, can be used. Note that in Scheme (A-1) or (A-2), deuteration may be performed by stirring organic compounds in a deuterated solvent in the presence of a base.

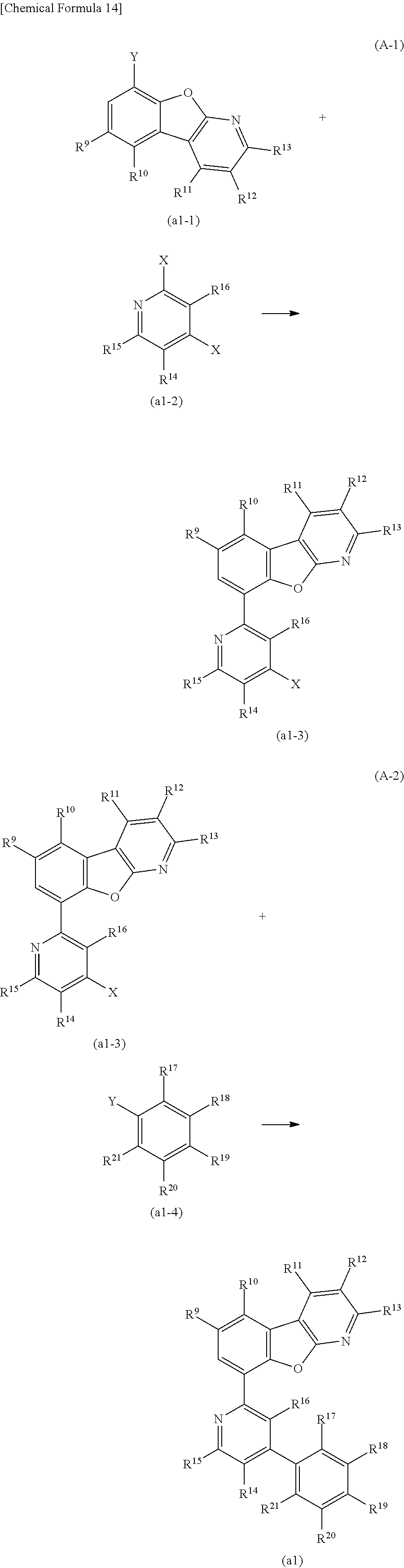

Since R⁹ to R²¹ in each of Synthesis Schemes (A-1) and (A-2) represent the same groups as the those in General Formula (G1), the description thereof is omitted here. In addition, Y represents a boronic acid or a boronic ester such as pinacol boron, and X represents any of chlorine, bromine, iodine, and a sulfonyloxy group; X is preferably an element with a larger atomic number to increase reactivity. Alternatively, a boronic acid or a boronic ester such as pinacol boron, which is used as X, and a halogen or a sulfonyloxy group, which is used as Y, may be reacted, for example.

In the case of conducting the Suzuki-Miyaura reaction using a palladium catalyst in Synthesis Schemes (A-1) and (A-2), a palladium compound such as tetrakis(triphenylphosphine)palladium(0), palladium(II) acetate, or tris(dibenzylideneacetone)dipalladium(0) and a ligand such as 2-dicyclohexylphosphino-2′,4′,6′-triisopropylbiphenyl can be used. In addition, an inorganic base such as potassium carbonate, sodium carbonate, or tripotassium phosphate or the like can be used. As the solvent, toluene, tetrahydrofuran, dioxane, ethylene glycol dimethyl ether, water, or the like can be used. Reagents that can be used in the reaction are not limited thereto.

Although Synthesis Schemes (A-1) and (A-2), where R¹³ and R¹⁴ each independently represent an alkyl group that has 1 to 6 carbon atoms and includes deuterium, employ a synthesis method using materials deuterated in advance for reactions, the synthesis method is not limited thereto. For example, in Synthesis Schemes (A-1) and (A-2), R¹³ and R¹⁴ may each be an alkyl group not including deuterium; in this case, R¹³ and R¹⁴ may be deuterated after the reactions shown in Synthesis Schemes (A-1) and (A-2). In the case where R¹³ and R¹⁴ are deuterated by an H-D exchange reaction, an inorganic base such as sodium tert-butoxide, sodium ethoxide, or sodium carbonate can be used. As a deuterated solvent, dimethyl sulfoxide-d₆, deuterated ethanol, deuterated water, or the like can be used. Reagents that can be used in the reaction are not limited thereto.

To deuterate R⁹ to R²⁰ by an H-D exchange reaction after Synthesis Schemes (A-1) and (A-2), the reaction is caused using a transition metal as a catalyst in a deuterated solvent, thereby giving a target substance. Examples of the reaction conditions include a hydrogen atmosphere, a high temperature, and a high pressure, and any of them can be selected as appropriate for the reaction. As the transition metal, a platinum-based carbon catalyst (Pd/C, Pt/C, Rh/C, Ru/C), platinum chloride, platinum dioxide, or the like can be used. Although deuterated water is preferably used as the deuterated solvent, other examples of the deuterated solvent include deuterated benzene, deuterated acetone, and deuterated ethanol. Reagents that can be used in the reaction are not limited thereto.

### <<Synthesis Method of Organometallic Complex Represented by General Formula (G1)>>

Synthesis Scheme (A-3) shows a synthesis method of the organometallic complex represented by General Formula (G1) where n is 2, and Synthesis Scheme (A-4) shows a synthesis method of the organometallic complex represented by General Formula (G1) where n is 1. As shown in Synthesis Scheme (A-3), a halogen-bridged dinuclear complex (a2) and the compound (a1) are reacted in an inert gas atmosphere, whereby the organometallic complex represented by General Formula (G1) where n is 2 can be obtained. As shown in Synthesis Scheme (A-4), a halogen-bridged dinuclear complex (a3) and a compound (a4) are reacted in an inert gas atmosphere, whereby the organometallic complex represented by General Formula (G1) where n is 1 can be obtained.

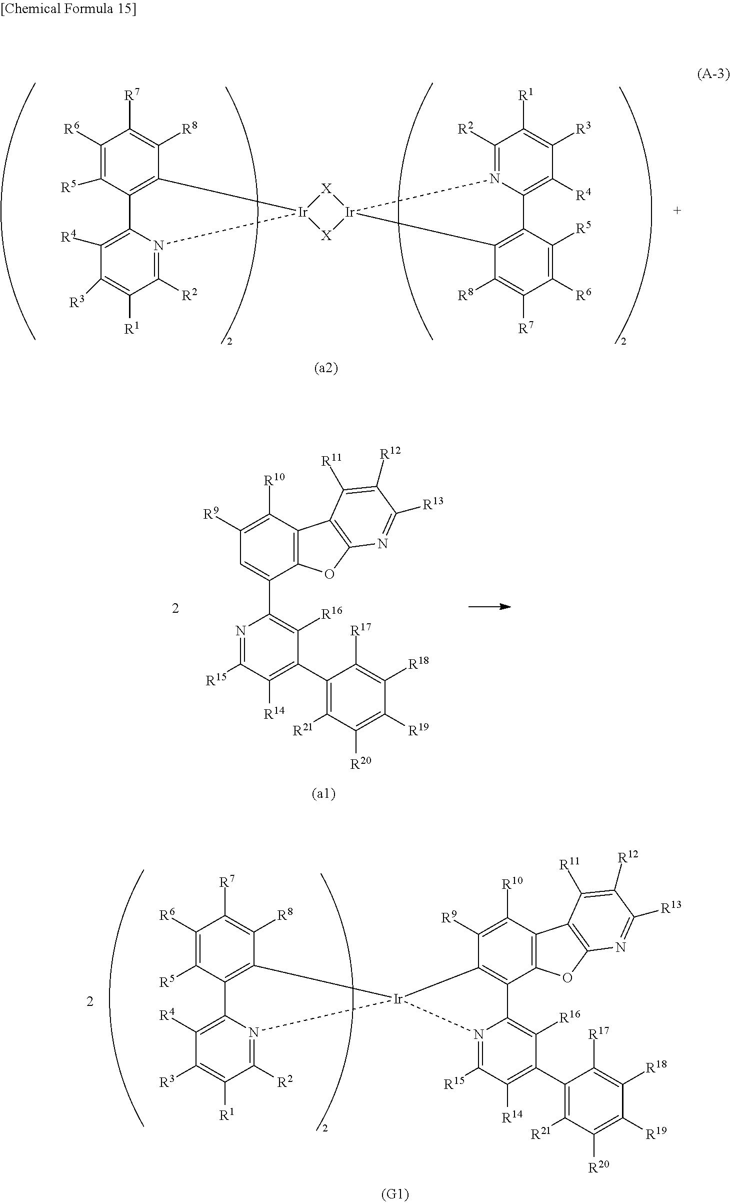

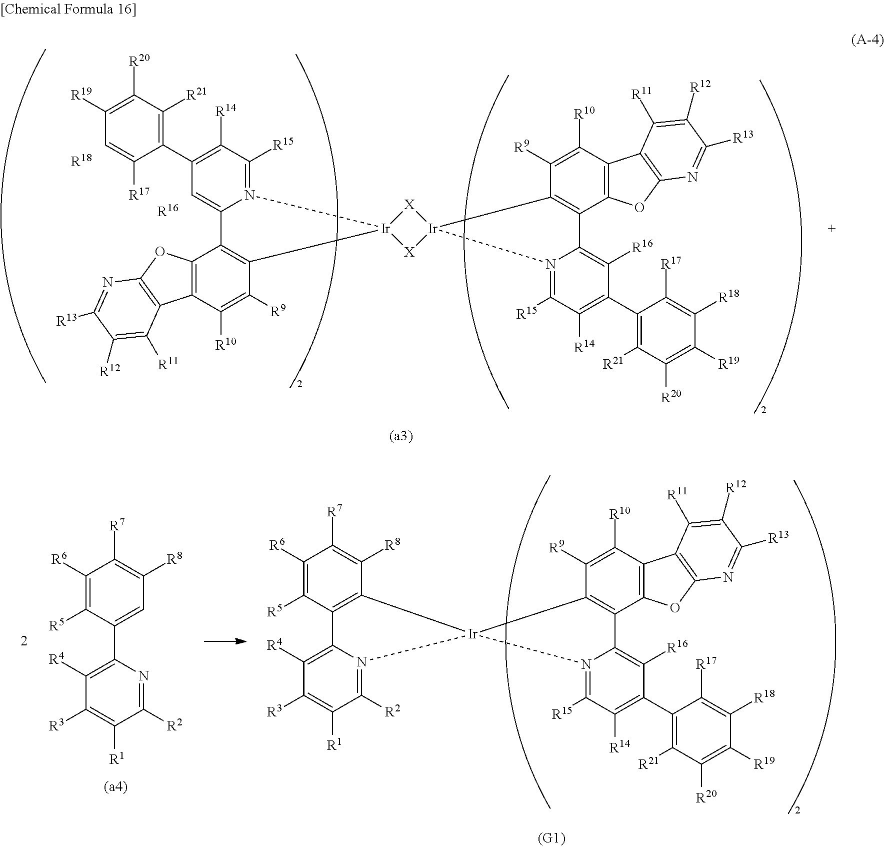

Since R¹ to R²¹ in each of Synthesis Schemes (A-3) and (A-4) represent the same groups as the those in General Formula (G1), the description thereof is omitted here. In addition, X represents a halogen element.

The organometallic complex obtained by the reaction shown in Synthesis Scheme (A-3) or (A-4) may be irradiated with light or heat to be further reacted to give an isomer such as a geometrical isomer or an optical isomer, which is also the organometallic complex of one embodiment of the present invention represented by General Formula (G1).

Alternatively, the organometallic complex represented by General Formula (G1) where n is 2 may be obtained in the following manner: the dinuclear complex (a2) having a halogen-bridged structure is reacted with an antichlor such as silver trifluoromethanesulfonate to precipitate silver chloride, and then a supernatant liquid is reacted with the compound (a1) in an inert gas atmosphere. Alternatively, the organometallic complex represented by General Formula (G1) where n is 1 may be obtained in the following manner: the dinuclear complex (a3) having a halogen-bridged structure is reacted with an antichlor such as silver trifluoromethanesulfonate to precipitate silver chloride, and then a supernatant liquid is reacted with the compound (a4) in an inert gas atmosphere.

The above is the description on examples of a method for synthesizing the organometallic complex that is a compound of one embodiment of the present invention; however, the present invention is not limited thereto and any other synthesis methods may be employed.

### [Molecular Orientation Parameter]

A molecular orientation parameter is described. A molecular orientation parameter a is a value obtained by estimating molecular orientation from an emission state of a light-emitting device. The radiation angle dependence of the emission intensity (spatial emission pattern) of a light-emitting device reflects the spatial distribution of a transition dipole of a light-emitting material. Analysis of this spatial distribution enables the orientation state in the light-emitting device to be examined. In this method, light emission itself from the light-emitting device is observed and analyzed. Even when the light-emitting material 119 is dispersed in a host material and included at a low concentration in the light-emitting layer 113, the orientation state of the light-emitting material 119 in the relationship between a light-emitting surface and a transition dipole moment can be examined as long as the light-emitting material 119 emits light.

When the organometallic complex of one embodiment of the present invention is used as the light-emitting material 119 in the light-emitting device 10, the molecular orientation parameter a of light emitted from the light-emitting device 10 using the organometallic complex is preferably less than or equal to 0.30, preferably less than or equal to 0.28. Such an organometallic complex has favorable orientation characteristics, whereby the light-emitting device 10 can have higher light extraction efficiency and higher emission efficiency.

<Method for Calculating Molecular Orientation Parameter a>

A method for calculating the molecular orientation parameter a of light emitted from the light-emitting device 10 is described. The measured angle dependence of the emission intensity of the light-emitting device is compared with the angle dependence of the emission intensity calculated by assuming, with a device simulator, a parameter a (see Formula (1) below) that represents the orientation of the light-emitting material 119; in this manner, the value of the molecular orientation parameter a appropriate for the measured light-emitting device can be estimated to obtain the orientation state of the light-emitting material in the light-emitting device (see Non-Patent Document 1).

Focusing on the shape of an emission spectrum obtained by the device simulator, the present inventors also perform comparison and fitting of measured values and calculated values of the shape of the emission spectrum and an angle dependent change in the shape. As the emission intensity in the measurement and calculation, not the emission intensity at a particular wavelength but the integrated intensity of the emission spectrum is used. Unlike the method disclosed in Non-Patent Document 1, the methods employed by the present inventors enable highly accurate estimation of the parameter a.

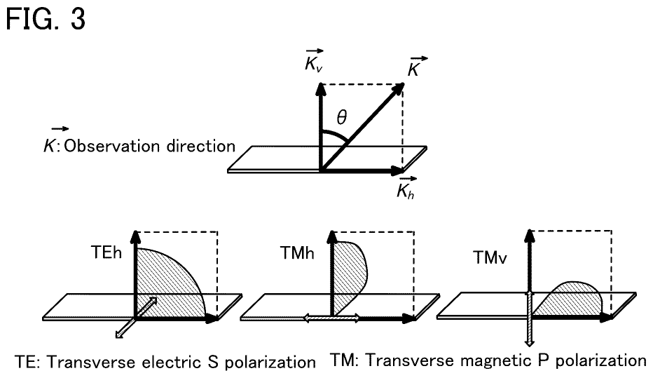

FIG. 3 illustrates a relationship between the observation direction of a detector in measuring the spatial distribution of the emission intensity and vector components of a transition dipole moment over a substrate. Since a transition dipole moment is a vector, it can be synthesized and decomposed. The average transition dipole moment in the light-emitting material 119 in the light-emitting layer 113 can be decomposed into the x-axis component (TEh component), the y-axis component (TMh component), and the z-axis component (TMv component), which are orthogonal to one another.

Light emission of the light-emitting material 119 is perpendicular to (in any direction within a plane perpendicular to) the transition dipole moment, as described above. Among the components decomposed into the three directions, the TEh and TMh components (x-axis and y-axis components) are transition dipole moments parallel to the substrate, making the light emission perpendicular to the substrate, that is these components enable emission of easily extracted light. By contrast, the TMv component (z-axis component) is a transition dipole moment perpendicular to the substrate, making the light emission parallel to the substrate, and thus the component leads to difficulty in light extraction.

In FIG. 3, a figure that extends from the center of an arrow representing the vector of each component schematically represents the emission intensity entering the detector that is rotated from the front of the substrate (θ=0°) to be substantially parallel to the substrate (θ=90°). The vertical distance from the center is proportional to the intensity.

The detector is located in the direction in which light is emitted. Thus, changing the angle of the detector to the substrate does not change the intensity of detected light (i.e., the vertical distance from the center of the arrow of the figure that extends from the center of the arrow in FIG. 3); thus, the figure that extends from the center of the arrow of the TEh component has a neat fan shape. By contrast, the figures that extend from the centers of the arrows of the TMh and TMv components have distorted fan shapes, and thus the intensity of detected light significantly depends on the angle θ of the detector to the substrate. As shown in FIG. 3, the intensity of the TMh component is increased when observed in a region where θ is smaller, whereas the intensity of the TMv component is increased when observed in a region where θ is larger. In that case, the emission intensity measured by the detector (the emission intensity at a wavelength λ and at an angle θ: I_{λ}(θ,λ)) can be represented by Formula (1).

$$\begin{matrix}[ Formula 1 ] & \\ {I}_{λ} ( θ , λ ) = a \cdot {I}_{TMv} + ( 1 - a ) \cdot ( {I}_{TMh} + {I}_{TEh} ) & Formula ( 1 )\end{matrix}$$

In the formula, I_{TMv}, I_{TMh}, and I_{TEh} represent spatial intensity distribution of light emitted from the transition dipoles arranged as illustrated in FIG. 3, and a represents the proportion of the transition dipole moments (TMv components) arranged perpendicular to the substrate. In addition, 1−a represents the proportion of the transition dipole moments (TMh and TEh components) arranged parallel to the substrate. That is, a can also be regarded as a parameter that represents the orientation of transition dipoles of light-emitting molecules.

In the above formula, when the transition dipole moments are arranged only in the direction completely parallel to the substrate, the TMv component is eliminated and a is 0. By contrast, when the transition dipole moments are arranged only in the direction perpendicular to the substrate, a is 1. The random orientations of the transition dipole moments are assumed to be isotropic, i.e., x-axis:y-axis:z-axis=1:1:1, and therefore the ratio of the component (TMv component) perpendicular to the substrate to the components (TMh and TEh components) parallel to the substrate is 1:2 and a=⅓ (approximately 0.33).

As described above, I_{TEh} is constant independent of the angle; however, I_{TMv} and I_{TMh} change depending on the angle (θ) of the substrate to the measurement device. Thus, by measuring the emission intensity while changing 0, a can be obtained from the change in I_{TMv} and I_{TMh} depending on 0.

In that case, I_{TEh} which does not change depending on the angle hinders the measurement. The amplitude direction of an electric field of emitted light is the same as the direction of the transition dipole moment, and I_{TEh} is an S-wave and I_{TMv} and I_{TMh} are P-waves. Thus, by disposing a linear polarizer in the direction perpendicular to the substrate surface, measurement can be performed under the condition where the TEh component is excluded.

The TMh component and the TMv component are compared. The emission direction of the TMh component is mainly perpendicular to the substrate and the emission direction of the TMv component is mainly parallel to the substrate; in a light-emitting device in which light emission is obtained from a solid, a large part of light emission from the TMv component is totally reflected and cannot be extracted to the outside. On the other hand, light emission from the TMh component is more easily extracted to the outside than light emission from the TMv component. Furthermore, in a light-emitting device in which the thickness is optically optimized, light emission from the TMh component whose emission direction is mainly perpendicular to the substrate is intensified through interference, so that the emission intensity of the TMh component is increased (thus, the emission efficiency is maximized). That is, unless the molecular orientation parameter a is very close to 1, a difference between the emission intensity of the TMv component and that of the TMh component is very large in the light-emitting device in which the thickness is optically optimized. That is, in the light-emitting device in which the emission efficiency is maximized, most light emission which is observed depends on the TMh component. In the case where the difference between the emission intensity of the TMh component and that of the TMv component is large as described above, it is difficult to experimentally extract light emission from the component which has lower intensity (namely the TMv component) from the distribution of the emission intensity depending on the angle.

In view of the above, the emission intensity in the front direction of the substrate is suppressed as much as possible by utilizing an interference effect (that is, light emission from the TMh component is reduced as much as possible by utilizing an interference effect), so that the value of a can be easily obtained. For this purpose, a light-emitting device for orientation measurement in which the thickness is adjusted is prepared for measurement. Specifically, the light-emitting device is fabricated and used for measurement, in which the luminance in the front direction is lowered by setting the distance between a light-emitting region and a cathode to nλ/2. In general, the thickness is adjusted by increasing the thickness of an electron-transport layer to which an alkali metal is added, for example. However, since there is a limitation on the conductivity of the film, the driving voltage might be increased or the carrier balance might be poor. Thus, in order to adjust the thickness, it is preferable to use a composite material of a material having a hole-transport property and a material having an acceptor property with respect to the material having a hole-transport property.

As the composite material, a material similar to a composite material that is preferably used for a hole-injection layer described later in Embodiment 2 can be used. In the device for orientation measurement, molybdenum oxide is preferably used as the acceptor material in order to inhibit an increase in driving voltage.

### [Computational Chemistry]

Next is described a search method using computational chemistry to find conditions and the like for aligning the transition dipole moment involved in light emission of the organometallic complex of one embodiment of the present invention parallel to the substrate.

In the calculation, a vector A is defined as a vector connecting two most distant atoms in a lowest triplet excited state of the organometallic complex. A plane A is defined as a plane that includes the vector A and corresponds to the largest area of a quadrilateral surrounding an atomic group that is included in the organometallic complex and projected perpendicularly onto the plane. A plane B is defined as a plane that is perpendicular to the plane A and includes the vector A. A vector B is defined as a transition dipole moment involved in light emission of the organometallic complex. A vector B′ is defined as a vector obtained by projecting the vector B onto the plane B. Note that the direction of the vector A is determined such that an angle between the vectors A and B is less than or equal to 90°.

The larger vector B is probably advantageous for the higher emission quantum yield of the organometallic complex. In other words, the vector B defined as described above is preferably larger, specifically, greater than or equal to 0.5 debye, in which case the emission quantum yield can be improved.

Furthermore, a smaller angle (ϕ) between the vectors A and B′ is probably advantageous to molecular orientation. In other words, an organometallic complex where the angle (ϕ) between the vectors A and B′ defined as described above is smaller, specifically, less than or equal to 25°, is preferably used as the light-emitting material 119, in which case the organometallic complex can be easily oriented parallel to the substrate.

Furthermore, the large vector B and the small angle (ϕ) between the vectors A and B′ are preferred. Thus, in the case where the magnitudes of the vectors A and B and 4 are used to solve the formula, (the magnitude of the vector A (nm))×(the magnitude of the vector B (debye))×cos ϕ, the obtained inner product of the vectors A and B is preferably large. This is because the organometallic complex with the larger inner product has a high emission quantum yield and the orientation is easily parallel to the substrate. With the use of the organometallic complex with an inner product of 1.00 or more, the light-emitting device 10 can have increased light extraction efficiency and high emission efficiency.

Detailed calculation methods of the vectors A and B, θ, the inner product, and the like will be described in detail in Example 6.

Note that the compounds described in this embodiment can be used in combination with any of the structures described in the other embodiments as appropriate.

### Embodiment 2

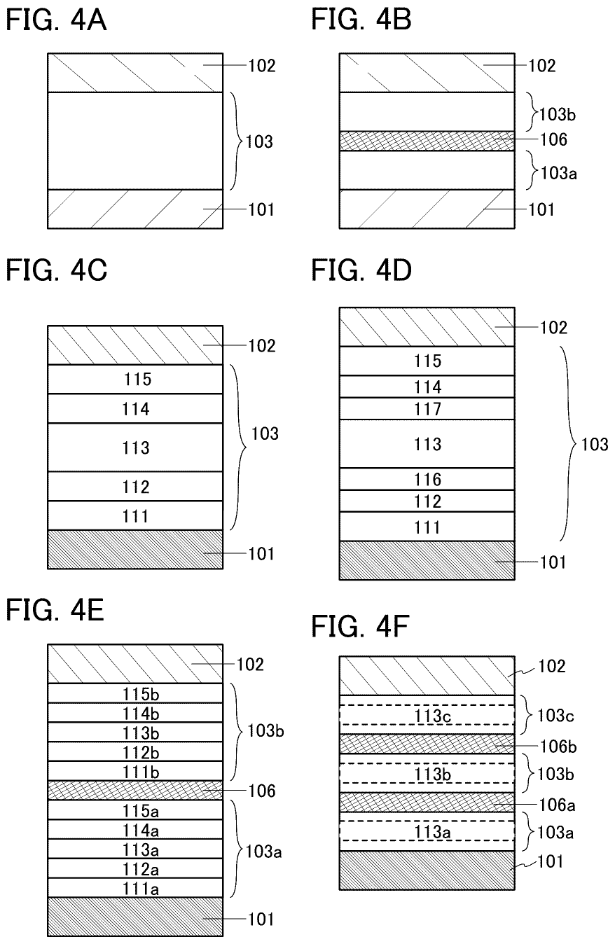

In this embodiment, a structure of a light-emitting device of one embodiment of the present invention is described with reference to FIGS. 4A to 4F.

### [Basic Structure of Light-Emitting Device]

A basic structure of the light-emitting device is described. FIG. 4A illustrates a light-emitting device having a structure (single structure) in which an organic compound layer including a light-emitting layer is provided between a pair of electrodes. Specifically, the organic compound layer 103 is positioned between the first electrode 101 and the second electrode 102.

FIG. 4B illustrates a light-emitting device that has a stacked-layer structure (tandem structure) in which a plurality of organic compound layers (two organic compound layers 103a and 103b in FIG. 4B) are provided between a pair of electrodes and a charge-generation layer 106 is provided between the organic compound layers. A light-emitting device having the tandem structure enables a light-emitting apparatus that has high efficiency without changing the amount of current.

The charge-generation layer 106 has a function of injecting electrons into one of the organic compound layers 103a and 103b and injecting holes into the other of the organic compound layers 103a and 103b when a potential difference is caused between the first electrode 101 and the second electrode 102. Thus, when voltage is applied such that the potential of the first electrode 101 is higher than that of the second electrode 102 in FIG. 4B, electrons are injected from the charge-generation layer 106 into the organic compound layer 103a and holes are injected from the charge-generation layer 106 into the organic compound layer 103b.

Note that in terms of light extraction efficiency, the charge-generation layer 106 preferably has a property of transmitting visible light (specifically, the charge-generation layer 106 preferably has a visible light transmittance higher than or equal to 40%). The charge-generation layer 106 functions even if it has lower conductivity than the first electrode 101 or the second electrode 102.

FIG. 4C illustrates a stacked-layer structure of the organic compound layer 103 in the light-emitting device of one embodiment of the present invention. In this case, the first electrode 101 is regarded as functioning as an anode and the second electrode 102 is regarded as functioning as a cathode. The organic compound layer 103 has a structure in which the hole-injection layer 111, the hole-transport layer 112, the light-emitting layer 113, the electron-transport layer 114, and the electron-injection layer 115 are stacked in this order over the first electrode 101. Note that the light-emitting layer 113 may have a stacked-layer structure of a plurality of light-emitting layers that emit light of different colors. For example, a light-emitting layer containing a light-emitting material that emits red light, a light-emitting layer containing a light-emitting material that emits green light, and a light-emitting layer containing a light-emitting material that emits blue light may be stacked with or without a layer containing a carrier-transport material therebetween. Alternatively, a light-emitting layer containing a light-emitting material that emits yellow light and a light-emitting layer containing a light-emitting material that emits blue light may be used in combination. Note that the stacked-layer structure of the light-emitting layer 113 is not limited to the above examples. For example, the light-emitting layer 113 may have a stacked-layer structure of a plurality of light-emitting layers that emit light of the same color. For example, a first light-emitting layer containing a light-emitting material that emits blue light and a second light-emitting layer containing a light-emitting material that emits blue light may be stacked with or without a layer containing a carrier-transport material therebetween. The structure in which a plurality of light-emitting layers that emit light of the same color are stacked can achieve higher reliability than a single-layer structure in some cases. In the case where a plurality of organic compound layers are provided as in the tandem structure illustrated in FIG. 4B, the layers in each organic compound layer are sequentially stacked from the anode side as described above. When the first electrode 101 is the cathode and the second electrode 102 is the anode, the stacking order of the layers in the organic compound layer 103 is reversed. Specifically, the layer 111 over the first electrode 101 serving as the cathode is an electron-injection layer; the layer 112 is an electron-transport layer; the layer 113 is a light-emitting layer; the layer 114 is a hole-transport layer; and the layer 115 is a hole-injection layer.

The light-emitting layer 113 included in the organic compound layers (103, 103a, and 103b) contains an appropriate combination of a light-emitting material and a plurality of substances, so that fluorescent light of a desired color or phosphorescent light of a desired color can be obtained. The light-emitting layer 113 may have a stacked-layer structure having different emission colors. In that case, light-emitting materials and other substances may be different between the stacked light-emitting layers. Alternatively, the plurality of organic compound layers (103a and 103b) in FIG. 4B may exhibit their respective emission colors. Also in that case, the light-emitting materials and other substances may be different between the light-emitting layers.

The light-emitting device of one embodiment of the present invention can have a micro optical resonator (microcavity) structure when, for example, the first electrode 101 is a reflective electrode and the second electrode 102 is a transflective electrode in FIG. 4C. Thus, light from the light-emitting layer 113 in the organic compound layer 103 can be resonated between the electrodes and light emitted through the second electrode 102 can be intensified. This makes it easy to achieve high definition. In addition, emission intensity with a predetermined wavelength in the front direction can be increased, leading to lower power consumption.

Note that when the first electrode 101 of the light-emitting device is a reflective electrode having a stacked-layer structure of a reflective conductive material and a light-transmitting conductive material (transparent conductive film), optical adjustment can be performed by adjusting the thickness of the transparent conductive film. Specifically, when the wavelength of light obtained from the light-emitting layer 113 is k, the optical path length between the first electrode 101 and the second electrode 102 (the product of the thickness and the refractive index) is preferably adjusted to be mλ/2 (m is an integer of 1 or more) or close to mλ/2.

To amplify desired light (wavelength: λ) emitted from the light-emitting layer 113, it is preferable to adjust each of the optical path length from the first electrode 101 to a region where the desired light is emitted in the light-emitting layer 113 (light-emitting region) and the optical path length from the second electrode 102 to the region where the desired light is emitted in the light-emitting layer 113 (light-emitting region) to be (2m′+1)λ/4 (m′ is an integer of 1 or more) or close to (2m′+1)λ/4. Here, the light-emitting region means a region where holes and electrons are recombined in the light-emitting layer 113.

By such optical adjustment, the spectrum of specific monochromatic light obtained from the light-emitting layer 113 can be narrowed and light emission with high color purity can be obtained.

In the above case, the optical path length between the first electrode 101 and the second electrode 102 is, to be exact, the total thickness from a reflective region in the first electrode 101 to a reflective region in the second electrode 102. However, it is difficult to precisely determine the reflective regions in the first electrode 101 and the second electrode 102; thus, the above effect can be considered to be obtained sufficiently wherever the reflective regions may be present in the first electrode 101 and the second electrode 102. Furthermore, the optical path length between the first electrode 101 and the light-emitting layer that emits the desired light is, to be exact, the optical path length between the reflective region in the first electrode 101 and the light-emitting region in the light-emitting layer that emits the desired light. However, it is difficult to precisely determine the reflective region in the first electrode 101 and the light-emitting region in the light-emitting layer that emits the desired light; thus, the above effect can be considered to be obtained sufficiently wherever the reflective region and the light-emitting region may be present in the first electrode 101 and the light-emitting layer that emits the desired light, respectively.

FIG. 4D illustrates a modification example of the stacked-layer structure illustrated in FIG. 4C. Also in this case, the first electrode 101 is regarded as serving as an anode, and the second electrode 102 is regarded as serving as a cathode. In this modification example, a hole-blocking layer and an electron-blocking layer are provided. That is, the organic compound layer 103 has a structure in which the hole-injection layer 111, the hole-transport layer 112, an electron-blocking layer 116, the light-emitting layer 113, a hole-blocking layer 117, the electron-transport layer 114, and the electron-injection layer 115 are stacked in this order over the first electrode 101.

The electron-blocking layer 116 is provided to prevent passing of electrons from the light-emitting layer 113 to the first electrode 101 side, for example. The hole-blocking layer 117 is provided to prevent passing of holes from the light-emitting layer 113 to the second electrode 102 side, for example. Note that the electron-blocking layer 116 can be regarded as part of the hole-transport layer 112. The hole-blocking layer 117 can be regarded as part of the electron-transport layer 114.

The light-emitting device illustrated in FIG. 4E is a light-emitting device having the tandem structure. The tandem structure enables a light-emitting device to emit light with high luminance. Furthermore, the amount of current needed for a predetermined luminance can be smaller in the tandem structure than in the single structure; thus, the tandem structure enables higher reliability. In addition, power consumption can be reduced.

The light-emitting device illustrated in FIG. 4F is an example of the light-emitting device having the tandem structure illustrated in FIG. 4B, and includes three organic compound layers (103a, 103b, and 103c) stacked with charge-generation layers (106a and 106b) positioned therebetween, as illustrated in FIG. 4F. The three organic compound layers (103a, 103b, and 103c) include respective light-emitting layers (113a, 113b, and 113c), and the emission colors of the light-emitting layers can be selected freely. For example, the light-emitting layer 113a can emit blue light, the light-emitting layer 113b can emit red light, green light, or yellow light, and the light-emitting layer 113c can emit blue light, or the light-emitting layer 113a can emit red light, the light-emitting layer 113b can emit blue light, green light, or yellow light, and the light-emitting layer 113c can emit red light.

In the light-emitting device of one embodiment of the present invention, at least one of the first electrode 101 and the second electrode 102 is a light-transmitting electrode (e.g., a transparent electrode or a transflective electrode). In the case where the light-transmitting electrode is a transparent electrode, the transparent electrode has a visible light transmittance higher than or equal to 40%. In the case where the light-transmitting electrode is a transflective electrode, the transflective electrode has a visible light reflectance higher than or equal to 20% and lower than or equal to 80%, preferably higher than or equal to 40% and lower than or equal to 70%. These electrodes preferably have a resistivity lower than or equal to 1×10⁻² Ωcm.

When one of the first electrode 101 and the second electrode 102 is a reflective electrode in the light-emitting device of one embodiment of the present invention, the visible light reflectance of the reflective electrode is higher than or equal to 40% and lower than or equal to 100%, preferably higher than or equal to 70% and lower than or equal to 100%. This electrode preferably has a resistivity lower than or equal to 1×10⁻² Ωcm.

### [Specific Structure of Light-Emitting Device]

Next, a specific structure of the light-emitting device of one embodiment of the present invention will be described. Here, the description is made using FIG. 4E illustrating the tandem structure. Note that the structure of the organic compound layer also applies to the structure of the light-emitting devices having the single structure in FIGS. 4A and 4C. When the light-emitting device in FIG. 4E has a microcavity structure, the first electrode 101 is formed as a reflective electrode and the second electrode 102 is formed as a transflective electrode. Thus, a single-layer structure or a stacked-layer structure can be formed using one or more kinds of desired electrode materials. Note that the second electrode 102 is formed after formation of the organic compound layer 103b, with the use of a material selected as appropriate.

### [Materials of Light-Emitting Device]

### <First Electrode and Second Electrode>

As materials for the first electrode 101 and the second electrode 102, any of the following materials can be used in an appropriate combination as long as the above functions of the electrodes can be fulfilled. For example, a metal, an alloy, an electrically conductive compound, a mixture of these, and the like can be used as appropriate. Specifically, In—Sn oxide (also referred to as ITO), In—Si—Sn oxide (also referred to as ITSO), In—Zn oxide, or In—W—Zn oxide can be used. In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example. It is also possible to use a Group 1 element or a Group 2 element in the periodic table that is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

In the light-emitting device in FIG. 4E, when the first electrode 101 is the anode, a hole-injection layer 111a and a hole-transport layer 112a of the organic compound layer 103a are sequentially stacked over the first electrode 101, with the use of a vacuum evaporation method. After the organic compound layer 103a and the charge-generation layer 106 are formed, a hole-injection layer 111b and a hole-transport layer 112b of the organic compound layer 103b are sequentially stacked over the charge-generation layer 106 in a similar manner.

Each of the light-emitting devices illustrated in FIGS. 4A to 4F can have a micro optical resonator (microcavity) structure when, for example, the first electrode 101 is a reflective electrode and the second electrode 102 is a transflective electrode. Thus, light from the light-emitting layer 113 in the organic compound layer 103 can be resonated between the electrodes and light emitted through the second electrode 102 can be intensified.

Note that when the first electrode 101 of the light-emitting device is a reflective electrode having a stacked-layer structure of a reflective conductive material and a light-transmitting conductive material (transparent conductive film), optical adjustment can be performed by adjusting the thickness of the transparent conductive film. Specifically, when the wavelength of light obtained from the light-emitting layer 113 is λ, the optical path length between the first electrode 101 and the second electrode 102 (the product of the thickness and the refractive index) is preferably adjusted to be mλ/2 (m is an integer of 1 or more) or close to mλ/2.

To amplify desired light (wavelength: λ) emitted from the light-emitting layer 113, it is preferable to adjust each of the optical path length from the first electrode 101 to a region where the desired light is emitted in the light-emitting layer 113 (light-emitting region) and the optical path length from the second electrode 102 to the region where the desired light is emitted in the light-emitting layer 113 (light-emitting region) to be (2m′+1)λ/4 (m′ is an integer of 1 or more) or close to (2m′+1)λ/4. Here, the light-emitting region means a region where holes and electrons are recombined in the light-emitting layer 113.

By such optical adjustment, the spectrum of specific monochromatic light obtained from the light-emitting layer 113 can be narrowed and light emission with high color purity can be obtained.

In the above case, the optical path length between the first electrode 101 and the second electrode 102 is, to be exact, the total thickness from a reflective region in the first electrode 101 to a reflective region in the second electrode 102. However, it is difficult to precisely determine the reflective regions in the first electrode 101 and the second electrode 102; thus, the above effect can be considered to be obtained sufficiently wherever the reflective regions may be present in the first electrode 101 and the second electrode 102. Furthermore, the optical path length between the first electrode 101 and the light-emitting layer that emits the desired light is, to be exact, the optical path length between the reflective region in the first electrode 101 and the light-emitting region in the light-emitting layer that emits the desired light. However, it is difficult to precisely determine the reflective region in the first electrode 101 and the light-emitting region in the light-emitting layer that emits the desired light; thus, the above effect can be considered to be obtained sufficiently wherever the reflective region and the light-emitting region may be present in the first electrode 101 and the light-emitting layer that emits the desired light, respectively.

In the light-emitting device of one embodiment of the present invention, at least one of the first electrode 101 and the second electrode 102 is a light-transmitting electrode (e.g., a transparent electrode or a transflective electrode). In the case where the light-transmitting electrode is a transparent electrode, the transparent electrode has a visible light transmittance higher than or equal to 40%. In the case where the light-transmitting electrode is a transflective electrode, the transflective electrode has a visible light reflectance higher than or equal to 20% and lower than or equal to 80%, preferably higher than or equal to 40% and lower than or equal to 70%. These electrodes preferably have a resistivity lower than or equal to 1×10⁻² Ωcm. When one of the first electrode 101 and the second electrode 102 is a reflective electrode in the light-emitting device of one embodiment of the present invention, the visible light reflectance of the reflective electrode is higher than or equal to 40% and lower than or equal to 100%, preferably higher than or equal to 70% and lower than or equal to 100%. This electrode preferably has a resistivity lower than or equal to 1×10⁻² Ωcm.

### <Hole-Injection Layer>

The hole-injection layers (111, 111a, and 111b) inject holes from the first electrode 101 serving as the anode and the charge-generation layers (106, 106a, and 106b) to the organic compound layers (103, 103a, and 103b) and contain an organic acceptor material and a material having a high hole-injection property.

The organic acceptor material allows holes to be generated in another organic compound whose HOMO level is close to the LUMO level of the organic acceptor material when charge separation is caused between the organic acceptor material and the organic compound. Thus, as the organic acceptor material, a compound having an electron-withdrawing group (e.g., a halogen group or a cyano group), such as a quinodimethane derivative, a chloranil derivative, or a hexaazatriphenylene derivative, can be used. Examples of the organic acceptor material include 7,7,8,8-tetracyano-2,3,5,6-tetrafluoroquinodimethane (abbreviation: F₄-TCNQ), 3,6-difluoro-2,5,7,7,8,8-hexacyanoquinodimethane, chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylen-1,3,4,5,6,8,9,10-octafluoro-7H-pyren-2-ylidene)malononitrile. Note that among organic acceptor materials, a compound in which electron-withdrawing groups are bonded to fused aromatic rings each having a plurality of heteroatoms, such as HAT-CN, is particularly preferable because it has a high acceptor property and stable film quality against heat. Besides, a [3]radialene derivative having an electron-withdrawing group (particularly a cyano group or a halogen group such as a fluoro group), which has a very high electron-accepting property, is preferable; specific examples include α,α,′,α,″-1,2,3-cyclopropanetriylidenetris[4-cyano-2,3,5,6-tetrafluorobenzeneacetonitrile], α,α,′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile].

As the material having a high hole-injection property, an oxide of a metal belonging to Group 4 to Group 8 of the periodic table (e.g., a transition metal oxide such as molybdenum oxide, vanadium oxide, ruthenium oxide, tungsten oxide, or manganese oxide) can be used. Specific examples include molybdenum oxide, vanadium oxide, niobium oxide, tantalum oxide, chromium oxide, tungsten oxide, manganese oxide, and rhenium oxide. Among the above oxides, molybdenum oxide is preferable because it is stable in the air, has a low hygroscopic property, and is easily handled. Other examples include a perylenetetracarboxylic acid derivative such as diquinoxalino[2,3-a:2′,3′-c]phenazine (abbreviation: HATNA), 2,3,8,9,14,15-hexafluorodiquinoxalino[2,3-a:2′,3′-c]phenazine (abbreviation: HATNA-F₆), 3,4,9,10-perylenetetracarboxylic diimide (abbreviation: PTCDI), or 3,4,9,10-perylenetetracarboxyl-bis-benzimidazole (abbreviation: PTCBI); (C₆₀—Iₕ)[5,6]fullerene (abbreviation: C₆₀); (C₇₀-D₅ₕ)[5,6]fullerene (abbreviation: C₇₀); an organic compound such as phthalocyanine (abbreviation: H₂Pc); and a metal phthalocyanine containing copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). A phthalocyanine-based metal complex such as CuPc or ZnPc and 2,3,8,9,14,15-hexafluorodiquinoxalino[2,3-a:2′,3′-c]phenazine are especially preferable. Among these materials, CuPc and ZnPc are preferable because they are inexpensive and have favorable characteristics. Using ZnPc, which has a low diffusion coefficient with respect to silicon, reduces the probability that metal diffusion to a semiconductor adversely affects the semiconductor characteristics; accordingly, ZnPc is particularly suitable for a display apparatus manufactured using a silicon semiconductor.

Other examples include aromatic amine compounds, which are low-molecular compounds, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), N,N′-bis[4-bis(3-methylphenyl)aminophenyl]-N,N′-diphenyl-4,4′-diaminobiphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), and 3-[N-(1-naphthyl)-N-(9-phenylcarbazol-3-yl)amino]-9-phenylcarbazole (abbreviation: PCzPCN1).

Other examples include high-molecular compounds (e.g., oligomers, dendrimers, and polymers) such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide](abbreviation: PTPDMA), and poly[N,N′-bis(4-butylphenyl)-N,N′-bis(phenyl)benzidine](abbreviation: Poly-TPD). Alternatively, it is possible to use a high-molecular compound to which acid is added, such as poly(3,4-ethylenedioxythiophene)/(polystyrenesulfonic acid) (abbreviation: PEDOT/PSS) or polyaniline/(polystyrenesulfonic acid) (abbreviation: PAni/PSS), for example.

As the material having a high hole-injection property, a mixed material containing a hole-transport material and the above-described organic acceptor material (electron-accepting material) can be used. In that case, the organic acceptor material extracts electrons from the hole-transport material, so that holes are generated in the hole-injection layer 111 and the holes are injected into the light-emitting layer 113 through the hole-transport layer 112. Note that the hole-injection layer 111 may be formed to have a single-layer structure using a mixed material containing a hole-transport material and an organic acceptor material (electron-accepting material), or a stacked-layer structure of a layer including a hole-transport material and a layer including an organic acceptor material (electron-accepting material).

The hole-transport material preferably has a hole mobility higher than or equal to 1×10⁻⁶ cm²/Vs in the case where the square root of the electric field strength [V/cm] is 600. Note that other substances can also be used as long as the substances have hole-transport properties higher than electron-transport properties.

Preferable examples of the hole-transport material include hole-transport materials such as a compound having a π-electron rich heteroaromatic ring (e.g., a carbazole derivative, a furan derivative, and a thiophene derivative) and an aromatic amine (an organic compound having an aromatic amine skeleton).

Examples of the carbazole derivative (an organic compound having a carbazole ring) include a bicarbazole derivative (e.g., a 3,3′-bicarbazole derivative) and an aromatic amine having a carbazolyl group.

Specific examples of the bicarbazole derivative (e.g., a 3,3′-bicarbazole derivative) include 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), and 9-(2-naphthyl)-9′-phenyl-3,3′-bi-9H-carbazole (abbreviation: βNCCP).

Specific examples of the aromatic amine having a carbazolyl group include 4-phenyl-4′-(9-phenyl-9H-carbazol-3-yl)triphenylamine (abbreviation: PCBA1BP), N-(biphenyl-4-yl)-N-(9,9-dimethyl-9H-fluoren-2-yl)-9-phenyl-9H-carbazol-3-amine (abbreviation: PCBiF), N-(biphenyl-4-yl)-N-[4-(9-phenyl-9H-carbazol-3-yl)phenyl]-9,9-dimethyl-9H-fluoren-2-amine (abbreviation: PCBBiF), N-[4-(9-phenyl-9H-carbazol-3-yl)phenyl]bis(9,9-dimethyl-9H-fluoren-2-yl)amine (abbreviation: PCBFF), N-(1,1′-biphenyl-4-yl)-N-[4-(9-phenyl-9H-carbazol-3-yl)phenyl]-9,9-dimethyl-9H-fluoren-4-amine, N-[4-(9-phenyl-9H-carbazol-3-yl)phenyl]-(9,9-dimethyl-9H-fluoren-2-yl)-9,9-dimethyl-9H-fluoren-4-amine, N-(1,1′-biphenyl-4-yl)-N-[4-(9-phenyl-9H-carbazol-3-yl)phenyl]-9,9-diphenyl-9H-fluoren-2-amine, N-(1,1′-biphenyl-4-yl)-N-[4-(9-phenyl-9H-carbazol-3-yl)phenyl]-9,9-diphenyl-9H-fluoren-4-amine, N-(1,1′-biphenyl-4-yl)-N-[4-(9-phenyl-9H-carbazol-3-yl)phenyl]-9,9′-spirobi(9H-fluoren)-2-amine, N-(1,1′-biphenyl-4-yl)-N-[4-(9-phenyl-9H-carbazol-3-yl)phenyl]-9,9′-spirobi(9H-fluoren)-4-amine, N-[4-(9-phenyl-9H-carbazol-3-yl)phenyl]-N-(1,1′:3′,1″-terphenyl-4-yl)-9,9-dimethyl-9H-fluoren-2-amine, N-[4-(9-phenyl-9H-carbazol-3-yl)phenyl]-N-(1,1′:4′,1″-terphenyl-4-yl)-9,9-dimethyl-9H-fluoren-2-amine, N-[4-(9-phenyl-9H-carbazol-3-yl)phenyl]-N-(1,1′:3′,1″-terphenyl-4-yl)-9,9-dimethyl-9H-fluoren-4-amine, N-[4-(9-phenyl-9H-carbazol-3-yl)phenyl]-N-(1,1′:4′,1″-terphenyl-4-yl)-9,9-dimethyl-9H-fluoren-4-amine, 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N′-bis(9-phenylcarbazol-3-yl)-N,N′-diphenylbenzene-1,3-diamine (abbreviation: PCA2B), N,N′,N″-triphenyl-N,N′,N″-tris(9-phenylcarbazol-3-yl)benzene-1,3,5-triamine (abbreviation: PCA3B), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), N-(9,9-spirobi[9H-fluoren]-2-yl)-N,9-diphenylcarbazol-3-amine (abbreviation: PCASF), N-(4-biphenyl)-4-(carbazol-9-yl)phenylaniline (abbreviation: YGA1BP), N,N′-bis[4-(carbazol-9-yl)phenyl]-N,N′-diphenyl-9,9-dimethylfluorene-2,7-diamine (abbreviation: YGA2F), and 4,4′,4″-tris(carbazol-9-yl)triphenylamine (abbreviation: TCTA).

Other examples of the carbazole derivative include 9-[4-(9-phenyl-9H-carbazol-3-yl)phenyl]phenanthrene (abbreviation: PCPPn), 3-[4-(1-naphthyl)phenyl]-9-phenyl-9H-carbazole (abbreviation: PCPN), 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), 9-[3-(triphenylsilyl)phenyl]-3,9′-bi-9H-carbazole (abbreviation: PSiCzCz), 9′-phenyl-9′H-9,3′:6′,9″-tercarbazole (abbreviation: PSiCzGI), 3,9-bis(9-phenyl-9H-carbazol-3-yl)-9H-carbazole (abbreviation: PCCzPC), 9-(biphenyl-4-yl)-9′-phenyl-3,3′-bi-9H-carbazole (abbreviation: PCCzBP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: PNCCBP), 9,9′-di-2-naphthyl-3,3′-9H,9′H-bicarbazole (abbreviation: BisPNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, and 9-(triphenylen-2-yl)-9′-[1,1′:3′,1″-terphenyl]-4-yl-3,3′-9H,9′H-bicarbazole.

Specific examples of the furan derivative (an organic compound having a furan ring) include 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II).

Specific examples of the thiophene derivative (an organic compound having a thiophene ring) include organic compounds having a thiophene ring such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV).

Specific examples of the aromatic amine include 4,4′-bis[N-(1-naphthyl)-N-phenylamino]biphenyl (abbreviation: NPB or α-NPD), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4-4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N¹-phenyl-N-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), N-(9,9-spirobi[9H-fluoren]-2-yl)-N,N′,N′-triphenyl-1,4-phenyldiamine (abbreviation: DPASF), N,N′-diphenyl-N,N′-bis(4-diphenylaminophenyl)spirobi[9H-fluorene]-2,7-diamine (abbreviation: DPA2SF), 4,4′,4″-tris[N-(1-naphthyl)-N-phenylamino]triphenylamine (abbreviation: 1′-TNATA), 4,4′,4″-tris(N,N-diphenylamino)triphenylamine (abbreviation: TDATA), 4,4′,4″-tris[N-(3-methylphenyl)-N-phenylamino]triphenylamine (abbreviation: m-MTDATA), N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), DNTPD, 1,3,5-tris[N-(4-diphenylaminophenyl)-N-phenylamino]benzene (abbreviation: DPA3B), N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)-triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-[4-(9-phenylfluoren-9-yl)phenyl]triphenylamine (abbreviation: BPAFLBi), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Other examples of the hole-transport material include high-molecular compounds (e.g., oligomers, dendrimers, and polymers) such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N′-phenylamino}phenyl)methacrylamide](abbreviation: PTPDMA), and poly[N,N′-bis(4-butylphenyl)-N,N′-bis(phenyl)benzidine](abbreviation: Poly-TPD). Alternatively, it is possible to use a high-molecular compound to which acid is added, such as poly(3,4-ethylenedioxythiophene)/(polystyrenesulfonic acid) (abbreviation: PEDOT/PSS) or polyaniline/(polystyrenesulfonic acid) (abbreviation: PAni/PSS), for example.

The hole-transport material is not limited to the above; any of a variety of known materials can also be used alone or in combination as the hole-transport material. Note that in the case where the above hole-transport material is used for the light-emitting layer, a compound in which some or all of hydrogen is replaced by deuterium can also be used. In that case, the efficiency of energy transfer in the light-emitting layer can be improved and deterioration of the compound can be inhibited, so that the reliability of the light-emitting device can be increased.

The hole-injection layers (111, 111a, and 111b) can be formed by any of known film formation methods such as a vacuum evaporation method.

### <Hole-Transport Layer>

The hole-transport layers (112, 112a, and 112b) transport the holes, which are injected from the first electrode 101 by the hole-injection layers (111, 111a, and 111b), to the light-emitting layers (113, 113a, and 113b). Note that the hole-transport layers (112, 112a, and 112b) each include a hole-transport material. Thus, the hole-transport layers (112, 112a, and 112b) can be formed using any of the hole-transport materials that can be used for the hole-injection layers (111, 111a, and 111b).

Note that in the light-emitting device of one embodiment of the present invention, the organic compound used for the hole-transport layers (112, 112a, and 112b) can also be used for the light-emitting layers (113, 113a, and 113b). The same organic compound is preferably used for the hole-transport layers (112, 112a, and 112b) and the light-emitting layers (113, 113a, and 113b), in which case holes can be efficiently transported from the hole-transport layers (112, 112a, and 112b) to the light-emitting layers (113, 113a, and 113b).

### <Electron-Blocking Layer>

The electron-blocking layer 116 is provided to prevent passing of electrons from the light-emitting layer 113 to the first electrode 101 side. A material having an excellent hole-transport property, a low electron-transport property, and a high LUMO level is suitable for the electron-blocking layer 116. Among the above-described substances that can be used as a material of the hole-transport layer 112, a material whose LUMO level is higher (preferably more than or equal to 0.30 eV higher) than that of a material (at least a host material) included in the light-emitting layer is preferably used to form the electron-blocking layer 116. Note that the electron-blocking layer, which transports holes, can also be regarded as part of the hole-transport layer 112.

### <Light-Emitting Layer>

The light-emitting layers (113, 113a, and 113b) each have the structure described in Embodiment 1 and include a light-emitting material. The light-emitting layers (113, 113a, and 113b) include a light-emitting material. Note that as a light-emitting material that can be used in the light-emitting layers (113, 113a, and 113b), a substance that exhibits emission color such as blue, violet, bluish violet, green, yellowish green, yellow, orange, or red can be used as appropriate. When a plurality of light-emitting layers are provided, the use of different light-emitting materials for the light-emitting layers enables a structure that exhibits different emission colors (e.g., white light emission obtained by a combination of complementary emission colors). When a plurality of light-emitting layers are provided, the light-emitting layers can exhibit the same color. The structure in which a plurality of light-emitting layers that emit light of the same color are stacked can achieve higher reliability than a single-layer structure in some cases. Furthermore, one light-emitting layer may have a stacked-layer structure including different light-emitting materials.

<<Material Having Function of Converting Singlet Excitation Energy into Light Emission>>

The following substances that emit fluorescent light (fluorescent substances) can be given as examples of the material having a function of converting singlet excitation energy into light emission and can be used in the light-emitting layers (113, 113a, and 113b): a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative. A pyrene derivative is particularly preferable because it has a high emission quantum yield. Specific examples of the pyrene derivative include N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-diphenyl-N,N′-bis[4-(9-phenyl-9H-fluoren-9-yl)phenyl]pyrene-1,6-diamine (abbreviation: 1,6FLPAPrn), N,N′-bis(dibenzofuran-2-yl)-N,N′-diphenylpyrene-1,6-diamine (abbreviation: 1,6FrAPrn), N,N′-bis(dibenzothiophen-2-yl)-N,N′-diphenylpyrene-1,6-diamine (abbreviation: 1,6ThAPrn), N,N′-(pyrene-1,6-diyl)bis[(N-phenylbenzo[b]naphtho[1,2-d]furan)-6-amine](abbreviation: 1,6BnfAPrn), N,N′-(pyrene-1,6-diyl)bis[(N-phenylbenzo[b]naphtho[1,2-d]furan)-8-amine](abbreviation: 1,6BnfAPrn-02), and N,N′-(pyrene-1,6-diyl)bis[(6,N-diphenylbenzo[b]naphtho[1,2-d]furan)-8-amine](abbreviation: 1,6BnfAPrn-03).

In addition, it is possible to use, for example, 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-bis[4-(9H-carbazol-9-yl)phenyl]-N,N′-diphenyl-4,4′-stilbenediamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), 4-(10-phenyl-9-anthryl)-4′-(9-phenyl-9H-carbazol-3-yl)triphenylamine (abbreviation: PCBAPA), 4-[4-(10-phenyl-9-anthryl)phenyl]-4′-(9-phenyl-9H-carbazol-3-yl)triphenylamine (abbreviation: PCBAPBA), perylene, 2,5,8,11-tetra-tert-butylperylene (abbreviation: TBP), N,N′-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), or the like.

It is also possible to use, for example, N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), 1,6BnfAPrn-03, N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02), or 3,10-bis[N-(dibenzofuran-3-yl)-N-phenylamino]naphtho[2,3-b;6,7-b′]bisbenzofuran (abbreviation: 3,10FrA2Nbf(IV)-02). In particular, a pyrenediamine compound such as 1,6FLPAPrn, 1,6mMemFLPAPrn, or 1,6BnfAPrn-03 can be used, for example.

<<Material Having Function of Converting Triplet Excitation Energy into Light Emission>>

Examples of the material having a function of triplet excitation energy into light emission and can be used in the light-emitting layer 113 include substances that emit phosphorescent light (phosphorescent substances).

A phosphorescent substance is a compound that emits phosphorescent light but does not emit fluorescent light at a temperature higher than or equal to a low temperature (e.g., 77 K) and lower than or equal to room temperature (i.e., higher than or equal to 77 K and lower than or equal to 313 K). The phosphorescent substance preferably includes a metal element with large spin-orbit interaction, and can be an organometallic complex, a metal complex (platinum complex), or a rare earth metal complex, for example. Specifically, the phosphorescent substance preferably includes a transition metal element. It is preferable that the phosphorescent substance include a platinum group element (ruthenium (Ru), rhodium (Rh), palladium (Pd), osmium (Os), iridium (Ir), or platinum (Pt)), especially iridium, in which case the probability of direct transition between the singlet ground state and the triplet excited state can be increased.

<<Phosphorescent Substance (from 450 nm to 570 nm: Blue or Green)>>

As examples of a phosphorescent substance which emits blue or green light and whose emission spectrum has a peak wavelength higher than or equal to 450 nm and lower than or equal to 570 nm, the following substances can be given.

Examples include organoiridium complexes having a 4H-triazole ring, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), and tris[3-(5-biphenyl)-5-isopropyl-4-phenyl-4H-1,2,4-triazolato]iridium(III) (abbreviation: [Ir(iPr5btz)₃]); organoiridium complexes having a 1H-triazole ring, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organoiridium complexes having an imidazole ring, such as fac-tris[1-(2,6-diisopropylphenyl)-2-phenyl-1H-imidazole]iridium(III) (abbreviation: [Ir(iPrpim)₃]) and tris[3-(2,6-dimethylphenyl)-7-methylimidazo[1,2-f]phenanthridinato]iridium(III) (abbreviation: [Ir(dmpimpt-Me)₃]); organoiridium complexes in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), bis[2-(4′,6′-difluorophenyl)pyridinato-N,C^{2′}]iridium(III) acetylacetonate (abbreviation: FIr(acac)); and an organoplatinum complex such as (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC)platinum(II) (abbreviation: PtON-TBBI).

<<Phosphorescent Substance (from 495 nm to 590 nm: Green or Yellow)>>

As examples of a phosphorescent substance which emits green or yellow light and whose emission spectrum has a peak wavelength higher than or equal to 495 nm and lower than or equal to 590 nm, the following substances can be given.

Examples of the phosphorescent substance include organoiridium complexes having a pyrimidine ring, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis{4,6-dimethyl-2-[6-(2,6-dimethylphenyl)-4-pyrimidinyl-κN³]phenyl-κC}iridium(III) (abbreviation: [Ir(dmppm-dmp)₂(acac)]), and (acetylacetonato)bis(4,6-diphenylpyrimidinato)iridium(III) (abbreviation: [Ir(dppm)₂(acac)]); organoiridium complexes having a pyrazine ring, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organoiridium complexes having a pyridine ring, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), bis[2-(2-pyridinyl-κN)phenyl-κC][2-(4-phenyl-2-pyridinyl-κN)phenyl-κC]iridium(III) (abbreviation: [Ir(ppy)₂(4dppy)]), bis[2-(2-pyridinyl-κN)phenyl-κC][2-(4-methyl-5-phenyl-2-pyridinyl-κN)phenyl-κC], [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d₃)₂(mbfpypy-d₃)]), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: Ir(5mtpy-d₆)₂(mbfpypy-iPr-d₄)), [2-d₃-methyl-(2-pyridinyl-κN)benzofuro[2,3-b]pyridine-κC]bis[2-(2-pyridinyl-κN)phenyl-κC]iridium(III) (abbreviation: Ir(ppy)₂(mbfpypy-d₃)), and [2-(4-methyl-5-phenyl-2-pyridinyl-κN)phenyl-κC]bis[2-(2-pyridinyl-κN)phenyl-κC]iridium(III) (abbreviation: Ir(ppy)₂(mdppy)); organometallic complexes such as bis(2,4-diphenyl-1,3-oxazolato-N,C^{2′})iridium(III) acetylacetonate (abbreviation: [Ir(dpo)₂(acac)]), bis{2-[4′-(perfluorophenyl)phenyl]pyridinato-N,C^{2′}}iridium(III) acetylacetonate (abbreviation: [Ir(p-PF-ph)₂(acac)]), and bis(2-phenylbenzothiazolato-N,C^{2′})iridium(III) acetylacetonate (abbreviation: [Ir(bt)₂(acac)]); and a rare earth metal complex such as tris(acetylacetonato) (monophenanthroline)terbium(III) (abbreviation: [Tb(acac)₃(Phen)]).

<<Phosphorescent Substance (from 570 nm to 750 nm: Yellow or Red)>>

As examples of a phosphorescent substance which emits yellow or red light and whose emission spectrum has a peak wavelength higher than or equal to 570 nm and lower than or equal to 750 nm, the following substances can be given.

Examples of the phosphorescent substance include organometallic complexes having a pyrimidine ring, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and (dipivaloylmethanato)bis[4,6-di(naphthalen-1-yl)pyrimidinato]iridium(III) (abbreviation: [Ir(d1npm)₂(dpm)]); organometallic complexes having a pyrazine ring, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), bis{4,6-dimethyl-2-[3-(3,5-dimethylphenyl)-5-phenyl-2-pyrazinyl-N]phenyl-κC}(2,6-dimethyl-3,5-heptanedionato-κ²O,O′)iridium(III) (abbreviation: [Ir(dmdppr-P)₂(dibm)]), bis{4,6-dimethyl-2-[5-(4-cyano-2,6-dimethylphenyl)-3-(3,5-dimethylphenyl)-2-pyrazinyl-κN]phenyl-κC}(2,2,6,6-tetramethyl-3,5-heptanedionato-κ²O,O′)iridium(III) (abbreviation: [Ir(dmdppr-dmCP)₂(dpm)]), bis{2-[5-(2,6-dimethylphenyl)-3-(3,5-dimethylphenyl)-2-pyrazinyl-κN]-4,6-dimethylphenyl-κC}(2,2′,6,6′-tetramethyl-3,5-heptanedionato-κ²O,O′)iridium(III) (abbreviation: [Ir(dmdppr-dmp)₂(dpm)]), (acetylacetonato)bis(2-methyl-3-phenylquinoxalinato-N,C^{2′})iridium(III) (abbreviation: [Ir(mpq)₂(acac)]), (acetylacetonato)bis(2,3-diphenylquinoxalinato-N,C^{2′})iridium(III) (abbreviation: [Ir(dpq)₂(acac)]), and (acetylacetonato)bis[2,3-bis(4-fluorophenyl)quinoxalinato]iridium(III) (abbreviation: [Ir(Fdpq)₂(acac)]); organometallic complexes having a pyridine ring, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), and bis[4,6-dimethyl-2-(2-quinolinyl-κN)phenyl-κC](2,4-pentanedionato-κ²O,O′)iridium(III) (abbreviation: [Ir(dmpqn)₂(acac)]); a platinum complex such as 2,3,7,8,12,13,17,18-octaethyl-21H,23H-porphyrin platinum(II) (abbreviation: [PtOEP]); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]).

### <<TADF Material>>

Any of materials described below can be used as the TADF material. The TADF material is a material that has a small difference between its S1 and T₁ levels (preferably less than or equal to 0.20 eV), enables up-conversion of a triplet excited state into a singlet excited state (i.e., reverse intersystem crossing) using a little thermal energy, and efficiently exhibits light (fluorescent light) from the singlet excited state. The thermally activated delayed fluorescence is efficiently obtained under the condition where the difference in energy between the triplet excitation energy level and the singlet excitation energy level is greater than or equal to 0.00 eV and less than or equal to 0.20 eV, preferably greater than or equal to 0.00 eV and less than or equal to 0.10 eV. Delayed fluorescent light by the TADF material refers to light emission having a spectrum similar to that of normal fluorescent light and an extremely long lifetime. The lifetime is longer than or equal to 1×10⁻⁶ seconds, or longer than or equal to 1×10⁻³ seconds.

Note that the TADF material can be also used as an electron-transport material, a hole-transport material, or a host material.

Examples of the TADF material include fullerene, a derivative thereof, an acridine derivative such as proflavine, and eosin. Other examples include a metal-containing porphyrin, such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (abbreviation: SnF₂(Proto IX)), a mesoporphyrin-tin fluoride complex (abbreviation: SnF₂(Meso IX)), a hematoporphyrin-tin fluoride complex (abbreviation: SnF₂(Hemato IX)), a coproporphyrin tetramethyl ester-tin fluoride complex (abbreviation: SnF₂(Copro III-4Me)), an octaethylporphyrin-tin fluoride complex (abbreviation: SnF₂(OEP)), an etioporphyrin-tin fluoride complex (abbreviation: SnF₂(Etio I)), and an octaethylporphyrin-platinum chloride complex (abbreviation: PtCl₂OEP).

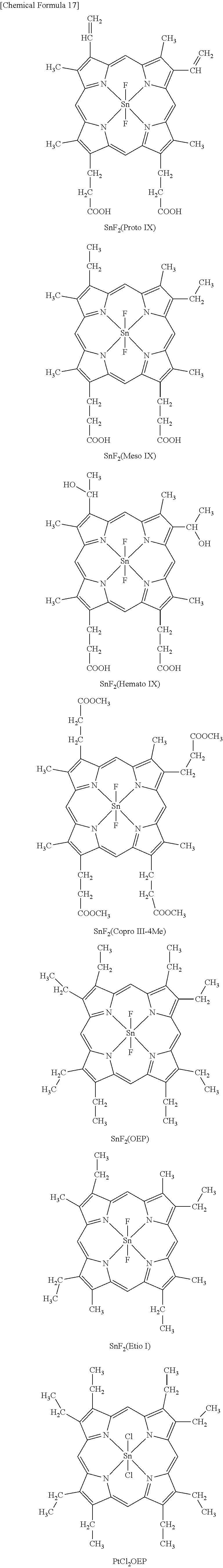

Additionally, a heteroaromatic compound having a π-electron rich heteroaromatic compound and a π-electron deficient heteroaromatic compound, such as 2-(biphenyl-4-yl)-4,6-bis(12-phenylindolo[2,3-a]carbazol-11-yl)-1,3,5-triazine (abbreviation: PIC-TRZ), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), 4-(9′-phenyl-3,3′-bi-9H-carbazol-9-yl)benzofuro[3,2-d]pyrimidine (abbreviation: 4PCCzBfpm), 4-[4-(9′-phenyl-3,3′-bi-9H-carbazol-9-yl)phenyl]benzofuro[3,2-d]pyrimidine (abbreviation: 4PCCzPBfpm), or 9-[3-(4,6-diphenyl-1,3,5-triazin-2-yl)phenyl]-9′-phenyl-2,3′-bi-9H-carbazole (abbreviation: mPCCzPTzn-02) may be used.

Note that a substance in which a π-electron rich heteroaromatic compound is directly bonded to a π-electron deficient heteroaromatic compound is particularly preferable because both the donor property of the π-electron rich heteroaromatic compound and the acceptor property of the π-electron deficient heteroaromatic compound are enhanced and the energy difference between the singlet excited state and the triplet excited state becomes small. As the TADF material, a TADF material in which the singlet and triplet excited states are in thermal equilibrium (TADF100) may be used. Since such a TADF material enables a short emission lifetime (excitation lifetime), the efficiency of a light-emitting device in a high-luminance region can be less likely to decrease.

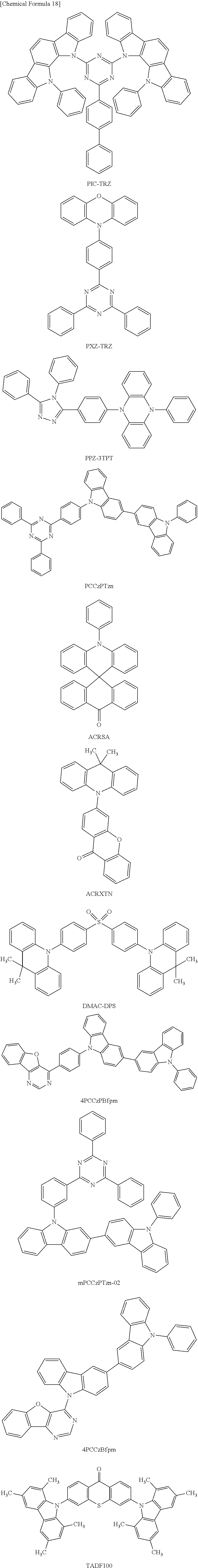

In addition to the above, another example of a material having a function of converting triplet excitation energy into light emission is a nano-structure of a transition metal compound having a perovskite structure. In particular, a nano-structure of a metal halide perovskite material is preferable. The nano-structure is preferably a nanoparticle or a nanorod.

As the organic compound (e.g., the host material) used in combination with the above-described light-emitting material (guest material) in the light-emitting layers (113, 113a, 113b, and 113c), one or more selected from substances having a larger energy gap than the light-emitting material (guest material) can be used.

### <<Host Material for Fluorescence>>

In the case where the light-emitting material used in the light-emitting layers (113, 113a, 113b, and 113c) is a fluorescent substance, an organic compound (host material) used in combination with the fluorescent substance is preferably an organic compound that has a high energy level in a singlet excited state and has a low energy level in a triplet excited state or an organic compound having a high fluorescence quantum yield. Thus, the hole-transport material (described above) and the electron-transport material (described below) shown in this embodiment, for example, can be used as long as they are organic compounds that satisfy such a condition. Note that in the case where the above hole-transport material is used for the light-emitting layer, a compound in which some or all of hydrogen is replaced by deuterium can also be used. In that case, the efficiency of energy transfer in the light-emitting layer can be improved and deterioration of the compound can be inhibited, so that the reliability of the light-emitting device can be increased.

In terms of a preferable combination with the light-emitting material (fluorescent substance), examples of the organic compound (host material), some of which are mentioned in the above specific examples, include fused polycyclic aromatic compounds such as an anthracene derivative, a tetracene derivative, a phenanthrene derivative, a pyrene derivative, a chrysene derivative, and a dibenzo[g,p]chrysene derivative.

Specific examples of the organic compound (host material) that is preferably used in combination with the fluorescent substance include 9-phenyl-3-[4-(10-phenyl-9-anthryl)phenyl]-9H-carbazole (abbreviation: PCzPA), 3,6-diphenyl-9-[4-(10-phenyl-9-anthryl)phenyl]-9H-carbazole (abbreviation: DPCzPA), 3-[4-(1-naphthyl)phenyl]-9-phenyl-9H-carbazole (abbreviation: PCPN), 9,10-diphenylanthracene (abbreviation: DPAnth), N,N-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), YGAPA, PCAPA, N,9-diphenyl-N-{4-[4-(10-phenyl-9-anthryl)phenyl]phenyl}-9H-carbazol-3-amine (abbreviation: PCAPBA), N-(9,10-diphenyl-2-anthryl)-N,9-diphenyl-9H-carbazol-3-amine (abbreviation: 2PCAPA), 6,12-dimethoxy-5,11-diphenylchrysene, N,N,N′,N′,N″,N″,N′″,N′″-octaphenyldibenzo[g,p]chrysene-2,7,10,15-tetraamine (abbreviation: DBC1), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4′-(9-phenyl-9H-fluoren-9-yl)biphenyl-4-yl]anthracene (abbreviation: FLPPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9-(1-naphthyl)-10-(2-naphthyl)anthracene (abbreviation: α,β-ADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(1-naphthyl)-10-[4-(2-naphthyl)phenyl]anthracene (abbreviation: αN-βNPAnth), 2,9-di(1-naphthyl)-10-phenylanthracene (abbreviation: 2α,N-αNPhA), 9-(1-naphthyl)-10-[3-(1-naphthyl)phenyl]anthracene (abbreviation: α,N-mα,NPAnth), 9-(2-naphthyl)-10-[3-(1-naphthyl)phenyl]anthracene (abbreviation: βN-mαNPAnth), 9-(1-naphthyl)-10-[4-(1-naphthyl)phenyl]anthracene (abbreviation: α,N-α,NPAnth), 9-(2-naphthyl)-10-[4-(2-naphthyl)phenyl]anthracene (abbreviation: βN-βNPAnth), 2-(1-naphthyl)-9-(2-naphthyl)-10-phenylanthracene (abbreviation: 2αN-βNPhA), 9-(2-naphthyl)-10-[3-(2-naphthyl)phenyl]anthracene (abbreviation: βN-mβNPAnth), 1-{4-[10-(biphenyl-4-yl)-9-anthracenyl]phenyl}-2-ethyl-1H-benzimidazole (abbreviation: EtBImPBPhA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 1,3,5-tri(1-pyrenyl)benzene (abbreviation: TPB3), 5,12-diphenyltetracene, and 5,12-bis(biphenyl-2-yl)tetracene.

### <<Host Material for Phosphorescence>>

In the case where the light-emitting material used in the light-emitting layers (113, 113a, 113b, and 113c) is a phosphorescent substance, an organic compound having triplet excitation energy (an energy difference between a ground state and a triplet excited state) which is higher than that of the light-emitting material may be selected as the organic compound (host material) used in combination with the phosphorescent substance. Note that when a plurality of organic compounds (e.g., a first host material and a second host material (or an assist material)) are used in combination with a light-emitting material to form an exciplex, the plurality of organic compounds are preferably mixed with the phosphorescent substance.

With such a structure, light emission can be efficiently obtained by exciplex-triplet energy transfer (ExTET), which is energy transfer from an exciplex to a light-emitting material. Note that a combination of the plurality of organic compounds that easily forms an exciplex is preferable, and it is particularly preferable to combine a compound that easily accepts holes (hole-transport material) and a compound that easily accepts electrons (electron-transport material).

In terms of a preferred combination with the light-emitting material (phosphorescent substance), examples of the organic compounds (the host material and the assist material), some of which are mentioned in the above specific examples, include an aromatic amine (an organic compound having an aromatic amine skeleton), a carbazole derivative (an organic compound having a carbazole ring), a dibenzothiophene derivative (an organic compound having a dibenzothiophene ring), a dibenzofuran derivative (an organic compound having a dibenzofuran ring), an oxadiazole derivative (an organic compound having an oxadiazole ring), a triazole derivative (an organic compound having a triazole ring), a benzimidazole derivative (an organic compound having a benzimidazole ring), a quinoxaline derivative (an organic compound having a quinoxaline ring), a dibenzoquinoxaline derivative (an organic compound having a dibenzoquinoxaline ring), a pyrimidine derivative (an organic compound having a pyrimidine ring), a triazine derivative (an organic compound having a triazine ring), a pyridine derivative (an organic compound having a pyridine ring), a bipyridine derivative (an organic compound having a bipyridine ring), a phenanthroline derivative (an organic compound having a phenanthroline ring), a furodiazine derivative (an organic compound having a furodiazine ring), and zinc- or aluminum-based metal complexes.

Among the above organic compounds, specific examples of the aromatic amine and the carbazole derivative, which are organic compounds having a high hole-transport property, are the same as the specific examples of the hole-transport materials described above, and those materials are preferable as the host material.

Among the above organic compounds, specific examples of the dibenzothiophene derivative and the dibenzofuran derivative, which are organic compounds having a high hole-transport property, include 4-{3-[3-(9-phenyl-9H-fluoren-9-yl)phenyl]phenyl}dibenzofuran (abbreviation: mmDBFFLBi-II), 4,4′,4″-(benzene-1,3,5-triyl)tri(dibenzofuran) (abbreviation: DBF3P-II), DBT3P-II, 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), and 4-[3-(triphenylen-2-yl)phenyl]dibenzothiophene (abbreviation: mDBTPTp-II). These derivatives are preferable as the host material.

Other examples of preferable host materials include metal complexes having an oxazole-based or thiazole-based ligand, such as bis[2-(2-benzoxazolyl)phenolato]zinc(II) (abbreviation: ZnPBO) and bis[2-(2-benzothiazolyl)phenolato]zinc(II) (abbreviation: ZnBTZ).

Among the above organic compounds, specific examples of the oxadiazole derivative, the triazole derivative, the benzimidazole derivative, the quinoxaline derivative, the dibenzoquinoxaline derivative, the quinazoline derivative, and the phenanthroline derivative, which are organic compounds having a high electron-transport property, include an organic compound including a heteroaromatic ring having an azole ring such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound including a heteroaromatic ring having a phenanthroline ring such as bathophenanthroline (abbreviation: BPhen), bathocuproine (abbreviation: BCP), 2,9-di(naphthalen-2-yl)-4,7-diphenyl-1,10-phenanthroline (abbreviation: NBphen), or 2,2′-(1,3-phenylene)bis(9-phenyl-1,10-phenanthroline) (abbreviation: mPPhen2P); and an organic compound including a heteroaromatic ring having a dibenzoquinoxaline ring such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 2-{4-[9,10-di(2-naphthyl)-2-anthryl]phenyl}-1-phenyl-1H-benzimidazole (abbreviation: ZADN), or 2-4′-(9-phenyl-9H-carbazol-3-yl)-3,1′-biphenyl-1-yl]dibenzo[f,h]quinoxaline (abbreviation: 2mpPCBPDBq). These organic compounds are preferable as the host material.

Specific examples of the pyridine derivative, the diazine derivative (e.g., the pyrimidine derivative, the pyrazine derivative, and the pyridazine derivative), the triazine derivative, and the furodiazine derivative, which are organic compounds having a high electron-transport property among the above organic compounds, include organic compounds including a heteroaromatic ring having a diazine ring such as 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), 9,9′-[pyrimidine-4,6-diylbis(biphenyl-3,3′-diyl)]bis(9H-carbazole) (abbreviation: 4,6mCzBP2Pm), 2-[3′-(9,9-dimethyl-9H-fluoren-2-yl)biphenyl-3-yl]-4,6-diphenyl-1,3,5-triazine (abbreviation: mFBPTzn), 8-(biphenyl-4-yl)-4-[3-(dibenzothiophen-4-yl)phenyl]-[1]benzofuro[3,2-d]pyrimidine (abbreviation: 8BP-4mDBtPBfpm), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 11-[3′-(dibenzothiophen-4-yl)biphenyl-3-yl]phenanthro[9′,10′:4,5]furo[2,3-b]pyrazine (abbreviation: 11mDBtBPPnfpr), 11-[3′-(dibenzothiophen-4-yl)biphenyl-4-yl]phenanthro[9′,10′:4,5]furo[2,3-b]pyrazine, 11-[3′-(9H-carbazol-9-yl)biphenyl-3-yl]phenanthro[9′,10′:4,5]furo[2,3-b]pyrazine, 12-(9′-phenyl-3,3′-bi-9H-carbazol-9-yl)phenanthro[9′,10′:4,5]furo[2,3-b]pyrazine (abbreviation: 12PCCzPnfpr), 9-[3′-(9-phenyl-9H-carbazol-3-yl)biphenyl-4-yl]naphtho[1′,2′:4,5]furo[2,3-b]pyrazine (abbreviation: 9pmPCBPNfpr), 9-(9′-phenyl-3,3′-bi-9H-carbazol-9-yl)naphtho[1′,2′:4,5]furo[2,3-b]pyrazine (abbreviation: 9PCCzNfpr), 10-(9′-phenyl-3,3′-bi-9H-carbazol-9-yl)naphtho[1′,2′:4,5]furo[2,3-b]pyrazine (abbreviation: 10PCCzNfpr), 9-[3′-(6-phenylbenzo[b]naphtho[1,2-d]furan-8-yl)biphenyl-3-yl]naphtho[1′,2′:4,5]furo[2,3-b]pyrazine (abbreviation: 9mBnfBPNfpr), 9-{3-[6-(9,9-dimethylfluoren-2-yl)dibenzothiophen-4-yl]phenyl}naphtho[1′,2′:4,5]furo[2,3-b]pyrazine (abbreviation: 9mFDBtPNfpr), 9-[3′-(6-phenyldibenzothiophen-4-yl)biphenyl-3-yl]naphtho[1′,2′:4,5]furo[2,3-b]pyrazine (abbreviation: 9mDBtBPNfpr-02), 9-[3-(9′-phenyl-3,3′-bi-9H-carbazol-9-yl)phenyl]naphtho[1′,2′:4,5]furo[2,3-b]pyrazine (abbreviation: 9mPCCzPNfpr), 9-[3′-(2,8-diphenyldibenzothiophen-4-yl)biphenyl-3-yl]naphtho[1′,2′:4,5]furo[2,3-b]pyrazine, 11-[3′-(2,8-diphenyldibenzothiophen-4-yl)biphenyl-3-yl]phenanthro[9′,10′:4,5]furo[2,3-b]pyrazine, 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)biphenyl-3-yl]-4,6-diphenyl-1,3,5-triazine (abbreviation: mTpBPTzn), 2-(biphenyl-4-yl)-4-phenyl-6-(9,9′-spirobi[9H-fluoren]-2-yl)-1,3,5-triazine (abbreviation: BP-SFTzn), 2,6-bis(4-naphthalen-1-ylphenyl)-4-[4-(3-pyridyl)phenyl]pyrimidine (abbreviation: 2,4NP-6PyPPm), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 6-(biphenyl-3-yl)-4-[3,5-bis(9H-carbazol-9-yl)phenyl)-2-phenylpyrimidine (abbreviation: 6mBP-4Cz2PPm), and 4-[3,5-bis(9H-carbazol-9-yl)phenyl]-2-phenyl-6-(biphenyl-4-yl)pyrimidine (abbreviation: 6BP-4Cz2PPm), and those materials are preferable as the host material.

Specific examples of the metal complex, which is an organic compound having a high electron-transport property among the above organic compounds, include zinc- or aluminum-based metal complexes, such as tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), and bis(8-quinolinolato)zinc(II) (abbreviation: Znq), and metal complexes having a quinoline ring or a benzoquinoline ring. These metal complexes are preferable as the host material.

Moreover, high-molecular compounds such as poly(2,5-pyridinediyl) (abbreviation: PPy), poly[(9,9-dihexylfluorene-2,7-diyl)-co-(pyridine-3,5-diyl)](abbreviation: PF-Py), and poly[(9,9-dioctylfluorene-2,7-diyl)-co-(2,2′-bipyridine-6,6′-diyl)](abbreviation: PF-BPy) are preferable as the host material.

Furthermore, the following organic compounds with a diazine ring or a triazine ring, which have a bipolar property, a high hole-transport property, and a high electron-transport property, can be used as the host material: 9-phenyl-9′-(4-phenyl-2-quinazolinyl)-3,3′-bi-9H-carbazole (abbreviation: PCCzQz), 2-[4′-(9-phenyl-9H-carbazol-3-yl)-3,1′-biphenyl-1-yl]dibenzo[f,h]quinoxaline (abbreviation: 2mpPCBPDBq), 5-[3-(4,6-diphenyl-1,3,5-triazin-2-yl)phenyl]-7,7-dimethyl-5H,7H-indeno[2,1-b]carbazole (abbreviation: mINc(II)PTzn), 11-[4-(biphenyl-4-yl)-6-phenyl-1,3,5-triazin-2-yl]-11,12-dihydro-12-(biphenyl-3-yl)indolo[2,3-a]carbazole (abbreviation: BP-mBPIcz(II)Tzn), 11-[4-(biphenyl-4-yl)-6-phenyl-1,3,5-triazin-2-yl]-11,12-dihydro-12-phenyl-indolo[2,3-a]carbazole (abbreviation: BP-Icz(II)Tzn), 7-[4-(9-phenyl-9H-carbazol-2-yl)quinazolin-2-yl]-7H-dibenzo[c,g]carbazole (abbreviation: PC-cgDBCzQz), 3-{3-[9-(4,6-diphenyl-1,3,5-triazin-2-yl)-2-dibenzofuranyl]phenyl}-9-phenyl-9H-carbazole (abbreviation: mPCPDBfTzn), 9,9′-[6-(biphenyl-4-yl)-2-phenyl-1,3,5-triazin-4,3″-diyl]bis(9H-carbazole) (abbreviation: Cz-pmCzBPTzn), 3-pheny-9-[4-phenyl-6-(9-phenyl-3-dibenzofuranyl)-1,3,5-triazin-2-yl]-9H-carbazole (abbreviation: PDBf-PCzTzn), and 9-[4-(4,6-diphenyl-1,3,5-triazin-2-yl)-2-dibenzothienyl]-2-phenyl-9H-carbazole (abbreviation: PCzDBtTzn).

### <Hole-Blocking Layer>

The hole-blocking layer 117 is provided to prevent passing of holes from the light-emitting layer 113 to the second electrode 102 side. A material having an excellent electron-transport property, a low hole-transport property, and a low HOMO level is suitable for the hole-blocking layer 117. Among later-described substances that can be used as a material of the electron-transport layer 114, a material whose HOMO level is lower (preferably more than or equal to 0.30 eV lower) than that of a material (at least a host material) included in the light-emitting layer is preferably used to form the hole-blocking layer 117. Note that the hole-blocking layer, which transports electrons, can also be regarded as part of the electron-transport layer 114.

### <Electron-Transport Layer>

The electron-transport layers (114, 114a, and 114b) transport the electrons, which are injected from the second electrode 102 and the charge-generation layers (106, 106a, and 106b) by the electron-injection layers (115, 115a, and 115b) described later, to the light-emitting layers (113, 113a, and 113b). The heat resistance of the light-emitting device of one embodiment of the present invention can be improved by including the stacked electron-transport layers. The material used in the electron-transport layers (114, 114a, and 114b) is preferably a substance having an electron mobility higher than or equal to 1×10⁻⁶ cm²/Vs in the case where the square root of the electric field strength [V/cm] is 600. Note that any other substance can also be used as long as the substance has an electron-transport property higher than a hole-transport property. The electron-transport layers (114, 114a, and 114b) can function even with a single-layer structure and may have a stacked-layer structure including two or more layers. When a photolithography process is performed over the electron-transport layer including the above-described mixed material, which has heat resistance, an adverse effect of the thermal process on the device characteristics can be reduced.

### <<Electron-Transport Material>>

As the electron-transport material that can be used for the electron-transport layers (114, 114a, and 114b), an organic compound having a high electron-transport property can be used, and for example, a heteroaromatic compound can be used. The term heteroaromatic compound refers to a cyclic compound including at least two different kinds of elements in a ring. Examples of cyclic structures include a three-membered ring, a four-membered ring, a five-membered ring, a six-membered ring, and the like, and in particular, a five-membered ring and a six-membered ring are preferable. The elements included in the heteroaromatic compound are preferably one or more of nitrogen, oxygen, and sulfur, in addition to carbon. In particular, a heteroaromatic compound containing nitrogen (a nitrogen-containing heteroaromatic compound) is preferable, and any of electron-transport materials, such as a nitrogen-containing heteroaromatic compound and a compound having a π-electron deficient heteroaromatic ring including the nitrogen-containing heteroaromatic compound, is preferably used.

Note that the electron-transport material can be different from the materials used in the light-emitting layer. Not all excitons formed by recombination of carriers in the light-emitting layer can contribute to light emission and some excitons are diffused into a layer in contact with the light-emitting layer or a layer in the vicinity of the light-emitting layer. In order to avoid this phenomenon, the energy level (the lowest singlet excitation level or the lowest triplet excitation level) of a material used for the layer in contact with the light-emitting layer or the layer in the vicinity of the light-emitting layer is preferably higher than that of a material used for the light-emitting layer. Therefore, when a material different from the material of the light-emitting layer is used as the electron-transport material, a device with high efficiency can be obtained.

The heteroaromatic compound is an organic compound including at least one heteroaromatic ring.

The heteroaromatic ring includes any one of a pyridine ring, a diazine ring, a triazine ring, an azole ring, an oxazole ring, a thiazole ring, and the like. A heteroaromatic ring having a diazine ring includes a heteroaromatic ring having a pyrimidine ring, a pyrazine ring, a pyridazine ring, or the like. A heteroaromatic ring having an azole ring includes a heteroaromatic ring having an imidazole ring, a triazole ring, or an oxadiazole ring.

The heteroaromatic ring includes a fused heteroaromatic ring having a fused ring structure. Examples of the fused heteroaromatic ring include a quinoline ring, a benzoquinoline ring, a quinoxaline ring, a dibenzoquinoxaline ring, a quinazoline ring, a benzoquinazoline ring, a dibenzoquinazoline ring, a phenanthroline ring, a furodiazine ring, and a benzimidazole ring.

Examples of the heteroaromatic compound having a five-membered ring structure, which is a heteroaromatic compound containing carbon and one or more of nitrogen, oxygen, and sulfur, include a heteroaromatic compound having an imidazole ring, a heteroaromatic compound having a triazole ring, a heteroaromatic compound having an oxazole ring, a heteroaromatic compound having an oxadiazole ring, a heteroaromatic compound having a thiazole ring, and a heteroaromatic compound having a benzimidazole ring.

Examples of the heteroaromatic compound having a six-membered ring structure, which is a heteroaromatic compound containing carbon and one or more of nitrogen, oxygen, and sulfur, include a heteroaromatic compound having a heteroaromatic ring, such as a pyridine ring, a diazine ring (a pyrimidine ring, a pyrazine ring, a pyridazine ring, or the like), a triazine ring, or an azole ring. Other examples include a heteroaromatic compound having a bipyridine structure, a heteroaromatic compound having a terpyridine structure, and the like, which are included in examples of a heteroaromatic compound in which pyridine rings are connected.

Examples of the heteroaromatic compound having a fused ring structure partly including the above six-membered ring structure include a heteroaromatic compound having a fused heteroaromatic ring such as a quinoline ring, a benzoquinoline ring, a quinoxaline ring, a dibenzoquinoxaline ring, a phenanthroline ring, a furodiazine ring (including a structure in which an aromatic ring is fused to a furan ring of a furodiazine ring), or a benzimidazole ring.

Specific examples of the above-described heteroaromatic compound having a five-membered ring structure (an azole ring (including an imidazole ring, a triazole ring, or an oxadiazole ring), an oxazole ring, a thiazole ring, or a benzimidazole ring) include 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl)stilbene (abbreviation: BzOs).

Specific examples of the above-described heteroaromatic compound having a six-membered ring structure (including a heteroaromatic ring having a pyridine ring, a diazine ring, a triazine ring, or the like) include a heteroaromatic compound including a heteroaromatic ring having a pyridine ring, such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB), a heteroaromatic compound including a heteroaromatic ring having a triazine ring, such as 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)biphenyl-3-yl]-4,6-diphenyl-1,3,5-triazine (abbreviation: mTpBPTzn), 2-(biphenyl-4-yl)-4-phenyl-6-(9,9′-spirobi[9H-fluoren]-2-yl)-1,3,5-triazine (abbreviation: BP-SFTzn), 2,6-bis(4-naphthalen-1-ylphenyl)-4-[4-(3-pyridyl)phenyl]pyrimidine (abbreviation: 2,4NP-6PyPPm), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-{3-[3-(dibenzothiophen-4-yl)phenyl]phenyl}-4,6-diphenyl-1,3,5-triazine (abbreviation: mDBtBPTzn), or mFBPTzn, and a heteroaromatic compound including a heteroaromatic ring having a diazine (pyrimidine) ring, such as 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 4,6mCzBP2Pm, 6-(biphenyl-3-yl)-4-[3,5-bis(9H-carbazol-9-yl)phenyl]-2-phenylpyrimidine (abbreviation: 6mBP-4Cz2PPm), 4-[3,5-bis(9H-carbazol-9-yl)phenyl]-2-phenyl-6-(biphenyl-4-yl)pyrimidine (abbreviation: 6BP-4Cz2PPm), 4-[3-(dibenzothiophen-4-yl)phenyl]-8-(naphthalen-2-yl)-[1]benzofuro[3,2-d]pyrimidine (abbreviation: 8βN-4mDBtPBfpm), 8BP-4mDBtPBfpm, 9mDBtBPNfpr, 9pmDBtBPNfpr, 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), or 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm). Note that examples of the above aromatic compounds including a heteroaromatic ring include heteroaromatic compounds having a fused heteroaromatic ring.

Other examples include heteroaromatic compounds including a heteroaromatic ring having a diazine (pyrimidine) ring, such as 2,2′-(pyridine-2,6-diyl)bis(4-phenylbenzo[h]quinazoline) (abbreviation: 2,6(P-Bqn)2Py), 2,2′-(2,2′-bipyridine-6,6′-diyl)bis(4-phenylbenzo[h]quinazoline) (abbreviation: 6,6′(P-Bqn)2BPy), 2,2′-(pyridine-2,6-diyl)bis{4-[4-(2-naphthyl)phenyl]-6-phenylpyrimidine}(abbreviation: 2,6(NP-PPm)2Py), or 6-(biphenyl-3-yl)-4-[3,5-bis(9H-carbazol-9-yl)phenyl]-2-phenylpyrimidine (abbreviation: 6mBP-4Cz2PPm), and a heteroaromatic compound including a heteroaromatic ring having a triazine ring, such as 2,4,6-tris(3′-(pyridin-3-yl)biphenyl-3-yl)-1,3,5-triazine (abbreviation: TmPPPyTz), 2,4,6-tris(2-pyridyl)-1,3,5-triazine (abbreviation: 2Py3Tz), or 2-[3-(2,6-dimethyl-3-pyridyl)-5-(9-phenanthryl)phenyl]-4,6-diphenyl-1,3,5-triazine (abbreviation: mPn-mDMePyPTzn).

Specific examples of the above-described heteroaromatic compound having a fused ring structure partly including a six-membered ring structure (the heteroaromatic compound having a fused ring structure) include a heteroaromatic compound having a quinoxaline ring, such as bathophenanthroline (abbreviation: BPhen), bathocuproine (abbreviation: BCP), 2,9-di(naphthalen-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), 2,2′-(pyridin-2,6-diyl)bis(4-phenylbenzo[h]quinazoline) (abbreviation: 2,6(P-Bqn)2Py), 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), and 2mpPCBPDBq.

For the electron-transport layers (114, 114a, and 114b), any of the metal complexes given below can be used as well as the heteroaromatic compounds described above. Examples of the metal complexes include a metal complex having a quinoline ring or a benzoquinoline ring, such as tris(8-quinolinolato)aluminum(III) (abbreviation: Alq₃), Almq₃, 8-quinolinolato-lithium (abbreviation: Liq), BeBq₂, bis(2-methyl-8-quinolinolato) (4-phenylphenolato)aluminum(III) (abbreviation: BAlq), or bis(8-quinolinolato)zinc(II) (abbreviation: Znq), and a metal complex having an oxazole ring or a thiazole ring, such as bis[2-(2-benzoxazolyl)phenolato]zinc(II) (abbreviation: ZnPBO) or bis[2-(2-benzothiazolyl)phenolato]zinc(II) (abbreviation: ZnBTZ).

A high-molecular compound such as poly(2,5-pyridinediyl) (abbreviation: PPy), poly[(9,9-dihexylfluorene-2,7-diyl)-co-(pyridine-3,5-diyl)](abbreviation: PF-Py), or poly[(9,9-dioctylfluorene-2,7-diyl)-co-(2,2′-bipyridine-6,6′-diyl)](abbreviation: PF-BPy) can be used as the electron-transport material.

Each of the electron-transport layers (114, 114a, and 114b) is not limited to a single layer and may be a stack of two or more layers each including any of the above substances.

### <Electron-Injection Layer>

The electron-injection layers (115, 115a, and 115b) include a substance having a high electron-injection property. The electron-injection layers (115, 115a, and 115b) are layers for increasing the efficiency of electron injection from the second electrode 102 and are preferably formed using a material whose value of the LUMO level has a small difference (less than or equal to 0.50 eV) from the work function of a material used for the second electrode 102. Thus, the electron-injection layer 115 can be formed using an alkali metal, an alkaline earth metal, or a compound thereof, such as lithium, cesium, lithium fluoride (LiF), cesium fluoride (CsF), calcium fluoride (CaF₂), 8-quinolinolato-lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), an oxide of lithium (Li₂O), or cesium carbonate. A rare earth metal and a compound thereof such as erbium fluoride (ErF₃) and ytterbium (Yb) can also be used. It is also possible to use a compound including a 1,3,4,6,7,8-tetrahydro-2H-pyrimido[1,2-a]pyrimidine skeleton, such as 1-(9,9′-spirobi[9H-fluoren]-2-yl)-1,3,4,6,7,8-hexahydro-2H-pyrimido[1,2-a]pyrimidine (abbreviation: 2hppSF), 1,1′-(9,9′-spirobi[9H-fluorene]-2,7-diyl)bis(1,3,4,6,7,8-hexahydro-2H-pyrimido[1,2-a]pyrimidine) (abbreviation: 2,7hpp2SF), or 1,1′-pyridine-2,6-diyl-bis(1,3,4,6,7,8-hexahydro-2H-pyrimido[1,2-a]pyrimidine) (abbreviation: hpp2Py). For the electron-injection layers (115, 115a, and 115b), a plurality of kinds of materials given above may be mixed or stacked as films. Electride may also be used for the electron-injection layers (115, 115a, and 115b). Examples of the electride include a substance in which electrons are added at high concentration to calcium oxide-aluminum oxide. Any of the substances used for the electron-transport layers (114, 114a, and 114b), which are given above, can also be used.

A mixed material in which an organic compound and an electron donor (donor) are mixed may also be used for the electron-injection layers (115, 115a, and 115b). Such a mixed material is excellent in an electron-injection property and an electron-transport property because electrons are generated in the organic compound by the electron donor. The organic compound here is preferably a material excellent in transporting the generated electrons; specifically, for example, the above-described electron-transport materials used for the electron-transport layers (114, 114a, and 114b), such as a metal complex and a heteroaromatic compound, can be used. As the electron donor, a substance having an electron-donating property with respect to the organic compound is used. Specifically, an alkali metal, an alkaline earth metal, and a rare earth metal are preferable, and lithium, cesium, magnesium, calcium, erbium, ytterbium, and the like are given as examples. In addition, an alkali metal oxide and an alkaline earth metal oxide are preferable, and lithium oxide, calcium oxide, barium oxide, and the like are given as examples. Alternatively, a Lewis base such as magnesium oxide can be used. Further alternatively, an organic compound such as tetrathiafulvalene (abbreviation: TTF) can be used. Alternatively, a stack of two or more of these materials may be used.

A mixed material in which an organic compound and a metal are mixed may also be used for the electron-injection layers (115, 115a, and 115b). The organic compound used here preferably has a LUMO level higher than or equal to −3.60 eV and lower than or equal to −2.30 eV. Moreover, a material having an unshared electron pair is preferable.

Thus, as the organic compound used in the above mixed material, a mixed material obtained by mixing a metal and the heteroaromatic compound given above as the material that can be used for the electron-transport layer may be used. Preferable examples of the heteroaromatic compound include materials having an unshared electron pair, such as a heteroaromatic compound having a five-membered ring structure (e.g., an imidazole ring, a triazole ring, an oxazole ring, an oxadiazole ring, a thiazole ring, or a benzimidazole ring), a heteroaromatic compound having a six-membered ring structure (e.g., a pyridine ring, a diazine ring (including a pyrimidine ring, a pyrazine ring, a pyridazine ring, or the like), a triazine ring, a bipyridine ring, or a terpyridine ring), and a heteroaromatic compound having a fused ring structure partly including a six-membered ring structure (e.g., a quinoline ring, a benzoquinoline ring, a quinoxaline ring, a dibenzoquinoxaline ring, or a phenanthroline ring). Since the materials are specifically described above, description thereof is omitted here.

As a metal used for the above mixed material, a transition metal that belongs to Group 5, Group 7, Group 9, or Group 11 or a material that belongs to Group 13 in the periodic table is preferably used, and examples include Ag, Cu, Al, and In. Here, the organic compound forms a singly occupied molecular orbital (SOMO) with the transition metal.

To amplify light obtained from the light-emitting layer 113b, for example, the optical path length between the second electrode 102 and the light-emitting layer 113b is preferably less than one fourth of the wavelength k of light emitted from the light-emitting layer 113b. In that case, the optical path length can be adjusted by changing the thickness of the electron-transport layer 114b or the electron-injection layer 115b.

When the charge-generation layer 106 is provided between the two organic compound layers (103a and 103b) as in the light-emitting device in FIG. 4E, a structure in which a plurality of organic compound layers are stacked between the pair of electrodes (the structure is also referred to as a tandem structure) can be obtained.

### <Charge-Generation Layer>

The charge-generation layer 106 has a function of injecting electrons into one of the organic compound layers 103a and 103b and injecting holes into the other of the organic compound layers 103a and 103b when a voltage is applied between the first electrode (anode) 101 and the second electrode (cathode) 102. The charge-generation layer 106 may be either a p-type layer in which an electron acceptor (acceptor) is added to a hole-transport material or an electron-injection buffer layer in which an electron donor (donor) is added to an electron-transport material. Alternatively, both of these layers may be stacked. Furthermore, an electron-relay layer may be provided between the p-type layer and the electron-injection buffer layer. Forming the charge-generation layer 106 that includes the p-type layer and the electron-injection buffer layer can inhibit an increase in driving voltage caused by the stack of the organic compound layers.

In the case where the charge-generation layer 106 is a p-type layer in which an electron acceptor is added to a hole-transport material, which is an organic compound, any of the materials described in this embodiment can be used as the hole-transport material. Examples of the electron acceptor include 7,7,8,8-tetracyano-2,3,5,6-tetrafluoroquinodimethane (abbreviation: F₄-TCNQ) and chloranil. Other examples include oxides of metals that belong to Group 4 to Group 8 of the periodic table. Specific examples include vanadium oxide, niobium oxide, tantalum oxide, chromium oxide, molybdenum oxide, tungsten oxide, manganese oxide, and rhenium oxide. Any of the above-described acceptor materials may be used. Furthermore, a mixed film obtained by mixing materials of a p-type layer or a stack of films containing the respective materials may be used.

In the case where the charge-generation layer 106 is an electron-injection buffer layer in which an electron donor is added to an electron-transport material, any of the materials described in this embodiment can be used as the electron-transport material. As the electron donor, it is possible to use an alkali metal, an alkaline earth metal, a rare earth metal, a metal belonging to Group 2 or Group 13 of the periodic table, or an oxide or a carbonate thereof. Specifically, lithium (Li), cesium (Cs), magnesium (Mg), calcium (Ca), ytterbium (Yb), indium (In), lithium oxide (Li₂O), cesium carbonate, or the like is preferably used. An organic compound such as tetrathianaphthacene may be used as the electron donor. An alkali metal compound such as Liq may be used. An organic compound such as tetrathianaphthacene may be used as the electron donor. An organic compound including a 1,3,4,6,7,8-tetrahydro-2H-pyrimido[1,2-a]pyrimidine skeleton, such as 2hppSF, 2,7hpp2SF, or hpp2Py may be used as the electron donor. When any of these organic compounds is used as the electron donor, the electron-transport material to be combined with the electron donor is preferably an organic compound including a heteroaromatic ring having a phenanthroline ring, such as bathophenanthroline (abbreviation: BPhen), bathocuproine (abbreviation: BCP), 2,9-di(naphthalen-2-yl)-4,7-diphenyl-1,10-phenanthroline (abbreviation: NBphen), or 2,2′-(1,3-phenylene)bis(9-phenyl-1,10-phenanthroline) (abbreviation: mPPhen2P), in which case driving voltage of the light-emitting device can be reduced.

When an electron-relay layer is provided between a p-type layer and an electron-injection buffer layer in the charge-generation layer 106, the electron-relay layer contains at least a substance having an electron-transport property and has a function of preventing an interaction between the electron-injection buffer layer and the p-type layer and transferring electrons smoothly. The LUMO level of the substance having an electron-transport property in the electron-relay layer is preferably between the LUMO level of the acceptor substance in the p-type layer and the LUMO level of the substance having an electron-transport property in the electron-transport layer in contact with the charge-generation layer 106. Specifically, the LUMO level of the substance having an electron-transport property in the electron-relay layer is preferably higher than or equal to −5.00 eV, further preferably higher than or equal to −5.00 eV and lower than or equal to −3.00 eV. Note that as the substance having an electron-transport property in the electron-relay layer, a phthalocyanine-based material or a metal complex having a metal-oxygen bond and an aromatic ligand is preferably used.

Note that in terms of light extraction efficiency, the charge-generation layer 106 preferably has a property of transmitting visible light (specifically, the charge-generation layer 106 preferably has a visible light transmittance higher than or equal to 40%). The charge-generation layer 106 functions even if it has lower conductivity than the first electrode 101 or the second electrode 102.

Although FIG. 4E illustrates the structure in which two of the organic compound layers 103 are stacked, three or more organic compound layers may be stacked with charge-generation layers each provided between two adjacent organic compound layers.

### <<Cap Layer>>

Although not illustrated in FIGS. 4A to 4F, a cap layer may be provided over the second electrode 102 of the light-emitting device. For example, a material with a high refractive index can be used for the cap layer. When the cap layer is provided over the second electrode 102, extraction efficiency of light emitted from the second electrode 102 can be improved.

Specific examples of a material that can be used for the cap layer include 5,5′-diphenyl-2,2′-di-5H-[1]benzothieno[3,2-c]carbazole (abbreviation: BisBTc) and 4,4′,4″-(benzene-1,3,5-triyl)tri(dibenzothiophene) (abbreviation: DBT3P-II).

### <Substrate>

The light-emitting device described in this embodiment can be formed over a variety of substrates. Note that the type of substrate is not limited to a certain type. Examples of the substrate include semiconductor substrates (e.g., a single crystal substrate and a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, and paper or a base material film including a fibrous material.

Examples of the glass substrate include a barium borosilicate glass substrate, an aluminoborosilicate glass substrate, and a soda lime glass substrate. Examples of the flexible substrate, the attachment film, and the base material film include plastics typified by polyethylene terephthalate (PET), polyethylene naphthalate (PEN), and polyether sulfone (PES), a synthetic resin such as an acrylic resin, polypropylene, polyester, polyvinyl fluoride, polyvinyl chloride, polyamide, polyimide, aramid, an epoxy resin, an inorganic vapor deposition film, and paper.

For manufacturing the light-emitting device in this embodiment, a gas phase method such as an evaporation method or a liquid phase method such as a spin coating method or an ink-jet method can be used. When an evaporation method is used, a physical vapor deposition method (PVD method) such as a sputtering method, an ion plating method, an ion beam evaporation method, a molecular beam evaporation method, or a vacuum evaporation method, a chemical vapor deposition method (CVD method), or the like can be used. Specifically, the layers having various functions (the hole-injection layer 111, the hole-transport layer 112, the light-emitting layer 113, the electron-transport layer 114, and the electron-injection layer 115) included in the organic compound layers of the light-emitting device can be formed by an evaporation method (e.g., a vacuum evaporation method), a coating method (e.g., a dip coating method, a die coating method, a bar coating method, a spin coating method, or a spray coating method), a printing method (e.g., an ink-jet method, screen printing (stencil), offset printing (planography), flexography (relief printing), gravure printing, or micro-contact printing), or the like.

In the case where a film formation method such as the coating method or the printing method is employed, a high-molecular compound (e.g., an oligomer, a dendrimer, or a polymer), a middle-molecular compound (a compound between a low-molecular compound and a high-molecular compound with a molecular weight of 400 to 4000), an inorganic compound (e.g., a quantum dot material), or the like can be used. The quantum dot material can be a colloidal quantum dot material, an alloyed quantum dot material, a core-shell quantum dot material, a core quantum dot material, or the like.

Materials that can be used for the layers (the hole-injection layer 111, the hole-transport layer 112, the light-emitting layer 113, the electron-transport layer 114, and the electron-injection layer 115) included in the organic compound layer 103 of the light-emitting device described in this embodiment are not limited to the materials described in this embodiment, and other materials can be used in combination as long as the functions of the layers are fulfilled.

The structure described above in this embodiment can be combined as appropriate with any of the structures described in the other embodiments.

### Embodiment 3

In this embodiment, a light-emitting apparatus 1000 of one embodiment of the present invention will be described in detail. Note that in this specification and the like, a light-emitting apparatus is sometimes referred to as a display apparatus.

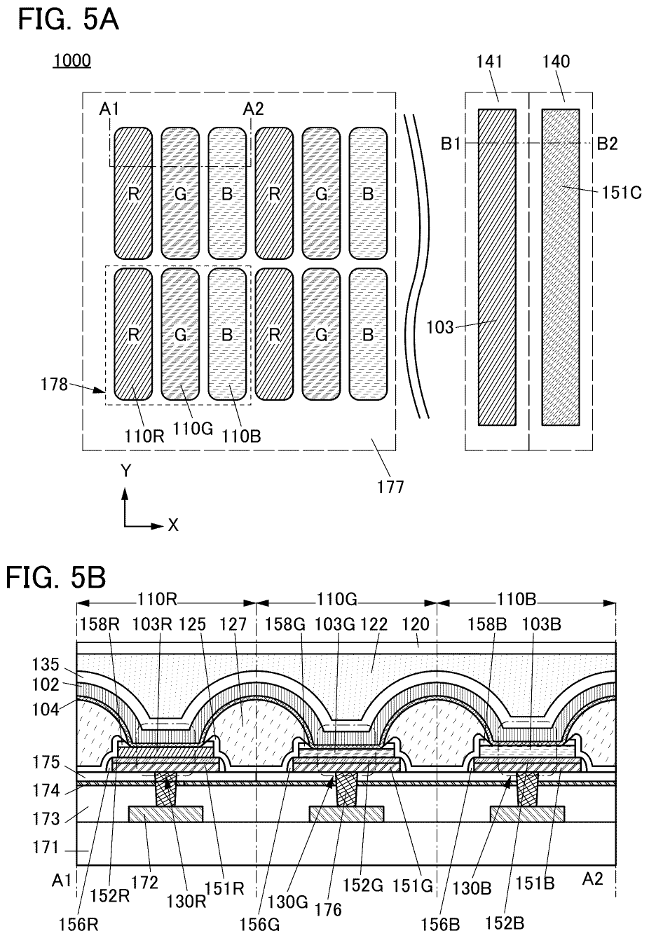

As illustrated in FIG. 5A, the light-emitting apparatus 1000 includes a pixel portion 177 in which a plurality of pixels 178 are arranged in matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared (IR) light.

In this specification and the like, the row direction and the column direction are sometimes referred to as the X direction and the Y direction, respectively. The X direction and the Y direction intersect with each other and are perpendicular to each other, for example.

FIG. 5A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The organic compound layer 103 is provided in the region 141. A conductive layer 151C is provided in the connection portion 140.

Although FIG. 5A illustrates an example where the region 141 and the connection portion 140 are positioned on the right side of the pixel portion 177, there is no particular limitation on the positions of the region 141 and the connection portion 140. The number of regions 141 and the number of connection portions 140 can each be one or two or more.

FIG. 5B is an example of a cross-sectional view along the dashed-dotted line A1-A2 in FIG. 5A. As illustrated in FIG. 5B, the light-emitting apparatus 1000 includes the insulating layer 171, a conductive layer 172 over the insulating layer 171, an insulating layer 173 over the insulating layer 171 and the conductive layer 172, an insulating layer 174 over the insulating layer 173, and an insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, a light-emitting device 130 is provided over the insulating layer 175 and the plug 176. A protective layer 135 is provided to cover the light-emitting device 130. A substrate 120 is bonded to the protective layer 135 with a resin layer 122. An inorganic insulating layer 125 and an insulating layer 127 over the inorganic insulating layer 125 are preferably provided between adjacent light-emitting devices 130.

Although FIG. 5B illustrates cross sections of a plurality of the inorganic insulating layers 125 and a plurality of the insulating layers 127, the inorganic insulating layers 125 are preferably connected to each other and the insulating layers 127 are preferably connected to each other when the light-emitting apparatus 1000 is seen from above. In other words, each of the inorganic insulating layer 125 and the insulating layer 127 preferably includes an opening portion over a first electrode.

In FIG. 5B, a light-emitting device 130R, a light-emitting device 130G, and a light-emitting device 130B are each illustrated as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light.

The display apparatus of one embodiment of the present invention can be, for example, a top-emission light-emitting apparatus where light is emitted in the direction opposite to a substrate over which light-emitting devices are formed. Note that the display apparatus of one embodiment of the present invention may be of a bottom-emission type.

Examples of a light-emitting material included in the light-emitting device 130 include an organometallic complex of one embodiment of the present invention and organic compounds such as a substance emitting fluorescent light (a fluorescent substance), a substance emitting phosphorescent light (a phosphorescent substance), and a substance exhibiting thermally activated delayed fluorescence (a thermally activated delayed fluorescent (TADF) material). Other examples include inorganic compounds (e.g., a quantum dot material).

The light-emitting device 130R has a structure as described in Embodiments 1 and 2. The light-emitting device 130R includes the first electrode (pixel electrode) including a conductive layer 151R and a conductive layer 152R, an organic compound layer 103R over the first electrode, a common layer 104 over the organic compound layer 103R, and a second electrode (common electrode) 102 over the common layer 104. Although the common layer 104 is not necessarily provided, it is preferable to provide the common layer 104 to reduce damage to the organic compound layer 103R during processing. In the case where the common layer 104 is provided, the common layer 104 is preferably an electron-injection layer. Furthermore, in the case where the common layer 104 is not provided, the organic compound layer 103R corresponds to the organic compound layer 103 described in Embodiments 1 and 2. In the case where the common layer 104 is provided, a stack of the organic compound layer 103R and the common layer 104 corresponds to the organic compound layer 103 described in Embodiments 1 and 2.

The light-emitting device 130G has a structure as described in Embodiments 1 and 2. The light-emitting device 130G includes the first electrode (pixel electrode) including a conductive layer 151G and a conductive layer 152G, an organic compound layer 103G over the first electrode, the common layer 104 over the organic compound layer 103G, and the second electrode (common electrode) 102 over the common layer 104. Although the common layer 104 is not necessarily provided, it is preferable to provide the common layer 104 to reduce damage to the organic compound layer 103G during processing. Furthermore, in the case where the common layer 104 is not provided, the organic compound layer 103G corresponds to the organic compound layer 103 described in Embodiments 1 and 2. In the case where the common layer 104 is provided, a stack of the organic compound layer 103G and the common layer 104 corresponds to the organic compound layer 103 described in Embodiments 1 and 2.

The light-emitting device 130B has a structure as described in Embodiments 1 and 2. The light-emitting device 130B includes the first electrode (pixel electrode) including a conductive layer 151B and a conductive layer 152B, an organic compound layer 103B over the first electrode, the common layer 104 over the organic compound layer 103B, and the second electrode (common electrode) 102 over the common layer 104. Although the common layer 104 is not necessarily provided, it is preferable to provide the common layer 104 to reduce damage to the organic compound layer 103B during processing. Furthermore, in the case where the common layer 104 is not provided, the organic compound layer 103B corresponds to the organic compound layer 103 described in Embodiments 1 and 2. In the case where the common layer 104 is provided, a stack of the organic compound layer 103B and the common layer 104 corresponds to the organic compound layer 103 described in Embodiments 1 and 2.

In the light-emitting device, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layers 103R, 103G, and 103B are island-shaped layers that are independent of each other on a light-emitting device basis or on an emission color basis. Providing the island-shaped organic compound layer 103 in each of the light-emitting devices 130 can inhibit leakage current between the adjacent light-emitting devices 130 even in a high-resolution light-emitting apparatus. This can prevent crosstalk, so that a light-emitting apparatus with extremely high contrast can be obtained. Specifically, a light-emitting apparatus having high current efficiency at low luminance can be obtained.

The island-shaped organic compound layer 103 is formed by forming an EL film and processing the EL film by a lithography method.

In the light-emitting apparatus of one embodiment of the present invention, the first electrode (pixel electrode) of the light-emitting device preferably has a stacked-layer structure. For example, in the example illustrated in FIG. 5B, the first electrode of the light-emitting device 130 is a stack of the conductive layer 151 and the conductive layer 152. In the case where the light-emitting apparatus 1000 is of atop-emission type and the pixel electrode of the light-emitting device 130 functions as the anode, for example, the conductive layer 151 preferably has high visible light reflectance, and the conductive layer 152 preferably has a visible-light-transmitting property and a high work function. In the case where the light-emitting apparatus 1000 is of a top-emission type, the higher the visible light reflectance of the pixel electrode is, the higher the efficiency of extraction of the light emitted by the organic compound layer 103 is. In the case where the pixel electrode functions as the anode, the higher the work function of the pixel electrode is, the easier hole injection into the organic compound layer 103 is. Accordingly, when the pixel electrode of the light-emitting device 130 has a stacked-layer structure of the conductive layer 151 with high visible light reflectance and the conductive layer 152 with a high work function, the light-emitting device 130 can have high light extraction efficiency and a low driving voltage.

In the case where the conductive layer 151 has high visible light reflectance, the visible light reflectance of the conductive layer 151 is preferably higher than or equal to 40% and lower than or equal to 100%, further preferably higher than or equal to 70% and lower than or equal to 100%, for example. When used as an electrode having a visible-light-transmitting property, the conductive layer 152 preferably has a visible light transmittance higher than or equal to 40%, for example.

Here, such a pixel electrode being a stack composed of a plurality of layers sometimes changes in quality as a result of, for example, a reaction between the plurality of layers. For example, when a film formed after the formation of the pixel electrode is removed by a wet etching method, contact of a chemical solution with the pixel electrode might cause galvanic corrosion.

In view of the above, as illustrated in FIG. 5B, an insulating layer 156 is preferably formed on the side surfaces of the conductive layers 151 and 152 in the light-emitting apparatus 1000 of this embodiment. This can inhibit a chemical solution from coming into contact with the conductive layer 151 even when a film that is formed after formation of the pixel electrode including the conductive layer 151 and the conductive layer 152 is removed by a wet etching method, for example. Accordingly, occurrence of galvanic corrosion in the pixel electrode can be inhibited, for example. This allows the light-emitting apparatus 1000 to be manufactured by a high-yield method and to be accordingly inexpensive. In addition, generation of a defect in the light-emitting apparatus 1000 can be inhibited, which makes the light-emitting apparatus 1000 highly reliable.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layers 151 and 152 may each have a stacked-layer structure of a plurality of layers that include different materials. In this case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 has a stacked-layer structure of two or more layers, for example, a layer in contact with the conductive layer 152 can be formed using a material that can be used for the conductive layer 152.

Note that an end portion of the conductive layer 151 may have a tapered shape. Specifically, when the end portion of the conductive layer 151 has a tapered shape with a taper angle less than 90°, a component with higher coverage can be provided along the side surface of the insulating layer 156.

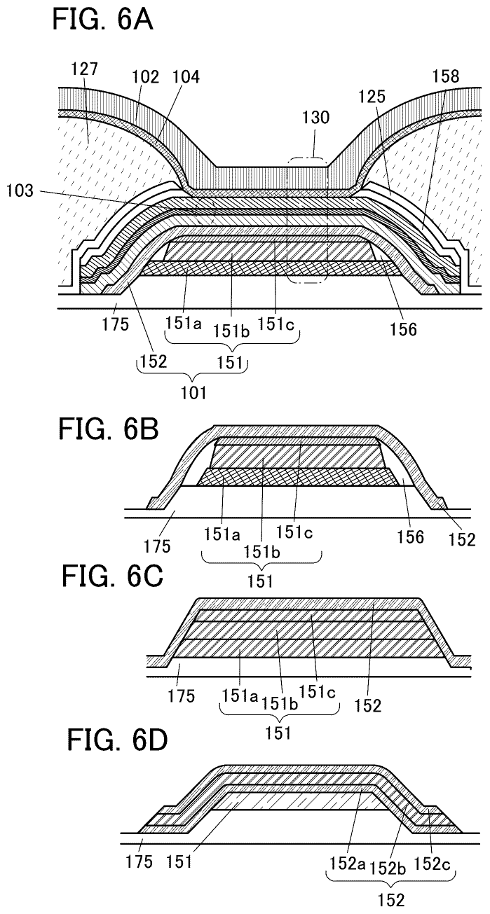

FIG. 6A illustrates the case where the conductive layer 151 has a stacked-layer structure of a plurality of layers containing different materials. As illustrated in FIG. 6A, the conductive layer 151 includes a conductive layer 151a, a conductive layer 151b over the conductive layer 151a, and a conductive layer 151c over the conductive layer 151b. In other words, the conductive layer 151 illustrated in FIG. 6A has a three-layer structure. In the case where the conductive layer 151 has a stacked-layer structure of a plurality of layers as described above, the visible light reflectance of at least one of the layers included in the conductive layer 151 is made higher than that of the conductive layer 152.

In the example illustrated in FIG. 6A, the conductive layer 151b is sandwiched between the conductive layers 151a and 151c. A material that is less likely to change in quality than the material for the conductive layer 151b is preferably used for the conductive layers 151a and 151c. The conductive layer 151a can be formed using, for example, a material that is less likely to migrate owing to contact with the insulating layer 175 than the material for the conductive layer 151b. The conductive layer 151c can be formed using a material an oxide of which has lower electrical resistivity than an oxide of the material for the conductive layer 151b and which is less likely to be oxidized than the material for the conductive layer 151b.

In this manner, the structure where the conductive layer 151b is sandwiched between the conductive layers 151a and 151c can expand the range of choices for the material for the conductive layer 151b. The conductive layer 151b, for example, can thus have higher visible light reflectance than at least one of the conductive layers 151a and 151c. For example, aluminum can be used for the conductive layer 151b. The conductive layer 151b may be formed using an alloy containing aluminum. The conductive layer 151a can be formed using titanium; titanium has lower visible light reflectance than aluminum but is less likely to migrate owing to contact with the insulating layer 175 than aluminum. Furthermore, the conductive layer 151c can be formed using titanium; titanium is less likely to be oxidized than aluminum and an oxide of titanium has lower electrical resistivity than aluminum oxide, although titanium has lower visible light reflectance than aluminum.

The conductive layer 151c may be formed using silver or an alloy containing silver. Silver has a feature of higher visible light reflectance than titanium. In addition, silver has a feature of being less likely to be oxidized than aluminum, and silver oxide has a feature of lower electrical resistivity than aluminum oxide. Thus, the conductive layer 151c formed using silver or an alloy containing silver can favorably increase the visible light reflectance of the conductive layer 151 and inhibit an increase in the electrical resistance of the pixel electrode due to oxidation of the conductive layer 151b. Here, as the alloy containing silver, an alloy of silver, palladium, and copper (also referred to as Ag—Pd—Cu or APC) can be used, for example. When the conductive layer 151c is formed using silver or an alloy containing silver and the conductive layer 151b is formed using aluminum, the visible light reflectance of the conductive layer 151c can be higher than that of the conductive layer 151b. Here, the conductive layer 151b may be formed using silver or an alloy containing silver. The conductive layer 151a may be formed using silver or an alloy containing silver.

Meanwhile, a film formed using titanium has better processability in etching than a film formed using silver. Thus, use of titanium for the conductive layer 151c can facilitate formation of the conductive layer 151c. Note that a film formed using aluminum also has better processability in etching than a film formed using silver.

The conductive layer 151 having a stacked-layer structure of a plurality of layers as described above can improve the characteristics of the light-emitting apparatus. For example, the light-emitting apparatus 1000 can have high light extraction efficiency and high reliability.

Here, in the case where the light-emitting device 130 has a microcavity structure, use of silver or an alloy containing silver, i.e., a material with high visible light reflectance, for the conductive layer 151c can favorably increase the light extraction efficiency of the light-emitting apparatus 1000.

As already described above, the conductive layer 151 preferably has a side surface with a tapered shape. Specifically, the side surface of the conductive layer 151 preferably has a tapered shape with a taper angle less than 90°. For example, in the conductive layer 151 illustrated in FIG. 6A, the side surface of at least one of the conductive layers 151a, 151b, and 151c preferably has a tapered shape.

The conductive layer 151 illustrated in FIG. 6A can be formed by a lithography method. Specifically, first, a conductive film to be the conductive layer 151a, a conductive film to be the conductive layer 151b, and a conductive film to be the conductive layer 151c are sequentially formed. Next, a resist mask is formed over the conductive film to be the conductive layer 151c. Then, the conductive film in the region not overlapping with the resist mask is removed by etching. Here, when the conductive film is processed under conditions where the resist mask is easily depressed (reduced in size) as compared to the case where the conductive layer 151 is formed such that the side surface does not have a tapered shape (i.e., the conductive layer 151 is formed to have a perpendicular side surface), the side surface of the conductive layer 151 can have a tapered shape.

Here, when the conductive film is processed under conditions where the resist mask is easily depressed (reduced in size), the conductive film might be easily processed in the horizontal direction. That is, the etching sometimes might become isotropic as compared to the case where the conductive layer 151 is formed to have a perpendicular side surface.

In the case where the conductive layer 151 is a stack of a plurality of layers formed of different materials, the plurality of layers sometimes differ in processability in the horizontal direction. For example, the conductive layers 151a, 151b, and 151c sometimes differ in processability in the horizontal direction.

In that case, after the processing of the conductive film, the side surface of the conductive layer 151b may be positioned inward from the side surfaces of the conductive layers 151a and 151c and a protruding portion may be formed. This might impair coverage of the conductive layer 151 with the conductive layer 152 and cause step disconnection of the conductive layer 152.

Thus, the insulating layer 156 is preferably provided as illustrated in FIG. 6A. FIG. 6A illustrates an example where the insulating layer 156 is provided over the conductive layer 151a to include a region overlapping with the side surface of the conductive layer 151b. In this structure, occurrence of step disconnection or thinning of the conductive layer 152 due to the protruding portion can be inhibited, so that poor connection or an increase in driving voltage can be inhibited.

Although FIG. 6A illustrates the structure where the side surface of the conductive layer 151b is entirely covered with the insulating layer 156, part of the side surface of the conductive layer 151b is not necessarily covered with the insulating layer 156. Also in a pixel electrode with a later-described structure, part of the side surface of the conductive layer 151b is not necessarily covered with the insulating layer 156.

In the case where the conductive layer 151 has the structure illustrated in FIG. 6A, the conductive layer 152 is provided to cover the conductive layers 151a, 151b, and 151c and the insulating layer 156 and to be electrically connected to the conductive layers 151a, 151b, and 151c. This can prevent a chemical solution from coming into contact with the conductive layers 151a, 151b, and 151c even when a film formed after formation of the conductive layer 152 is removed by a wet etching method, for example. It is thus possible to inhibit occurrence of corrosion in all of the conductive layers 151a, 151b, and 151c. Hence, the light-emitting apparatus 1000 can be fabricated by a high-yield method. Moreover, the light-emitting apparatus 1000 can have high reliability since generation of defects is inhibited therein.

The insulating layer 156 preferably has a curved surface as illustrated in FIG. 6A. In that case, step disconnection in the conductive layer 152 covering the insulating layer 156 is less likely to occur than in the case where the insulating layer 156 has a perpendicular side surface (a side surface parallel to the Z direction), for example. In addition, step disconnection in the conductive layer 152 covering the insulating layer 156 is less likely to occur also in the case where the side surface of the insulating layer 156 has a tapered shape, or specifically, a tapered shape with a taper angle less than 90°, than in the case where the insulating layer 156 has a perpendicular side surface, for example. As described above, the light-emitting apparatus 1000 can be fabricated in a high yield. Moreover, the light-emitting apparatus 1000 can have high reliability since generation of defects is inhibited therein.

FIG. 6A illustrates the structure where the side surface of the conductive layer 151b is located inward from that of the conductive layer 151a; however, one embodiment of the present invention is not limited to this structure. For example, the side surface of the conductive layer 151b may be located outward from that of the conductive layer 151a. The side surface of the conductive layer 151b may be located outward from that of the conductive layer 151c.

FIGS. 6B to 6D illustrate other structures of the first electrode 101. FIG. 6B illustrates a variation structure of the first electrode 101 in FIG. 6A, in which the insulating layer 156 covers the side surfaces of the conductive layers 151a, 151b, and 151c instead of covering only the side surface of the conductive layer 151b.

FIG. 6C illustrates a structure of the first electrode 101 in FIG. 6A in which the insulating layer 156 is not provided.

FIG. 6D illustrates a variation structure of the first electrode 101 in FIG. 6A, in which the conductive layer 151 does not have a stacked-layer structure but the conductive layer 152 has a stacked-layer structure.

A conductive layer 152a has higher adhesion to a conductive layer 152b than the insulating layer 175 does, for example. For the conductive layer 152a, an oxide containing one or more selected from indium, tin, zinc, gallium, titanium, aluminum, and silicon, for example, can be used. For example, it is preferable to use a conductive oxide containing one or more of indium oxide, indium tin oxide, indium zinc oxide, zinc oxide, zinc oxide containing gallium, titanium oxide, indium titanium oxide, zinc titanate, aluminum zinc oxide, indium zinc oxide containing gallium, indium zinc oxide containing aluminum, indium tin oxide containing silicon, indium zinc oxide containing silicon, and the like. Accordingly, peeling of the conductive layer 152b can be inhibited. A structure in which the conductive layer 152b is not in contact with the insulating layer 175 can be achieved.

The conductive layer 152b is a layer whose visible light reflectance (e.g., reflectance with respect to light with a predetermined wavelength longer than or equal to 400 nm and shorter than 750 nm) is higher than those of the conductive layers 151, 152a, and 152c. The visible light reflectance of the conductive layer 152b can be, for example, higher than or equal to 40% and lower than or equal to 100%, preferably higher than or equal to 70% and lower than or equal to 100%. For the conductive layer 152b, a material having higher visible light reflectance than aluminum can be used, for example. Specifically, for the conductive layer 152b, silver or an alloy containing silver can be used, for example. An example of the alloy containing silver is an alloy of silver, palladium, and copper (APC). In the above manner, the light-emitting apparatus 1000 can have high light extraction efficiency. Note that a metal other than silver may be used for the conductive layer 152b.

When the conductive layers 151 and 152 serve as the anode, a layer having a high work function is preferably used as the conductive layer 152c. The conductive layer 152c has a higher work function than the conductive layer 152b, for example. For the conductive layer 152c, a material similar to the material usable for the conductive layer 152a can be used, for example. For example, the conductive layers 152a and 152c can be formed using the same kind of material. For example, in the case where indium tin oxide is used for the conductive layer 152a, indium tin oxide can also be used for the conductive layer 152c.

When the conductive layers 151 and 152 serve as the cathode, a layer having a low work function is preferably used as the conductive layer 152c. For example, the conductive layer 152c has a lower work function than the conductive layer 152b.

The conductive layer 152c is preferably a layer having high visible light transmittance (e.g., transmittance with respect to light with a predetermined wavelength longer than or equal to 400 nm and shorter than 750 nm). For example, the visible light transmittance of the conductive layer 152c is preferably higher than those of the conductive layers 151 and 152b. The visible light transmittance of the conductive layer 152c can be, for example, higher than or equal to 40% and lower than or equal to 100%, preferably higher than or equal to 60% and lower than or equal to 100%, and is further preferably higher than or equal to 70% and lower than or equal to 100%, still further preferably higher than or equal to 80% and lower than or equal to 100%. In that case, the amount of light that is absorbed by the conductive layer 152c after being emitted from the organic compound layer 103 can be reduced. As described above, the conductive layer 152b under the conductive layer 152c can be a layer having high visible light reflectance. Thus, the light-emitting apparatus 1000 can have high light extraction efficiency.

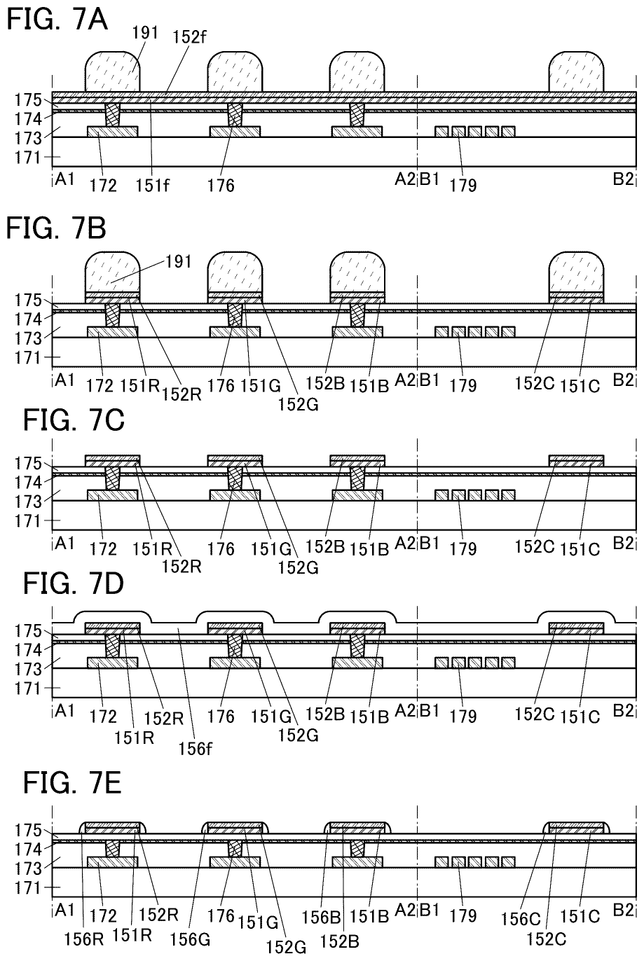

Next, a method for manufacturing the light-emitting apparatus 1000 having the structure illustrated in FIG. 5A is described with reference to FIGS. 7A to 7E, FIGS. 8A and 8B, FIGS. 9A to 9D, FIGS. 10A to 10C, FIGS. 11A to 11C, FIGS. 12A to 12C, FIGS. 13A to 13G, FIGS. 14A to 14I, and FIGS. 15A and 15B. The organic compound layer of the light-emitting device included in the light-emitting apparatus 1000 is formed by manufacturing steps including treatment using water. When the light-emitting device of one embodiment of the present invention is used as the light-emitting device included in the light-emitting apparatus of one embodiment of the present invention, the light-emitting apparatus including the light-emitting device with reduced driving voltage and high emission efficiency can be provided.

### [Fabrication Method Example]

Thin films included in the display apparatus (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a plasma-enhanced CVD (PECVD) method and a thermal CVD method. An example of a thermal CVD method is a metal organic CVD (MOCVD) method.

Thin films included in the display apparatus (e.g., insulating films, semiconductor films, and conductive films) can also be formed by a wet film-formation method such as spin coating, dipping, spray coating, ink-jetting, dispensing, screen printing, offset printing, doctor blade coating, slit coating, roll coating, curtain coating, or knife coating.

Specifically, for fabrication of the light-emitting device, a vacuum process such as an evaporation method and a solution process such as a spin coating method or an ink-jet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, the functional layers (e.g., the hole-injection layer, the hole-transport layer, the hole-blocking layer, the light-emitting layer, the electron-blocking layer, the electron-transport layer, and the electron-injection layer) included in the organic compound layer can be formed by an evaporation method (e.g., a vacuum evaporation method), a coating method (e.g., a dip coating method, a die coating method, a bar coating method, a spin coating method, or a spray coating method), a printing method (e.g., ink-jetting, screen printing (stencil), offset printing (planography), flexography (relief printing), gravure printing, or micro-contact printing), or the like.

Thin films included in the display apparatus can be processed by a lithography method, for example. Alternatively, a nanoimprinting method, a sandblasting method, a lift-off method, or the like may be used to process thin films. Alternatively, island-shaped thin films may be directly formed by a film formation method using a shielding mask such as a metal mask.

As a lithography method, for example, a photolithography method can be used. Two typical examples of photolithography methods are given. In one of the methods, a resist mask is formed over a thin film that is to be processed, the thin film is processed by etching, for example, and then the resist mask is removed. In the other method, a photosensitive thin film is formed and then processed into a desired shape by light exposure and development.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used. It is preferable to use EUV light, X-rays, or an electron beam for extremely minute processing. Note that when exposure is performed by scanning of a beam such as an electron beam, a photomask is not needed.

For etching of thin films, a dry etching method, a wet etching method, a sandblasting method, or the like can be used.

First, as illustrated in FIG. 7A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate having heat resistance high enough to withstand at least heat treatment performed later can be used. When an insulating substrate is used, it is possible to use a glass substrate, a quartz substrate, a sapphire substrate, a ceramic substrate, an organic resin substrate, or the like. Alternatively, it is possible to use a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 7A, openings reaching the conductive layer 172 are formed in the insulating layers 175, 174, and 173. Then, the plugs 176 are formed to fill the openings.

Next, as illustrated in FIG. 7A, a conductive film 151f to be the conductive layers 151R, 151G, 151B, and 151C is formed over the plugs 176 and the insulating layer 175. The conductive film 151f can be formed by a sputtering method or a vacuum evaporation method, for example. A metal material can be used for the conductive film 151f, for example.

Next, as illustrated in FIG. 7A, a conductive film 152f to be the conductive layers 152R, 152G, 152B, and 152C is formed over the conductive film 151f. The conductive film 152f can be formed by a sputtering method or a vacuum evaporation method, for example. A conductive oxide can be used for the conductive film 152f, for example. The conductive film 152f can have a stacked-layer structure of a film formed using a metal material and a film formed thereover using a conductive oxide. For example, the conductive film 152f can have a stacked-layer structure of a film formed using titanium, silver, or an alloy containing silver and a film formed thereover using a conductive oxide.

The conductive film 152f can be formed by an ALD method. In this case, for the conductive film 152f, an oxide containing one or more selected from indium, tin, zinc, gallium, titanium, aluminum, and silicon can be used. In this case, the conductive film 152f can be formed by repeating a cycle of introduction of a precursor (generally referred to as a metal precursor or the like in some cases), purge of the precursor, introduction of an oxidizer (generally referred to as a reactant, a non-metal precursor, or the like in some cases), and purge of the oxidizer. Here, in the case where an oxide film including a plurality of kinds of metals (e.g., an indium tin oxide film) is formed as the conductive film 152f, the composition of the metals can be controlled by varying the number of cycles for different kinds of precursors.

For example, in the case where an indium tin oxide film is formed as the conductive film 152f, after a precursor containing indium is introduced, the precursor is purged, and an oxidizer is introduced to form an In—O film, and then a precursor containing tin is introduced, the precursor is purged, and an oxidizer is introduced to form a Sn—O film. Here, when the number of cycles of forming an In—O film is larger than the number of cycles of forming a Sn—O film, the number of In atoms included in the conductive film 152f can be larger than the number of Sn atoms included therein.

For example, to form a zinc oxide film as the conductive film 152f, a Zn—O film is formed in the above procedure. For another example, to form an aluminum zinc oxide film as the conductive film 152f, a Zn—O film and an Al—O film are formed in the above procedure. For another example, to form a titanium oxide film as the conductive film 152f, a Ti—O film is formed in the above procedure. For another example, to form an indium tin oxide film including silicon as the conductive film 152f, an In—O film, a Sn—O film, and a Si—O film are formed in the above procedure. For another example, to form a zinc oxide film including gallium, a Ga—O film and a Zn—O film are formed in the above procedure.

As a precursor containing indium, it is possible to use, for example, triethylindium, trimethylindium, or [1,1,1-trimethyl-N-(trimethylsilyl)amide]-indium. As a precursor containing tin, it is possible to use, for example, tin chloride or tetrakis(dimethylamido)tin. As a precursor containing zinc, it is possible to use, for example, diethylzinc or dimethylzinc. As a precursor containing gallium, it is possible to use, for example, triethylgallium. As a precursor containing titanium, it is possible to use, for example, titanium chloride, tetrakis(dimethylamido)titanium, or tetraisopropyl titanate. As a precursor containing aluminum, it is possible to use, for example, aluminum chloride or trimethylaluminum. As a precursor containing silicon, it is possible to use, for example, trisilylamine, bis(diethylamino)silane, tris(dimethylamino)silane, bis(tert-butylamino)silane, or bis(ethylmethylamino)silane. As the oxidizer, water vapor, oxygen plasma, or an ozone gas can be used.

Subsequently, a resist mask 191 is formed over the conductive films 151f and 152f as illustrated in FIG. 7A. The resist mask 191 can be formed by application of a photosensitive material (photoresist), light exposure, and development.

Subsequently, as illustrated in FIG. 7B, the conductive films 151f and 152f in a region not overlapping with the resist mask 191, for example, are removed by an etching method, specifically, a dry etching method, for instance, so that the pixel electrodes each including the conductive layers 151 and 152 are formed. Note that in the case where the conductive film 151f includes a layer formed using a conductive oxide such as indium tin oxide, for example, the layer may be removed by a wet etching method. In the case where part of the conductive film 151f is removed by a dry etching method, for example, a depressed portion may be formed in a region of the insulating layer 175 not overlapping with the conductive layer 151.

The conductive film 152f may be processed by a lithography method to form the conductive layers 152R, 152G, 152B, and 152C, and then the conductive film 151f may be processed using the conductive layers 152R, 152G, 152B, and 152C as masks. Specifically, after a resist mask is formed, part of the conductive film 152f is removed by an etching method, for example. The conductive film 152f can be removed by a wet etching method, for example. The conductive film 152f may be removed by a dry etching method. After that, the conductive film 151f is preferably removed by a wet etching method.

Here, hydrophobization treatment is preferably performed on the conductive layer 152. The hydrophobization treatment can change the hydrophilic properties of the subject surface to hydrophobic properties or increase the hydrophobic properties of the subject surface. The hydrophobization treatment for the conductive layer 152 can increase the adhesion between the conductive layer 152 and the organic compound layer 103 formed in a later step and inhibit film peeling. Note that the hydrophobization treatment is not necessarily performed.

Next, the resist mask 191 is removed as illustrated in FIG. 7C. The resist mask 191 can be removed by ashing using oxygen plasma, for example. Alternatively, an oxygen gas and any of CF₄, C₄F₈, SF₆, CHF₃, Cl₂, H₂O, BCl₃, and a Group 18 element such as He may be used. Alternatively, the resist mask 191 may be removed by wet etching.

Then, as illustrated in FIG. 7D, an insulating film 156f to be insulating layers 156R, 156G, 156B, and 156C is formed over the conductive layers 151R and 152R, the conductive layers 151G and 152G, the conductive layers 151B and 152B, the conductive layers 151C and 152C, and the insulating layer 175. The insulating film 156f can be formed by a CVD method, an ALD method, a sputtering method, or a vacuum evaporation method, for example.

For the insulating film 156f, an inorganic material can be used. As the insulating film 156f, an inorganic insulating film such as an oxide insulating film, a nitride insulating film, an oxynitride insulating film, or a nitride oxide insulating film can be used, for example. For example, an oxide insulating film including silicon, a nitride insulating film including silicon, an oxynitride insulating film including silicon, a nitride oxide insulating film including silicon, or the like can be used as the insulating film 156f. For the insulating film 156f, silicon oxynitride can be used, for example.

Subsequently, as illustrated in FIG. 7E, the insulating film 156f is processed to form the insulating layers 156R, 156G, 156B, and 156C. The insulating layer 156 can be formed by performing etching substantially uniformly on the top surface of the insulating film 156f, for example. Such uniform etching for planarization is also referred to as etch back treatment. Note that the insulating layer 156 may be formed by a lithography method.

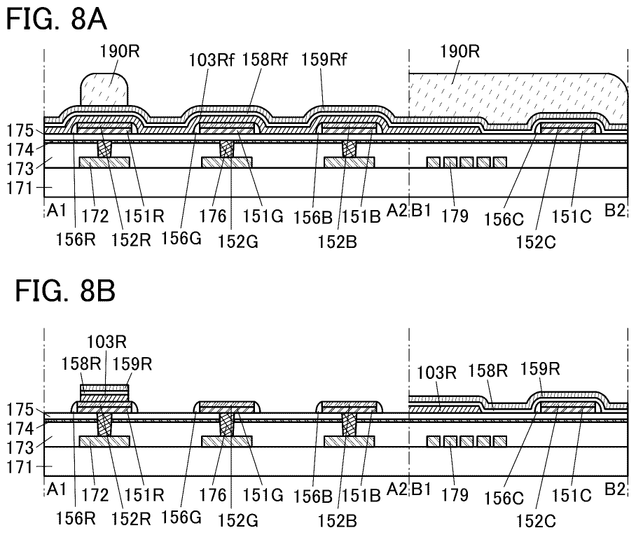

Next, as illustrated in FIG. 8A, an organic compound film 103Rf to be the organic compound layer 103R is formed over the conductive layers 152R, 152G, and 152B, the insulating layers 156R, 156G, and 156B, and the insulating layer 175.

As illustrated in FIG. 8A, the organic compound film 103Rf is not formed over the conductive layer 152C. For example, a mask for defining a film formation area (also referred to as an area mask, a rough metal mask, or the like to be distinguished from a fine metal mask) is used, so that the organic compound film 103Rf can be formed only in a desired region. Employing a film formation step using an area mask and a processing step using a resist mask enables a light-emitting device to be fabricated by a relatively easy process.

The organic compound film 103Rf can be formed by an evaporation method, specifically a vacuum evaporation method, for example. The organic compound film 103Rf may be formed by a transfer method, a printing method, an ink-jet method, a coating method, or the like.

Next, as illustrated in FIG. 8A, a sacrificial film 158Rf to be a sacrificial layer 158R and a mask film 159Rf to be a mask layer 159R are sequentially formed over the organic compound film 103Rf, the conductive layer 152C, and the insulating layer 175.

Although this embodiment shows an example in which a mask film having a two-layer structure of the sacrificial film 158Rf and the mask film 159Rf is formed, the mask film may have a single-layer structure or a stacked-layer structure of three or more layers. In this specification and the like, a mask layer may be referred to as a sacrificial layer.

Providing the sacrificial layer over the organic compound film 103Rf can reduce damage to the organic compound film 103Rf in the manufacturing process of the display apparatus, resulting in an increase in reliability of the light-emitting device.

As the sacrificial film 158Rf, a film that is highly resistant to the process conditions for the organic compound film 103Rf, specifically, a film having high etching selectivity with respect to the organic compound film 103Rf is used. For the mask film 159Rf, a film having high etching selectivity with respect to the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each lower than or equal to 200° C., preferably lower than or equal to 150° C., further preferably lower than or equal to 120° C., still further preferably lower than or equal to 100° C., and yet still further preferably lower than or equal to 80° C.

The sacrificial film 158Rf and the mask film 159Rf are preferably films that can be removed by a wet etching method. The use of a wet etching method can reduce damage to the organic compound film 103Rf in processing of the sacrificial film 158Rf and the mask film 159Rf, as compared to the case of using a dry etching method.

The sacrificial film 158Rf and the mask film 159Rf can be formed by a sputtering method, an ALD method (including a thermal ALD method and a PEALD method), a CVD method, or a vacuum evaporation method, for example. Alternatively, the sacrificial film 158Rf and the mask film 159Rf may be formed by the above-described wet film-formation method.

The sacrificial film 158Rf that is formed over and in contact with the organic compound film 103Rf is preferably formed by a formation method that is less likely to damage the organic compound film 103Rf than a formation method of the mask film 159Rf. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, and an inorganic insulating film, for example, can be used.

For each of the sacrificial film 158Rf and the mask film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. A metal material that can block ultraviolet rays is preferably used for one or both of the sacrificial film 158Rf and the mask film 159Rf, in which case the organic compound film 103Rf can be inhibited from being irradiated with ultraviolet rays and deteriorating.

The sacrificial film 158Rf and the mask film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In place of gallium described above, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

As each of the sacrificial film and the mask film, a film including a material having a light-blocking property, particularly with respect to ultraviolet rays, is preferably used. Although a variety of materials such as a metal, an insulator, a semiconductor, and a metalloid that have a property of blocking ultraviolet rays can be used as a light-blocking material, each of the sacrificial film and the mask film is preferably a film capable of being processed by etching and is particularly preferably a film having good processability because part or the whole of each of the sacrificial film and the mask film is removed in a later step.

The sacrificial film and the mask film are preferably formed using a semiconductor material such as silicon or germanium, for example, for excellent compatibility with a semiconductor manufacturing process. Alternatively, an oxide or a nitride of the semiconductor material can be used. A non-metallic material such as carbon or a compound thereof can be used. A metal such as titanium, tantalum, tungsten, chromium, or aluminum or an alloy containing at least one of these metals can be used. Alternatively, an oxide containing the above-described metal, such as titanium oxide or chromium oxide, or a nitride such as titanium nitride, chromium nitride, or tantalum nitride can be used.

When a film including a material having a property of blocking ultraviolet rays is used as each of the sacrificial film and the mask film, the organic compound layer can be inhibited from being irradiated with ultraviolet rays in a light exposure step, for example. The organic compound layer is inhibited from being damaged by ultraviolet rays, so that the reliability of the light-emitting device can be improved.

The same effect is obtained when a film including a material having a property of blocking ultraviolet rays is used for a later-described inorganic insulating film 125f.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film. For example, an inorganic insulating material such as aluminum oxide, hafnium oxide, or silicon oxide can be used for the sacrificial film 158Rf and the mask film 159Rf. As the sacrificial film 158Rf and the mask film 159Rf, aluminum oxide films can be formed by an ALD method, for example. An ALD method is preferably used, in which case damage to a base (in particular, the organic compound layer) can be reduced.

For example, an inorganic insulating film (e.g., an aluminum oxide film) formed by an ALD method can be used as the sacrificial film 158Rf, and an inorganic film (e.g., an In—Ga—Zn oxide film, an aluminum film, or a tungsten film) formed by a sputtering method can be used as the mask film 159Rf.

The same inorganic insulating film can be used for both the sacrificial film 158Rf and the inorganic insulating layer 125 that is to be formed later. For example, an aluminum oxide film formed by an ALD method can be used for both the sacrificial film 158Rf and the inorganic insulating layer 125. For the sacrificial film 158Rf and the inorganic insulating layer 125, the same film formation conditions may be used or different film formation conditions may be used. For example, when the sacrificial film 158Rf is formed under conditions similar to those of the inorganic insulating layer 125, the sacrificial film 158Rf can be an insulating layer having a high barrier property against at least one of water and oxygen. Meanwhile, since the sacrificial film 158Rf is a layer a large part or the whole of which is to be removed in a later step, it is preferable that the processing of the sacrificial film 158Rf be easy. Therefore, the sacrificial film 158Rf is preferably formed with a substrate temperature lower than that for formation of the inorganic insulating layer 125.

One or both of the sacrificial film 158Rf and the mask film 159Rf may be formed using an organic material. For example, as the organic material, a material that can be dissolved in a solvent chemically stable with respect to at least the uppermost film of the organic compound film 103Rf may be used. Specifically, a material that will be dissolved in water or an alcohol can be suitably used. In forming a film of such a material, it is preferable to apply the material dissolved in a solvent such as water or an alcohol by a wet film-formation method and then perform heat treatment for evaporating the solvent. At this time, the heat treatment is preferably performed in a reduced-pressure atmosphere, in which case the solvent can be removed at a low temperature in a short time and thermal damage to the organic compound film 103Rf can be reduced accordingly.

The sacrificial film 158Rf and the mask film 159Rf may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluorine resin like perfluoropolymer.

For example, an organic film (e.g., a PVA film) formed by an evaporation method or any of the above wet film-formation methods can be used as the sacrificial film 158Rf, and an inorganic film (e.g., a silicon nitride film) formed by a sputtering method can be used as the mask film 159Rf.

Subsequently, a resist mask 190R is formed over the mask film 159Rf as illustrated in FIG. 8A. The resist mask 190R can be formed by application of a photosensitive material (photoresist), light exposure, and development.

The resist mask 190R may be formed using either a positive resist material or a negative resist material.

The resist mask 190R is provided at a position overlapping with the conductive layer 152R. The resist mask 190R is preferably provided also at a position overlapping with the conductive layer 152C. This can inhibit the conductive layer 152C from being damaged during the process of manufacturing the display apparatus. Note that the resist mask 190R is not necessarily provided over the conductive layer 152C. The resist mask 190R is preferably provided to cover the area from an end portion of the organic compound film 103Rf to an end portion of the conductive layer 152C (the end portion closer to the organic compound film 103Rf), as illustrated in the cross-sectional view along the line B1-B2 in FIG. 8A.

Next, as illustrated in FIG. 8B, part of the mask film 159Rf is removed using the resist mask 190R, so that the mask layer 159R is formed. The mask layer 159R remains over the conductive layers 152R and 152C. After that, the resist mask 190R is removed. Then, part of the sacrificial film 158Rf is removed using the mask layer 159R as a mask (also referred to as a hard mask), so that the sacrificial layer 158R is formed.

Each of the sacrificial film 158Rf and the mask film 159Rf can be processed by a wet etching method or a dry etching method. The sacrificial film 158Rf and the mask film 159Rf are preferably processed by isotropic etching.

The use of a wet etching method can reduce damage to the organic compound film 103Rf in processing of the sacrificial film 158Rf and the mask film 159Rf, as compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a chemical solution containing a mixed solution of any of these acids, for example.

Since the organic compound film 103Rf is not exposed in the processing of the mask film 159Rf, the range of choice for a processing method for the mask film 159Rf is wider than that for the sacrificial film 158Rf Specifically, even in the case where a gas containing oxygen is used as the etching gas in the processing of the mask film 159Rf, deterioration of the organic compound film 103Rf can be inhibited.

In the case of using a dry etching method to process the sacrificial film 158Rf, deterioration of the organic compound film 103Rf can be inhibited by not using a gas containing oxygen as the etching gas. In the case of using a dry etching method, it is preferable to use a gas containing CF₄, C₄F₈, SF₆, CHF₃, Cl₂, H₂O, BCl₃, or a Group 18 element such as He, for example, as the etching gas.

For example, in the case where an aluminum oxide film formed by an ALD method is used as the sacrificial film 158Rf, part of the sacrificial film 158Rf can be removed by a dry etching method using CHF₃ and He or using CHF₃, He, and CH₄. In the case where an In—Ga—Zn oxide film formed by a sputtering method is used as the mask film 159Rf, part of the mask film 159Rf can be removed by a wet etching method using diluted phosphoric acid. Alternatively, part of the mask film 159Rf may be removed by a dry etching method using CH₄ and Ar. Alternatively, part of the mask film 159Rf can be removed by a wet etching method using diluted phosphoric acid. In the case where a tungsten film formed by a sputtering method is used as the mask film 159Rf, part of the mask film 159Rf can be removed by a dry etching method using SF₆, CF₄, and O₂ or using CF₄, Cl₂, and O₂.

The resist mask 190R can be removed by a method similar to that for the resist mask 191. For example, the resist mask 190R can be removed by ashing using oxygen plasma. Alternatively, an oxygen gas and any of CF₄, C₄F₈, SF₆, CHF₃, Cl₂, H₂O, BCl₃, and a Group 18 element such as He may be used. Alternatively, the resist mask 190R may be removed by wet etching. At this time, the sacrificial film 158Rf is located on the outermost surface, and the organic compound film 103Rf is not exposed; thus, the organic compound film 103Rf can be inhibited from being damaged in the step of removing the resist mask 190R. In addition, the range of choice for the method for removing the resist mask 190R can be widened.

Next, as illustrated in FIG. 8B, the organic compound film 103Rf is processed, so that the organic compound layer 103R is formed. For example, part of the organic compound film 103Rf is removed using the mask layer 159R and the sacrificial layer 158R as a hard mask to form the organic compound layer 103R.

Accordingly, as illustrated in FIG. 8B, the stacked-layer structure of the organic compound layer 103R, the sacrificial layer 158R, and the mask layer 159R remains over the conductive layer 152R. The conductive layers 152G and 152B are exposed.

In the example illustrated in FIG. 8B, an end portion of the organic compound layer 103R is located inward from an end portion of the conductive layer 152R. With this structure, a pixel can be miniaturized, so that a high-resolution display can be formed. Although not illustrated in FIG. 8B, by the above etching treatment, a depressed portion may be formed in the insulating layer 175 in a region not overlapping with the organic compound layer 103R.

As described above, the resist mask 190R is preferably provided to cover the area from the end portion of the organic compound layer 103R to the end portion of the conductive layer 152C (the end portion closer to the organic compound layer 103R) in the cross section along the dashed-dotted line B1-B2. In that case, as illustrated in FIG. 8B, the sacrificial layer 158R and the mask layer 159R are provided to cover the area from the end portion of the organic compound layer 103R to the end portion of the conductive layer 152C (the end portion closer to the organic compound layer 103R) in the cross section along the dashed-dotted line B1-B2. Hence, the insulating layer 175 can be inhibited from being exposed in the cross section along the dashed-dotted line B1-B2, for example. This can prevent the insulating layers 175, 174, and 173 from being partly removed by etching or the like and thus prevent the conductive layer 179 from being exposed. Accordingly, the conductive layer 179 can be inhibited from being unintentionally electrically connected to another conductive layer. For example, a short circuit between the conductive layer 179 and a common electrode 155 formed in a later step can be inhibited.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Accordingly, damage to the organic compound film 103Rf can be reduced. Furthermore, a defect such as attachment of a reaction product generated in the etching can be inhibited.

In the case of using a dry etching method, it is preferable to use a gas containing at least one of H₂, CF₄, C₄F₈, SF₆, CHF₃, Cl₂, H₂O, BCl₃, and Group 18 elements such as He and Ar as the etching gas, for example. Alternatively, a gas containing oxygen and at least one of the above is preferably used as the etching gas. Alternatively, an oxygen gas may be used as the etching gas. Specifically, for example, a gas containing H₂ and Ar or a gas containing CF₄ and He can be used as the etching gas. For another example, a gas containing CF₄, He, and oxygen can be used as the etching gas. For another example, a gas containing H₂ and Ar and a gas containing oxygen can be used as the etching gas.

As described above, in one embodiment of the present invention, the mask layer 159R is formed in the following manner: the resist mask 190R is formed over the mask film 159Rf and part of the mask film 159Rf is removed using the resist mask 190R. After that, part of the organic compound film 103Rf is removed using the mask layer 159R as a hard mask, so that the organic compound layer 103R is formed. In other words, the organic compound layer 103R is formed by processing the organic compound film 103Rf by a lithography method. In addition, part of the organic compound film 103Rf may be removed using the resist mask 190R. Then, the resist mask 190R may be removed.

Next, hydrophobization treatment for the conductive layer 152G, for example, is preferably performed. At the time of processing the organic compound film 103Rf, the properties of a surface of the conductive layer 152G change to hydrophilic properties in some cases, for example. The hydrophobization treatment for the conductive layer 152G, for example, can increase the adhesion between the conductive layer 152G and a layer to be formed in a later step (which is the organic compound layer 103G here) and inhibit film peeling. Note that the hydrophobization treatment is not necessarily performed.

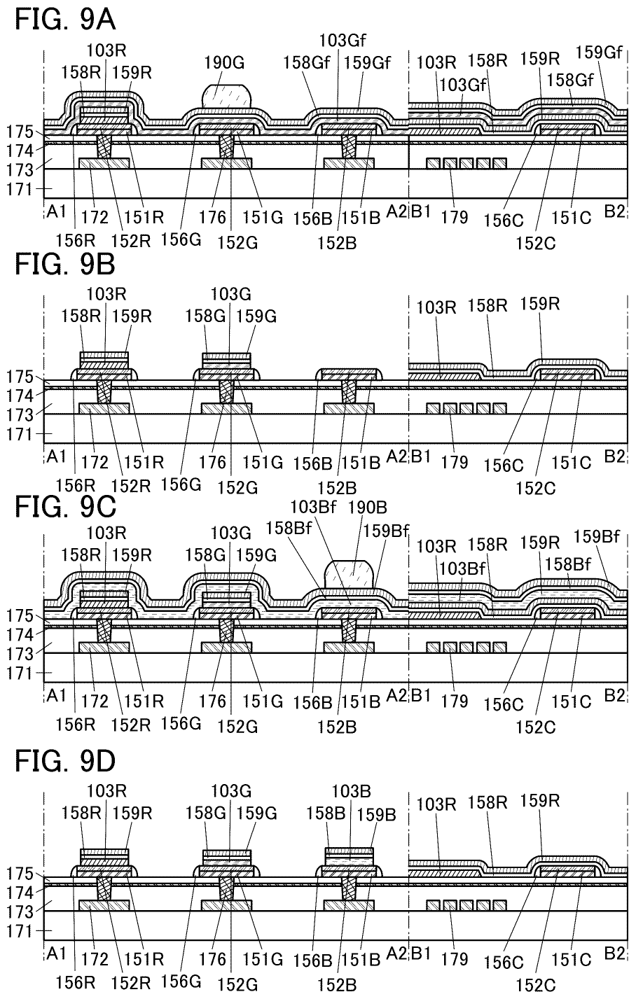

Next, as illustrated in FIG. 9A, an organic compound film 103Gf to be the organic compound layer 103G is formed over the conductive layers 152G and 152B, the insulating layers 156R, 156G, and 156B, the mask layer 159R, and the insulating layer 175.

The organic compound film 103Gf can be formed by a method similar to that for forming the organic compound film 103Rf. The organic compound film 103Gf can have a structure similar to that of the organic compound film 103Rf.

Then, as illustrated in FIG. 9A, a sacrificial film 158Gf to be a sacrificial layer 158G and a mask film 159Gf to be a mask layer 159G are sequentially formed over the organic compound film 103Gf and the mask layer 159R. After that, a resist mask 190G is formed. The materials and the formation methods of the sacrificial film 158Gf and the mask film 159Gf are similar to those of the sacrificial film 158Rf and the mask film 159Rf. The material and the formation method of the resist mask 190G are similar to those of the resist mask 190R.

The resist mask 190G is provided at a position overlapping with the conductive layer 152G.

Subsequently, as illustrated in FIG. 9B, part of the mask film 159Gf is removed using the resist mask 190G, so that the mask layer 159G is formed. The mask layer 159G remains over the conductive layer 152G. After that, the resist mask 190G is removed. Then, part of the sacrificial film 158Gf is removed using the mask layer 159G as a mask, so that the sacrificial layer 158G is formed. Next, the organic compound film 103Gf is processed, so that the organic compound layer 103G is formed. For example, part of the organic compound film 103Gf is removed using the mask layer 159G and the sacrificial layer 158G as a hard mask to form the organic compound layer 103G.

Accordingly, as illustrated in FIG. 9B, the stacked-layer structure of the organic compound layer 103G, the sacrificial layer 158G, and the mask layer 159G remains over the conductive layer 152G. The mask layer 159R and the conductive layer 152B are exposed.

Next, hydrophobization treatment for the conductive layer 152B, for example, is preferably performed. At the time of processing the organic compound film 103Gf, the properties of a surface of the conductive layer 152B change to hydrophilic properties in some cases, for example. The hydrophobization treatment for the conductive layer 152B, for example, can increase the adhesion between the conductive layer 152B and a layer to be formed in a later step (which is the organic compound layer 103B here) and inhibit film peeling. Note that the hydrophobization treatment is not necessarily performed.

Next, as illustrated in FIG. 9C, the organic compound film 103Bf to be the organic compound layer 103B is formed over the conductive layer 152B, the insulating layers 156R, 156G, and 156B, the mask layers 159R and 159G, and the insulating layer 175.

The organic compound film 103Bf can be formed by a method similar to that for forming the organic compound film 103Rf. The organic compound film 103Bf can have a structure similar to that of the organic compound film 103Rf.

Then, as illustrated in FIG. 9C, a sacrificial film 158Bf to be a sacrificial layer 158B and a mask film 159Bf to be a mask layer 159B are sequentially formed over the organic compound film 103Bf and the mask layer 159R. After that, a resist mask 190B is formed. The materials and the formation methods of the sacrificial film 158Bf and the mask film 159Bf are similar to those of the sacrificial film 158Rf and the mask film 159Rf. The material and the formation method of the resist mask 190B are similar to those of the resist mask 190R.

The resist mask 190B is provided at a position overlapping with the conductive layer 152B.

Subsequently, as illustrated in FIG. 9D, part of the mask film 159Bf is removed using the resist mask 190B, so that the mask layer 159B is formed. The mask layer 159B remains over the conductive layer 152B. After that, the resist mask 190B is removed. Then, part of the sacrificial film 158Bf is removed using the mask layer 159B as a mask, so that the sacrificial layer 158B is formed. Next, the organic compound film 103Bf is processed, so that the organic compound layer 103B is formed. For example, part of the organic compound film 103Bf is removed using the mask layer 159B and the sacrificial layer 158B as a hard mask to form the organic compound layer 103B.

Accordingly, as illustrated in FIG. 9D, the stacked-layer structure of the organic compound layer 103B, the sacrificial layer 158B, and the mask layer 159B remains over the conductive layer 152B. The mask layers 159R and 159G are exposed.

The side surfaces of the organic compound layers 103R, 103G, and 103B are preferably perpendicular or substantially perpendicular to their formation surfaces. For example, the angles between the formation surfaces and these side surfaces are each preferably greater than or equal to 60° and less than or equal to 90°.

The distance between two adjacent layers among the organic compound layers 103R, 103G, and 103B, which are formed by a lithography method as described above, can be shortened to less than or equal to 8 μm, less than or equal to 5 μm, less than or equal to 3 μm, less than or equal to 2 μm, or less than or equal to 1 μm. Here, the distance can be defined, for example, as the distance between opposite end portions of two adjacent layers among the organic compound layers 103R, 103G, and 103B. Shortening the distance between the island-shaped organic compound layers can provide a display apparatus having high resolution and a high aperture ratio. In addition, the distance between the first electrodes of adjacent light-emitting devices can also be shortened to be, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

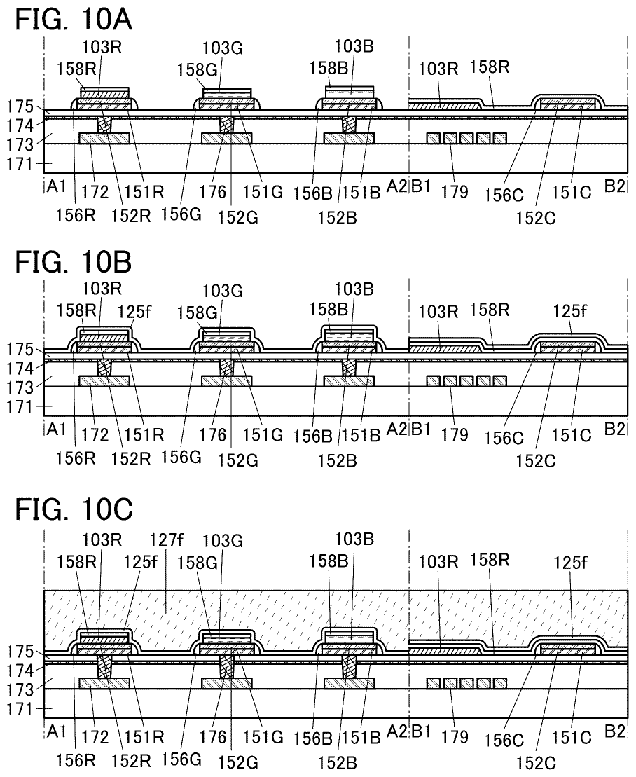

Next, as illustrated in FIG. 10A, the mask layers 159R, 159G, and 159B are preferably removed. The sacrificial layers 158R, 158G, and 158B and the mask layers 159R, 159G, and 159B remain in the display apparatus in some cases depending on the subsequent steps. Removing the mask layers 159R, 159G, and 159B at this stage can inhibit the mask layers 159R, 159G, and 159B from being left in the display apparatus. For example, in the case where a conductive material is used for the mask layers 159R, 159G, and 159B, removing the mask layers 159R, 159G, and 159B in advance can inhibit generation of a leakage current, formation of a capacitor, and the like due to the remaining mask layers 159R, 159G, and 159B.

This embodiment describes an example in which the mask layers 159R, 159G, and 159B are removed; however, the mask layers 159R, 159G, and 159B are not necessarily removed. For example, in the case where the mask layers 159R, 159G, and 159B include the above-described material having a property of blocking ultraviolet rays, the procedure preferably proceeds to the next step without removing the mask layers 159R, 159G, and 159B, in which case the organic compound layers can be protected from ultraviolet rays.

The step of removing the mask layers can be performed by a method similar to that for the step of processing the mask films. Specifically, by using a wet etching method, damage applied to the organic compound layers 103R, 103G, and 103B at the time of removing the mask layers can be reduced as compared to the case of using a dry etching method.

The mask layers may be removed by being dissolved in a solvent such as water or an alcohol. Examples of an alcohol include ethyl alcohol, methyl alcohol, isopropyl alcohol (IPA), and glycerin.

After the mask layers are removed, drying treatment may be performed in order to remove water included in the organic compound layers 103R, 103G, and 103B and water adsorbed onto the surfaces of the organic compound layers 103R, 103G, and 103B. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, as illustrated in FIG. 10B, the inorganic insulating film 125f to be the inorganic insulating layer 125 is formed to cover the organic compound layers 103R, 103G, and 103B and the sacrificial layers 158R, 158G, and 158B.

As described later, an insulating film 127f to be the insulating layer 127 is formed in contact with the top surface of the inorganic insulating film 125f. Therefore, the top surface of the inorganic insulating film 125f preferably has a high affinity for the material used for the insulating film (e.g., a photosensitive resin composition containing an acrylic resin). To improve the affinity, surface treatment is preferably performed so that the top surface of the inorganic insulating film 125f is made hydrophobic (or its hydrophobic property is improved). For example, it is preferable to perform the treatment using a silylation agent such as hexamethyldisilazane (HMDS). By making the top surface of the inorganic insulating film 125f hydrophobic in such a manner, an insulating film 127f can be formed with favorable adhesion. Note that the above-described hydrophobization treatment may be performed as the surface treatment.

Then, as illustrated in FIG. 10C, an insulating film 127f to be the insulating layer 127 is formed over the inorganic insulating film 125f.

The inorganic insulating film 125f and the insulating film 127f are preferably formed by a formation method by which the organic compound layers 103R, 103G, and 103B are less damaged. The inorganic insulating film 125f, which is formed in contact with the side surfaces of the organic compound layers 103R, 103G, and 103B, is particularly preferably formed by a formation method that causes less damage to the organic compound layers 103R, 103G, and 103B than the formation method of the insulating film 127f.

Each of the inorganic insulating film 125f and the insulating film 127f is formed at a temperature lower than the upper temperature limits of the organic compound layers 103R, 103G, and 103B. When the inorganic insulating film 125f is formed at a high substrate temperature, the formed inorganic insulating film 125f, even with a small thickness, can have a low impurity concentration and a high barrier property against at least one of water and oxygen.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm is preferably formed in the above-described range of the substrate temperature.

The inorganic insulating film 125f is preferably formed by an ALD method, for example. An ALD method is preferably used, in which case damage due to film formation is reduced and a film with good coverage can be formed. As the inorganic insulating film 125f, an aluminum oxide film is preferably formed by an ALD method, for example.

Alternatively, the inorganic insulating film 125f may be formed by a sputtering method, a CVD method, or a PECVD method, each of which has a higher deposition rate than an ALD method. In that case, a highly reliable display apparatus can be manufactured with high productivity.

The insulating film 127f is preferably formed by the aforementioned wet film-formation method. For example, the insulating film 127f is preferably formed by spin coating using a photosensitive material, and specifically, preferably formed using a photosensitive resin composition containing an acrylic resin.

The insulating film 127f is preferably formed using a resin composition containing a polymer, an acid-generating agent, and a solvent, for example. The polymer is formed using one or more kinds of monomers and has a structure where one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

Heat treatment (also referred to as prebaking) is preferably performed after the insulating film 127f is formed. The heat treatment is performed at a temperature lower than the upper temperature limits of the organic compound layers 103R, 103G, and 103B. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, the solvent included in the insulating film 127f can be removed.

Then, part of the insulating film 127f is exposed to visible light or ultraviolet rays. Here, when a positive photosensitive resin composition containing an acrylic resin is used for the insulating film 127f, a region where the insulating layer 127 is not formed in a later step is irradiated with visible light or ultraviolet rays. The insulating layer 127 is formed in regions that are sandwiched between any two of the conductive layers 152R, 152G, and 152B and around the conductive layer 152C. Thus, the top surfaces of the conductive layers 152R, 152G, 152B, and 152C are irradiated with visible light or ultraviolet rays. Note that when a negative photosensitive material is used for the insulating film 127f, the region where the insulating layer 127 is to be formed is irradiated with visible light or ultraviolet rays.

The width of the insulating layer 127 that is to be formed later can be controlled with the exposed region of the insulating film 127f. In this embodiment, processing is performed such that the insulating layer 127 includes a portion overlapping with the top surface of the conductive layer 151.

The light used for the exposure preferably includes the i-line (wavelength: 365 nm). Furthermore, the light used for the exposure may include at least one of the g-line (wavelength: 436 nm) and the h-line (wavelength: 405 nm).

Here, when a barrier insulating layer against oxygen (e.g., an aluminum oxide film) is provided as one or both of the sacrificial layer 158 (the sacrificial layers 158R, 158G, and 158B) and the inorganic insulating film 125f, diffusion of oxygen into the organic compound layers 103R, 103G, and 103B can be inhibited. When the organic compound layer is irradiated with light (visible light or ultraviolet rays), the organic compound included in the organic compound layer is brought into an excited state and a reaction between the organic compound and oxygen in the atmosphere is promoted in some cases. Specifically, when the organic compound layer is irradiated with light (visible light or ultraviolet rays) in an atmosphere containing oxygen, oxygen may be bonded to the organic compound included in the organic compound layer. By providing the sacrificial layer 158 and the inorganic insulating film 125f over the island-shaped organic compound layer, bonding of oxygen in the atmosphere to the organic compound included in the organic compound layer can be inhibited.

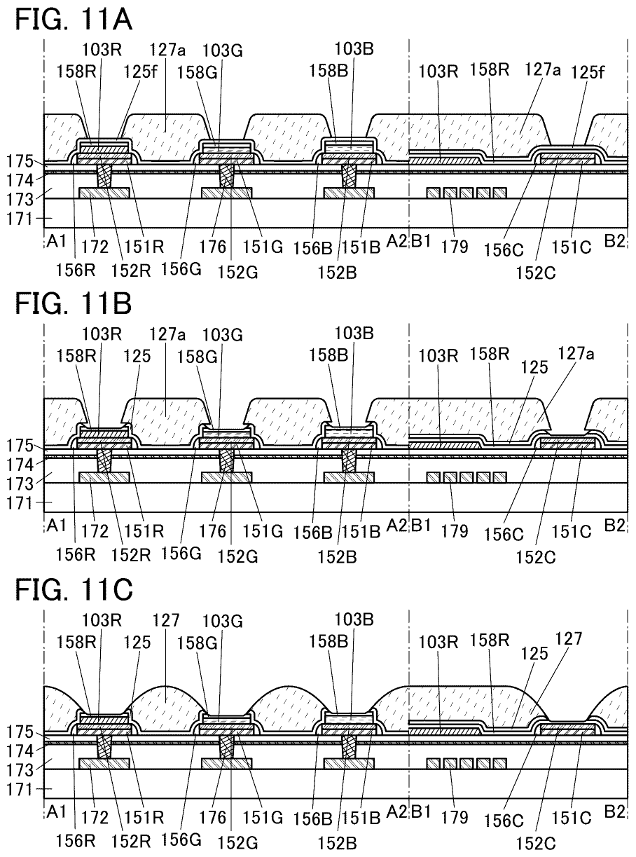

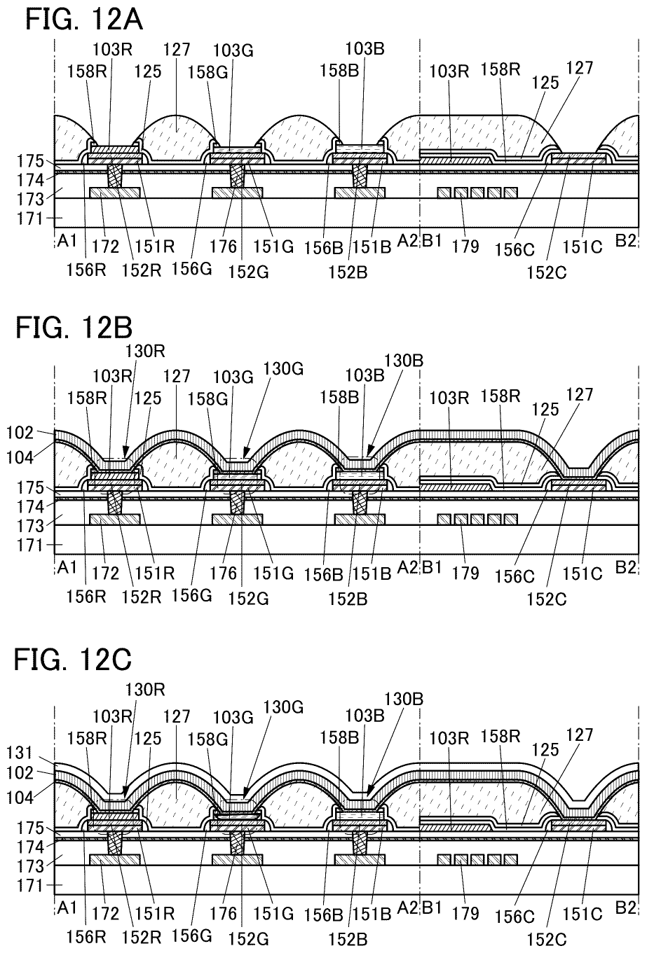

Next, as illustrated in FIG. 11A, development is performed to remove the exposed region of the insulating film 127f, so that an insulating layer 127a is formed. The insulating layer 127a is formed in regions that are sandwiched between any two of the conductive layers 152R, 152G, and 152B and a region surrounding the conductive layer 152C. Here, when an acrylic resin is used for the insulating film 127f, an alkaline solution, such as TMAH, can be used as a developer.

Then, a residue (scum) due to the development may be removed. For example, the residue can be removed by ashing using oxygen plasma.

Etching may be performed to adjust the surface level of the insulating layer 127a. The insulating layer 127a may be processed by ashing using oxygen plasma, for example. In the case where a non-photosensitive material is used for the insulating film 127f, the surface level of the insulating film 127f can be adjusted by the ashing, for example.

Next, as illustrated in FIG. 11B, etching treatment is performed using the insulating layer 127a as a mask to remove part of the inorganic insulating film 125f and reduce the thickness of part of the sacrificial layers 158R, 158G, and 158B. Thus, the inorganic insulating layer 125 is formed under the insulating layer 127a. Moreover, the surfaces of the thin portions of the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layers 158R, 158G, and 158B, in which case the first etching treatment can be performed collectively.

By etching using the insulating layer 127a with a tapered side surface as a mask, the side surface of the inorganic insulating layer 125 and upper end portions of the side surfaces of the sacrificial layers 158R, 158G, and 158B can each be made to have a tapered shape relatively easily.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layers 158R, 158G, and 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used. The capacitively coupled plasma etching apparatus including parallel plate electrodes may have a structure where a high-frequency voltage is applied to one of the parallel plate electrodes. Alternatively, the capacitively coupled plasma etching apparatus may have a structure where different high-frequency voltages are applied to one of the parallel-plate electrodes. Alternatively, the capacitively coupled plasma etching apparatus may have a structure where high-frequency voltages with the same frequency are applied to the parallel-plate electrodes. Alternatively, the capacitively coupled plasma etching apparatus may have a structure where high-frequency voltages with different frequencies are applied to the parallel-plate electrodes.

In the case of performing dry etching, a by-product or the like generated by the dry etching is sometimes deposited on the top surface and the side surface of the insulating layer 127a, for example. Accordingly, a component of the etching gas, a component of the inorganic insulating film 125f, a component of the sacrificial layers 158R, 158G, and 158B, and the like are included in the insulating layer 127 in the completed display apparatus in some cases.

The first etching treatment is preferably performed by wet etching. The use of a wet etching method can reduce damage to the organic compound layers 103R, 103G, and 103B, as compared to the case of using a dry etching method. For example, the wet etching can be performed using an alkaline solution. For instance, TMAH, which is an alkaline solution, can be used for the wet etching of an aluminum oxide film. In this case, puddle wet etching can be performed. Note that the inorganic insulating film 125f is preferably formed using a material similar to that of the sacrificial layers 158R, 158G, and 158B, in which case the above etching treatment can be performed collectively.

The sacrificial layers 158R, 158G, and 158B are not removed completely by the first etching treatment, and the etching treatment is stopped when the thicknesses of the sacrificial layers 158R, 158G, and 158B are reduced. The sacrificial layers 158R, 158G, and 158B remain over the corresponding organic compound layers 103R, 103G, and 103B in this manner, whereby the organic compound layers 103R, 103G, and 103B can be prevented from being damaged by treatment in a later step.

Next, the insulating layer 127a is preferably irradiated with visible light or ultraviolet rays by performing light exposure on the entire substrate. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a to a tapered shape.

Here, when a barrier insulating layer against oxygen (e.g., an aluminum oxide film) is provided as each of the sacrificial layers 158R, 158G, and 158B, diffusion of oxygen into the organic compound layers 103R, 103G, and 103B can be inhibited. When the organic compound layer is irradiated with light (visible light or ultraviolet rays), the organic compound included in the organic compound layer is brought into an excited state and a reaction between the organic compound and oxygen in the atmosphere is promoted in some cases. Specifically, when the organic compound layer is irradiated with light (visible light or ultraviolet rays) in an atmosphere containing oxygen, oxygen may be bonded to the organic compound included in the organic compound layer. By providing the sacrificial layers 158R, 158G, and 158B over the island-shaped organic compound layers, bonding of oxygen in the atmosphere to the organic compounds included in the organic compound layers can be inhibited.

Then, heat treatment (also referred to as post-baking) is performed. The heat treatment can change the insulating layer 127a into the insulating layer 127 having a tapered side surface (FIG. 11C). The heat treatment is performed at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. The substrate temperature in the heat treatment of this step is preferably higher than that in the heat treatment (prebaking) after the formation of the insulating film 127f. In that case, the adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 158R, 158G, and 158B are left, the organic compound layers 103R, 103G, and 103B can be prevented from being damaged and deteriorating in the heat treatment. This increases the reliability of the light-emitting devices.

The side surface of the insulating layer 127 may have a concave shape depending on the material of the insulating layer 127 and the temperature, time, and atmosphere of the post-baking. For example, when the temperature of the post-baking is higher or the duration of the post-baking is longer, the insulating layer 127 is more likely to change in shape and thus a concave shape may be more likely to be formed.

Next, as illustrated in FIG. 12A, etching treatment is performed using the insulating layer 127 as a mask to partly remove the sacrificial layers 158R, 158G, and 158B. Note that part of the inorganic insulating layer 125 is also removed in some cases. Thus, openings are formed in the sacrificial layers 158R, 158G, and 158B, and the top surfaces of the organic compound layers 103R, 103G, and 103B and the conductive layer 152C are exposed. Note that the etching treatment using the insulating layer 127 as a mask may be hereinafter referred to as second etching treatment.

An end portion of the inorganic insulating layer 125 is covered with the insulating layer 127. FIG. 12A illustrates an example where part of an end portion of the sacrificial layer 158G (specifically a tapered portion formed by the first etching treatment) is covered with the insulating layer 127 and a tapered portion formed by the second etching treatment is exposed.

If the first etching treatment is not performed and the inorganic insulating layer 125 and the sacrificial layer are collectively etched after the post-baking, the inorganic insulating layer 125 and the sacrificial layer under an end portion of the insulating layer 127 may disappear because of side etching and a void may be formed. The void causes unevenness on the formation surface of the common electrode 155, so that step disconnection is more likely to be caused in the common electrode 155. Even when a void is formed owing to side etching of the inorganic insulating layer 125 and the sacrificial layer by the first etching treatment, the post-baking performed subsequently can make the insulating layer 127 fill the void. After that, the thinned sacrificial layer is etched by the second etching treatment; thus, the amount of side etching decreases, a void is less likely to be formed, and even if a void is formed, it can be extremely small. Consequently, the formation surface of the common electrode 155 can be made flatter.

Note that the insulating layer 127 may cover the entire end portion of the sacrificial layer 158G. For example, the end portion of the insulating layer 127 may droop to cover the end portion of the sacrificial layer 158G. For another example, the end portion of the insulating layer 127 may be in contact with the top surface of at least one of the organic compound layers 103R, 103G, and 103B. As described above, when light exposure is not performed on the insulating layer 127a after the development, the shape of the insulating layer 127 may be likely to change.

The second etching treatment is performed by wet etching. The use of a wet etching method can reduce damage to the organic compound layers 103R, 103G, and 103B, as compared to the case of using a dry etching method. The wet etching can be performed using an alkaline solution such as TMAH, for example.

Meanwhile, in the case where the second etching treatment is performed by a wet etching method and gaps due to, for example, poor adhesion between the organic compound layer 103 and another layer exist at the interface between the organic compound layer 103 and the sacrificial layer 158, the interface between the organic compound layer 103 and the inorganic insulating layer 125, and the interface between the organic compound layer 103 and the insulating layer 175, the chemical solution used in the second etching treatment sometimes enters the gaps to come into contact with the pixel electrode. Here, when the chemical solution comes into contact with both the conductive layer 151 and the conductive layer 152, one of the conductive layers 151 and 152 that has a lower spontaneous potential than the other suffers from galvanic corrosion in some cases. For example, when the conductive layer 151 is formed using aluminum and the conductive layer 152 is formed using indium tin oxide, the conductive layer 152 sometimes corrodes. As a result, the yield of the display apparatus decreases in some cases. Moreover, the reliability of the display apparatus decreases in some cases.

As described above, when the insulating layer 156 is formed to cover the side surfaces of the conductive layers 151 and 152, the step disconnection of the inorganic insulating layer 125 can be prevented, whereby the chemical solution can be prevented from coming into contact with a lower component such as the conductive layer 151 in the second etching treatment, for example. Thus, corrosion of the pixel electrode can be prevented.

As described above, by providing the insulating layer 127, the inorganic insulating layer 125, and the sacrificial layers 158R, 158G, and 158B, poor connection due to a disconnected portion and an increase in electrical resistance due to a locally thinned portion can be inhibited from occurring in the common electrode 155 between the light-emitting devices. Thus, the display apparatus of one embodiment of the present invention can have improved display quality.

Heat treatment is performed after the organic compound layers 103R, 103G, and 103B are partly exposed. By the heat treatment, water included in the organic compound layers and water adsorbed onto the surfaces of the organic compound layers, for example, can be removed. The shape of the insulating layer 127 may be changed by the heat treatment. Specifically, the insulating layer 127 may be widened to cover at least one of the end portion of the inorganic insulating layer 125, the end portions of the sacrificial layers 158R, 158G, and 158B, and the top surfaces of the organic compound layers 103R, 103G, and 103B.

If the temperature of the heat treatment is too low, water included in the organic compound layers and water adsorbed onto the surfaces of the organic compound layers, for example, cannot be sufficiently removed. If the temperature of the heat treatment is too high, the organic compound layer 103 may deteriorate and the insulating layer 127 may change in shape excessively. Therefore, the temperature of the heat treatment is preferably higher than the temperature at which water is released from the organic compound layer 103 and lower than the glass transition temperature of the organic compound included in the organic compound layer 103, further preferably lower than the glass transition temperature of the organic compound included in the upper surface of the organic compound layer 103. Specifically, the substrate temperature is preferably higher than or equal to 80° C. and lower than or equal to 130° C., further preferably higher than or equal to 90° C. and lower than or equal to 120° C., still further preferably higher than or equal to 100° C. and lower than or equal to 120° C., and yet still further preferably higher than or equal to 100° C. and lower than or equal to 110° C. The heating atmosphere may be an air atmosphere or an inert gas atmosphere. Although the heating atmosphere may be an atmospheric-pressure atmosphere or a reduced-pressure atmosphere, a reduced-pressure atmosphere is preferably employed to prevent re-adsorption of water released from the organic compound layer 103.

By the heat treatment, water included in the organic compound layers and water adsorbed onto the surfaces of the organic compound layers, for example, can be sufficiently removed without deterioration of the organic compound layers 103R, 103G, and 103B and an excessive change in the shape of the insulating layer 127. Thus, degradation of the characteristics of the light-emitting device can be prevented.

Next, as illustrated in FIG. 12B, the common layer 104 and the common electrode 155 are formed over the organic compound layers 103R, 103G, and 103B, the conductive layer 152C, and the insulating layer 127. The common layer 104 and common electrode 155 can be formed by a sputtering method, a vacuum evaporation method, or the like. The common layer 104 may be formed by an evaporation method while the common electrode 155 may be formed by a sputtering method.

Next, as illustrated in FIG. 12C, the protective layer 135 is formed over the common electrode 155. The protective layer 135 can be formed by a vacuum evaporation method, a sputtering method, a CVD method, an ALD method, or the like.

Then, the substrate 120 is attached to the protective layer 135 using the resin layer 122, so that the display apparatus can be manufactured. As described above, in the method for manufacturing the display apparatus of one embodiment of the present invention, the insulating layer 156 is provided on the side surfaces of the conductive layers 151 and 152. This can increase the yield of the display apparatus and inhibit generation of defects.

As described above, in the method for manufacturing the display apparatus of one embodiment of the present invention, the island-shaped organic compound layers 103R, 103G, and 103B are each formed not by using a fine metal mask but by processing a film formed on the entire surface; thus, the island-shaped layers can be formed to have a uniform thickness. Consequently, a high-resolution display apparatus or a display apparatus with a high aperture ratio can be obtained. Furthermore, even when the resolution or the aperture ratio is high and the distance between the subpixels is extremely short, the organic compound layers 103R, 103G, and 103B can be inhibited from being in contact with each other in the adjacent subpixels. As a result, generation of a leakage current between the subpixels can be inhibited. This can prevent crosstalk, so that a display apparatus with extremely high contrast can be obtained. Moreover, even a display apparatus that includes tandem light-emitting devices formed by a lithography method can have favorable characteristics.

The structure described in this embodiment can be used in combination with any of the structures described in other embodiments as appropriate.

### Embodiment 4

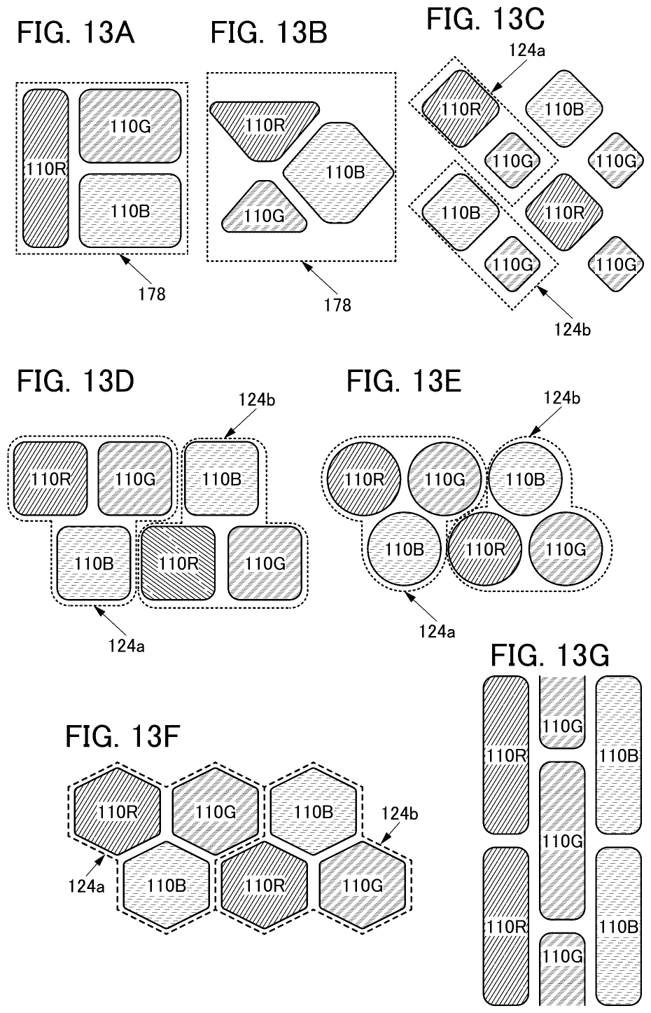

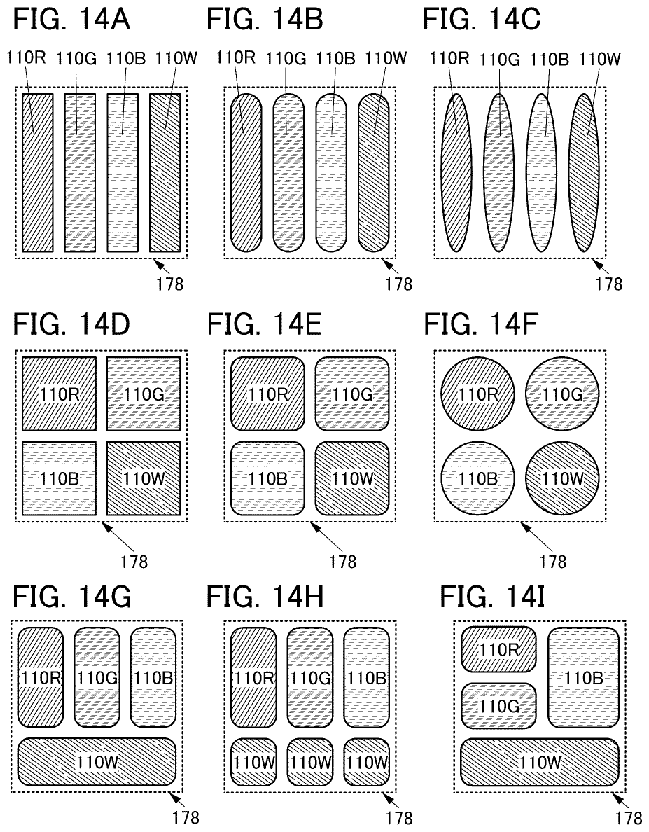

In this embodiment, the light-emitting apparatus of one embodiment of the present invention will be described with reference to FIGS. 13A to 13G and FIGS. 14A to 14I.

### [Pixel Layout]

In this embodiment, pixel layouts different from that in FIGS. 5A and 5B will be mainly described. There is no particular limitation on the subpixel layout, and a variety of methods can be employed. Examples of the subpixel layout include stripe layout, S-stripe layout, matrix layout, delta layout, Bayer layout, and PenTile layout.

There is no particular limitation on the arrangement of subpixels, and a variety of methods can be employed.

In this embodiment, the top surface shapes of the subpixels shown in the diagrams correspond to top surface shapes of light-emitting regions.

Examples of a top surface shape of the subpixel include polygons such as a triangle, a tetragon (including a rectangle and a square), and a pentagon; these polygons with rounded corners; an ellipse; and a circle.

The circuit constituting the subpixel is not necessarily placed within the dimensions of the subpixel illustrated in the diagrams and may be placed outside the subpixel.

The pixel 178 illustrated in FIG. 13A employs S-stripe layout. The pixel 178 illustrated in FIG. 13A includes three subpixels, the subpixel 110R, the subpixel 110G, and the subpixel 110n.

The pixel 178 illustrated in FIG. 13B includes the subpixel 110R whose top surface has a rough trapezoidal shape with rounded corners or a rough triangular shape with rounded corners, the subpixel 110G whose top surface has a rough trapezoidal shape with rounded corners or a rough triangular shape with rounded corners, and the subpixel 110B whose top surface has a rough tetragonal or rough hexagonal shape with rounded corners. The subpixel 110R has a larger light-emitting area than the subpixel 110G. In this manner, the shapes and sizes of the subpixels can be determined independently. For example, the size of a subpixel including a light-emitting device with higher reliability can be smaller.

Pixels 124a and 124b illustrated in FIG. 13C employ PenTile layout. FIG. 13C illustrates an example in which the pixels 124a including the subpixels 110R and 110G and the pixels 124b including the subpixels 110G and 110B are alternately arranged.

The pixels 124a and 124b illustrated in FIGS. 13D to 13F employ delta layout. The pixel 124a includes two subpixels (the subpixels 110R and 110G) in the upper row (first row) and one subpixel (the subpixel 110B) in the lower row (second row). The pixel 124b includes one subpixel (the subpixel 110B) in the upper row (first row) and two subpixels (the subpixels 110R and 110G) in the lower row (second row).

FIG. 13D illustrates an example where the top surface of each subpixel has a rough tetragonal shape with rounded corners. FIG. 13E illustrates an example where the top surface of each subpixel is circular. FIG. 13F illustrates an example where the top surface of each subpixel has a rough hexagonal shape with rounded corners.

In FIG. 13F, subpixels are placed in respective hexagonal regions that are arranged densely. One subpixel of the subpixels is placed so as to be surrounded by six subpixels. The subpixels are arranged such that subpixels that emit light of the same color are not adjacent to each other. For example, one subpixel 110R is surrounded by three subpixels 110G and three subpixels 110B that are alternately arranged.

FIG. 13G illustrates an example where subpixels of different colors are arranged in a zigzag manner. Specifically, the positions of the top sides of two subpixels arranged in the row direction (e.g., the subpixels 110R and 110G or the subpixels 110G and 110B) are not aligned in the top view.

In the pixels illustrated in FIGS. 13A to 13G, for example, it is preferable that the subpixel 110R be a subpixel R that emits red light, the subpixel 110G be a subpixel G that emits green light, and the subpixel 110B be a subpixel B that emits blue light. Note that the structures of the subpixels are not limited thereto, and the colors and the order of the subpixels can be determined as appropriate. For example, the subpixel 110G may be the subpixel R that emits red light, and the subpixel 110R may be the subpixel G that emits green light.

In a photolithography method, as a pattern to be formed by processing becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel may have a polygonal shape with rounded corners, an elliptical shape, a circular shape, or the like.

Furthermore, in the method for fabricating the light-emitting apparatus of one embodiment of the present invention, the organic compound layer is processed into an island shape with the use of a resist mask. A resist film formed over the organic compound layer needs to be cured at a temperature lower than the upper temperature limit of the organic compound layer. Therefore, the resist film is insufficiently cured in some cases depending on the upper temperature limit of the material of the organic compound layer and the curing temperature of the resist material. An insufficiently cured resist film may have a shape different from a desired shape by processing. As a result, the top surface of the organic compound layer may have a polygonal shape with rounded corners, an elliptical shape, a circular shape, or the like. For example, when a resist mask with a square top surface is intended to be formed, a resist mask with a circular top surface may be formed, and the top surface of the organic compound layer may be circular.

To obtain a desired top surface shape of the organic compound layer, a technique of correcting a mask pattern in advance so that a transferred pattern agrees with a design pattern (an optical proximity correction (OPC) technique) may be used. Specifically, with the OPC technique, a pattern for correction is added to a corner portion of a figure on a mask pattern, for example.

As illustrated in FIGS. 14A to 14I, the pixel can include four types of subpixels.

The pixels 178 illustrated in FIGS. 14A to 14C employ stripe layout.

FIG. 14A illustrates an example where each subpixel has a rectangular top surface shape. FIG. 14B illustrates an example where each subpixel has a top surface shape formed by combining two half circles and a rectangle. FIG. 14C illustrates an example where each subpixel has an elliptical top surface shape.

The pixels 178 illustrated in FIGS. 14D to 14F employ matrix layout.

FIG. 14D illustrates an example where each subpixel has a square top surface shape. FIG. 14E illustrates an example where each subpixel has a substantially square top surface shape with rounded corners. FIG. 14F illustrates an example where each subpixel has a circular top surface shape.

FIGS. 14G and 14H each illustrate an example where one pixel 178 is composed of two rows and three columns.

The pixel 178 illustrated in FIG. 14G includes three subpixels (the subpixels 110R, 110G, and 110B) in the upper row (first row) and one subpixel (a subpixel 110W) in the lower row (second row). In other words, the pixel 178 includes the subpixel 110R in the left column (first column), the subpixel 110G in the middle column (second column), the subpixel 110B in the right column (third column), and the subpixel 110W across these three columns.

The pixel 178 illustrated in FIG. 14H includes three subpixels (the subpixels 110R, 110G, and 110B) in the upper row (first row) and three of the subpixels 110W in the lower row (second row). In other words, the pixel 178 includes the subpixels 110R and 110W in the left column (first column), the subpixels 110G and 110W in the middle column (second column), and the subpixels 110B and 110W in the right column (third column). Matching the positions of the subpixels in the upper row and the lower row as illustrated in FIG. 14H enables dust that would be produced in the fabrication process, for example, to be removed efficiently. Thus, a light-emitting apparatus having high display quality can be provided.

In the pixel 178 illustrated in FIGS. 14G and 14H, the subpixels 110R, 110G, and 110B are arranged in a stripe layout, whereby the display quality can be improved.

FIG. 14I illustrates an example where one pixel 178 is composed of three rows and two columns.

The pixel 178 illustrated in FIG. 14I includes the subpixel 110R in the upper row (first row), the subpixel 110G in the middle row (second row), the subpixel 110B across the first row and the second row, and one subpixel (the subpixel 110W) in the lower row (third row). In other words, the pixel 178 includes the subpixels 110R and 110G in the left column (first column), the subpixel 110B in the right column (second column), and the subpixel 110W across these two columns.

In the pixel 178 illustrated in FIG. 14I, the subpixels 110R, 110G, and 110B are arranged in what is called an S-stripe layout, whereby the display quality can be improved.

The pixel 178 illustrated in each of FIGS. 14A to 14I is composed of four subpixels, which are the subpixels 110R, 110G, 110B, and 110W. For example, the subpixel 110R can be a subpixel that emits red light, the subpixel 110G can be a subpixel that emits green light, the subpixel 110B can be a subpixel that emits blue light, and the subpixel 110W can be a subpixel that emits white light. Note that at least one of the subpixels 110R, 110G, 110B, and 110W may be a subpixel that emits cyan light, magenta light, yellow light, or near-infrared light.

As described above, the pixel composed of the subpixels each including the light-emitting device can employ any of a variety of layouts in the light-emitting apparatus of one embodiment of the present invention.

This embodiment can be combined as appropriate with any of the other embodiments and examples. In this specification, in the case where a plurality of structure examples are shown in one embodiment, the structure examples can be combined as appropriate.

### Embodiment 5

In this embodiment, a light-emitting apparatus of one embodiment of the present invention will be described.

The light-emitting apparatus in this embodiment can be a high-definition light-emitting apparatus. Thus, the light-emitting apparatus in this embodiment can be used for display portions of information terminals (wearable devices) such as watch-type and bracelet-type information terminals and display portions of wearable devices capable of being worn on a head, such as a virtual reality (VR) device like a head mounted display (HMD) and a glasses-type augmented reality (AR) device.

The light-emitting apparatus in this embodiment can be a high-resolution light-emitting apparatus or a large-sized light-emitting apparatus. Accordingly, the light-emitting apparatus in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

### [Display Module]

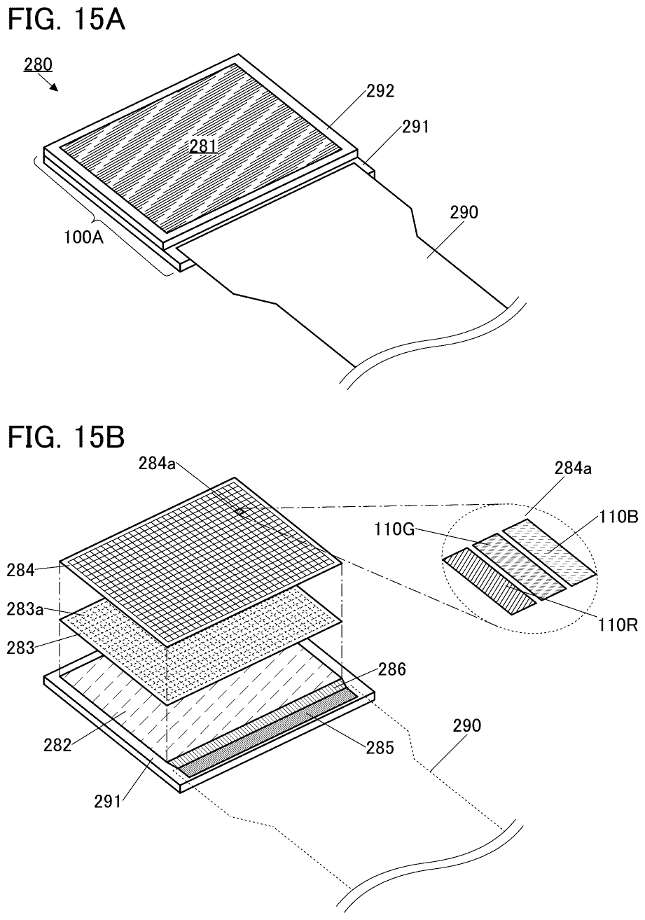

FIG. 15A is a perspective view of a display module 280. The display module 280 includes a light-emitting apparatus 100A and an FPC 290. Note that the light-emitting apparatus included in the display module 280 is not limited to the light-emitting apparatus 100A and may be any of light-emitting apparatuses 100B to 100F described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 15B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 15B. The pixels 284a can employ any of the structures described in the above embodiments. FIG. 15B illustrates an example where the pixel 284a has a structure similar to that of the pixel 178 illustrated in FIGS. 5A and 5B.

The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each of which controls light emission of one light-emitting device. For example, the pixel circuit 283a can include at least one selection transistor, one current control transistor (driving transistor), and a capacitor per light-emitting device. A gate signal is input to a gate of the selection transistor, and a video signal is input to a source or a drain of the selection transistor. With such a structure, an active-matrix light-emitting apparatus is obtained.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have significantly high definition. For example, the pixels 284a are preferably arranged in the display portion 281 with a pixel density higher than or equal to 2000 ppi, further preferably higher than or equal to 3000 ppi, still further preferably higher than or equal to 5000 ppi, yet still further preferably higher than or equal to 6000 ppi, and lower than or equal to 20000 ppi or lower than or equal to 30000 ppi.

Such a display module 280 has extremely high definition, and thus can be suitably used for a VR device such as an HMD or a glasses-type AR device. For example, even in the case of a structure in which the display portion of the display module 280 is seen through a lens, pixels of the extremely-high-definition display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion. For example, the display module 280 can be favorably used in a display portion of a wearable electronic appliance, such as a wrist watch.

### [Light-Emitting Apparatus 100A]

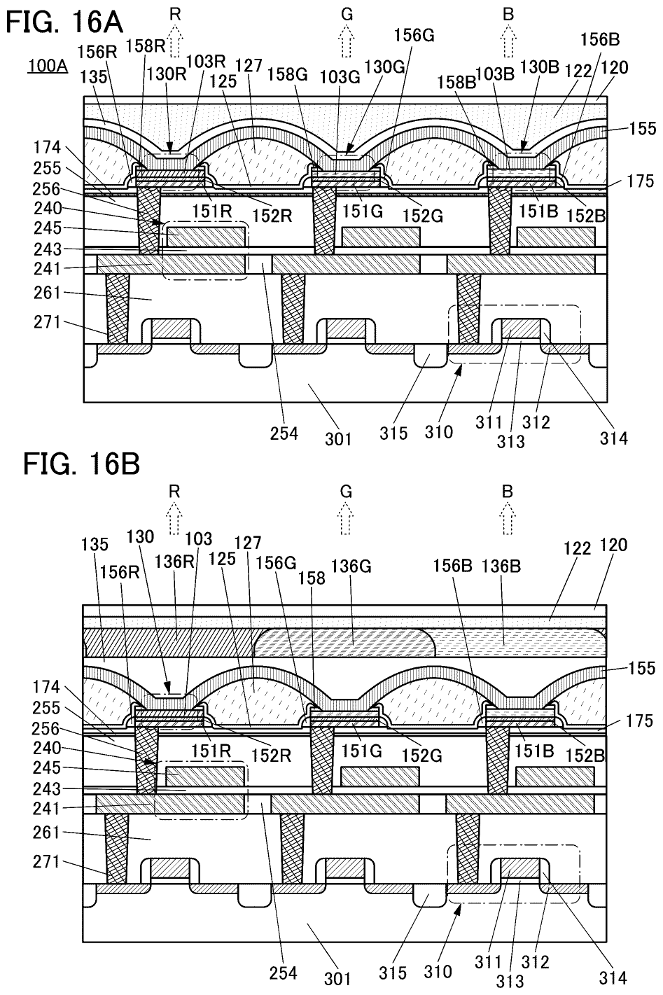

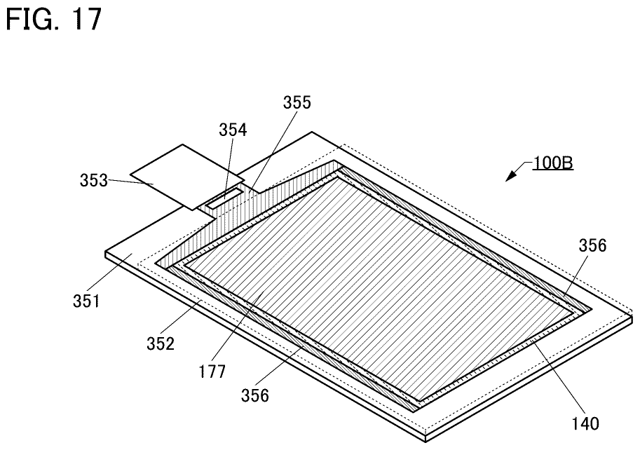

The light-emitting apparatus 100A illustrated in FIG. 16A includes a substrate 301, the light-emitting devices 130R, 130G, and 130B, a capacitor 240, and a transistor 310.

The substrate 301 corresponds to the substrate 291 in FIGS. 15A and 15B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. FIG. 16A illustrates an example in which the light-emitting devices 130R, 130G, and 130B each have the stacked-layer structure illustrated in FIG. 1A. An insulator is provided in regions between adjacent light-emitting devices. For example, in FIG. 16A, the inorganic insulating layer 125 and the insulating layer 127 over the inorganic insulating layer 125 are provided in those regions.

The insulating layer 156R is provided to cover the side surfaces of the conductive layers 151R and 152R of the light-emitting device 130R. The insulating layer 156G is provided to cover the side surfaces of the conductive layers 151G and 152G of the light-emitting device 130G. The insulating layer 156B is provided to cover the side surfaces of the conductive layers 151B and 152B of the light-emitting device 130B. The sacrificial layer 158R is positioned over the organic compound layer 103R of the light-emitting device 130R. The sacrificial layer 158G is positioned over the organic compound layer 103G of the light-emitting device 130G. The sacrificial layer 158B is positioned over the organic compound layer 103B of the light-emitting device 130B.

The conductive layers 151R, 151G, and 151B is electrically connected to the sources or the drains of the corresponding transistors 310 through plugs 256 embedded in the insulating layers 243, 255, 174, and 175, the conductive layers 241 embedded in the insulating layer 254, and the plugs 271 embedded in the insulating layer 261. The top surface of the insulating layer 175 and the top surface of the plug 256 are level with or substantially level with each other. Any of a variety of conductive materials can be used for the plugs.

The protective layer 135 is provided over the light-emitting devices 130R, 130G, and 130B. The substrate 120 is bonded to the protective layer 135 with the resin layer 122. Embodiment 3 can be referred to for the details of the light-emitting device 130 and the components thereover up to the substrate 120. The substrate 120 corresponds to the substrate 292 in FIG. 15A.

FIG. 16B illustrates a modification example of the light-emitting apparatus 100A illustrated in FIG. 16A. The light-emitting apparatus illustrated in FIG. 16B includes the coloring layers 136R, 136G, and 136B, and each of the light-emitting devices 130 includes a region overlapping with one of the coloring layers 136R, 136G, and 136B. In the light-emitting apparatus illustrated in FIG. 16B, the light-emitting device 130 can emit white light, for example. For example, the coloring layer 136R, the coloring layer 136G, and the coloring layer 136B can transmit red light, green light, and blue light, respectively.

### [Light-Emitting Apparatus 100B]

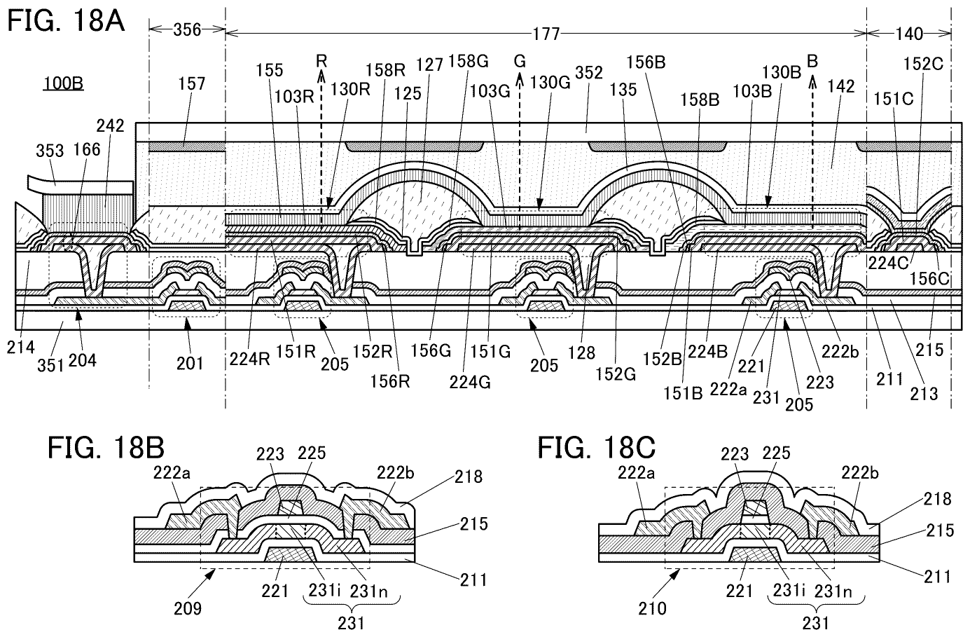

FIG. 17 is a perspective view of the light-emitting apparatus 100B, and FIG. 18A is a cross-sectional view of the light-emitting apparatus 100B.

In the light-emitting apparatus 100B, a substrate 352 and a substrate 351 are bonded to each other. In FIG. 17, the substrate 352 is denoted by a dashed line.

The light-emitting apparatus 100B includes the pixel portion 177, the connection portion 140, a circuit 356, a wiring 355, and the like. FIG. 17 illustrates an example in which an integrated circuit (IC) 354 and an FPC 353 are mounted on the light-emitting apparatus 100B. Thus, the structure illustrated in FIG. 17 can be regarded as a display module including the light-emitting apparatus 100B, the IC, and the FPC. Here, a light-emitting apparatus in which a substrate is equipped with a connector such as an FPC or mounted with an IC is referred to as a display module.

The connection portion 140 is provided outside the pixel portion 177. The connection portion 140 can be provided along one side or a plurality of sides of the pixel portion 177. The number of connection portions 140 may be one or more. FIG. 17 illustrates an example in which the connection portion 140 is provided to surround the four sides of the pixel portion 177. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 17 illustrates an example in which the IC 354 is provided for the substrate 351 by a chip on glass (COG) method, a chip on film (COF) method, or the like. An IC including a scan line driver circuit, a signal line driver circuit, or the like can be used as the IC 354, for example. Note that the light-emitting apparatus 100B and the display module are not necessarily provided with an IC. Alternatively, the IC may be mounted on the FPC by a COF method, for example.

FIG. 18A illustrates an example of cross sections of part of a region including the FPC 353, part of the circuit 356, part of the pixel portion 177, part of the connection portion 140, and part of a region including an edge portion of the light-emitting apparatus 100B.

The light-emitting apparatus 100B illustrated in FIG. 18A includes a transistor 201, a transistor 205, the light-emitting device 130R that emits red light, the light-emitting device 130G that emits green light, the light-emitting device 130B that emits blue light, and the like between the substrate 351 and the substrate 352.

The stacked-layer structure of each of the light-emitting devices 130R, 130G, and 130B is the same as that illustrated in FIG. 1A except for the structure of the pixel electrode. The above embodiments can be referred to for the details of the light-emitting devices.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B. Here, the conductive layers 224R, 151R, and 152R can be collectively referred to as the pixel electrode of the light-emitting device 130R; the conductive layers 151R and 152R excluding the conductive layer 224R can also be referred to as the pixel electrode of the light-emitting device 130R. Similarly, the conductive layers 224G, 151G, and 152G can be collectively referred to as the pixel electrode of the light-emitting device 130G; the conductive layers 151G and 152G excluding the conductive layer 224G can also be referred to as the pixel electrode of the light-emitting device 130G. The conductive layers 224B, 151B, and 152B can be collectively referred to as the pixel electrode of the light-emitting device 130B; the conductive layers 151B and 152B excluding the conductive layer 224B can also be referred to as the pixel electrode of the light-emitting device 130B.

The conductive layer 224R is connected to a conductive layer 222b included in the transistor 205 through the opening provided in an insulating layer 214. The edge portion of the conductive layer 151R is positioned outward from an edge portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depression portion covering an opening provided in the insulating layer 214. A layer 128 is embedded in the depression portion.

The layer 128 has a function of filling the depression portions of the conductive layers 224R, 224G, and 224B to enable planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depression portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 135 is provided over the light-emitting devices 130R, 130G, and 130B. The protective layer 135 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 18A, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Alternatively, the space may be filled with a resin other than the frame-shaped adhesive layer 142.

FIG. 18A illustrates an example in which the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 18A, the insulating layer 156C is provided to include a region overlapping with the side surface of the conductive layer 151C.

The light-emitting apparatus 100B has a top-emission structure. Light from the light-emitting device is emitted toward the substrate 352. For the substrate 352, a material having a high visible-light-transmitting property is preferably used. The pixel electrode contains a material that reflects visible light, and the counter electrode (the common electrode 155) contains a material that transmits visible light.

The transistor 201 and the transistor 205 are formed over the substrate 351. These transistors can be fabricated using the same materials in the same steps.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers covering the transistors. This is because such an insulating layer can function as a barrier layer. Such a structure can effectively reduce diffusion of impurities to the transistors from the outside and increase the reliability of the light-emitting apparatus.

An inorganic insulating film is preferably used as each of the insulating layers 211, 213, and 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. Two or more of the above insulating films may also be stacked.

An organic insulating layer is suitable for the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably functions as an etching protective layer. This can inhibit formation of a depressed portion in the insulating layer 214 at the time of processing of the conductive layer 224R, 151R, or 152R or the like. Alternatively, a depressed portion may be provided in the insulating layer 214 at the time of processing of the conductive layer 224R, 151R, or 152R or the like.

Each of the transistors 201 and 205 includes a conductive layer 221 functioning as a gate, the insulating layer 211 functioning as a gate insulating layer, a conductive layer 222a and a conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the light-emitting apparatus of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is employed for each of the transistors 201 and 205. The two gates may be connected to each other and supplied with the same signal to drive the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. A semiconductor having crystallinity is preferably used, in which case deterioration of transistor characteristics can be suppressed.

The semiconductor layer of the transistor preferably includes a metal oxide. That is, a transistor including a metal oxide in its channel formation region (hereinafter, also referred to as an OS transistor) is preferably used in the light-emitting apparatus of this embodiment.

Examples of an oxide semiconductor having crystallinity include a c-axis-aligned crystalline oxide semiconductor (CAAC-OS) and a nanocrystalline oxide semiconductor (nc-OS).

Alternatively, a transistor including silicon in its channel formation region (a Si transistor) may be used. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and excellent frequency characteristics.

With the use of Si transistors such as LTPS transistors, a circuit required to be driven at a high frequency (e.g., a source driver circuit) can be formed on the same substrate as the display portion. This allows for simplification of an external circuit mounted on the light-emitting apparatus and a reduction in costs of parts and mounting costs.

An OS transistor has much higher field-effect mobility than a transistor including amorphous silicon. In addition, the OS transistor has an extremely low leakage current between a source and a drain in an off state (hereinafter also referred to as an off-state current), and electric charge accumulated in a capacitor that is connected in series to the transistor can be held for a long period. Furthermore, the light-emitting apparatus can consume less power by including the OS transistor.

To increase the luminance of the light-emitting device included in the pixel circuit, the amount of current fed through the light-emitting device needs to be increased. To increase the current amount, the source-drain voltage of a driving transistor included in the pixel circuit needs to be increased. An OS transistor has a higher breakdown voltage between a source and a drain than a Si transistor; hence, a high voltage can be applied between the source and the drain of the OS transistor. Therefore, when an OS transistor is used as the driving transistor in the pixel circuit, the amount of current flowing through the light-emitting device can be increased, so that the luminance of the light-emitting device can be increased.

Regarding saturation characteristics of a current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor operates in the saturation region, the source-drain current hardly changes with an increase in the source-drain voltage; hence, the luminance of the light-emitting device can be stable.

As described above, by using OS transistors as the driving transistors included in the pixel circuits, it is possible to suppress black-level degradation, increase the luminance, increase the number of gray levels, and suppress variations in light-emitting devices, for example.

The semiconductor layer preferably contains indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

It is particularly preferable that an oxide containing indium (In), gallium (Ga), and zinc (Zn) (also referred to as IGZO) be used for the semiconductor layer. It is preferable to use an oxide containing indium, tin, and zinc. It is preferable to use an oxide containing indium, gallium, tin, and zinc. It is preferable to use an oxide containing indium (In), aluminum (Al), and zinc (Zn) (also referred to as IAZO). It is preferable to use an oxide containing indium (In), aluminum (Al), gallium (Ga), and zinc (Zn) (also referred to as IAGZO).

When the semiconductor layer is an In-M-Zn oxide, the atomic proportion of In is preferably higher than or equal to the atomic proportion of M in the In-M-Zn oxide. Examples of the atomic ratio of the metal elements in such an In-M-Zn oxide are In:M:Zn=1:1:1, 1:1:1.2, 2:1:3, 3:1:2, 4:2:3, 4:2:4.1, 5:1:3, 5:1:6, 5:1:7, 5:1:8, 6:1:6, and 5:2:5 and a composition in the neighborhood of any of the above atomic ratios. Note that the neighborhood of the atomic ratio includes ±30% of an intended atomic ratio.

For example, in the case of describing an atomic ratio of In:Ga:Zn=4:2:3 or a composition in the neighborhood thereof, the case is included in which with the atomic proportion of In being 4, the atomic proportion of Ga is greater than or equal to 1 and less than or equal to 3 and the atomic proportion of Zn is greater than or equal to 2 and less than or equal to 4. In the case of describing an atomic ratio of In:Ga:Zn=5:1:6 or a composition in the neighborhood thereof, the case is included in which with the atomic proportion of In being 5, the atomic proportion of Ga is greater than 0.1 and less than or equal to 2 and the atomic proportion of Zn is greater than or equal to 5 and less than or equal to 7. In the case of describing an atomic ratio of In:Ga:Zn=1:1:1 or a composition in the neighborhood thereof, the case is included in which with the atomic proportion of In being 1, the atomic proportion of Ga is greater than 0.1 and less than or equal to 2 and the atomic proportion of Zn is greater than 0.1 and less than or equal to 2.

The transistors included in the circuit 356 and the transistors included in the pixel portion 177 may have the same structure or different structures. One structure or two or more kinds of structures may be employed for a plurality of transistors included in the circuit 356. Similarly, one structure or two or more kinds of structures may be employed for a plurality of transistors included in the pixel portion 177.

All transistors included in the pixel portion 177 may be OS transistors, or all transistors included in the pixel portion 177 may be Si transistors. Alternatively, some of the transistors included in the pixel portion 177 may be OS transistors and the others may be Si transistors.

For example, when both an LTPS transistor and an OS transistor are used in the pixel portion 177, the light-emitting apparatus can have low power consumption and high driving capability. Note that a structure in which an LTPS transistor and an OS transistor are used in combination is referred to as LTPO in some cases. For example, it is preferable that an OS transistor be used as a transistor functioning as a switch for controlling electrical continuity between wirings and an LTPS transistor be used as a transistor for controlling a current.

For example, one transistor included in the pixel portion 177 functions as a transistor for controlling a current flowing through the light-emitting device and can be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased in the pixel circuit.

Another transistor included in the pixel portion 177 functions as a switch for controlling selection or non-selection of a pixel and can be referred to as a selection transistor. A gate of the selection transistor is electrically connected to a gate line, and one of a source and a drain thereof is electrically connected to a source line (signal line). An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

As described above, the light-emitting apparatus of one embodiment of the present invention can have all of a high aperture ratio, high definition, high display quality, and low power consumption.

Note that the light-emitting apparatus of one embodiment of the present invention has a structure including the OS transistor and the light-emitting device having a metal maskless (MML) structure. This structure can significantly reduce a leakage current that would flow through a transistor and a leakage current that would flow between adjacent light-emitting devices (sometimes referred to as a horizontal leakage current or a lateral leakage current). Displaying images on the light-emitting apparatus having this structure can bring one or more of image crispness, image sharpness, high color saturation, and a high contrast ratio to the viewer. When a leakage current that would flow through the transistor and a lateral leakage current that would flow between the light-emitting devices are extremely low, leakage of light at the time of black display (black-level degradation) or the like can be minimized.

In particular, in the case where a light-emitting device having an MML structure employs a side-by-side (SBS) structure, which is the above-described structure for separately forming or coloring light-emitting layers, a layer provided between light-emitting devices (for example, also referred to as an organic layer or a common layer which is shared by the light-emitting devices) is disconnected; accordingly, side leakage can be prevented or be made extremely low.

FIGS. 18B and 18C illustrate other structure examples of transistors.

Transistors 209 and 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 18B illustrates an example of the transistor 209 in which the insulating layer 225 covers the top and side surfaces of the semiconductor layer 231. The conductive layer 222a and the conductive layer 222b are connected to the corresponding low-resistance regions 231n through openings provided in the insulating layer 225 and the insulating layer 215. One of the conductive layers 222a and 222b functions as a source, and the other functions as a drain.

In the transistor 210 illustrated in FIG. 18C, the insulating layer 225 overlaps with the channel formation region 231i of the semiconductor layer 231 and does not overlap with the low-resistance regions 231n. The structure illustrated in FIG. 18C can be obtained by processing the insulating layer 225 with the conductive layer 223 used as a mask, for example. In FIG. 18C, the insulating layer 215 is provided to cover the insulating layer 225 and the conductive layer 223, and the conductive layer 222a and the conductive layer 222b are connected to the corresponding low-resistance regions 231n through openings in the insulating layer 215.

A connection portion 204 is provided in a region of the substrate 351 where the substrate 352 does not overlap. In the connection portion 204, the wiring 355 is electrically connected to the FPC 353 through a conductive layer 166 and a connection layer 242. An example is described in which the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Light-Emitting Apparatus 100C]

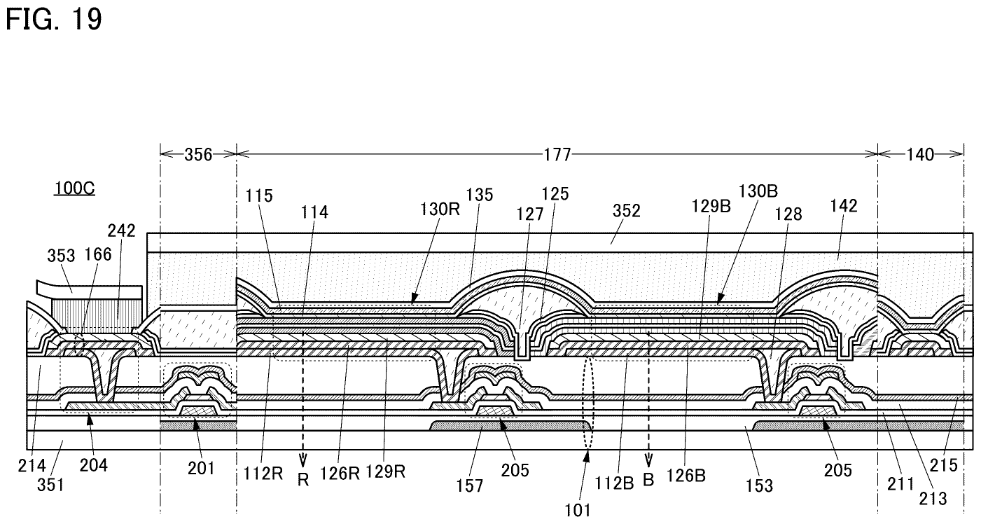

A light-emitting apparatus 100C illustrated in FIG. 19 differs from the light-emitting apparatus 100B illustrated in FIG. 18A mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

The light-blocking layer 157 is preferably formed between the substrate 351 and the transistor 201 and between the substrate 351 and the transistor 205. FIG. 19 illustrates an example in which the light-blocking layer 157 is provided over the substrate 351, an insulating layer 153 is provided over the light-blocking layer 157, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the common electrode 155.

Although not illustrated in FIG. 19, the light-emitting device 130G is also provided.

Although FIG. 19 and the like illustrate an example in which the top surface of the layer 128 includes a flat portion, the shape of the layer 128 is not particularly limited.

### [Light-Emitting Apparatus 100D]

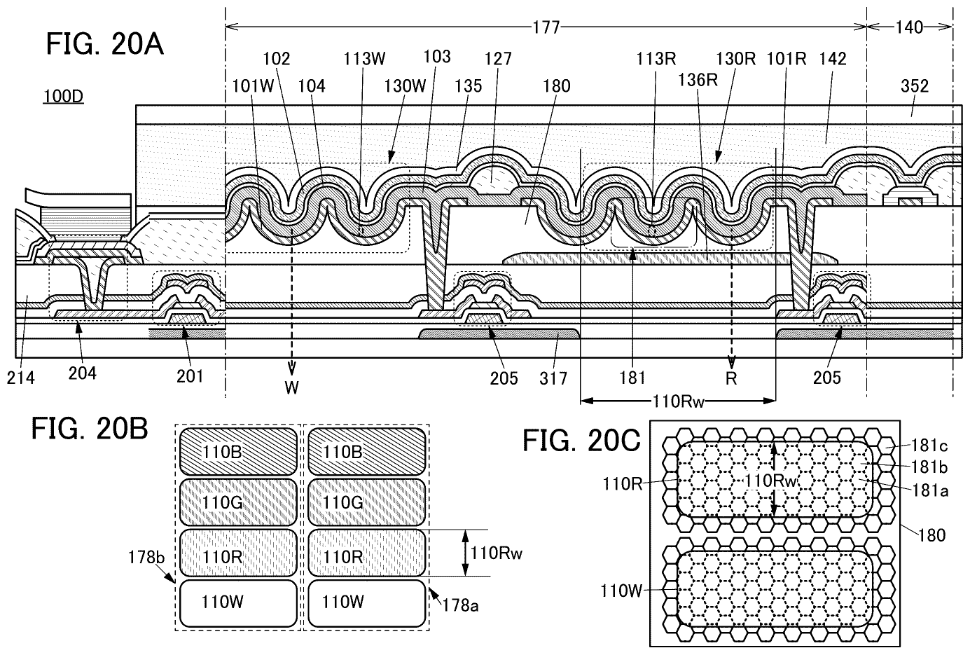

The light-emitting apparatus 100D with a bottom-emission structure illustrated in FIGS. 20A to 20C is an example of a bottom-emission light-emitting apparatus different from the light-emitting apparatus 100C illustrated in FIG. 19. The light-emitting apparatus 100D is different from the light-emitting apparatus 100C in including an organic resin layer 180. Note that in the drawings, reference numerals of some of the components that are shown in FIGS. 16A and 16B are omitted; for the details of the components, the description made with reference to FIGS. 16A and 16B is to be referred to.

FIG. 20B shows a top-view layout of the pixels 178 (a pixel 178a and a pixel 178b) each including the subpixels 110 (the subpixels 110R, 110G, 110B, and 110W), and FIG. 20C shows a top view of the organic resin layer 180 in a region where the subpixels 110R and 110W of the pixel 178 are formed. Note that the width between a light-blocking layer 317 and another light-blocking layer 317 corresponds to a width 110Rw in the light-emitting region of the subpixel 110R.

As illustrated in FIG. 20A, the organic resin layer 180 is provided over the insulating layer 214. As shown in FIG. 20C and the region surrounded by the dashed-dotted line in FIG. 20A, the organic resin layer 180 includes a depressed portion 181 (depressed portions 181a and 181b) having a curved surface at least in a region where the subpixel is formed. Note that the depressed portion 181 may also be provided outside the light-emitting region, like a depressed portion 181c. When the depressed portion 181c is provided, light that has been emitted in the region overlapping with the light-blocking layer 317 or light that has progressed to the region overlapping with the light-blocking layer 317 can be refracted and extracted from the light-emitting region, increasing the emission efficiency.

A plurality of the depressed portions 181 may be formed in a matrix. The depressed portions 181a and 181b may be provided in contact with each other or may have a flat surface therebetween.

In FIGS. 20A to 20C, although the top surface shape and the cross-sectional shape of the depressed portion are hexagonal (FIG. 20C) and semicircular (FIG. 20A), respectively, other shapes may be employed as needed. Examples of a top surface shape of the depressed portion include polygons such as a triangle, a tetragon (including a rectangle and a square), and a pentagon; these polygons with rounded corners; an ellipse; and a circle.

As the organic resin layer 180, an insulating layer including an organic material can be used. For the organic resin layer 180, an acrylic resin, a polyimide resin, an epoxy resin, an imide resin, a polyamide resin, a polyimide-amide resin, a silicone resin, a siloxane resin, a benzocyclobutene-based resin, a phenol resin, or a precursor of any of these resins can be used, for example. Alternatively, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used for the organic resin layer 180.

Further alternatively, a photosensitive resin can be used for the organic resin layer 180. A photoresist may be used as the photosensitive resin. As the photosensitive resin, a positive photosensitive material or a negative photosensitive material can be used.

The organic resin layer 180 may contain a material absorbing visible light. For example, the organic resin layer 180 itself may be made of a material absorbing visible light, or the organic resin layer 180 may contain a pigment absorbing visible light. For the organic resin layer 180, for example, a resin that can be used as a color filter transmitting red, blue, or green light and absorbing light of the other colors or a resin that contains carbon black as a pigment and functions as a black matrix can be used.

The first electrodes 101 (a first electrode 101R and a first electrode 101W) are provided over the organic resin layer 180, and the organic compound layer 103 is provided over the first electrodes 101.

Along the depressed portion of the organic resin layer 180, the first electrode 101 formed over the organic resin layer 180 has a depressed portion in a manner similar to that of the organic resin layer 180. Furthermore, along the depressed portion of the first electrode 101, the organic compound layer 103 formed over the first electrode 101 has a depressed portion in a manner similar to that of the first electrode 101. Furthermore, along the depressed portion of the organic compound layer 103, the common layer 104 formed over the organic compound layer 103 has a depressed portion in a manner similar to that of the organic compound layer 103. Furthermore, along the depressed portion of the common layer 104, the second electrode 102 formed over the common layer 104 has a depressed portion in a manner similar to that of the common layer 104. That is, the depressed portions of the organic resin layer 180, the first electrode 101, the organic compound layer 103, the common layer 104, and the second electrode 102 overlap with each other.

The common layer 104 is provided over the organic compound layer 103 and the insulating layer 127, and the second electrode 102 is provided over the common layer 104. The protective layer 135 is provided over the second electrode 102, and the substrate 352 is bonded with the use of the adhesive layer 142.

Although the light-emitting devices 130G and 130B are not illustrated in FIGS. 20A to 20C, the light-emitting devices 130G and 130B are also provided.

### [Light-Emitting Apparatus 100E]

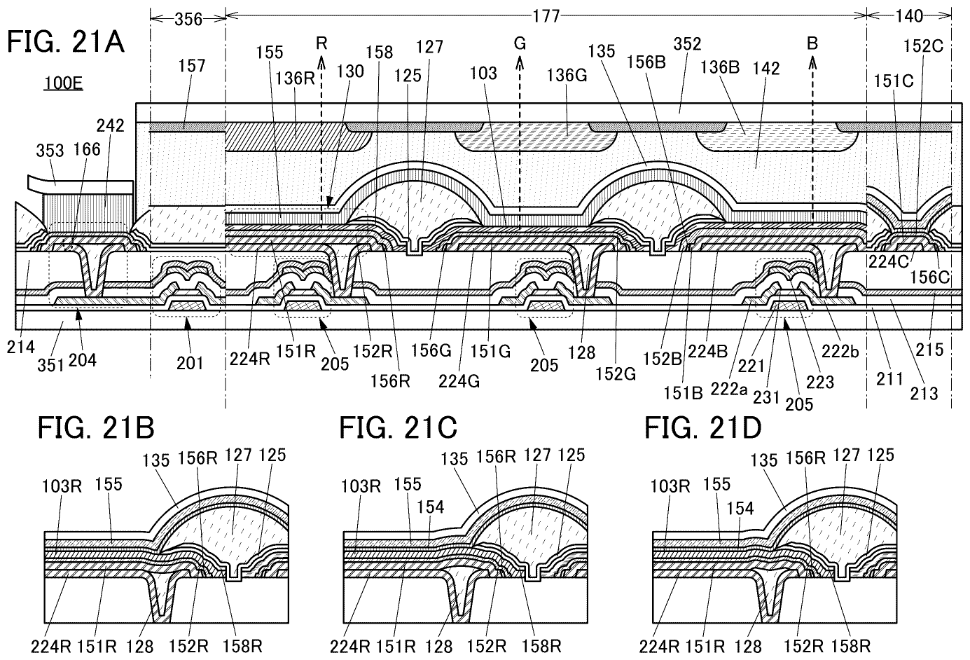

The light-emitting apparatus 100E illustrated in FIG. 21A is a modification example of the top-emission light-emitting apparatus 100B illustrated in FIG. 18A and differs from the light-emitting apparatus 100B mainly in including the coloring layers 136R, 136G, and 136B.

In the light-emitting apparatus 100E, the light-emitting device 130 includes a region overlapping with one of the coloring layers 136R, 136G, and 136B. The coloring layers 136R, 136G, and 136B can be provided on the surface of the substrate 352 on the substrate 351 side. End portions of the coloring layers 136R, 136G, and 136B can overlap with the light-blocking layer 157.

In the light-emitting apparatus 100E, the light-emitting device 130 can emit white light, for example. For example, the coloring layer 136R, the coloring layer 136G, and the coloring layer 136B can transmit red light, green light, and blue light, respectively. Note that in the light-emitting apparatus 100E, the coloring layers 136R, 136G, and 136B may be provided between the protective layer 135 and the adhesive layer 142.

Although FIG. 18A, FIG. 21A, and the like each illustrate an example in which the top surface of the layer 128 includes a flat portion, the shape of the layer 128 is not particularly limited. FIGS. 21B to 21D illustrate modification examples of the layer 128.

As illustrated in FIGS. 21B and 21D, the top surface of the layer 128 can have a shape such that its middle and the vicinity thereof are depressed (i.e., a shape including a concave surface) in the cross section. A common layer 154 may be provided so as to be in contact with the common electrode 155.

As illustrated in FIG. 21C, the top surface of the layer 128 can have a shape in which its center and the vicinity thereof bulge, i.e., a shape including a convex surface, in a cross-sectional view.

The top surface of the layer 128 may include one or both of a convex surface and a concave surface. The number of convex surfaces and the number of concave surfaces included in the top surface of the layer 128 are not limited and can each be one or two or more.

The level of the top surface of the layer 128 and the level of the top surface of the conductive layer 224R may be the same or substantially the same, or may be different from each other. For example, the level of the top surface of the layer 128 may be lower or higher than the level of the top surface of the conductive layer 224R.

In the example illustrated in FIG. 21B, it can be said that the layer 128 fits inside the depression portion of the conductive layer 224R. By contrast, as illustrated in FIG. 21D, the layer 128 is also present outside the depression portion of the conductive layer 224R, i.e., the top surface of the layer 128 may extend beyond the depression portion.

### [Light-Emitting Apparatus 100F]

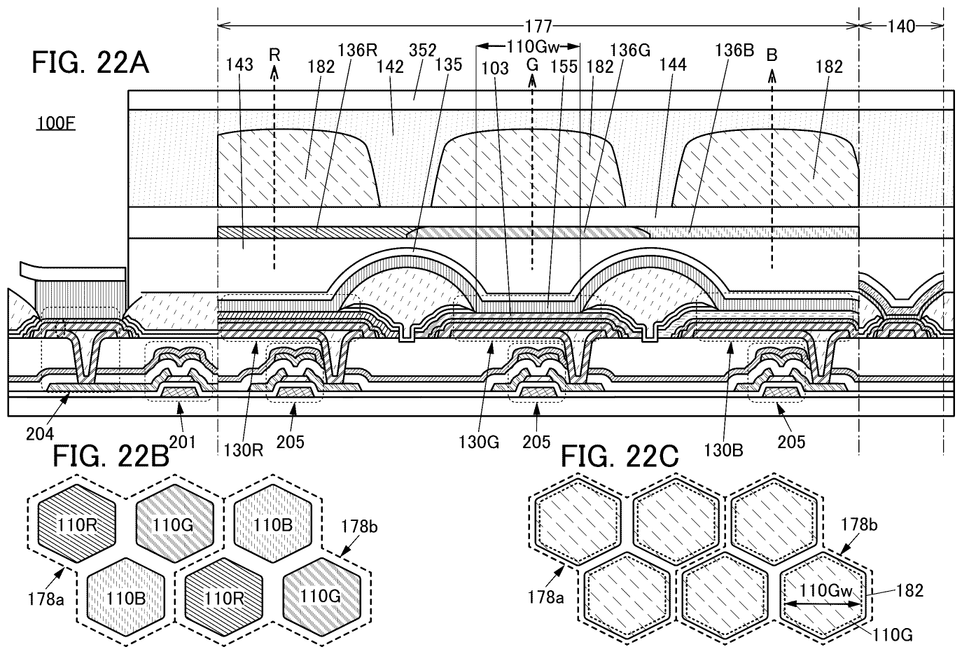

The light-emitting apparatus 100F illustrated in FIGS. 22A to 22C is a modification example of the top-emission light-emitting apparatus 100B illustrated in FIGS. 18A to 18C and includes microlenses 182 over the coloring layers 136R, 136G, and 136B. Note that in the drawings, reference numerals of some of the components that are shown in FIGS. 18A to 18D are omitted; for the details of the components, the description made with reference to FIGS. 18A to 18D is to be referred to.

FIG. 22B is a top-view layout of the pixel 178 (the pixels 178a and 178b) including the subpixel 110 (the subpixels 110R, 110G, and 110B), and FIG. 22C is a top view of the microlens 182 in a region where the subpixels 110R, 110G, and 110B included in the pixel 178 are formed. Note that the width of the region where the common electrode 155 and the organic compound layer 103 are in contact with each other corresponds to a width 110Gw in the light-emitting region of the subpixel 110G.

In the light-emitting apparatus 100F illustrated in FIG. 22A, a planarization film 143 is provided over the protective layer 135, and the coloring layers 136R, 136G, and 136B are provided over the planarization film 143. A planarization film 144 is provided to cover the coloring layers 136R, 136G, and 136B. The microlenses 182 are provided over the planarization film 144.

Note that as illustrated in FIG. 22C, the microlenses 182 are preferably provided on a subpixel basis in the region where the subpixels are formed.

Although the top surface shape of the microlens 182 is hexagonal in FIG. 22C, a different shape may be employed as needed. Examples of a top surface shape of the microlens 182 include polygons such as a triangle, a tetragon (including a rectangle and a square), and a pentagon; these polygons with rounded corners; an ellipse; and a circle.

The microlenses 182 can be formed using a material similar to that of the organic resin layer 180.

This embodiment can be combined as appropriate with the other embodiments or examples. In this specification, in the case where a plurality of structure examples are shown in one embodiment, the structure examples can be combined as appropriate.

### Embodiment 6

In this embodiment, electronic appliances of embodiments of the present invention will be described.

Electronic appliances of this embodiment include the light-emitting apparatus of one embodiment of the present invention in their display portions. The light-emitting apparatus of one embodiment of the present invention is highly reliable and can be easily increased in definition and resolution. Thus, the light-emitting apparatus of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the light-emitting apparatus of one embodiment of the present invention can have high definition, and thus can be favorably used for an electronic appliance having a relatively small display portion. Examples of such an electronic appliance include watch-type and bracelet-type information terminal devices (wearable devices) and wearable devices capable of being worn on a head, such as a VR device like a head-mounted display, a glasses-type AR device, and an MR device.

The resolution of the light-emitting apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, 4K resolution, 8K resolution, or higher resolution is preferable. The pixel density (definition) of the light-emitting apparatus of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With such a light-emitting apparatus having one or both of high resolution and high definition, the electronic appliance can provide higher realistic sensation, sense of depth, and the like in personal use such as portable use or home use. There is no particular limitation on the screen ratio (aspect ratio) of the light-emitting apparatus of one embodiment of the present invention. For example, the light-emitting apparatus is compatible with a variety of screen ratios such as 1:1 (a square), 4:3, 16:9, and 16:10.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic appliance in this embodiment can have a variety of functions. For example, the electronic appliance in this embodiment can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

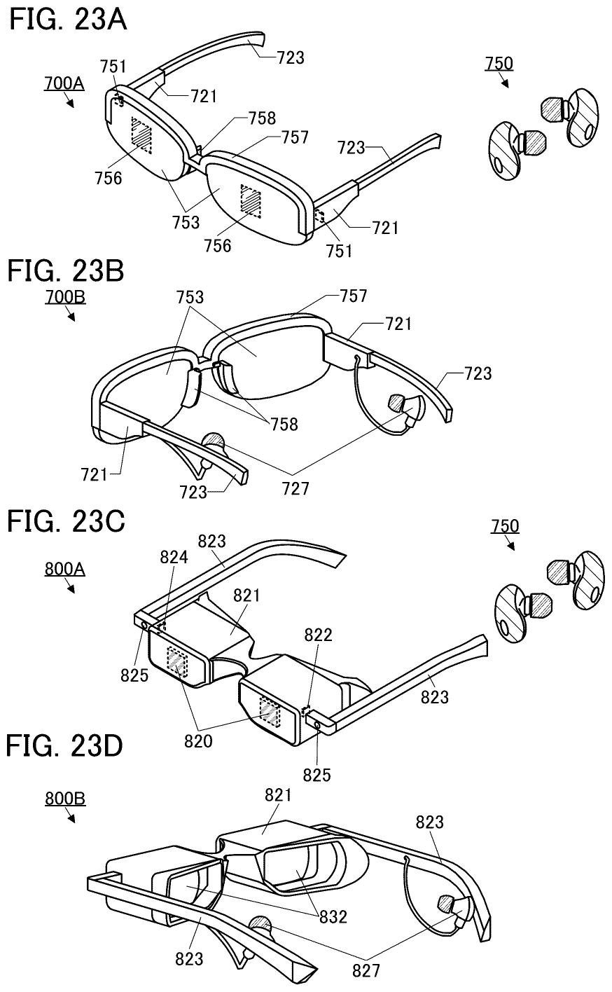

Examples of head-mounted wearable devices are described with reference to FIGS. 23A to 23D. These wearable devices have at least one of a function of displaying AR contents, a function of displaying VR contents, a function of displaying SR contents, and a function of displaying MR contents. The electronic appliance having a function of displaying contents of at least one of AR, VR, SR, MR, and the like enables the user to feel a higher level of immersion.

An electronic appliance 700A illustrated in FIG. 23A and an electronic appliance 700B illustrated in FIG. 23B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The light-emitting apparatus of one embodiment of the present invention can be used for the display panels 751. Thus, a highly reliable electronic appliance is obtained.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliances 700A and 700B are electronic appliances capable of AR display.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721. The touch sensor module has a function of detecting a touch on the outer surface of the housing 721. Various types of processing can be executed by detecting a tap operation, a slide operation, or the like by the user with the touch sensor module. For example, a moving image can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving element. One or both of an inorganic semiconductor and an organic semiconductor can be used for an active layer of the photoelectric conversion device.

An electronic appliance 800A illustrated in FIG. 23C and an electronic appliance 800B illustrated in FIG. 23D each include a pair of display portions 820, a housing 821, a communication portion 822, a pair of wearing portions 823, a control portion 824, a pair of image capturing portions 825, and a pair of lenses 832.

The light-emitting apparatus of one embodiment of the present invention can be used in the display portions 820. Thus, a highly reliable electronic appliance is obtained.

The display portions 820 are positioned inside the housing 821 so as to be seen through the lenses 832. When the pair of display portions 820 display different images, three-dimensional display using parallax can be performed.

The electronic appliances 800A and 800B can function as electronic appliances for VR. The user who wears the electronic appliance 800A or the electronic appliance 800B can see images displayed on the display portions 820 through the lenses 832.

The electronic appliances 800A and 800B preferably include a mechanism for adjusting horizontally the positions of the lenses 832 and the display portions 820 so that the lenses 832 and the display portions 820 are positioned optimally in accordance with the positions of the user's eyes. Moreover, the electronic appliances 800A and 800B preferably include a mechanism for adjusting focus by changing the distance between the lenses 832 and the display portions 820.

The electronic appliance 800A or the electronic appliance 800B can be mounted on the user's head with the wearing portions 823. FIG. 23C, for instance, shows an example where the wearing portion 823 has a shape like a temple (also referred to as a joint or the like) of glasses; however, one embodiment of the present invention is not limited thereto. The wearing portion 823 can have any shape with which the user can wear the electronic appliance, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is described here, a range sensor (hereinafter also referred to as a sensing portion) capable of measuring the distance between the user and an object may be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic appliance 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic appliance 800A.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750. The earphones 750 include a communication portion (not illustrated) and has a wireless communication function. The earphones 750 can receive information (e.g., audio data) from the electronic appliance with the wireless communication function. For example, the electronic appliance 700A in FIG. 23A has a function of transmitting information to the earphones 750 with the wireless communication function. For another example, the electronic appliance 800A in FIG. 23C has a function of transmitting information to the earphones 750 with the wireless communication function.

The electronic appliance may include an earphone portion. The electronic appliance 700B in FIG. 23B includes earphone portions 727. For example, the earphone portion 727 can be connected to the control portion by a wiring. Part of the wiring that connects the earphone portion 727 and the control portion may be positioned inside the housing 721 or the wearing portion 723.

Similarly, the electronic appliance 800B in FIG. 23D includes earphone portions 827. For example, the earphone portion 827 can be connected to the control portion 824 by a wiring. Part of the wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of a headset by including the audio input mechanism.

As described above, both the glasses-type device (e.g., the electronic appliances 700A and 700B) and the goggles-type device (e.g., the electronic appliances 800A and 800B) are preferable as the electronic appliance of one embodiment of the present invention.

The electronic appliance of one embodiment of the present invention can transmit information to earphones by wire or wirelessly.

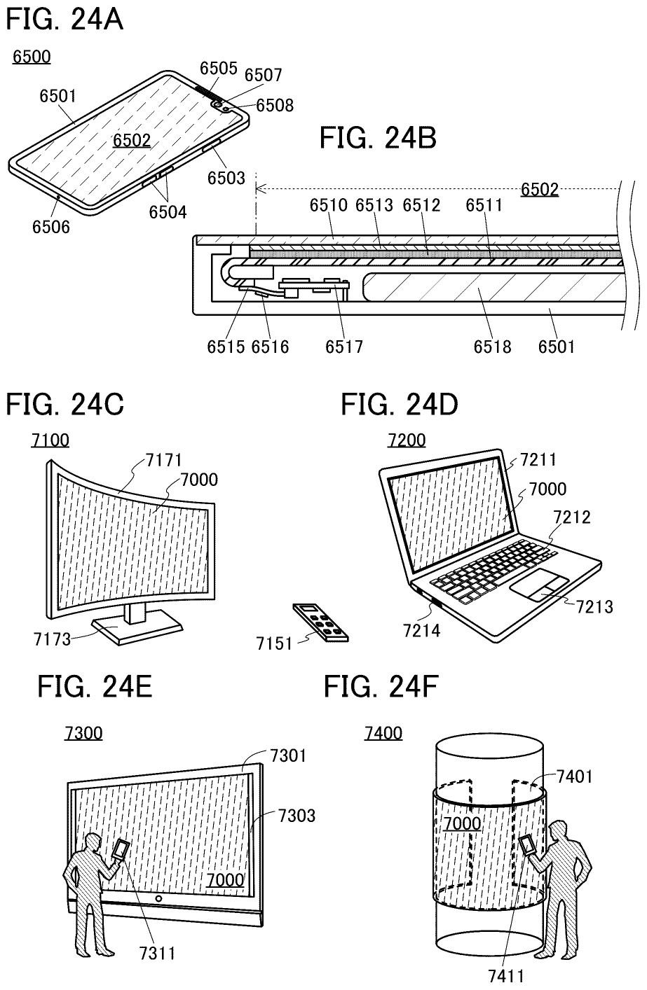

An electronic appliance 6500 illustrated in FIG. 24A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The light-emitting apparatus of one embodiment of the present invention can be used in the display portion 6502. Thus, a highly reliable electronic appliance is obtained.

FIG. 24B is a schematic cross-sectional view including an edge portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The light-emitting apparatus of one embodiment of the present invention can be used in the display panel 6511. Thus, an extremely lightweight electronic appliance can be obtained. Since the display panel 6511 is extremely thin, the battery 6518 with high capacity can be mounted without an increase in the thickness of the electronic appliance. An electronic appliance with a narrow bezel can be provided when part of the display panel 6511 is folded back and the portion connected to the FPC 6515 is provided on the back side of a pixel portion.

FIG. 24C illustrates an example of a television device. In a television device 7100, a display portion 7000 is incorporated in a housing 7171. Here, the housing 7171 is supported by a stand 7173.

The light-emitting apparatus of one embodiment of the present invention can be used in the display portion 7000. Thus, a highly reliable electronic appliance can be provided.

Operation of the television device 7100 illustrated in FIG. 24C can be performed with an operation switch provided in the housing 7171 and a separate remote controller 7151. Alternatively, the display portion 7000 may include a touch sensor, and the television device 7100 may be operated by touch on the display portion 7000 with a finger or the like. The remote controller 7151 may be provided with a display portion for displaying information output from the remote controller 7151. With operation keys or a touch panel of the remote controller 7151, channels and volume can be controlled and video displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 24D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The light-emitting apparatus of one embodiment of the present invention can be used in the display portion 7000. Thus, a highly reliable electronic appliance is obtained.

FIGS. 24E and 24F illustrate examples of digital signage.

Digital signage 7300 illustrated in FIG. 24E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 24F shows digital signage 7400 attached to a cylindrical pillar 7401. The digital signage 7400 includes the display portion 7000 provided along a curved surface of the pillar 7401.

In FIGS. 24E and 24F, the light-emitting apparatus of one embodiment of the present invention can be used in the display portion 7000. Thus, a highly reliable electronic appliance can be provided.

A larger area of the display portion 7000 can increase the amount of information that can be provided at a time. The display portion 7000 having a larger area attracts more attentions, so that the effectiveness of the advertisement can be increased, for example.

The touch panel is preferably used in the display portion 7000, in which case in addition to display of still or moving images on the display portion 7000, intuitive operation by a user is possible. Moreover, in the case of an application for providing information such as route information or traffic information, usability with intuitive operation can be enhanced

As illustrated in FIGS. 24E and 24F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, a displayed image on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

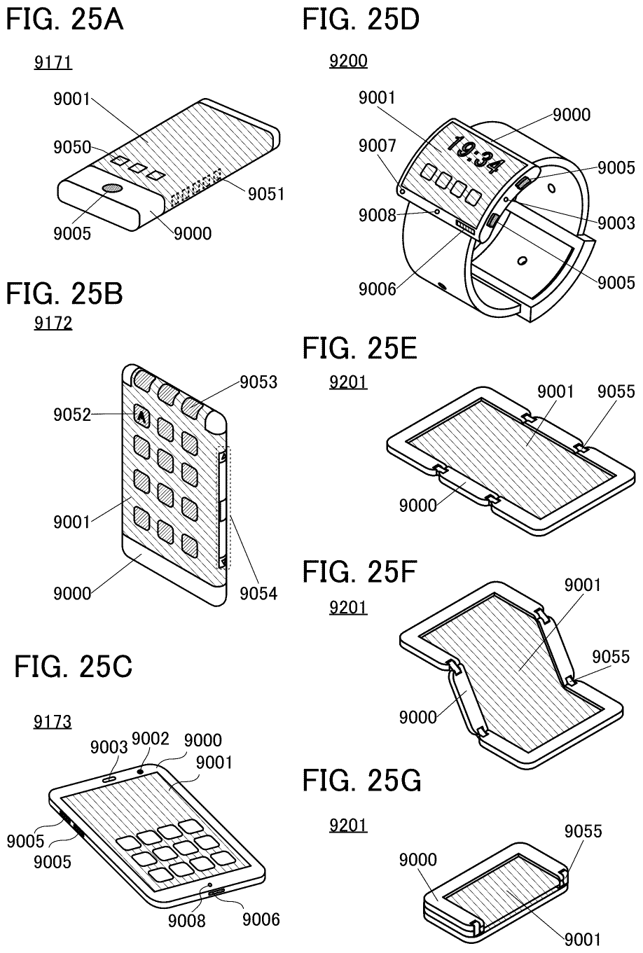

Electronic appliances illustrated in FIGS. 25A to 25G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 25A to 25G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic appliances are not limited thereto, and the electronic appliances can have a variety of functions. The electronic appliances may include a plurality of display portions. The electronic appliances may be provided with a camera or the like and have a function of taking a still image or a moving image, a function of storing the taken image in a storage medium (an external storage medium or a storage medium incorporated in the camera), a function of displaying the taken image on the display portion, and the like.

The electronic appliances in FIGS. 25A to 25G are described in detail below.

FIG. 25A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 25A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 25B is a perspective view of a portable information terminal 9172. The portable information terminal 9172 has a function of displaying information on three or more surfaces of the display portion 9001. Here, an example in which information 9052, information 9053, and information 9054 are displayed on different surfaces is described. For example, the user of the portable information terminal 9172 can check the information 9053 displayed so as to be seen from above the portable information terminal 9172, with the portable information terminal 9172 put in a breast pocket of his/her clothes. Thus, the user can see the display without taking out the portable information terminal 9172 from the pocket and decide whether to answer the call, for example.

FIG. 25C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 25D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 25E to 25G are perspective views of a foldable portable information terminal 9201. FIG. 25E is a perspective view showing the portable information terminal 9201 that is opened. FIG. 25G is a perspective view showing the portable information terminal 9201 that is folded. FIG. 25F is a perspective view showing the portable information terminal 9201 that is shifted from one of the states in FIGS. 25E and 25G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with any of the other embodiments or examples. In this specification, in the case where a plurality of structure examples are shown in one embodiment, the structure examples can be combined as appropriate.

### Example 1

### Synthesis Example 1

This example describes a synthesis method of {2-(methyl-d₃)-8-[5-(methyl-d₃)-4-phenyl-2-pyridinyl-κN]benzofuro[2,3-b]pyridin-7-yl-κC}bis{2-[5-(methyl-d₃)-2-pyridinyl-KM]phenyl-κC}iridium(III) (abbreviation: Ir(5mppy-d₃)₂(mbfpy5m4ppy-d₆) (Structural Formula (100)), which is the organometallic complex of one embodiment of the present invention. A structural formula of Ir(5mppy-d₃)₂(mbfpy5m4ppy-d₆) is shown below.

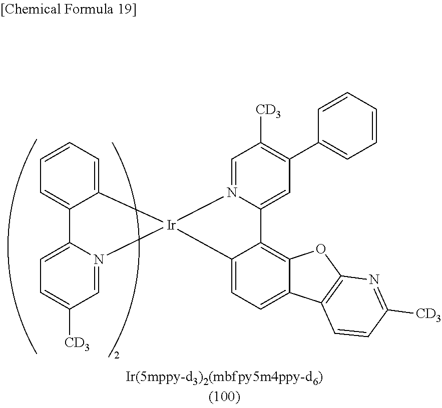

### Step 1: Synthesis of 8-(4-chloro-5-methyl-2-pyridinyl)-2-methylbenzofuro[2,3-b]pyridine

Into a three-neck flask were put 21 g of 2-methyl-8-(4,4,5,5-tetramethyl-1,3,2-dioxaborolan-2-yl)benzofuro[2,3-b]pyridine, 13 g of 2,4-dichloro-5-picoline, 19 g of potassium carbonate, 345 mL of ethylene glycol dimethyl ether (abbreviation: DME), and 60 mL of water, and the mixture was degassed. Furthermore, 0.79 g of tetrakis(triphenylphosphine)palladium(0) (abbreviation: Pd(PPh₃)₄) was added, and the mixture was stirred at 100° C. for 9 hours to cause a reaction. After the reaction was completed, the reacted solution was filtered. The residue was washed with toluene and water and then recrystallized with toluene to give a pale yellow solid. The filtrate was subjected to extraction with toluene. The obtained residue was purified by silica gel column chromatography with the developing solvent of toluene and ethyl acetate, whose ratio was changed from 10:0 to 10:1 (toluene:ethyl acetate). The obtained solid was recrystallized with toluene to give a pale yellow solid. In addition to the solid obtained from the residue, 19 g of a target pale yellow solid was obtained in a yield of 89%. The synthesis scheme (a-1) of Step 1 is shown in Formula (a-1).

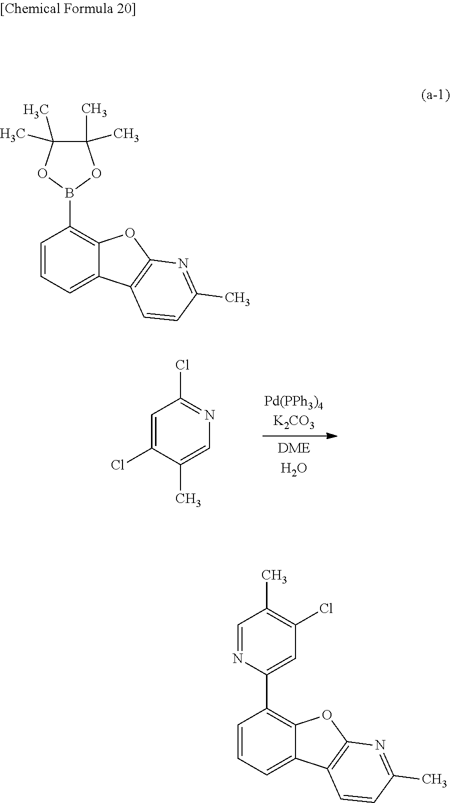

### Step 2: Synthesis of 2-methyl-8-(5-methyl-4-phenyl-2-pyridinyl)benzofuro[2,3-b]pyridine

Into a three-neck flask were put 19 g of 8-(4-chloro-5-methyl-2-pyridinyl)-2-methylbenzofuro[2,3-b]pyridine obtained above in Step 1, 8.1 g of phenylboronic acid, 39 g of tripotassium phosphate, 350 mL of toluene, and 35 mL of water, and the mixture was degassed. Furthermore, 1.5 g of 2-dicyclohexylphosphino-2′,6′-dimethoxybiphenyl (abbreviation: SPhos) and 0.83 g of tris(dibenzylideneacetone)dipalladium(0) (abbreviation: Pd₂(dba)₃) were added, and the mixture was stirred at 110° C. for 18 hours to cause a reaction. After the reaction was completed, extraction was performed with toluene. The obtained residue was purified by silica gel column chromatography using toluene and ethyl acetate in a ratio of 10:1 as the developing solvent. After that, purification was performed by high performance liquid chromatography using chloroform as the mobile phase to give 17 g of a target white solid in a yield of 81%. The synthesis scheme of Step 2 is shown in Formula (a-2).

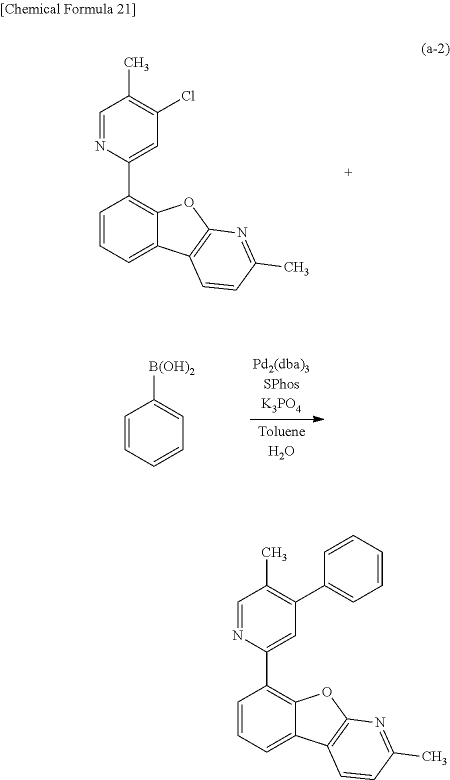 [SMILES: Cc1ccc2c(n1)oc1c(-c3cc(Cl)c(C)cn3)cccc12 ; OB(O)c1ccccc1 ; Cc1ccc2c(n1)oc1c(-c3cc(-c4ccccc4)c(C)cn3)cccc12]

### Step 3: Synthesis of 2-(methyl-d₃)-8-(5-(methyl-d₃)-4-phenyl-2-pyridinyl)benzofuro[2,3-b]pyridine

Into a three-neck flask were put 4.5 g of 2-methyl-8-(5-methyl-4-phenyl-2-pyridinyl)benzofuro[2,3-b]pyridine obtained above in Step 2 and 42 g of dimethyl sulfoxide-d₆ (abbreviation: DMSO-d₆), and the mixture was degassed. The mixture was stirred at 60° C. and returned to room temperature after dissolution of powder was confirmed, and 1.5 g of sodium tert-butoxide (abbreviation: tBuONa) was added to the mixture, and stirring was performed at room temperature for 1 hour to cause a reaction. After the reaction was completed, extraction was performed with toluene. The obtained residue was purified by silica gel column chromatography using toluene and ethyl acetate in a ratio of 10:1 as the developing solvent to give 4.4 g of a target pale yellow solid in a yield of 95%. The synthesis scheme of Step 3 is shown in Formula (a-3).

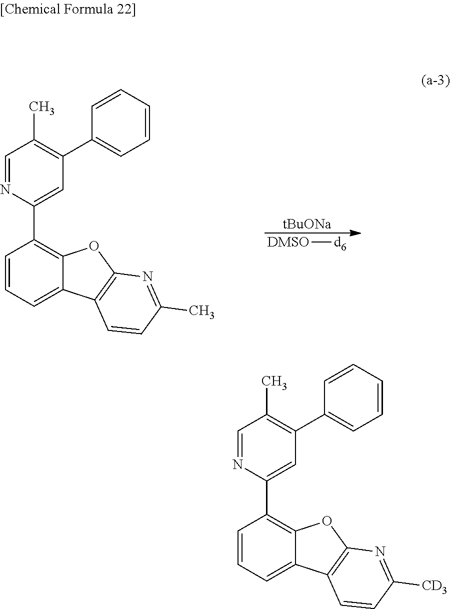

### Step 4: Synthesis of 5-(methyl-d₃)-2-phenylpyridine

Into a three-neck flask was put 10 g of 5-methyl-2-phenylpyridine and 92 g of dimethyl sulfoxide-d₆ (abbreviation: DMSO-d₆), and the mixture was degassed. Furthermore, 3.4 g of sodium tert-butoxide (abbreviation: tBuONa) was added, and the mixture was stirred at room temperature for 2 hours to cause a reaction. After the reaction was completed, extraction was performed with toluene. The obtained residue was purified by silica gel column chromatography using toluene and ethyl acetate in a ratio of 10:1 as the developing solvent to give 10 g of a target transparent oily substance in a yield of 96%. The synthesis scheme of Step 4 is shown in Formula (a-4).

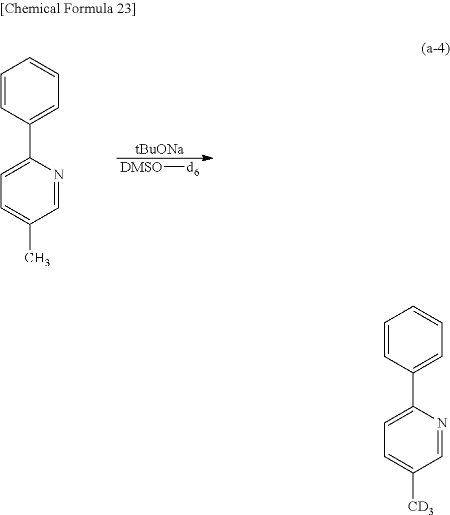

### Step 5: Synthesis of di-μ-chloro-tetrakis{2-[5(methyl-d₃)-2-pyridinyl-κN)phenyl-κC}diiridium(III)

Into a round-bottom flask were put 4.1 g of 5-(methyl-d₃)-2-phenylpyridine obtained above in Step 4, 3.3 g of iridium(III) chloride hydrate, 37 mL of 2-ethoxyethanol, and 12 mL of water, and the mixture was irradiated with microwaves (2.45 GHz, 100 W) for 1 hour and 30 minutes while being bubbled with argon. After the reaction was completed, the mixture was cooled with ice and filtered. By washing the residue with methanol, 3.7 g of a target yellow solid was obtained in a yield of 58%. The synthesis scheme of Step 5 is shown in Formula (a-5).

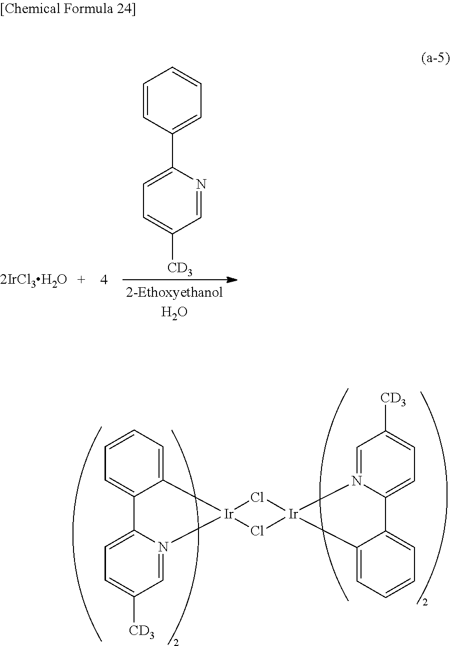

### Step 6: Synthesis of Ir(5mppy-d₃)₂(mbfpy5m4ppy-d₆)

Into a three-neck flask were put 3.7 g of di-μ-chloro-tetrakis(2-{methyl-d₃)-2-pyridinyl-N)phenyl-κC}diiridium(III) obtained above in Step 5 and 162 mL of dichloromethane, and the mixture was light-shielded. Then, 2.5 g of silver trifluoromethanesulfonate (abbreviation: AgOTf) dissolved in 32 mL of methanol was dripped to the mixture, and stirring was performed at room temperature for 23 hours to cause a reaction. The obtained mixture was filtered through Celite, and the filtrate was concentrated to give a solid. Into a three-neck flask were put this solid, 2.1 g of 2-(methyl-d₃)-8-(5-(methyl-d₃)-4-phenyl-2-pyridinyl)benzofuro[2,3-b]pyridine obtained above in Step 3, 65 mL of 2-ethoxyethanol, and 65 mL of N,N-dimethylformamide (abbreviation: DMF) were degassed. The mixture was stirred at 135° C. for 13 hours to cause a reaction. After the reaction was completed, the reacted solution was filtered. The residue was purified by silica gel chromatography with the developing solvent of dichloromethane and ethyl acetate, whose ratio was changed from 10:0 to 10:1 (dichloromethane:ethyl acetate). Next, purification by high performance liquid chromatography with chloroform as the mobile phase was performed, and then recrystallization with toluene was performed, whereby 1.4 g of a target yellow solid was obtained in a yield of 26%. By a train sublimation method, 0.49 g of the obtained yellow solid was purified by sublimation. In the purification by sublimation, the solid was heated at 380° C. to 385° C. under a pressure of 5.5 Pa. After the sublimation purification, 0.42 g of a target yellow solid was obtained at a yield of 86%. The synthesis scheme of Step 6 is shown in Formula (a-6).

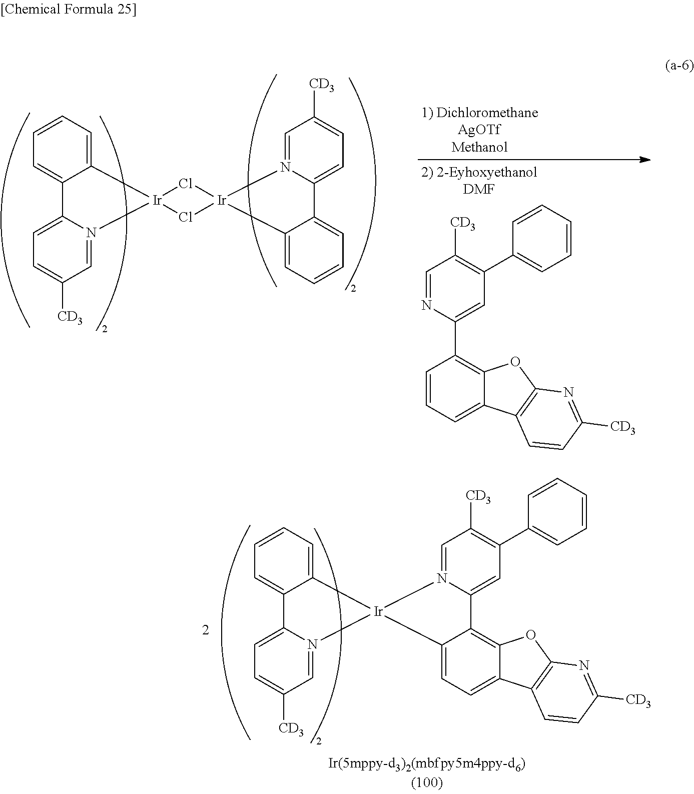

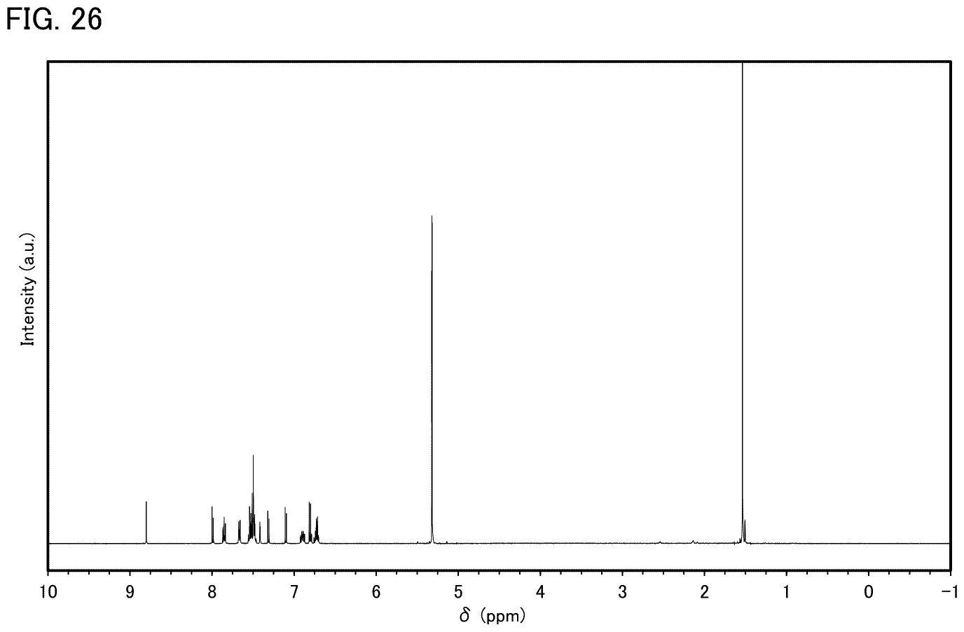

Analysis results by nuclear magnetic resonance spectroscopy (¹H-NMR) of the yellow solid obtained in Step 6 are shown below. FIG. 26 shows a ¹H NMR spectrum. The results show that Ir(5mppy-d₃)₂(mbfpy5m4ppy-d₆) (Structural Formula (100)), which is the organometallic complex of one embodiment of the present invention, was obtained in this synthesis example.

¹H-NMR. δ(CD₂Cl₂, 500 MHz): 6.70-6.76 (m, 3H), 6.79-6.82 (m, 2H), 6.87-6.92 (m, 2H), 7.10 (d, 1H, J=7.5 Hz), 7.31 (d, 1H, J=7.5 Hz), 7.42 (s, 1H), 7.47-7.56 (m, 9H), 7.67 (d, 2H, J=7.5 Hz), 7.85 (t, 2H, J=8.0 Hz), 7.99 (d, 1H, J=7.5 Hz), 8.80 (s, 1H)

### <Measurement of Emission and Absorption Spectra>

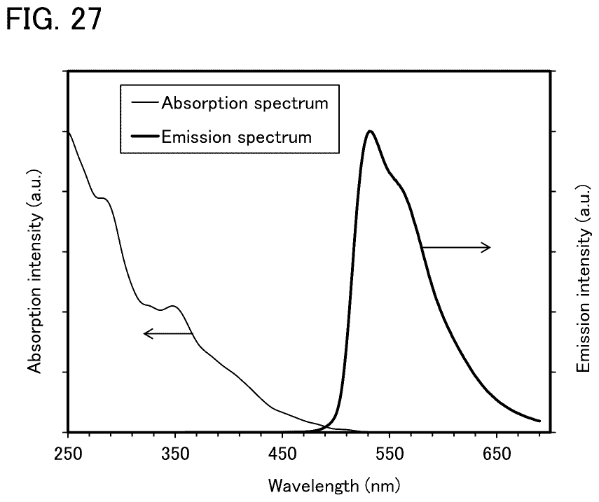

Next, an ultraviolet-visible absorption spectrum (hereinafter, simply referred to as an “absorption spectrum”) of a dichloromethane solution of Ir(5mppy-d₃)₂(mbfpy5m4ppy-d₆) and an emission spectrum thereof were measured. The absorption spectrum were measured with an ultraviolet-visible spectrophotometer (V-770DS, produced by JASCO Corporation). The emission spectrum was measured with a fluorescence spectrophotometer (FP-8600 manufactured by JASCO Corporation). FIG. 27 shows the obtained absorption and emission spectra of the dichloromethane solution. The horizontal axis represents the wavelength and the vertical axes represent the absorption intensity and the emission intensity.

From the results in FIG. 27, the dichloromethane solution of Ir(5mppy-d₃)₂(mbfpy5m4ppy-d₆) exhibits absorption peaks at around 348 nm and 400 nm and an emission peak at around 532 nm.

### Example 2

### Synthesis Example 2

This example describes a synthesis method of {2-(methyl-d₃)-8-[5-(methyl-d₃)-4-phenyl-2-pyridinyl-κN]benzofuro[2,3-b]pyridin-7-yl-κC}bis{2-[4,5-di(methyl-d₆)-2-pyridinyl-KM]phenyl-κC}iridium(III) (abbreviation: Ir(dmppy-d₆)₂(mbfpy5m4ppy-d₆) (Structural Formula (101)), which is the organometallic complex of one embodiment of the present invention. A structural formula of Ir(dmppy-d₆)₂(mbfpy5m4ppy-d₆) is shown below.

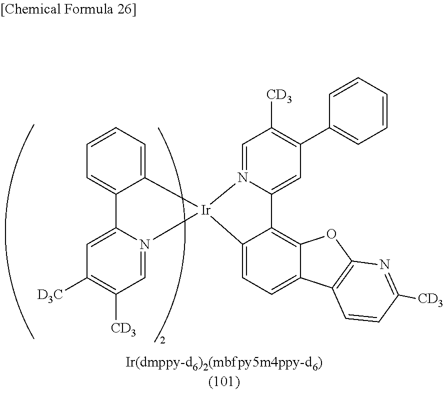

### Step 1: Synthesis of 4,5-di(methyl-d₆)-2-phenylpyridine

Into a three-neck flask were put 9.0 g of 4,5-dimethyl-2-pyridine and 77 g of dimethyl sulfoxide-d₆ (abbreviation: DMSO-d₆), and the mixture was degassed. Furthermore, 2.8 g of sodium tert-butoxide (abbreviation: tBuONa) was added, and the mixture was stirred at room temperature for 1 hour and 30 minutes to cause a reaction. After the reaction was completed, extraction was performed with toluene. The obtained residue was purified by silica gel chromatography with the developing solvent of toluene and ethyl acetate, whose ratio was changed from 40:1 to 10:1 (toluene:ethyl acetate), whereby 9.0 g of a target yellow oily substance was obtained in a yield of 97%. The synthesis scheme of Step 1 is shown in Formula (b-1).

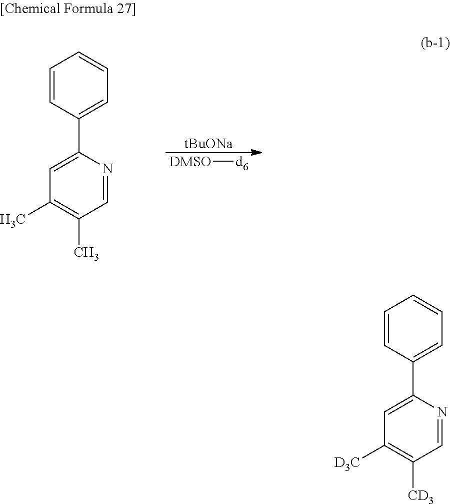

### Step 2: Synthesis of di-μ-chloro-tetrakis{2-[4,5-di(methyl-d)-2-pyridinyl-κN]phenyl-κC}diiridium(III)

Into a round-bottom flask were put 4.0 g of 4,5-di(methyl-d₆)-2-phenylpyridine obtained above in Step 1, 3.0 g of iridium(III) chloride hydrate, 37 mL of 2-ethoxyethanol, and 12 mL of water, and irradiation with microwaves (2.45 GHz, 100 W) for 1 hour and 30 minutes was performed while being bubbled with argon. After the reaction was completed, the mixture was cooled down to be filtered. By washing the residue with methanol, 3.2 g of a target yellow solid was obtained in a yield of 52%. The synthesis scheme of Step 2 is shown in Formula (b-2).

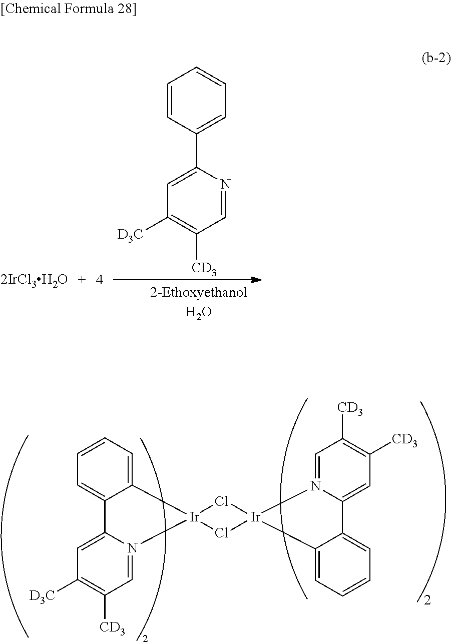

### Step 3: Synthesis of Ir(dmppy-d₆)₂(mbfpy5m4ppy-d₆)

Into a three-neck flask were put 3.2 g of di-μ-chloro-tetrakis{2-(methyl-d₆)-2-pyridinyl-κN)phenyl-κC}diiridium(III) obtained above in Step 2 and 130 mL of dichloromethane, and the mixture was light-shielded. Then, 2.0 g of silver trifluoromethanesulfonate (abbreviation: AgOTf) dissolved in 26 mL of methanol was dripped to the mixture, and stirring was performed at room temperature for 20 hours. After the reaction solution was made to pass through Celite, the mixture was concentrated to give a solid. Into a three-neck flask were put this solid, 1.9 g of 2-(methyl-d₃)-8-(5-(methyl-d₃)-4-phenyl-2-pyridinyl)benzofuro[2,3-b]pyridine, 55 mL of 2-ethoxyethanol, and 55 mL of N,N-dimethylformamide (abbreviation: DMF) were degassed. The mixture was stirred at 135° C. for 13 hours to cause a reaction. After the reaction was completed, the reacted solution was filtered and the filtrate was concentrated. Then, toluene was added to the obtained solid and the mixture was filtered. This solid was purified by silica gel column chromatography with the developing solvent of toluene and ethyl acetate, whose ratio was changed from 20:0 to 20:1 (toluene:ethyl acetate). The residue was dissolved in hot toluene and purified by silica gel column chromatography with the developing solvent of toluene and ethyl acetate, whose ratio was changed from 20:0 to 20:1 (toluene:ethyl acetate). A purification product derived from the filtrate and a purification product derived from the residue were combined, and further purified by silica gel chromatography with the developing solvent of toluene and ethyl acetate, whose ratio was changed from 50:1 to 30:1 (toluene:ethyl acetate). The obtained solid was recrystallized with toluene to give 2.1 g of a target yellow solid in a yield of 44%.

Then, 1.2 g of the obtained yellow solid was sublimated and purified by a train sublimation method. In the purification by sublimation, the solid was heated at 345° C. to 365° C. under a pressure of 5.6 Pa. After the sublimation purification, 0.93 g of a target yellow solid was obtained in a yield of 76%. The synthesis scheme of Step 3 is shown in Formula (b-3).

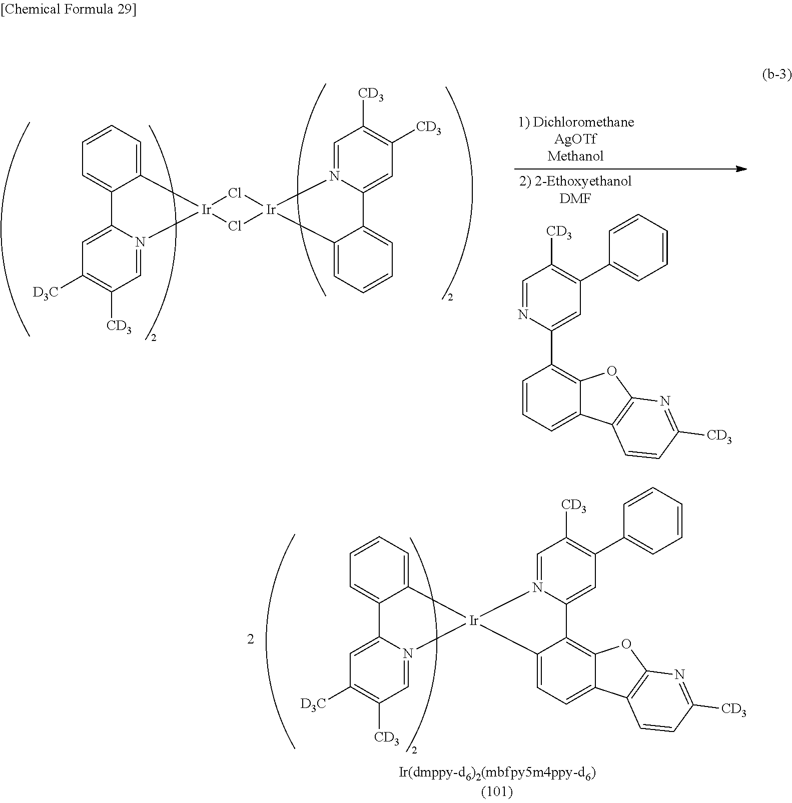

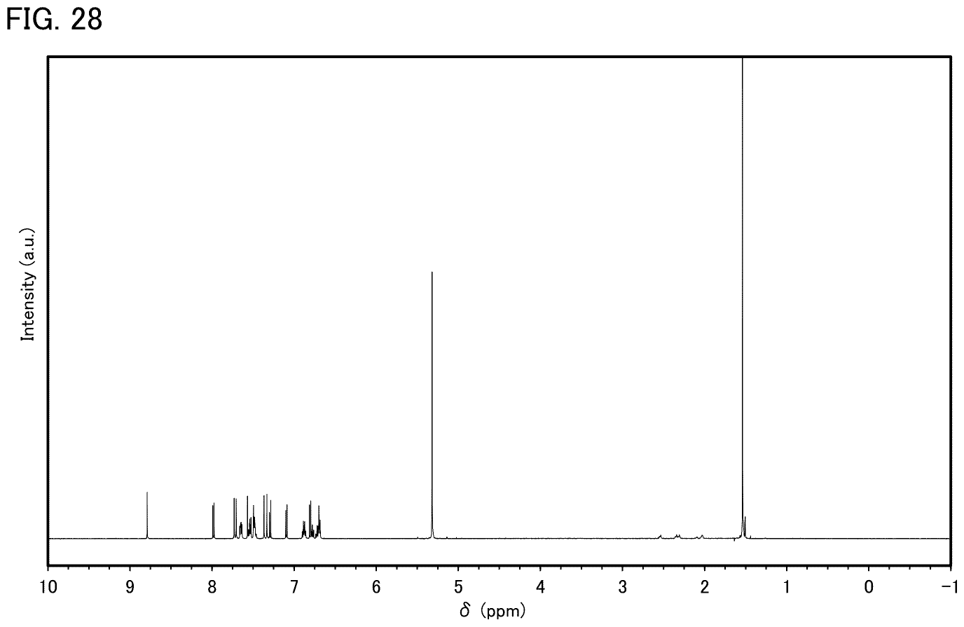

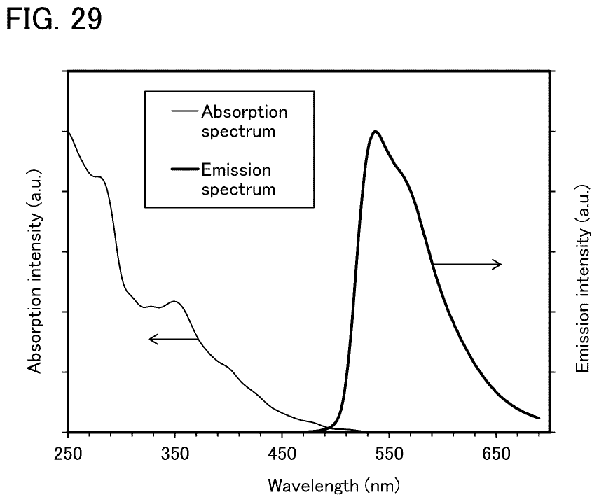

Analysis results by nuclear magnetic resonance spectroscopy (¹H-NMR) of the yellow solid obtained in Step 3 are shown below. FIG. 28 shows a ¹H NMR spectrum. The results show that Ir(6mppy-d₆)₂(mbfpy5m4ppy-d₆) (Structural Formula (101)), which is the organometallic complex of one embodiment of the present invention, was obtained in this synthesis example.

¹H-NMR. δ(CD₂Cl₂, 500 MHz): 6.69-6.73 (m, 3H), 6.76-6.81 (m, 2H), 6.86-6.90 (m, 2H), 7.10 (d, 1H J=7.5 Hz), 7.29 (d, 1H J=8.0 Hz), 7.33 (s, 1H), 7.37 (s, 1H), 7.46-7.50 (m, 3H), 7.53-7.57 (m, 3H), 7.64-7.66 (m, 2H), 7.71 (s, 1H), 7.73 (s, 1H), 7.98 (d, 1H, J=7.5 Hz), 8.79 (s, 1H)

### <Measurement of Emission and Absorption Spectra>

Next, an ultraviolet-visible absorption spectrum (hereinafter, simply referred to as an “absorption spectrum”) of a dichloromethane solution of Ir(dmppy-d₆)₂(mbfpy5m4ppy-d₆) and an emission spectrum thereof were measured. The absorption spectrum were measured with an ultraviolet-visible spectrophotometer (V-770DS, produced by JASCO Corporation). The emission spectrum was measured with a fluorescence spectrophotometer (FP-8600 manufactured by JASCO Corporation). FIG. 29 shows the obtained absorption and emission spectra of the dichloromethane solution. The horizontal axis represents the wavelength and the vertical axes represent the absorption intensity and the emission intensity.

From the results in FIG. 29, the dichloromethane solution of Ir(dmppy-d₆)₂(mbfpy5m4ppy-d₆) exhibits absorption peaks at around 350 nm and 400 nm and an emission peak at around 537 nm.

### Example 3

This example describes fabrication of a light-emitting device 1 and a comparative light-emitting device 2 and the results of comparison of their characteristics. The light-emitting device 1 includes, for a light-emitting layer, Ir(5mppy-d₃)₂(mbfpy5m4ppy-d₆) (Structural Formula (100)), which is an organometallic complex of one embodiment of the present invention and whose synthesis method is described in Example 1, and the comparative light-emitting device 2 including, for a light-emitting layer, [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)). Note that in this example, Ir(5mppy-d₃)₂(mbfpy5m4ppy-d₆), whose synthesis method is described in Example 1, is referred to as Complex (100), and Ir(5mppy-d₃)₂(mbfpypy-d₃), which is a comparative organometallic complex, is referred to as Complex (c).

Structural formulae of the organic compounds used for the light-emitting device 1 and the comparative light-emitting device 2 are shown below. Device structures of the light-emitting device 1 and the comparative light-emitting device 2 are also shown below.

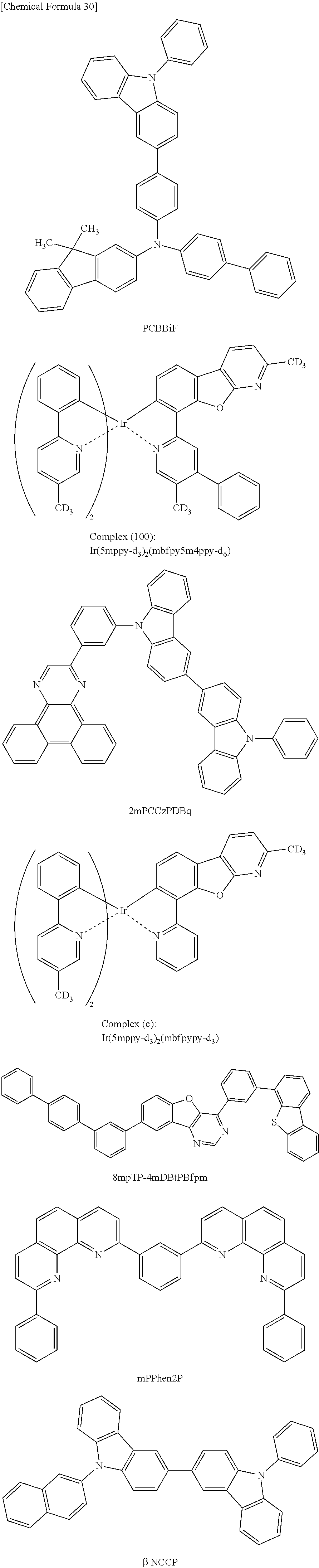

TABLE 1

| | | |
|---|---|---|
| Thick- | Light-emitting | Comparative light- |
| ness | device 1 | emitting device 2 |

| Second electrode | | 200 nm | Al |
|---|---|---|---|
| Electron-injection layer | | 1 nm | LiF |
| Electron- | 2 | 20 nm | mPPhen2P |
| transport | 1 | 10 nm | 2mPCCzPDBq |
| layer | | | |

| | | | |
|---|---|---|---|
| Light-emitting layer | 40 nm | 8mpTP- | 8mpTP- |

| | |
|---|---|
| 4mDBtP Bfpm:βNCCP:Complex (100) | 4mDBtPBfpm:βNCCP:Complex (c) |
| (0.50:0.50:0.10) | (0.50:0.50:0.10) |

| | | |
|---|---|---|
| Hole-transport layer | 50 nm | PCBBiF |
| Hole-injection layer | 10 nm | PCBBiF:OCHD-003 (1:0.03) |
| First electrode | 70 nm | ITSO |

### <Fabrication of Light-Emitting Device 1>

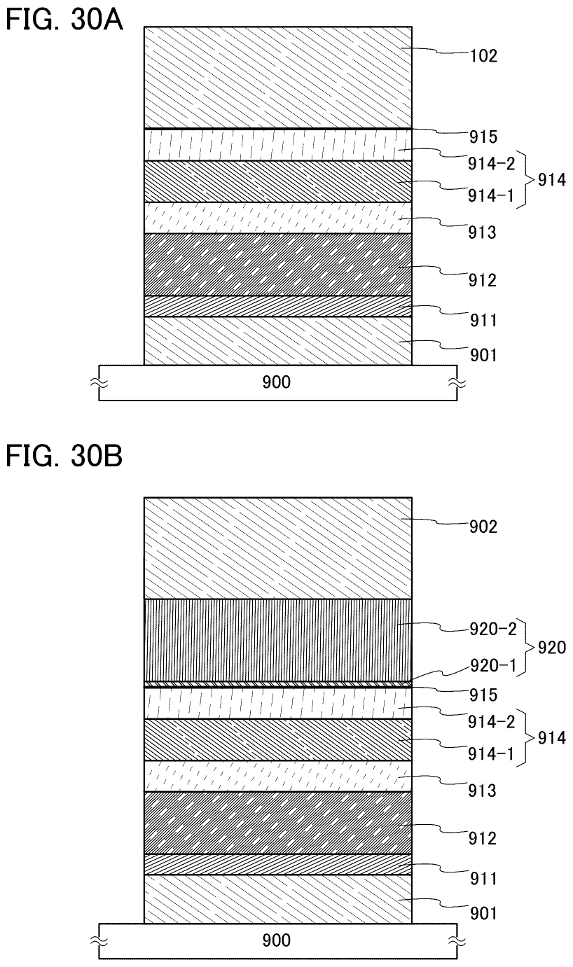

In the light-emitting devices 1 described in this example, as illustrated in FIG. 30A, a hole-injection layer 911, a hole-transport layer 912, a light-emitting layer 913, an electron-transport layer 914 (a first electron-transport layer 914-1 and a second electron-transport layer 914-2), and an electron-injection layer 915 are stacked in this order over a first electrode 901 formed over a substrate 900, and a second electrode 902 is stacked over the electron-injection layer.

First, the first electrode 901 was formed over the substrate 900. The electrode area was set to 4 mm² (2 mm×2 mm). A glass substrate was used as the substrate 900. As the first electrode 901 as a transparent electrode, a film of indium tin oxide including silicon oxide (ITSO) was formed to a thickness of 70 nm by a sputtering method. In this example, the first electrode 901 functions as an anode.

For pretreatment, a surface of the substrate was washed with water, and baking was performed at 200° C. for 1 hour. After that, the substrate was transferred into a vacuum evaporation apparatus where the pressure had been reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Next, the hole-injection layer 911 was formed over the first electrode 901. The hole-injection layer 911 was formed in the following manner: the pressure in the vacuum evaporation apparatus was reduced to 1×10⁻⁴ Pa, and then N-(biphenyl-4-yl)-N-[4-(9-phenyl-9H-carbazol-3-yl)phenyl]-9,9-dimethyl-9H-fluoren-2-amine (abbreviation: PCBBiF) and an electron acceptor material (OCHD-003) that contains fluorine and has a molecular weight of 672 were deposited by co-evaporation to a thickness of 10 nm in a weight ratio of PCBBiF:OCHD-003=1:0.03.

Then, the hole-transport layer 912 was formed over the hole-injection layer 911. The hole-transport layer 912 was formed to a thickness of 50 nm by evaporation of PCBBiF.

Next, the light-emitting layer 913 was formed over the hole-transport layer 912. To form the light-emitting layer 913, 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm) as a host material, 9-(2-naphthyl)-9′-phenyl-3,3′-bi-9H-carbazole (abbreviation: βNCCP) as an assist material, and Complex (100) as a light-emitting material were co-evaporated to a thickness of 40 nm such that the weight ratio of 8mpTP-4mDBtPBfpm:βNCCP:Complex (100) was 0.50:0.50:0.10.

Next, the electron-transport layer 914 (the first electron-transport layer 914-1 and the second electron-transport layer 914-2) was formed over the light-emitting layer 913. First, the first electron-transport layer 914-1 was formed to a thickness of 10 nm by evaporation of 2-{3-[3-(N-phenyl-9H-carbazol-3-yl)-9H-carbazol-9-yl]phenyl}dibenzo[f,h]quinoxaline (abbreviation: 2mPCCzPDBq). Then, over the first electron-transport layer 914-1, the second electron-transport layer 914-2 was formed to a thickness of 20 nm by evaporation of 2,2′-(1,3-phenylene)bis(9-phenyl-1,10-phenanthroline) (abbreviation: mPPhen2P).

Next, lithium fluoride (LiF) was deposited by evaporation to a thickness of 1 nm over the electron-transport layer 914, so that the electron-injection layer 915 was formed.

After that, the second electrode 902 was formed over the electron-injection layer 915. The second electrode 902 was formed by evaporating aluminum (Al) to a thickness of 200 nm. In this example, the second electrode 902 functions as a cathode.

Through the above process, the light-emitting device 1 was fabricated.

### <Fabrication of Comparative Light-Emitting Device 2>

The comparative light-emitting device 2 has a structure in which Complex (100) of the light-emitting device 1 is replaced with Complex (c). In other words, the comparative light-emitting device 2 is different from the light-emitting device 1 in that Complex (c) was used instead of Complex (100) as the light-emitting material in the light-emitting layer 913, and the other components were formed in the same manner as those in the light-emitting device 1.

The above light-emitting devices were each sealed using a glass substrate in a glove box containing a nitrogen atmosphere so as not to be exposed to the air (a sealing material was applied to surround the device and UV treatment and heat treatment at 80° C. for an hour were performed at the time of sealing). Then, the initial characteristics of the light-emitting devices were measured.

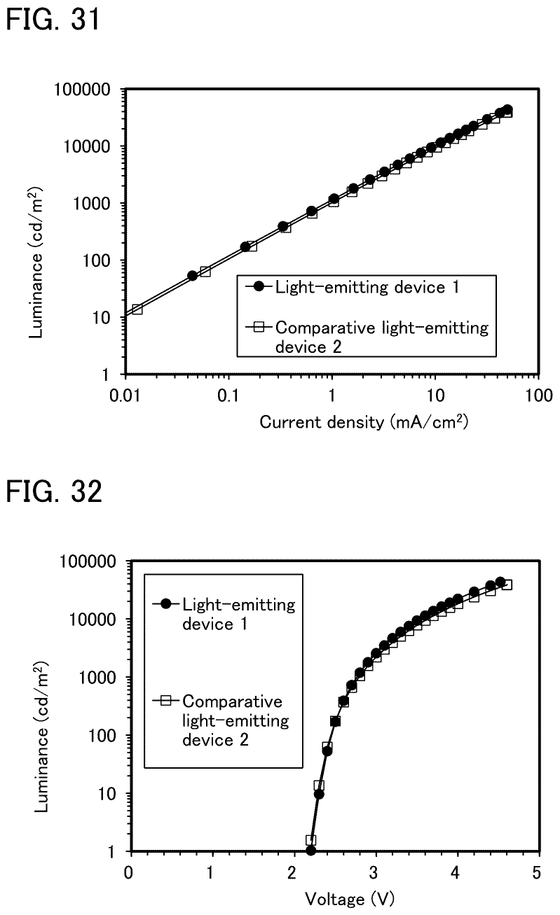

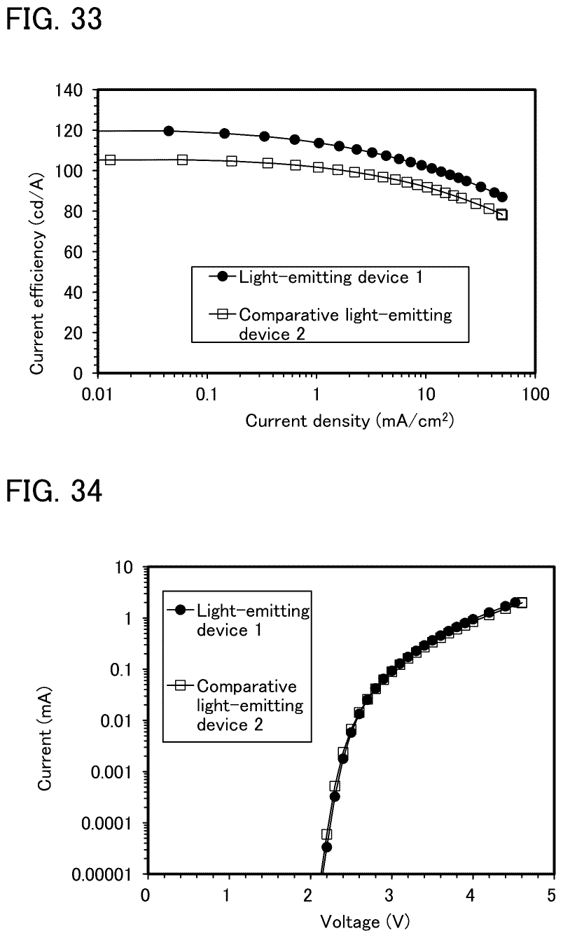

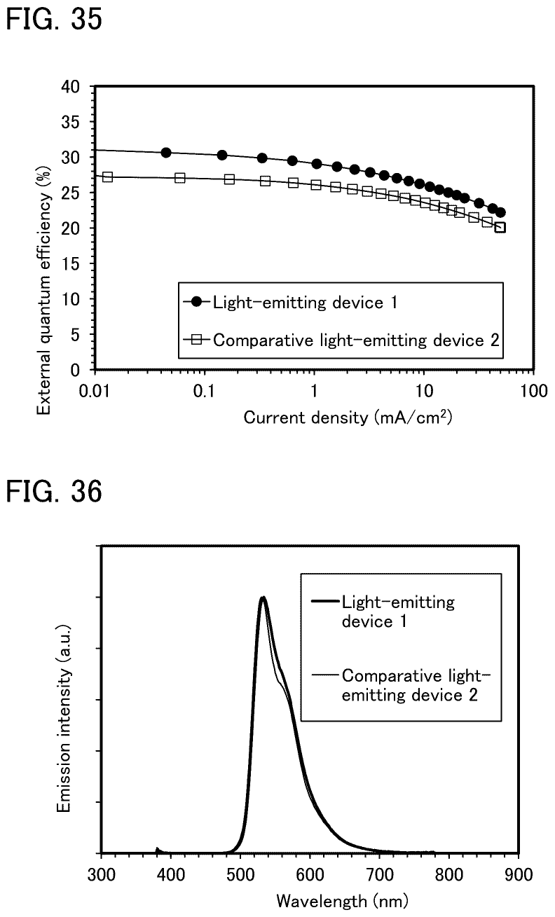

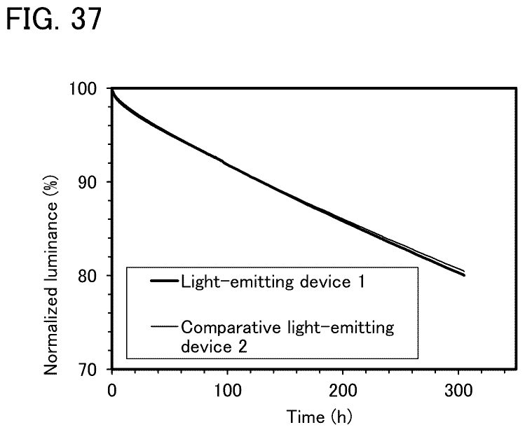

Next, FIG. 31 shows the luminance-current density characteristics of the light-emitting devices, FIG. 32 shows the luminance-voltage characteristics thereof, FIG. 33 shows the current efficiency-current density characteristics thereof, FIG. 34 shows the current-voltage characteristics thereof, FIG. 35 shows the external quantum efficiency-current density characteristics thereof, and FIG. 36 shows the electroluminescence spectra thereof. Table 2 shows the main characteristics of the light-emitting devices at a luminance of approximately 1000 cd/m². Note that the luminance, CIE chromaticity, and electroluminescence spectra were measured with a spectroradiometer (SR-UL1R manufactured by TOPCON TECHNOHOUSE CORPORATION).

TABLE 2

| | | | | | | | | External |
|---|---|---|---|---|---|---|---|---|
| | | | Current | | | | Current | quantum |
| | Voltage | Current | density | Chromaticity | Chromaticity | Luminance | efficiency | efficiency |
| | (V) | (mA) | (mA/cm²) | x | y | (cd/m²) | (cd/A) | (%) |
| Light-emitting | 2.8 | 0.042 | 1.05 | 0.36 | 0.62 | 1194 | 114 | 29 |
| device 1 | | | | | | | | |
| Comparative | 2.8 | 0.042 | 1.04 | 0.35 | 0.62 | 1055 | 102 | 26 |
| light-emitting | | | | | | | | |
| device 2 | | | | | | | | |

FIG. 31 to FIG. 36 and the above table reveal that the light-emitting device 1 exhibits green light emission derived from Complex (100) and has favorable emission characteristics.

FIG. 33 and FIG. 35 show that the light-emitting device 1 has higher current efficiency and higher external quantum efficiency than the comparative light-emitting device 2.

FIG. 37 shows a luminance change over driving time when each light-emitting device was driven at a constant current of 2 mA (50 mA/cm²). FIG. 37 shows that the light-emitting device 1 has a small change in luminance over driving time and is as highly reliable as the comparative light-emitting device 2.

These results demonstrate that the light-emitting device of embodiments of the present invention has favorable characteristics and long lifetimes.

### Example 4

This example describes fabrication of a light-emitting device 2 and a comparative light-emitting device 4 and the results of comparison of their characteristics. The light-emitting device 3 includes, for a light-emitting layer, Ir(dmppy-d₆)₂(mbfpy5m4ppy-d₆)) (Structural Formula (101)), which is an organometallic complex of one embodiment of the present invention and whose synthesis method is described in Example 2, and the comparative light-emitting device 4 includes, for a light-emitting layer, Ir(5mppy-d₃)₂(mbfpypy-d₃), which is an organometallic complex for comparison 7. Note that in this example, Ir(dmppy-d₆)₂(mbfpy5m4ppy-d₆), whose synthesis method is described in Example 2, is referred to as Complex (101), and Ir(5mppy-d₃)₂(mbfpypy-d₃), which is a comparative organometallic complex, is referred to as Complex (c).

Structural formulae of the organic compounds used for the light-emitting device 3 and the comparative light-emitting device 4 are shown below. Device structures of the light-emitting device 3 and the comparative light-emitting device 4 are also shown in below.

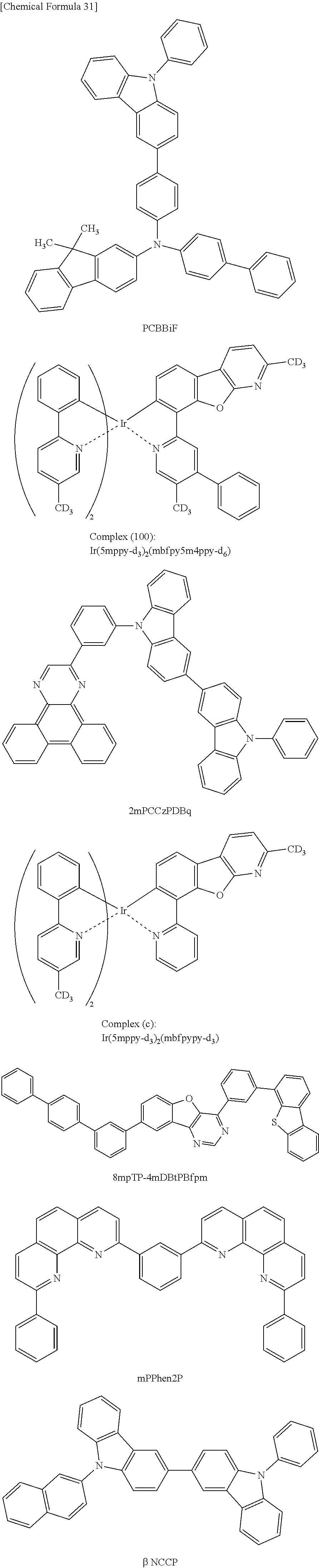

TABLE 3

| | | |
|---|---|---|
| Thick- | Light-emitting | Comparative light- |
| ness | device 3 | emitting device 4 |

| Second electrode | | 200 nm | Al |
|---|---|---|---|
| Electron-injection layer | | 1 nm | LiF |
| Electron- | 2 | 20 nm | mPPhen2P |
| transport | 1 | 10 nm | 2mPCCzPDBq |
| layer | | | |

| | | | |
|---|---|---|---|
| Light-emitting layer | 40 nm | 8mpTP- | 8mpTP- |

| | |
|---|---|
| 4mDBtPBfpm:βNCCP:Complex (101) | 4mDBtPBfpm:βNCCP:Complex (c) |
| (0.50:0.50:0.10) | (0.50:0.50:0.10) |

| | | |
|---|---|---|
| Hole-transport layer | 50 nm | PCBBiF |
| Hole-injection layer | 10 nm | PCBBiF:OCHD-003 (1:0.03) |
| First electrode | 70 nm | ITSO |

### <Fabrication of Light-Emitting Device 3>

The light-emitting device 3 has a structure in which Complex (100) of the light-emitting device 1, whose fabrication method is described in Example 3, was replaced with Complex (101). In other words, the comparative light-emitting device 3 is different from the light-emitting device 1 in that Complex (101) was used instead of Complex (100) as the light-emitting material in the light-emitting layer 913, and the other components were formed in the same manner as those in the light-emitting device 1.

### <Fabrication of Comparative Light-Emitting Device 4>

The comparative light-emitting device 4 has a structure in which Complex (101) of the light-emitting device 3 is replaced with Complex (c) and was fabricated in a manner similar to that of the comparative light-emitting device 2, whose fabrication method is described in Example 3.

The above light-emitting devices were each sealed using a glass substrate in a glove box containing a nitrogen atmosphere so as not to be exposed to the air (a sealing material was applied to surround the device and UV treatment and heat treatment at 80° C. for an hour were performed at the time of sealing). Then, the initial characteristics of the light-emitting devices were measured.

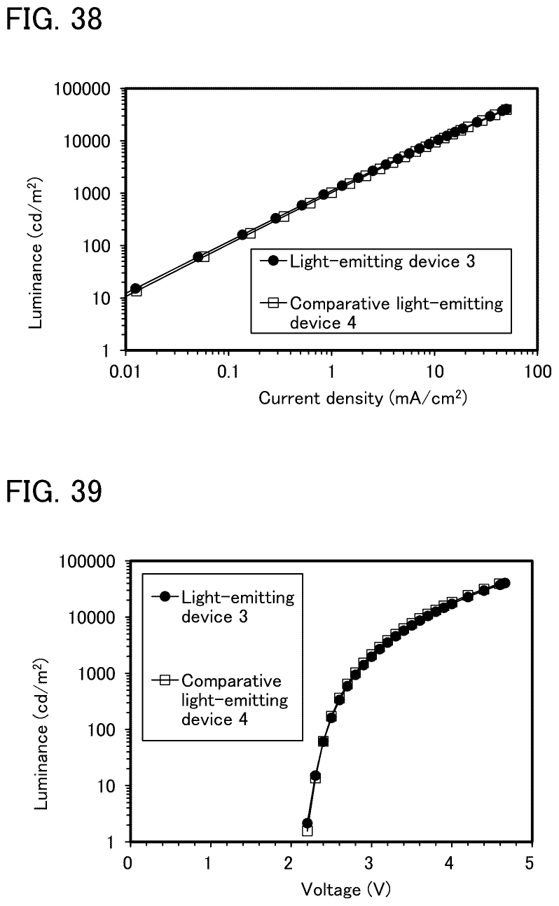

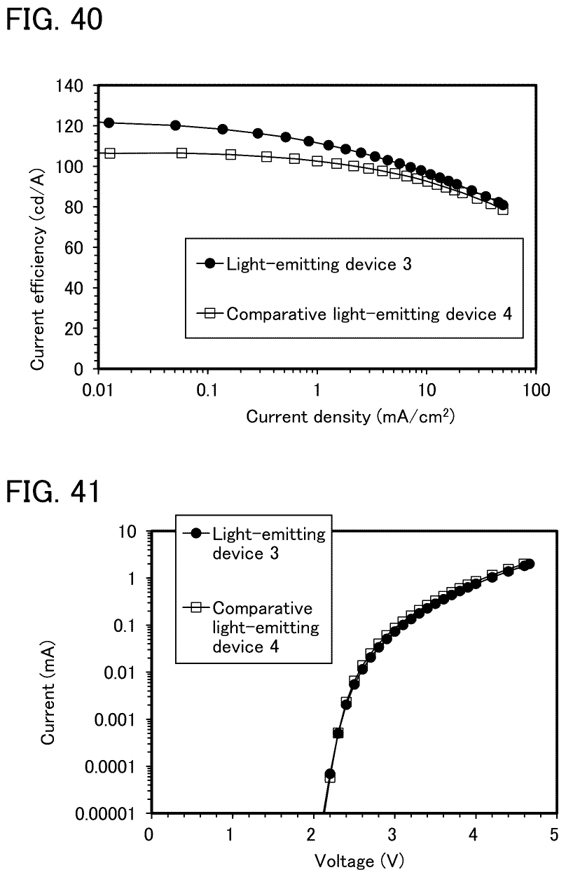

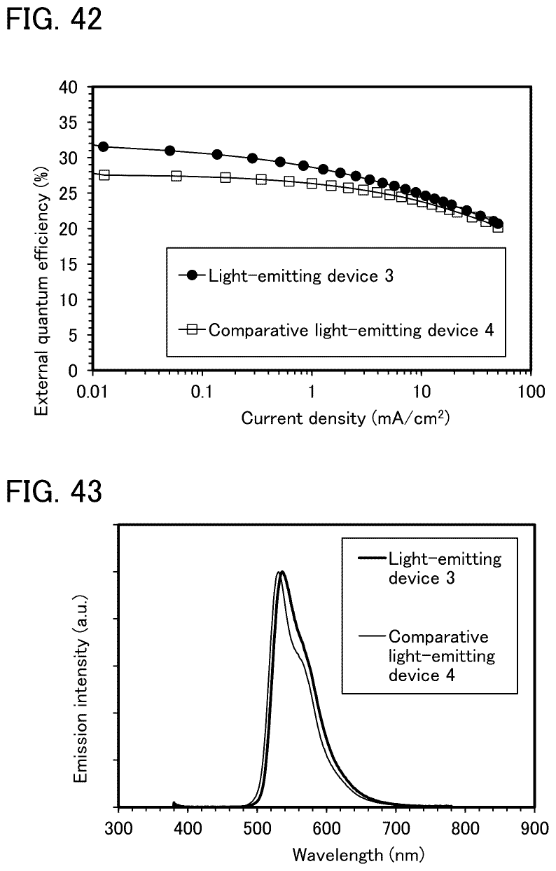

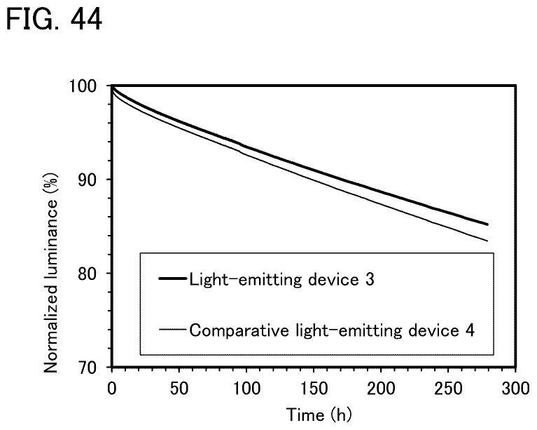

Next, FIG. 38 shows the luminance-current density characteristics of the light-emitting devices, FIG. 39 shows the luminance-voltage characteristics thereof, FIG. 40 shows the current efficiency-current density characteristics thereof, FIG. 41 shows the current-voltage characteristics thereof, FIG. 42 shows the external quantum efficiency-current density characteristics thereof, and FIG. 43 shows the electroluminescence spectra thereof. Table 4 shows the main characteristics of the light-emitting devices at a luminance of approximately 1000 cd/m². Note that the luminance, CIE chromaticity, and electroluminescence spectra were measured with a spectroradiometer (SR-UL1R manufactured by TOPCON TECHNOHOUSE CORPORATION).

TABLE 4

| | | | | | | | | External |
|---|---|---|---|---|---|---|---|---|
| | | | Current | | | | Current | quantum |
| | Voltage | Current | density | Chromaticity | Chromaticity | Luminance | efficiency | efficiency |
| | (V) | (mA) | (mA/cm²) | x | y | (cd/m²) | (cd/A) | (%) |
| Light-emitting | 2.8 | 0.033 | 0.84 | 0.38 | 0.60 | 941 | 112 | 29 |
| device 3 | | | | | | | | |
| Comparative | 2.8 | 0.040 | 1.00 | 0.35 | 0.62 | 1026 | 103 | 26 |
| light-emitting | | | | | | | | |
| device 4 | | | | | | | | |

FIG. 38 to FIG. 43 and the above table reveal that the light-emitting device 3 exhibits green light emission derived from Complex (101) and has favorable emission characteristics.

FIG. 40 and FIG. 42 show that the light-emitting device 3 has higher current efficiency and higher external quantum efficiency than the comparative light-emitting device 4.

FIG. 44 shows a luminance change over driving time when each light-emitting device was driven at a constant current of 2 mA (50 mA/cm²). FIG. 44 shows that the light-emitting device 3 has a small change in luminance over driving time and is highly reliable.

These results demonstrate that the light-emitting device of embodiments of the present invention has favorable characteristics and long lifetimes.

### Example 5

In this example, in order to calculate the molecular orientation parameters a, a light-emitting device 5a, a light-emitting device 6a, and a comparative light-emitting device 7a for orientation measurement in which an organometallic complex was used as a light-emitting material and the front luminance was greatly reduced by optical path length adjustment were fabricated and subjected to the measurement. Note that in this example, besides the light-emitting devices for orientation measurement, a light-emitting device 5b, a light-emitting device 6b, and a comparative light-emitting device 7b were also fabricated as normal light-emitting devices in which the front luminance was not reduced by optical path length adjustment, and data on them are also described. In this example, Ir(5mppy-d₃)₂(mbfpy5m4ppy-d₆) (Structural Formula (100)) is referred to as Complex (100), Ir(dmppy-d₆)₂(mbfpy5m4ppy-d₆) (Structural Formula (101)) is referred to as Complex (101) and Ir(5mppy-d₃)₂(mbfpypy-d₃), which is a comparative organometallic complex, is referred to as Complex (c).

Structural formulae of organic compounds used for the light-emitting devices for orientation measurement are shown below. Device structures of the light-emitting devices 5a, 5b, 6a, and 6b and the comparative light-emitting devices 7a and 7b are also shown below.

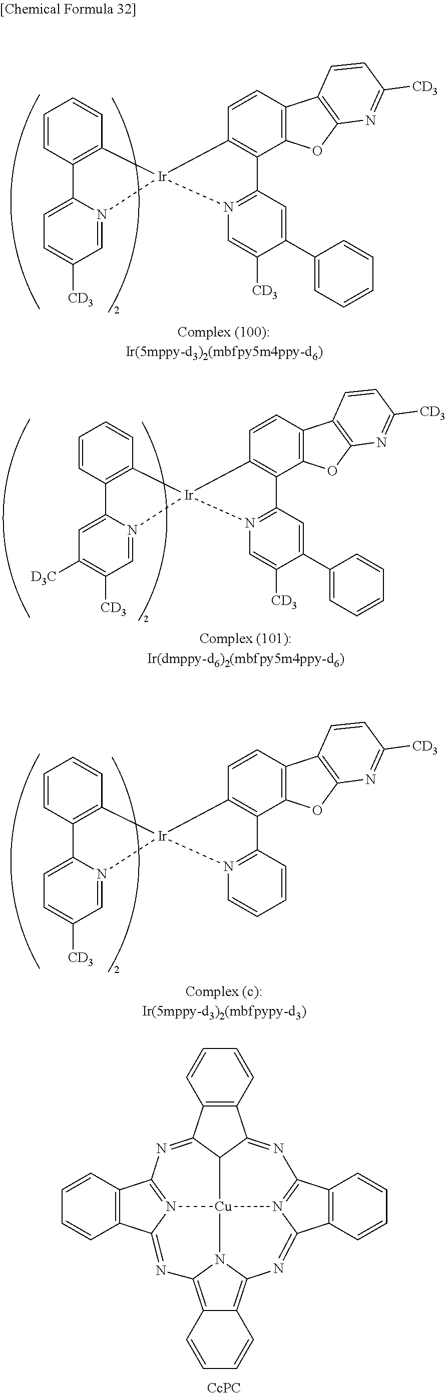

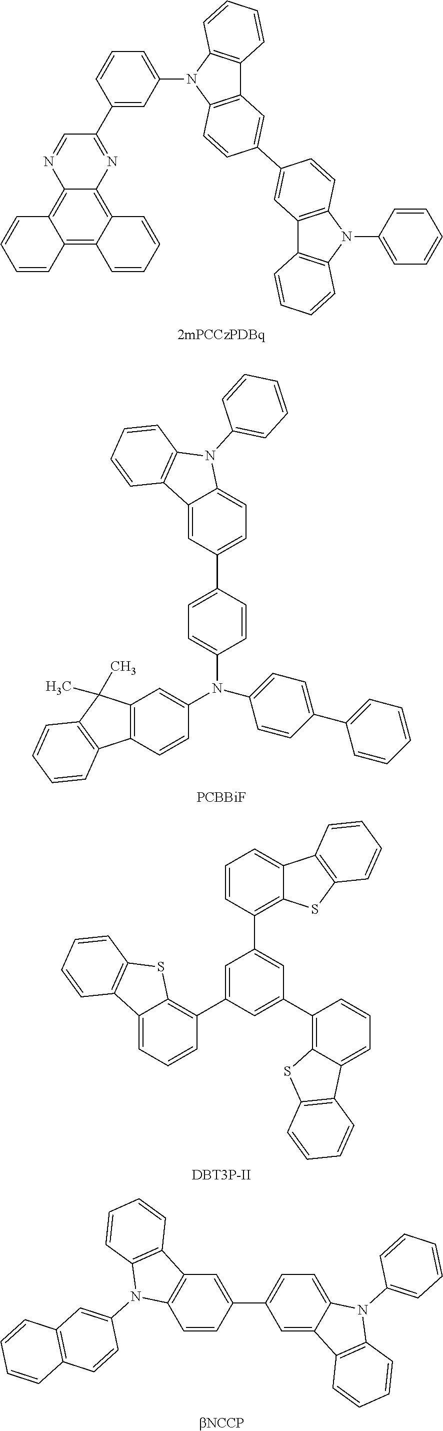

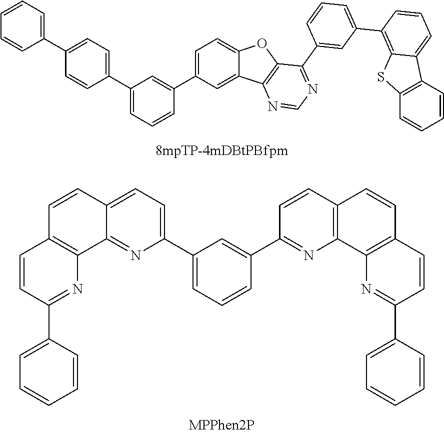 [SMILES: c1ccc(-c2ccc(-c3cccc(-c4ccc5oc6c(-c7cccc(-c8cccc9c8sc8ccccc89)c7)ncnc6c5c4)c3)cc2)cc1 ; c1ccc(-c2ccc3ccc4ccc(-c5cccc(-c6ccc7ccc8ccc(-c9ccccc9)nc8c7n6)c5)nc4c3n2)cc1]

TABLE 5

| | | | | | | | Compar- | Compar- |
|---|---|---|---|---|---|---|---|---|
| | | | Light- | Light- | Light- | Light- | ative | ative |
| | | Thick- | emitting | emitting | emitting | emitting | light- | light- |
| | | ness | device | device | device | device | emitting | emitting |
| | | (nm) | 5a | 5b | 6a | 6b | device 7a | device 7b |
| Second electrode | | 200 | Al | | | | | |
| Thick- | 2 | 75 | DBT3P- | — | DBT3P- | — | DBT3P- | — |
| ness | | | II:MoO3 | | II:MoO3 | | II:MoO3 | |
| adjustment | | | (1:0.5) | | (1:0.5) | | (1:0.5) | |
| layer | | | | | | | | |
| | 1 | 2 | CuPc | — | CuPc | — | CuPc | — |
| Electron- | | 0.1 | Li₂O | | | | | |
| injection | | | | | | | | |
| layer | | | | | | | | |
| Electron- | 2 | 20 | mPPhen2P | | | | | |
| transport | 1 | 10 | 2mPCCzPDBq | | | | | |
| layer | | | | | | | | |

| | | | | |
|---|---|---|---|---|
| Light- | 40 | 8mpTP- | 8mpTP- | 8mpTP- |
| emitting | | 4mDBtPBfpm:βNCCP:Complex (100) | 4mDBtPBfpm:βNCCP:Complex (101) | 4mDBtPBfpm:βNCCP:Complex (c) |
| layer | | (0.40:0.60:0.10) | (0.40:0.60:0.10) | (0.40:0.60:0.10) |

| | | |
|---|---|---|
| Hole-transport layer | 50 | PCBBiF |
| Hole-injection layer | 10 | PCBBiF:OCHD-003 (1:0.03) |
| First electrode | 70 | ITSO |

As shown in the above table, each of the light-emitting devices 5a and 5b uses Complex (100) as a light-emitting material. Each of the light-emitting devices 6a and 6b uses Complex (101) as a light-emitting material. Each of the comparative light-emitting devices 7a and 7b uses Complex (c) as a light-emitting material.

### (Fabrication of Light-Emitting Device 5a)

The light-emitting device 5a for orientation measurement has a structure in which, as illustrated in FIG. 30B, the hole-injection layer 911, the hole-transport layer 912, the light-emitting layer 913, the electron-transport layer 914 (the first electron-transport layer 914-1 and the second electron-transport layer 914-2), and the electron-injection layer 915 are stacked in this order over the first electrode 901 formed over the substrate 900, and a thickness adjustment layer 920 (a first thickness adjustment layer 920-1 and a second thickness adjustment layer 920-2) for front luminance reduction and the second electrode 902 are stacked over the electron-injection layer 915.

The light-emitting device 5a is different from the light-emitting device 1, whose fabrication method is described in Example 3, in the mixing ratio of the materials included in the light-emitting layer 113, the structure of the electron-injection layer 915, and the additionally formed thickness adjustment layer 920 (the first thickness adjustment layer 920-1 and the second thickness adjustment layer 920-2) between the electron-injection layer 915 and the second electrode 902. The other components were formed in the same manner as those in the light-emitting device 1.

Specifically, after the formation of the hole-transport layer 912, the light-emitting layer 913 of the light-emitting device 5a was formed by co-evaporation of 8mpTP-4mDBtPBfpm, βNCCP, and Complex (100) to a thickness of 40 nm such that the weight ratio of 8mpTP-4mDBtPBfpm to βNCCP and Complex (100) was 0.40:0.60:0.10. The electron-injection layer 915 of the light-emitting device 5a was formed by evaporation of lithium oxide (Li₂O) to a thickness of 0.1 nm over the electron-transport layer 914. After that, the first thickness adjustment layer 920-1 was formed by evaporation of copper phthalocyanine (abbreviation: CuPc) to a thickness of 2 nm. Then, the second thickness adjustment layer 920-2 was formed by co-evaporation of 4,4′,4″-(benzene-1,3,5-triyl)tri(dibenzothiophene) (abbreviation: DBT3P-II) and molybdenum oxide (MoO₃) to a thickness of 75 nm such that the weight ratio of DBT3P-II to MoO₃ was 1:0.5. Then, aluminum (Al) was deposited by evaporation to a thickness of 200 nm over the second thickness adjustment layer 920-2, whereby the second electrode 902 was formed.

### (Fabrication of Light-Emitting Device 5b)

The light-emitting device 5b is a normal light-emitting device having a structure in which the thickness adjustment layer 920 of the light-emitting device 5a was not formed, that is, the front luminance was not reduced by optical path length. In other words, the light-emitting device 5b is different from the light-emitting device 5a in that the second electrode 902 was formed over the electron-injection layer 915 without the formation of the thickness adjustment layer 920 after the formation of the electron-injection layer 915 in the method for manufacturing the light-emitting device 5a. The other components were formed in the same manner as those in the light-emitting device 5a.

### (Fabrication of Light-Emitting Device 6a)

The light-emitting device 6a is a light-emitting device for orientation measurement with a structure in which Complex (100) of the light-emitting device 5a was replaced with Complex (101). In other words, the light-emitting device 6a is different from the light-emitting device 5a in that Complex (101) was used instead of Complex (100) as the light-emitting material in the light-emitting layer 913, and the other components were formed in the same manner as those in the light-emitting device 5a.

### (Fabrication of Light-Emitting Device 6b)

The light-emitting device 6b is a normal light-emitting device having a structure in which the front luminance was not reduced by optical path length and Complex (100) of the light-emitting device 5b was replaced with Complex (101). In other words, the light-emitting device 6b is different from the light-emitting device 5b in that Complex (101) was used instead of Complex (100) as the light-emitting material in the light-emitting layer 913, and the other components were formed in the same manner as those in the light-emitting device 5b.

### (Fabrication of Comparative Light-Emitting Device 7a)

The comparative light-emitting device 7a is a light-emitting device for orientation measurement with a structure in which Complex (100) of the light-emitting device 5a was replaced with Complex (c), which is an organometallic complex for comparison. In other words, the comparative light-emitting device 7a is different from the light-emitting device 5a in that Complex (c) was used instead of Complex (100) as the light-emitting material in the light-emitting layer 913, and the other components were formed in the same manner as those in the light-emitting device 5a.

### (Fabrication of Comparative Light-Emitting Device 7b)

The comparative light-emitting device 7b is a normal light-emitting device having a structure in which the front luminance was not reduced by optical path length and Complex (100) of the light-emitting device 5b was replaced with Complex (c). In other words, the comparative light-emitting device 7b is different from the light-emitting device 5b in that Complex (c) was used instead of Complex (100) as the light-emitting material in the light-emitting layer 913, and the other components were formed in the same manner as those in the light-emitting device 5b.

The above light-emitting devices were each sealed using a glass substrate in a glove box containing a nitrogen atmosphere so as not to be exposed to the air (a sealing material was applied to surround the device and UV treatment and heat treatment at 80° C. for an hour were performed at the time of sealing). Then, the initial characteristics of the light-emitting devices were measured.

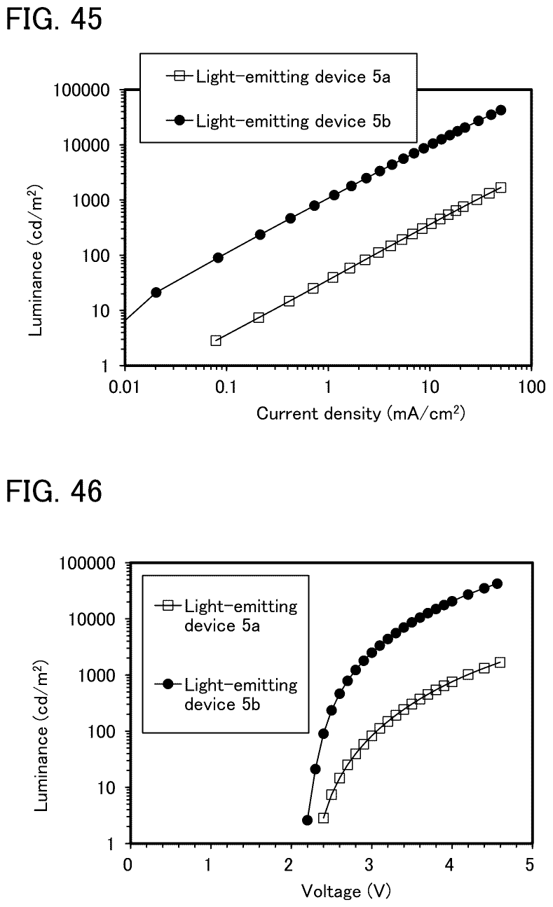

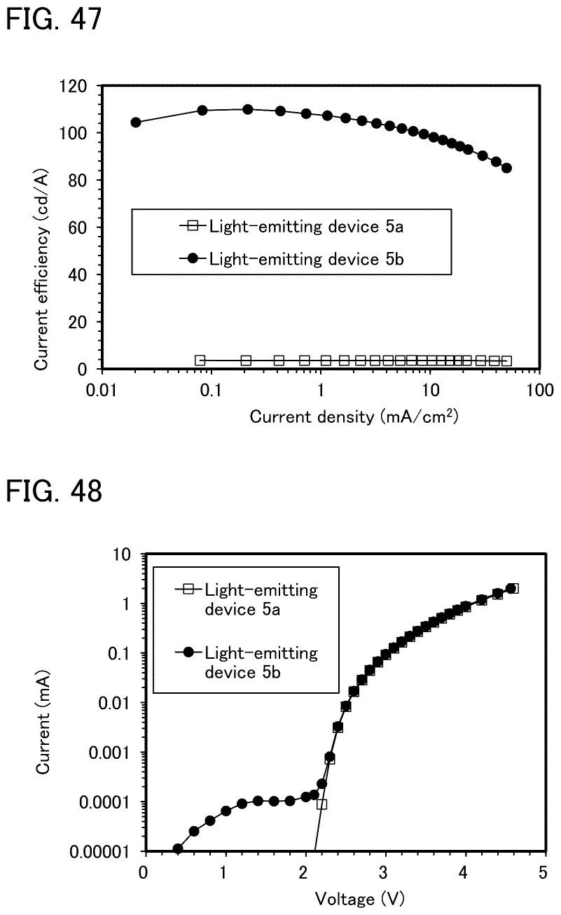

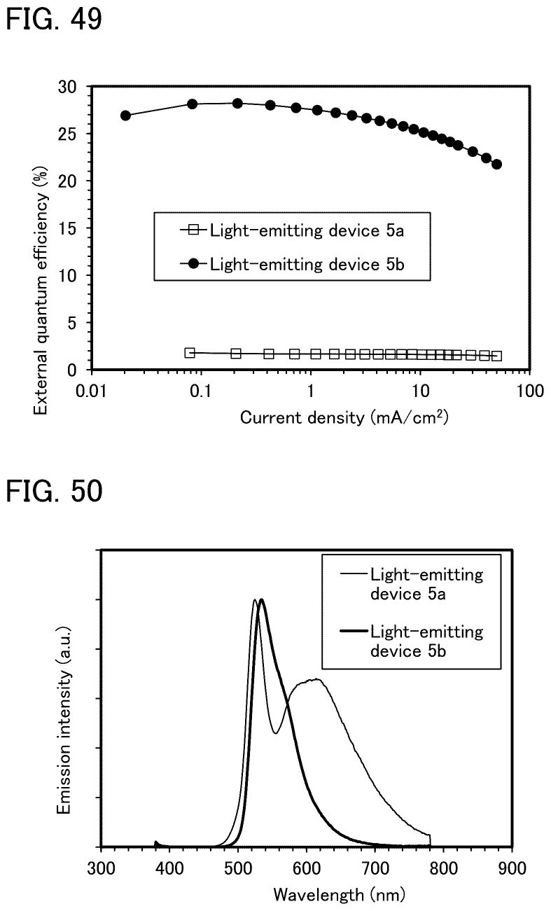

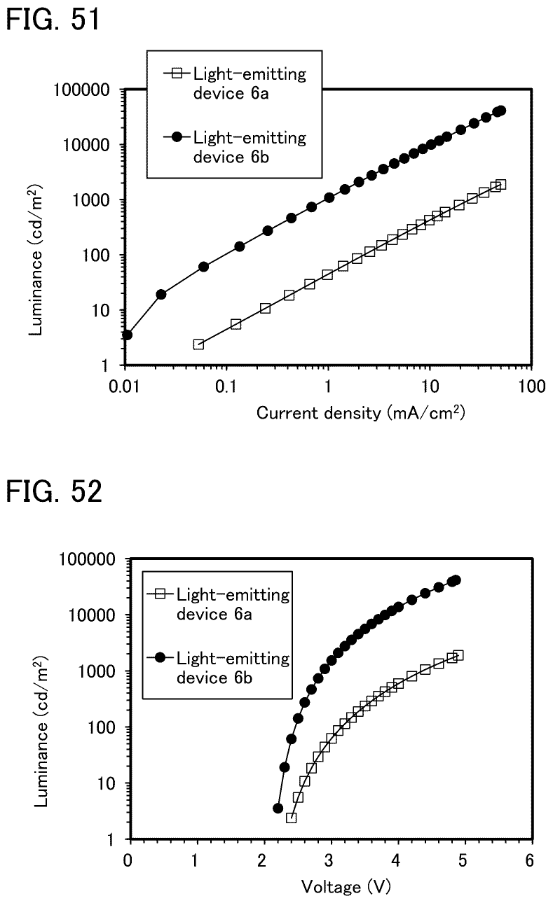

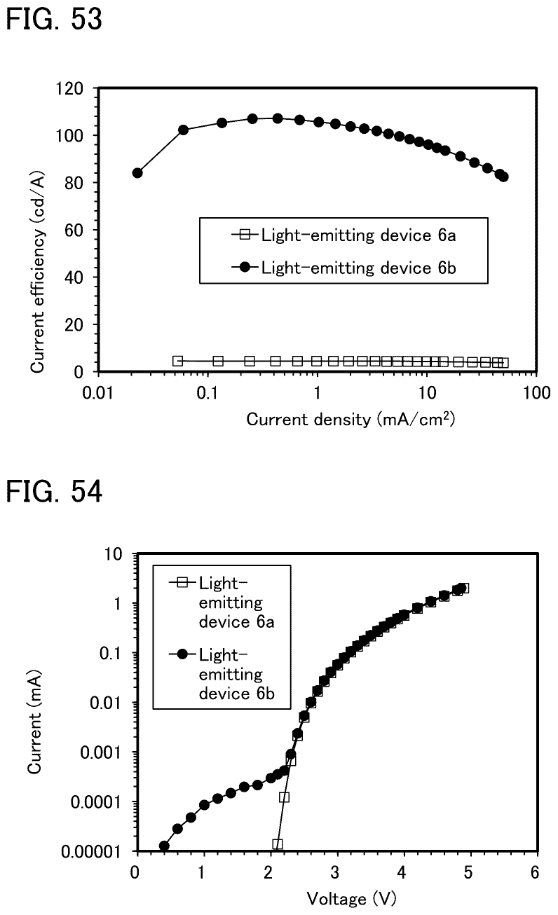

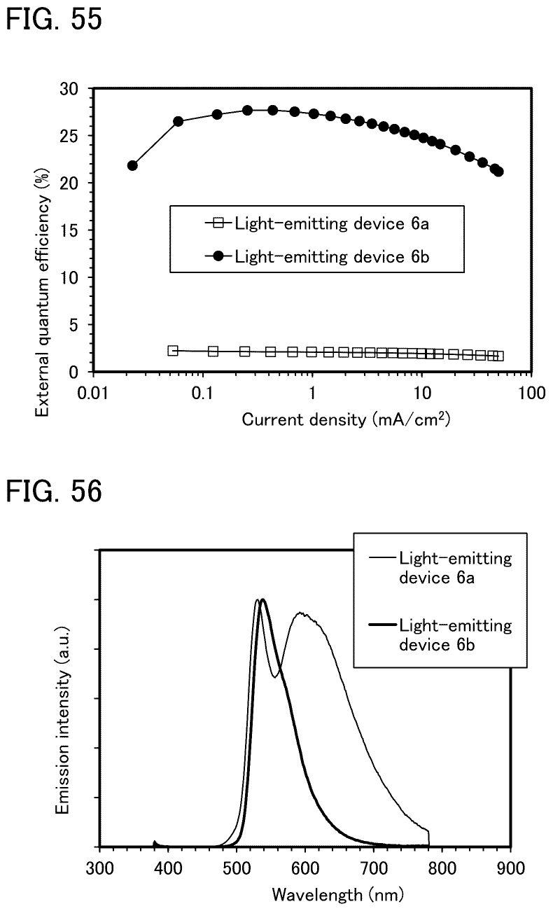

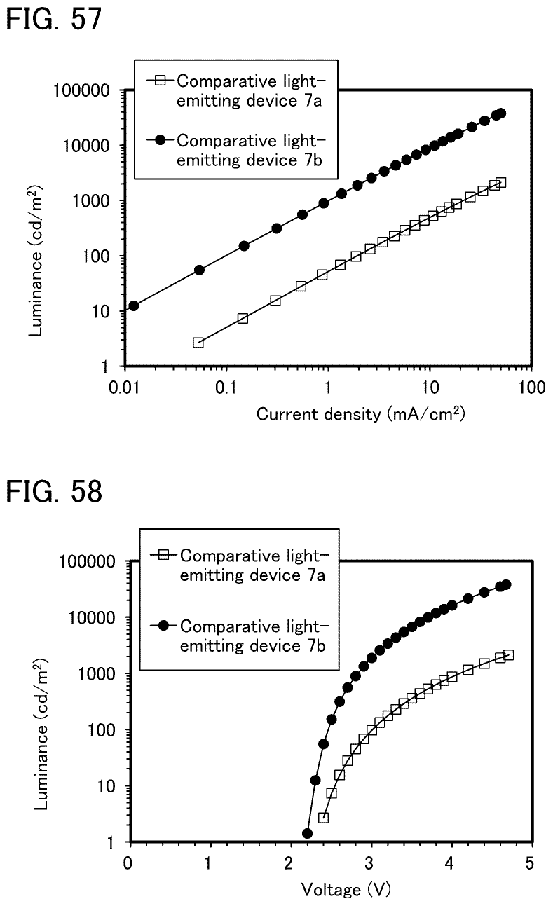

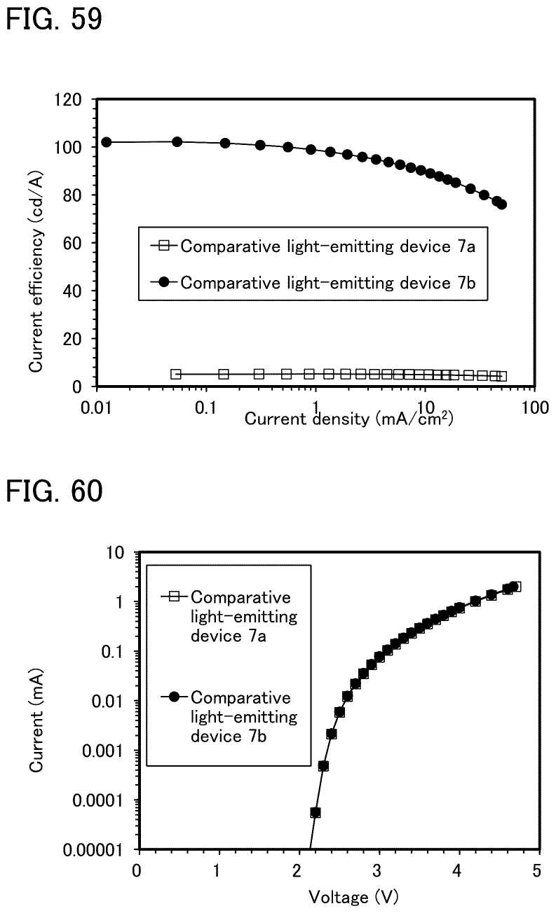

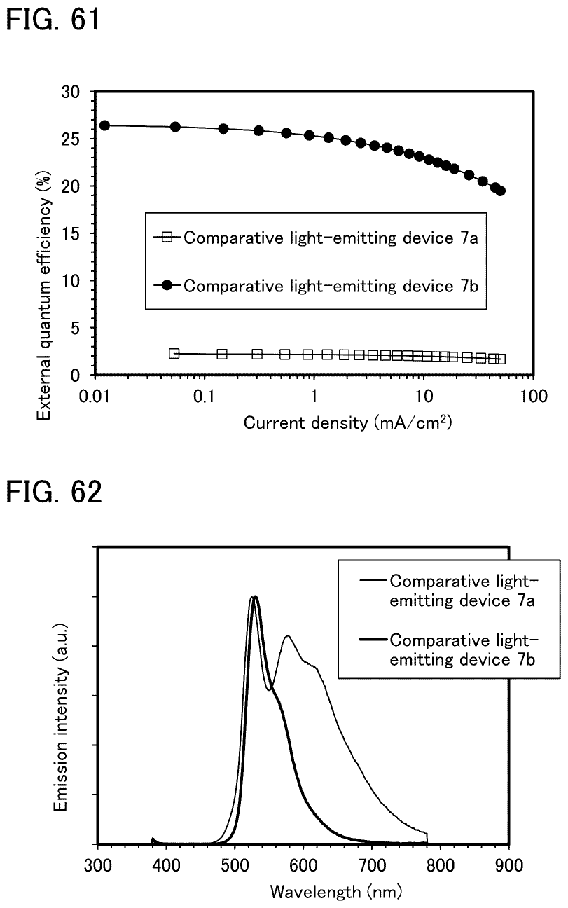

FIG. 45 shows the luminance-current density characteristics of the light-emitting devices 5a and 5b, FIG. 46 shows the luminance-voltage characteristics thereof, FIG. 47 shows the current efficiency-current density characteristics thereof, FIG. 48 shows the current-voltage characteristics thereof, FIG. 49 shows the external quantum efficiency-current density characteristics thereof, and FIG. 50 shows the electroluminescence spectra thereof. FIG. 51 shows the luminance-current density characteristics of the light-emitting devices 6a and 6b, FIG. 52 shows the luminance-voltage characteristics thereof, FIG. 53 shows the current efficiency-current density characteristics thereof, FIG. 54 shows the current-voltage characteristics thereof, FIG. 55 shows the external quantum efficiency-current density characteristics thereof, and FIG. 56 shows the electroluminescence spectra thereof. FIG. 57 shows the luminance-current density characteristics of the comparative light-emitting devices 7a and 7b, FIG. 58 shows the luminance-voltage characteristics thereof, FIG. 59 shows the current efficiency-current density characteristics thereof, FIG. 60 shows the current-voltage characteristics thereof, FIG. 61 shows the external quantum efficiency-current density characteristics thereof, and FIG. 62 shows the electroluminescence spectra thereof. Table 6 shows the main characteristics of the light-emitting devices at a luminance of approximately 1000 cd/m². Note that the luminance, CIE chromaticity, and electroluminescence spectra were measured with a spectroradiometer (SR-UL1R manufactured by TOPCON TECHNOHOUSE CORPORATION).

TABLE 6

| | | | | | | | | External |
|---|---|---|---|---|---|---|---|---|
| | | | Current | | | | Current | quantum |
| | Voltage | Current | density | Chromaticity | Chromaticity | Luminance | efficiency | efficiency |
| | (V) | (mA) | (mA/cm²) | x | y | (cd/m²) | (cd/A) | (%) |
| Light-emitting | 4.2 | 1.2 | 29 | 0.45 | 0.52 | 1017 | 3.5 | 1.5 |
| device 5a | | | | | | | | |
| Light-emitting | 2.7 | 0.029 | 0.73 | 0.37 | 0.62 | 792 | 108 | 28 |
| device 5b | | | | | | | | |
| Light-emitting | 4.4 | 1.0 | 26 | 0.48 | 0.50 | 1050 | 4.0 | 1.8 |
| device 6a | | | | | | | | |
| Light-emitting | 2.9 | 0.041 | 1.0 | 0.39 | 0.60 | 1084 | 106 | 27 |
| device 6b | | | | | | | | |
| Comparative | 4.0 | 0.73 | 18 | 0.45 | 0.52 | 868 | 4.7 | 1.9 |
| light-emitting | | | | | | | | |
| device 7a | | | | | | | | |
| Comparative | 2.8 | 0.036 | 0.90 | 0.34 | 0.63 | 892 | 99 | 25 |
| light-emitting | | | | | | | | |
| device 7b | | | | | | | | |

FIG. 45 to FIG. 62 and the above table show that the light-emitting devices 5a and 6a and the comparative light-emitting device 7a, in each of which the front luminance was attenuated by the thickness adjustment layer, have lower emission efficiency than light-emitting devices 5b and 6b and the comparative light-emitting device 7b

Next, the orientation characteristics of the light-emitting devices 5a and 6a and the comparative light-emitting device 7a were measured and calculated.

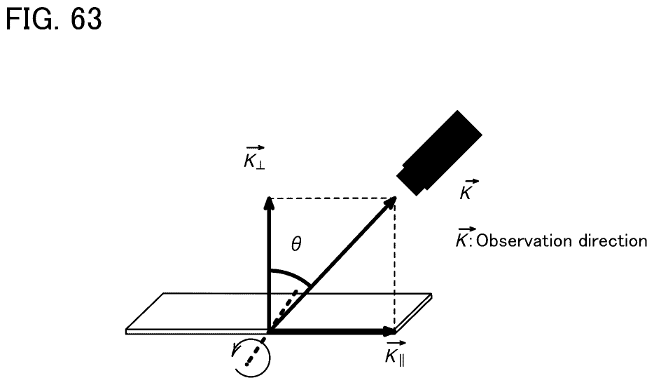

First, an EL emission spectrum was measured in steps of 10 in the following manner: the substrate provided with the light-emitting device for orientation measurement (any of the light-emitting devices 5Aa, 6a, and 7a) was inclined to a detector (a multi-channel spectrometer PMA-12, produced by Hamamatsu Photonics K.K.) so that the line perpendicular to the surface makes θ=0° to 80°, as shown in FIG. 63, to obtain the angle dependence of the shape of the EL emission spectrum. Here, a linear polarizer (Glan-Taylor prism) was disposed between the light-emitting device for orientation measurement and the detector in the direction perpendicular to the substrate surface, thereby removing an S polarization from light emitted from the light-emitting device for orientation measurement to enable the measurement of the spectrum of only a P polarization.

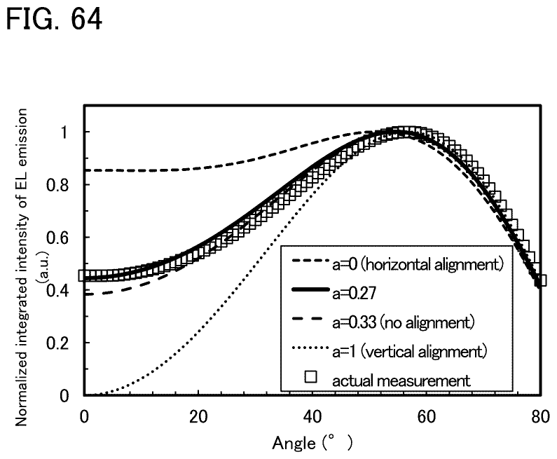

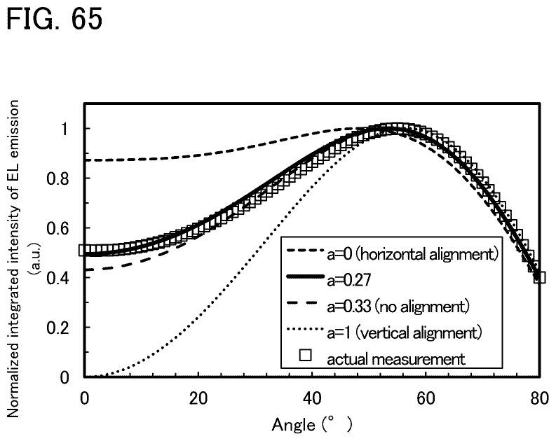

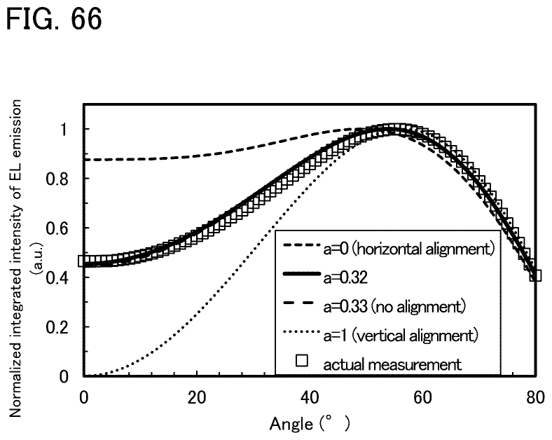

FIG. 64, FIG. 65, and FIG. 66 are graphs in each of which the vertical axis represents the integrated intensity of the EL emission spectrum in the range of 480 nm to 790 nm depending on the angle (θ) and the horizontal axis represents the angle (θ) of the detector to the substrate. FIG. 64 shows the results of the light-emitting device 5a, FIG. 65 shows the results of the light-emitting device 6a, and FIG. 66 shows the results of the light-emitting device 7a.

In each graph, a curve plotted by open squares represents the measured values, and a solid curve and a dashed curve represent the calculation results obtained by setfos (Cybernet Systems Co., Ltd.), which is an organic device simulator. The calculation was performed by inputting the thickness of each layer in each light-emitting device, the measured values of the refractive index and the extinction coefficient, the measured value of the emission spectrum of the organometallic complex, the position and the width of a light-emitting region, and the molecular orientation parameter a.

Among them, the thickness of each layer, the refractive index, and the extinction coefficient were measured with a spectroscopic ellipsometer (M-2000U, produced by J.A. Woollam Japan). A film used for the measurement was formed by deposition of the material to a thickness of 50 nm over a quartz substrate by a vacuum evaporation method.

The emission spectrum of the organometallic complex was measured with a detector (a multi-channel spectrometer PMA-12, produced by Hamamatsu Photonics K.K.). A film used for the measurement was formed to a thickness of 50 nm over a quartz substrate by co-evaporation using a vacuum evaporation method, with the same composition as the light-emitting layer of the light-emitting device for orientation measurement.

Furthermore, the light-emitting region was set in the calculation by setfos. In the light-emitting device 5a, the state of the light-emitting region was assumed in which the recombination probability shows a Gaussian attenuation curve with respect to the cathode direction and the anode direction with a point 20 nm away from the interface between the hole-transport layer and the light-emitting layer in the cathode direction as a top, and the light-emitting region was set to spread such that the standard deviation a of the Gaussian function was 7.4 nm. In the light-emitting device 6a, the state of the light-emitting region was assumed in which the recombination probability shows a Gaussian attenuation curve with respect to the cathode direction with the interface between the hole-transport layer and the light-emitting layer as a top, and the light-emitting region was set to spread such that the standard deviation a of the Gaussian function was 17 nm. In the comparative light-emitting device 7a, the state of the light-emitting region was assumed in which the recombination probability shows a Gaussian attenuation curve with respect to the cathode direction and the anode direction with a point 26 nm away from the interface between the hole-transport layer and the light-emitting layer in the cathode direction as a top, and the light-emitting region was set to spread such that the standard deviation a of the Gaussian function was 13 nm. Note that the reason why the light-emitting regions of the light-emitting devices are set in different manners is that the carrier recombination region changes depending on the carrier-trapping property, which differs between the organometallic complexes in the light-emitting layers.

In this manner, the angle dependence of the integrated intensity of the emission spectrum corresponding to each molecular orientation parameter a can be calculated. As shown in FIG. 64, the measured value of the light-emitting device 5a agrees well with the value calculated from the case with a=0.27. As shown in FIG. 65, the measured value of the light-emitting device 6a agrees well with the value calculated from the case with a=0.27. As shown in FIG. 66, the measured value of the light-emitting device 7a agrees well with the value calculated from the case with a=0.32.

The above results show that, in the light-emitting devices 5a and 6a, the transition dipole moment involved in light emission of the organometallic complex as the light-emitting material in the light-emitting layer is more easily parallel to the substrate than in the comparative light-emitting device 7a. This means that, in the complexes (100) and (101), the transition dipole moments are more easily aligned parallel to the substrate than in Complex (c).

### Example 6

This example describes calculation results to show the orientation characteristics of the organometallic complexes of one embodiment of the present invention used as the light-emitting materials in light-emitting devices. Note that in this example, Ir(5mppy-d₃)₂(mbfpy5m4ppy-d₆) (Structural Formula (100)) is referred to as Complex (100), Ir(dmppy-d₆)₂(mbfpy5m4ppy-d₆) (Structural Formula (101)) is referred to as Complex (101) and Ir(5mppy-d₃)₂(mbfpypy-d₃), which is a comparative organometallic complex, is referred to as Complex (c). Structural formulae of the complexes (100), (101), and (c) are shown below.

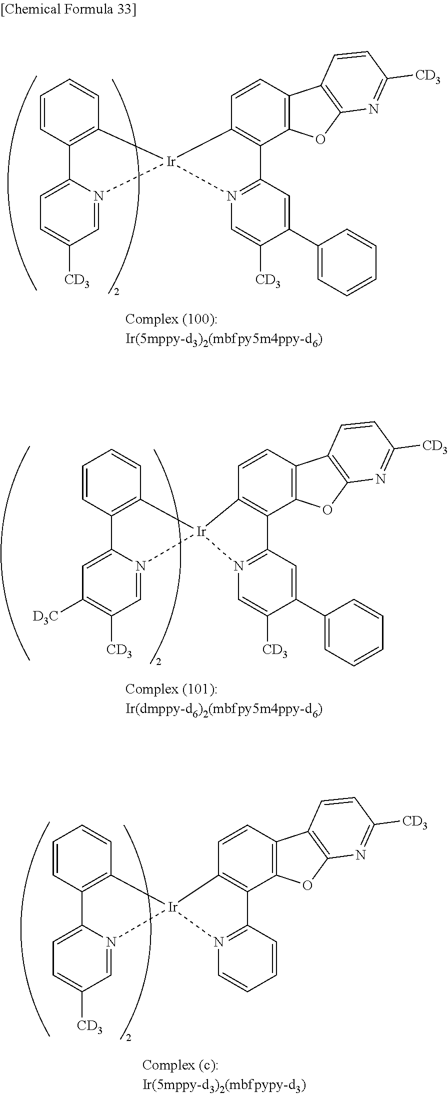

The structure subjected to quantum chemical calculation was sampled by conformational analysis in MacroModel with Maestro GUI produced by Schrodinger, Inc. The quantum chemical calculation software, Jaguar, was used to calculate the most stable structure in the singlet ground state by the density functional theory (DFT), whereby the most stable conformational structure was determined. This structure was subjected to calculation under the following conditions to obtain the most stable structure: as basis functions, DYALL-2ZCVP_ZORA-J-PT-GEN++ was used for an iridium atom and LACVP** was used for the other atoms; B3PW91 was used as a functional; time-dependent density functional theory (TD-DFT) using spin-free ZORA relativistic Hamiltonian was employed; and the excited state was the triplet state. The above structure was also subjected to single point energy calculation of the excited state using spin-orbital ZORA relativistic Hamiltonian, whereby the transition dipole moment was visualized.

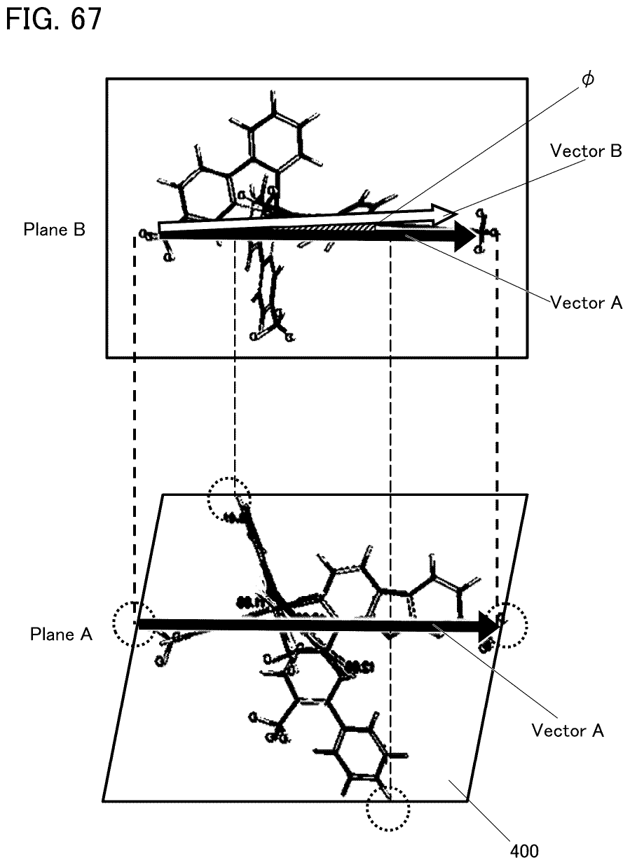

In the same structure, the vector A is defined as a vector connecting the two most distant atoms. The plane A is defined as a plane that includes the vector A and corresponds to the largest area of a quadrilateral surrounding an atomic group that is included in the organometallic complex and projected perpendicularly onto the plane. The plane B is defined as a plane that is perpendicular to the plane A and includes the vector A. The vector B is defined as a transition dipole moment involved in light emission of the organometallic complex. The vector B′ is defined as a vector obtained by projecting the vector B onto the plane B. Note that the direction of the vector A is determined such that an angle between the vectors A and B is less than or equal to 90°. Then, the magnitude of the vector A (nm), the magnitude of the vector B (debye), and the angle (ϕ) between the vectors A and B′ are obtained, and the formula, (the magnitude of the vector A)×(the magnitude of the vector B (debye))×cos ϕ, is calculated to find the inner product. FIG. 67 illustrates the vectors and ϕ in Complex (100), as an example. FIG. 67 illustrates a quadrilateral 400 surrounding Complex (100) on the plane A. The calculation results are listed in a table below.

TABLE 7

| | Magnitude of | Magnitude of | | |
|---|---|---|---|---|
| | vector A | vector B | φ | Inner |
| | (nm) | (debye) | (°) | product |
| Complex (100) | 1.69 | 0.89 | 5 | 1.50 |
| Complex (101) | 1.76 | 0.93 | 10 | 1.61 |
| Complex (c) | 1.69 | 0.44 | 30 | 0.64 |

It is found that, according to the orientation parameters a obtained in the experiment shown in Example 5, the complexes (100) and (101) have better orientation characteristics than Complex (c). This result probably correlates to the angle (ϕ) between the vectors A and B′ and the inner product, as shown in Table 7. In each of the organometallic complexes referred to as the complexes (100) and (101), the transition dipole moment contributes significantly to an improvement in emission efficiency and thus a light-emitting device formed using the organometallic complex can have high emission efficiency. By contrast, in Complex (c), the angle (ϕ) between the vectors A and B′ is large and the inner product is small, which probably leads to low planarity of a molecule and small contribution of the transition dipole moment to an improvement in emission efficiency.

This application is based on Japanese Patent Application Serial No. 2024-015113 filed with Japan Patent Office on Feb. 2, 2024, the entire contents of which are hereby incorporated by reference.

What is claimed is:

1. An organometallic complex represented by General Formula (G1), 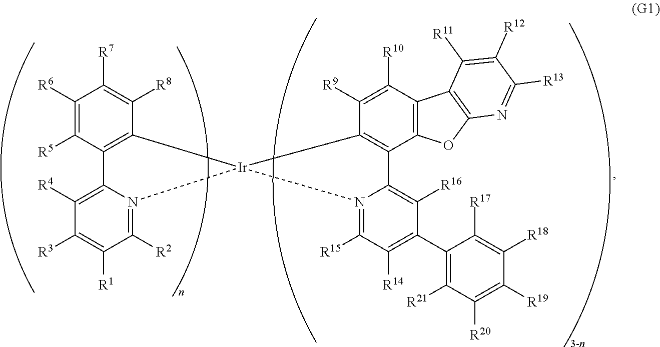
wherein:
each of R¹, R¹³, and R¹⁴ independently represents an alkyl group that has 1 to 6 carbon atoms and comprises deuterium;
each of R² to R¹² independently represents hydrogen or an alkyl group that has 1 to 6 carbon atoms and comprises deuterium;
each of R¹⁵ to R²¹ independently represents hydrogen; and
n represents 1 or 2.

2. The organometallic complex according to claim 1,
wherein the organometallic complex is represented by General Formula (G2),

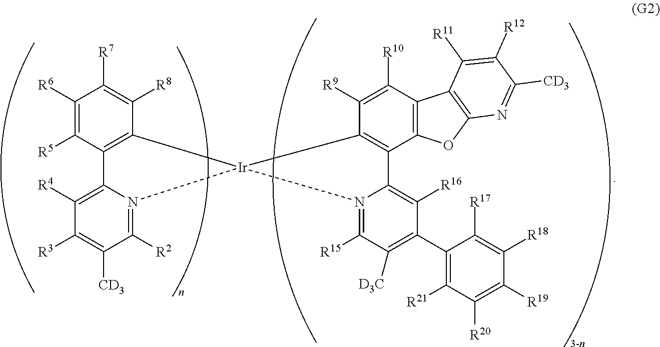

3. The organometallic complex according to claim 1,
wherein n is 2.

4. The organometallic complex according to claim 1,
wherein when a vector B is defined as a transition dipole moment involved in light emission of the organometallic complex, the vector B is greater than or equal to 0.5 debye.

5. The organometallic complex according to claim 1,
wherein a vector A is defined as a vector connecting two most distant atoms in a lowest triplet excited state of the organometallic complex, the organometallic complex comprising an atomic group,
wherein a plane A is defined as a plane that comprises the vector A and corresponds to a largest area of a quadrilateral surrounding the atomic group projected perpendicularly onto the plane,
wherein a plane B is defined as a plane that is perpendicular to the plane A and comprises the vector A,
wherein a vector B is defined as a transition dipole moment involved in light emission of the organometallic complex,
wherein a vector B′ is defined as a vector obtained by projecting the vector B onto the plane B,
wherein an angle between the vector B′ and the vector A is less than or equal to 25°, and
wherein a direction of the vector A is determined such that an angle between the vector A and the vector B is less than or equal to 90°.

6. The organometallic complex according to claim 1,
wherein the organometallic complex is represented by Structural Formula (100) or Structural Formula (101),

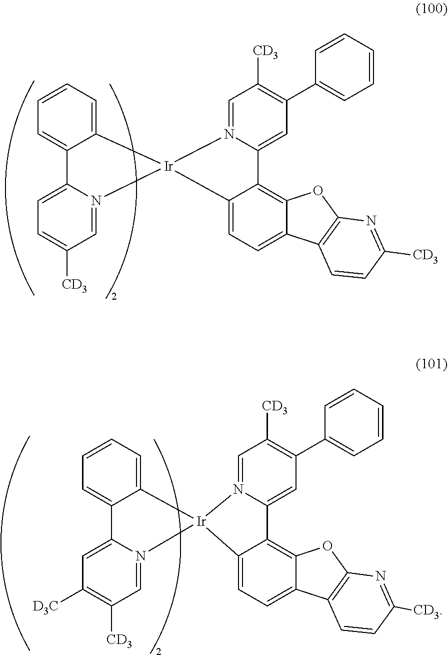

7. A light-emitting device comprising the organometallic complex according to claim 1.

8. A light-emitting device comprising:
an organometallic complex as a light-emitting material in a light-emitting layer,
wherein the organometallic complex comprises a first ligand and a second ligand,
wherein the first ligand comprises a benzene ring and a pyridine ring,
wherein a carbon at a 2-position of the pyridine ring is bonded to the benzene ring,
wherein the second ligand comprises a benzofuro[2,3-b]pyridine ring, and
wherein a molecular orientation parameter a of light emitted from the light-emitting device is less than or equal to 0.28.
